(19) United States
(12) Patent Application Publication
(10) Pub. No.: US 2022/0059781 A1
(43) Pub. Date: Feb. 24, 2022

(54) ORGANOMETALLIC COMPOUND, ORGANIC LIGHT-EMITTING DEVICE INCLUDING THE SAME, AND ELECTRONIC APPARATUS INCLUDING THE ORGANIC LIGHT-EMITTING DEVICE

(71) Applicant: Samsung Electronics Co., Ltd., Suwon-si (KR)

(72) Inventors: Jeoungin Yi, Seoul (KR); Seungyeon Kwak, Suwon-si, Gyeonggi-do (KR); Yoonhyun Kwak, Seoul (KR); Juhyun Kim, Seoul (KR); Sangho Park, Anyang-si (KR); Myungsun Sim, Suwon-si (KR); Sunyoung Lee, Seoul (KR)

(21) Appl. No.: 17/407,626

(22) Filed: Aug. 20, 2021

(30) Foreign Application Priority Data
Aug. 21, 2020 (KR) 10-2020-0105532
Aug. 19, 2021 (KR) 10-2021-0109382

(51) Int. Cl. H01L 51/00; C07F 15/00; C09K 11/06

(52) U.S. Cl. CPC H01L 51/0085; H01L 51/5012; C09K 11/06; C07F 15/0086

(57) ABSTRACT

An organometallic compound represented by Formula 1:

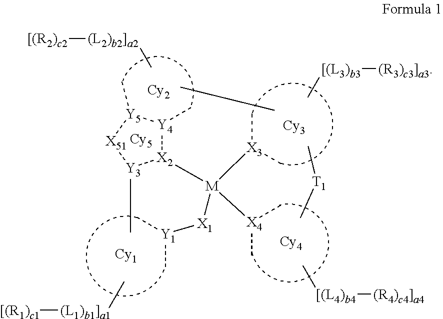

wherein, M is a transition metal; X₁ is a chemical bond, O, S, N(R′), P(R′), B(R′), C(R′)(R″), or Si(R′)(R″); X₂ to X₄ are each independently C or N; a bond between X₁ or Y₁ and M is a covalent bond; one of a bond between X₂ and M, X₃ and M, and X₄ and M is covalent and the other two are coordinate; Y₁ and Y₃-Y₅ are each independently C or N; ring CY₁ to ring CY₄ are each independently a C₅-C₃₀ carbocyclic group or a C₁-C₃₀ heterocyclic group, and at least one of ring CY₁ to ring CY₄ is independently a condensed cyclic group wherein two or more rings are condensed with each other; and T₁, X₅₁, L₁ to L₄; R₁ to R₄, a1 to a4, b1 to b4, and c1 to c4 are as described herein.

### CROSS-REFERENCE TO RELATED APPLICATION

This application claims priority to and the benefit of Korean Patent Application No. 10-2020-0105532, filed on Aug. 21, 2020, and Korean Patent Application 10-2021-0109382, filed on Aug. 19, 2021, both in the Korean Intellectual Property Office, and all the benefits accruing therefrom under 35 U.S.C. § 119, the contents of which are incorporated by reference herein in their entireties.

### BACKGROUND

### 1. Field

One or more embodiments relate to an organometallic compound, an organic light-emitting device including the same, and an electronic apparatus including the organic light-emitting device.

### 2. Description of the Related Art

Organic light-emitting devices are self-emissive devices, which have improved characteristics in terms of viewing angles, response time, brightness, driving voltage, and response speed, and produce full-color images.

In an example, an organic light-emitting device includes an anode, a cathode, and an organic layer between the anode and the cathode, wherein the organic layer includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transition from an excited state to a ground state to thereby generate light.

### SUMMARY

One or more embodiments relate to an organometallic compound, an organic light-emitting device including the same, and an electronic apparatus including the organic light-emitting device.

Additional aspects will be set forth in part in the description, which follows and, in part, will be apparent from the description, or may be learned by practice of the presented embodiments of the disclosure.

An aspect of the present disclosure provides an organometallic compound represented by Formula 1:

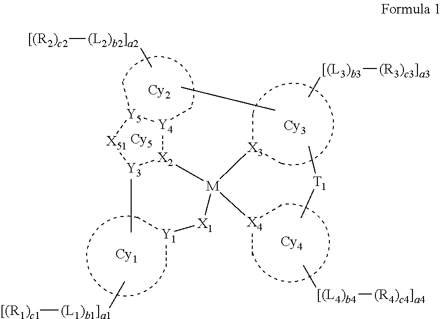

wherein, in Formula 1,

M is a transition metal,

X₁ is a chemical bond, O, S, N(R′), P(R′), B(R′), C(R′)(R″), or Si(R′)(R″), and when X₁ is a chemical bond, Y₁ is directly bonded to M,

X₂ to X₄ are each independently C or N,

a bond between X₁ or Y₁ and M is a covalent bond, one of a bond between X₂ and M, a bond between X₃ and M, and a bond between X₄ and M is a covalent bond, and the other two bonds are coordinate bonds,

Y₁ and Y₃ to Y₅ are each independently C or N,

X₂ and Y₃ are connected to each other via a chemical bond, X₂ and Y₄ are connected to each other via a chemical bond, Y₄ and Y₅ are connected to each other via a chemical bond, X₅₁ and Y₃ are connected to each other via a chemical bond, and X₅₁ and Y₅ are connected to each other via a chemical bond,

ring CY₁ to ring CY₄ are each independently a C₅-C₃₀ carbocyclic group or a C₁-C₃₀ heterocyclic group, and at least one of ring CY₁ to ring CY₄ are each independently a condensed cyclic group wherein two or more rings are condensed with each other,

a cyclometallated ring formed between ring CY₅, ring CY₂, ring CY₃, and M is a 6-membered ring,

T₁ is a single bond, a double bond, *—N(R₅)—*′, *—B(R₅)—*′, *—P(R₅)—*′, *—C(R₅)(R₆)—*, *—Si(R₅)(R₆)—*′, *—Ge(R₅)(R₆)—*′, *—S—*′, *—Se—*′, *—O—*′, *—C(═O)—*′, *—S(═O)—*′, *—S(═O)₂—*′, *—C(R₅)=*′, *═C(R₅)—*′, *—C(R₅)═C(R₆)—*′, *—C(═S)—*′ or *—C≡C—*′, and each of * and *′ is a binding site to a neighboring atom,

X₅₁ is N-[(L₇)_{b7}-(R₇)_{c7}],

L₁ to L₄ and L₇ are each independently a single bond, a C₅-C₃₀ carbocyclic group that is unsubstituted or substituted with at least one R₁₀ₐ, or a C₁-C₃₀ heterocyclic group that is unsubstituted or substituted with at least one R₁₀ₐ,

b1 to b4 and b7 are each independently 1, 2, 3, 4, or 5,

R₁ to R₇, R′, and R″ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

c1 to c4 and c7 are each independently 1, 2, 3, 4, or 5,

at least one of R₇ in number of c7 is a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,

a1 to a4 are each independently 0, 1, 2, 3, 4, or 5,

two or more of a plurality of R₁(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of a plurality of R₂(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of a plurality of R₃(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of a plurality of R₄(s) are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of R₁ to R₄ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

R₁₀ₐ is as described in connection with R₁, and

the substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:

deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₁₀ alkynyl group, a C₁-C₁₀ alkoxy group, or a C₁-C₆₀ alkylthio group;

a C₁-C₆ alkyl group, a C₂-C₆₀ alkenyl group, a C₂-C₁₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₇-C₆₀ alkyl aryl group, a C₇-C₆₀ aryl alkyl group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₁₀ heteroaryl group, a C₂-C₁₀ alkyl heteroaryl group, a C₂-C₁₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof,

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉), or

a combination thereof,

wherein Q₁ to Q₉, Q₁₁ to Q₁₉, Q₂₁ to Q₂₉, and Q₃₁ to Q₃₉ are each independently hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group that is unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group that is unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a C₂-C₆₀ alkyl heteroaryl group; a C₂-C₆₀ heteroaryl alkyl group; a C₁-C₆₀ heteroaryloxy group; a C₁-C₆₀ heteroarylthio group; a monovalent non-aromatic condensed polycyclic group; or a monovalent non-aromatic condensed heteropolycyclic group, and

wherein Formula 1 satisfies at least one of Condition A, Condition B, Condition C and Condition D:

Condition A

a group represented by *-[(L₇)_{b7}-(R₇)_{c7}] in N-[(L₇)_{b7}-(R₇)_{c7}] is a group represented by Formula N51:

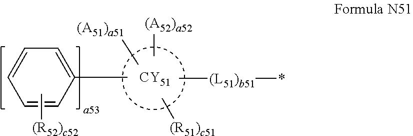

wherein, in Formula N51,

ring CY₅₁ is a C₅-C₃₀ carbocyclic group or a C₁-C₃₀ heterocyclic group,

L₅₁, b51, R₅₁, and c51 are each as described in connection with L₇, b₇, R₇, and c7,

R₅₂ and c52 are each as described in connection with R₇ and c7,

A₅₁ is a C₁-C₆₀ alkyl group,

A₅₂ is a deuterated C₁-C₆₀ alkyl group,

a51 and a52 are each independently an integer from 0 to 10, and the sum of a51 and a52 is an integer of 1 or more,

a53 is an integer from 1 to 10, and

* indicates a binding site to a neighboring nitrogen atom,

Condition B

the ring CY₁ is a condensed cyclic group wherein two or more rings are condensed with each other,

Condition C

the ring CY₃ is a condensed cyclic group wherein two or more rings are condensed with each other,

a4 is 1, 2, 3, 4, or 5, and

at least one of R₄ in number of c4 is a C₁-C₆₀ alkyl group substituted with at least one C₆-C₆₀ aryl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,

Condition D

the ring CY₄ is a condensed cyclic group wherein two or more rings are condensed with each other,

a3 is 1, 2, 3, 4, or 5, and

at least one of R₃ in number of c3 is a C₁-C₆₀ alkyl group substituted with at least one C₆-C₆₀ aryl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

According to another aspect, provided is an organic light-emitting device including a first electrode, a second electrode, and an organic layer located between the first electrode and the second electrode, wherein the organic layer includes an emission layer, and wherein the organic layer further includes at least one organometallic compound represented by Formula 1.

The organometallic compound contained in the emission layer of the organic layer may act as a dopant.

Another aspect provides an electronic apparatus including the organic light-emitting device.

### BRIEF DESCRIPTION OF THE DRAWING

The above and other aspects, features, and advantages of certain embodiments of the disclosure will be more apparent from the following description taken in conjunction with

FIGURE which shows a schematic cross-sectional view of an organic light-emitting device according to one or more embodiments.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

The organometallic compound is represented by Formula 1:

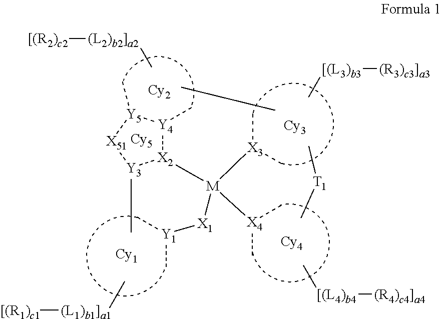

M in Formula 1 is a transition metal.

In one or more embodiments, M may be cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au).

In one or more embodiments, M may be Pt, Pd, or Au.

X₁ in Formula 1 is a chemical bond (for example, a covalent bond, a coordinate bond, or the like), O, S, N(R′), P(R′), B(R′), C(R′)(R″), or Si(R′)(R″). R′ and R″ are as described above. When X₁ is a chemical bond, Y₁ and M may directly be linked to each other.

In one or more embodiments, X₁ in Formula 1 may be O or S.

X₂ to X₄ in Formula 1 are each independently C or N.

In one or more embodiments, two of the X₂ to X₄ is N, and the other one is C.

In one or more embodiments, in Formula 1, X₂ and X₄ may each be N and X₃ may be C.

A bond between X₁ or Y₁ and M in Formula 1 is a covalent bond, one bond selected from a bond between X₂ and M, a bond between X₃ and M, and a bond between X₄ and M is a covalent bond, and the other two bonds are coordinate bonds. Thus, the organometallic compound represented by Formula 1 may be electrically neutral.

In one or more embodiments, in Formula 1, a bond between X₁ or Y₁ and M and a bond between X₃ and M may each be a covalent bond, and a bond between X₂ and M and a bond between X₄ and M may be a coordinate bond.

In one or more embodiments, in Formula 1,

i) X₂ and X₄ are each N, X₃ is C, a bond between X₂ and M and a bond between X₄ and M are each a coordinate bond, and a bond between X₃ and M is a covalent bond,

i) X₂ and X₃ may each be N, X₄ may be C, a bond between X₂ and M and a bond between X₃ and M may each be a coordinate bond, and a bond between X₄ and M may be a covalent bond, or

iii) X₃ and X₄ may each be N, X₂ may be C, a bond between X₃ and M and a bond between X₄ and M may each be a coordinate bond, and a bond between X₂ and M may be a covalent bond.

Y₁ and Y₃ to Y₅ in Formula 1 are each independently C or N.

For example, Y₁ and Y₃ to Y₅ in Formula 1 may be C.

In Formula 1, X₂ and Y₃ are connected to each other via a chemical bond, X₂ and Y₄ are connected to each other via a chemical bond, Y₄ and Y₅ are connected to each other via a chemical bond, X₅₁ and Y₃ are connected to each other via a chemical bond, and X₅₁ and Y₅ are connected to each other via a chemical bond. Accordingly, ring CY₅ in the Formula 1 may be a 5-membered ring condensed with ring CY₂.

Ring CY₁ to ring CY₄ in Formula 1 are each independently a C₅-C₃₀ carbocyclic group or a C₁-C₃₀ heterocyclic group, and at least one of ring CY₁ to ring CY₄ is a condensed cyclic group wherein two or more rings are condensed with each other.

For example, ring CY₁ to ring CY₄ may each independently be i) a first ring, ii) a second ring, iii) a condensed ring wherein two or more first rings are condensed with each other, iv) a condensed ring wherein two or more second rings are condensed with each other, or v) a condensed ring wherein one or more first rings and one or more second rings are condensed with each other,

at least one of ring CY₁ to ring CY₄ may each independently be iii) a condensed cyclic group wherein two or more first rings are condensed with each other, iv) a condensed cyclic group wherein two or more second rings are condensed with each other, or v) a condensed cyclic group wherein at least one first ring is condensed with at least one second ring,

the first ring is a cyclopentane group, a cyclopentadiene group, a furan group, a thiophene group, a pyrrole group, a silole group, a germole group, a borole group, a phosphole group, a selenophene group, an oxazole group, an oxadiazole group, an oxatriazole group, a thiazole group, a thiadiazole group, a thiatriazole group, a pyrazole group, an imidazole group, a triazole group, a tetrazole group, an azasilole group, an azagermole group, an azaborole group, an azaphosphole group, or an azaselenophene group, and

the second ring is an adamantane group, a norbornane group, a norbornene group, a bicyclo[1.1.1]pentane group, a bicyclo[2.1.1]hexane group, a bicyclo[2.2.2]octane group, a cyclohexane group, a cyclohexene group, a benzene group, a pyridine group, a pyrimidine group, a pyrazine group, a pyridazine group, or a triazine group.

In one or more embodiments, ring CY₁ to ring CY₄ may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, an imidazole group, a triazole group, an oxazole group, an isooxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, an adamantane group, a norbornane group, a norbornene group, a benzene group condensed with a cyclohexane group, a benzene group condensed with an adamantane group, a benzene group condensed with a norbornane group, a 5,6,7,8-tetrahydroisoquinoline group, a 5,6,7,8-tetrahydroquinoline group, a pyridine group condensed with an adamantane group, or a pyridine group condensed with a norbornane group.

In one or more embodiments, at least one of ring CY₁ to ring CY₄ (for example, at least one of ring CY₁, CY₃, and CY₄) may each independently be a naphthalene group, an anthracene group, a phenanthrene group, a triphenylene group, a pyrene group, a chrysene group, a 1,2,3,4-tetrahydronaphthalene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza-9H-fluorene-9-one group, an azadibenzothiophene 5,5-dioxide group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a benzene group condensed with a cyclohexane group, a benzene group condensed with an adamantane group, a benzene group condensed with a norbornane group, a 5,6,7,8-tetrahydroisoquinoline group, a 5,6,7,8-tetrahydroquinoline group, a pyridine group condensed with an adamantane group, or a pyridine group condensed with a norbornane group.

In one or more embodiments, at least one of ring CY₁ to ring CY₄ (for example, at least one of ring CY₁, ring CY₃, and ring CY₄) may each independently be a naphthalene group, an anthracene group, a phenanthrene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenbenzosilole group, an azanaphthobenbenzoborole group, an azanaphthobenbenzophosphole group, an azanaphthobenbenzogermole group, an azanaphthobenbenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthroabenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a benzene group condensed with a cyclohexane group, a benzene group condensed with an adamantane group, a benzene group condensed with a norbornane group, a 5,6,7,8-tetrahydroisoquinoline group, a 5,6,7,8-tetrahydroquinoline group, a pyridine group condensed with an adamantane group, or a pyridine group condensed with a norbornane group.

In one or more embodiments,

ring CY₁ may be a naphthalene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group,

ring CY₃ may be a benzene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group, and

ring CY₄ may be a pyridine group, an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group.

In one or more embodiments,

ring CY₁ may be a benzene group, a naphthalene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group,

ring CY₃ may be a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group, and

ring CY₄ may be a pyridine group, an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group.

In one or more embodiments,

ring CY₁ may be a benzene group, a naphthalene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group,

ring CY₃ may be a benzene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group, and

ring CY₄ may be an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group.

In one or more embodiments, ring CY₁ in Formula 1 may not be a fluorene group and a carbazole group.

In one or more embodiments, ring CY₄ in Formula 1 may not be a benzimidazole group.

A cyclometalated ring formed between ring CY₅, ring CY₂, ring CY₃, and M in Formula 1 is a 6-membered ring.

T₁ in Formula 1 is a single bond, a double bond, *—N(R₅)—*′, *—B(R₅)—*′, *—P(R₅)—*′, *—C(R₅)(R₆)—*′, *—Si(R₅)(R₆)—*′, *—Ge(R₅)(R₆)—*′, *—S—*′, *—Se—*′, *—O—*′, *—C(═O)—*′, *—S(═O)—*′, *—S(═O)₂—*′, *—C(R₅)=*′ *═C(R₅)—*′ *—C(R₅)═C(R₆)—*′ *—C(═S)—*′, or *—C≡C—*′. * and *′ each indicate a binding site to a neighboring atom. R₅ and R₆ are as described above. R₅ and R₆ may optionally be linked to each other via a single bond, a double bond, *—N(R₅ₐ)—*′, *—B(R₅ₐ)—*′, *—P(R₅ₐ)—*′, *—C(R₅ₐ)(R₆ₐ)—*′, *—Si(R₅ₐ)(R₆ₐ)—*′, *—Ge(R₅ₐ)(R₆ₐ)—*′, *—S—*′, *—Se—*′, *-0-*′, *—C(═O)—*′, *—S(═O)—*′, *—S(═O)₂—*′ *—C(R₅ₐ)=*′, *═C(R₅ₐ)—*′, *—C(R₅ₐ)═C(R₆ₐ)—*, *—C(═S)—*′, or *—C≡C—*′ to form a C₅-C₃₀carbocyclic group that is unsubstituted or substituted with at least one R₁₀ₐ or a C₁-C₃₀ heterocyclic group that is unsubstituted or substituted with at least one R₁₀ₐ. R₅ₐ and R₆ₐ are as described in connection with R₅ and R₆, and R₁₀ₐ is as described in connection with R₁.

For example, T₁ may be a single bond.

X₅₁ in Formula 1 is N-[(L₇)_{b7}-(R₇)_{c7].}

In Formula 1, L₁ to L₄ and L₇ may each independently be a single bond, a C₅-C₃₀ carbocyclic group that is unsubstituted or substituted with at least one R₁₀ₐ, or a C₁-C₃₀ heterocyclic group that is unsubstituted or substituted with at least one R₁₀ₐ. R₁₀ₐ is as described in connection with R₁.

For example, L₁ to L₄ and L₇ in Formula 1 may each independently be:

a single bond; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with at least one R₁₀ₐ.

In one or more embodiments, L₁ to L₄ and L₇ in Formula 1 may each independently be:

a single bond; or

a benzene group that is unsubstituted or substituted with at least one R₁₀ₐ.

In one or more embodiments, L₁ to L₄ and L₇ in Formula 1 may each independently be:

a single bond; or

a benzene group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

b1 to b4 and b7 in Formula 1 indicate the numbers of L₁ to L₄ and L₇, respectively, and may each independently be 1, 2, 3, 4, or 5. When b1 is 2 or more, two or more of Li(s) may be identical to or different from each other, when b2 is 2 or more, two or more of L₂(s) may be identical to or different from each other, when b3 is 2 or more, two or more of L₃(s) may be identical to or different from each other, when b4 is 2 or more, two or more of L₄(s) may be identical to or different from each other, and when b7 is 2 or more, two or more of L₇(s) may be identical to or different from each other.

For example, b1 to b4 and b7 in Formula 1 may each independently be 1, 2, or 3.

R₁ to R₇, R′, and R″ in Formula 1 are each independently hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ are as described in the present specification.

For example, R₁ to R₇, R′, and R″ may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₁-C₂₀ alkoxy group, or a C₁-C₂₀ alkylthio group;

a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl) a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group or azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a deuterated phenyl group, a (C₁-C₂₀ alkyl)phenyl group, a biphenyl group, a deuterated biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or

—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

wherein Q₁ to Q₉ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

c1 to c4 and c7 in Formula 1 indicate the numbers of R₁ to R₄ and R₇, respectively, and may each independently be 1, 2, 3, 4 or 5. When c1 is 2 or more, two or more of R₁(s) may be identical to or different from each other, when c2 is 2 or more, two or more of R₂(s) may be identical to or different from each other, when c3 is 2 or more, two or more of R₃(s) may be identical to or different from each other, when c4 is 2 or more, two or more of R₄(s) may be identical to or different from each other, and when c7 is 2 or more, two or more of R₇(s) may be identical to or different from each other. For example, c1 to c4 and c7 may each independently be 1 or 2.

At least one of R₇ in number of c7 may be a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

For example, R₇ may be hydrogen; deuterium; a C₁-C₂₀ alkyl group; a deuterated C₁-C₂₀ alkyl group; or a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof, and at least one of R₇ in number of c7 may be a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

Regarding Formula 1, a1 to a4 respectively indicate the numbers of *-[(L₁)_{b1}-(R₁)_{c1}]*-[(L₂)_{b2}-(R₂)_{c2}], *-[(L₃)_{b3}-(R₃)_{c3}], and *-[(L₄)_{b4}-(R₄)_{c4}], and may each independently be 0, 1, 2, 3, 4, or 5. When a1 is 2 or more, two or more *-[(L₁)_{b1}-(R₁)_{c1}] may be identical to or different from each other, when a2 is 2 or more, two or more *-[(L₂)_{b2}-(R₂)_{c2}] may be identical to or different from each other, when a3 is 2 or more, two or more *-[(L₃)_{b3}-(R₃)_{c3}] may be identical to or different from each other, and when a4 is 2 or more, two or more *-[(L₄)_{b4}-(R₄)_{c4}] may be identical to or different from each other.

In one or more embodiments, in Formula 1,

a) L₁ to L₄ and L₇ may each independently be:

a single bond; or

a benzene group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof,

b) b1 to b4 and b7 may each independently be 1, 2, or 3,

c) R₁ and R₂ may each independently be hydrogen, deuterium, a C₁-C₂₀ alkyl group, or a deuterated C₁-C₂₀ alkyl group,

d) R₃ and R₄ may each independently be:

hydrogen, deuterium, a C₁-C₂₀ alkyl group, or a deuterated C₁-C₂₀ alkyl group;

a C₁-C₂₀ alkyl group substituted with at least one phenyl group; or

a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof,

e) R₇ in N-[(L₇)_{b7}-(R₇)_{c7}] number of c7 may be hydrogen; deuterium; a C₁-C₂₀ alkyl group; a deuterated C₁-C₂₀ alkyl group; or a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof, and at least one of R₇ in number of c7 may be a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof,

f) c1 to c4 and c7 may each independently be 1, 2, or 3, and

g) a1 to a4 may each independently be 0, 1, 2, or 3.

Formula 1 satisfies at least one of Condition A, Condition B, Condition C and Condition D:

Condition A

a group represented by *-[(L₇)_{b7}-(R₇)_{c7}] in N-[(L₇)_{b7}-(R₇)_{c7}] is a group represented by Formula N51,

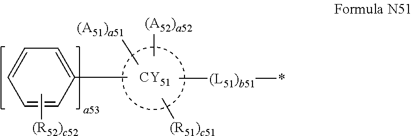

Condition B

the ring CY₁ is a condensed cyclic group wherein two or more rings are condensed with each other,

Condition C

the ring CY₃ is a condensed cyclic group wherein two or more rings are condensed with each other,

a4 is 1, 2, 3, 4, or 5, and

at least one of R₄ in number of c4 is a C₁-C₆₀ alkyl group substituted with at least one C₆-C₆₀ aryl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,

Condition D

the ring CY₄ is a condensed cyclic group wherein two or more rings are condensed with each other,

a3 is 1, 2, 3, 4, or 5, and

at least one of R₃ in number of c3 is a C₁-C₆₀ alkyl group substituted with at least one C₆-C₆₀ aryl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

Ring CY₅₁ in Formula N51 is a C₅-C₃₀ carbocyclic group or a C₁-C₃₀ heterocyclic group. Ring CY₅₁ may be understood by referring to relative description provided herein or may be as described in connection with ring CY₃. For example, ring CY₅₁ may be a benzene group.

L₅₁, b51, R₅₁ and c51 in Formula N51 are as described in connection with L₇, b7, R₇, and c7, and R₅₂ and c52 are as described in connection with R₇ and c7.

A₅₁ in Formula N51 is a C₁-C₆₀ alkyl group. For example, A₅₁ may be a C₁-C₂₀ alkyl group or a C₄-C₂₀ alkyl group.

A₅₂ in Formula N51 is a deuterated C₁-C₆₀ alkyl group. In one or more embodiments, A₅₂ may be a hydrogen-free deuterated C₁-C₂₀ alkyl group.

In one or more embodiments, Formula 1 may satisfy Condition A. When Formula 1 satisfies Condition A, an angle between a plane including the transition dipole moment of the organometallic compound and a plane including four atoms of the tetradentate ligand bonded to metal (M) of Formula 1 may be 10° or less. In one or more embodiments, the horizontal orientation ratio of the transition dipole moment of the organometallic compound represented by Formula 1 may be from about 80% to about 100%.

For example, an angle between a plane including the transition dipole moment of the organometallic compound and a plane including four atoms of the tetradentate ligand bonded to metal (or platinum) of Formula 1 may be from 0° to 10°, from 0° to 9°, from 0° to 8°, from 0° to 7°, from 0° to 6°, from 0° to 5°, from 0° to 4°, from 0° to 3°, from 0° to 2° or 0° to 1°. Since the angle between the plane including the transition dipole moment of the organometallic compound represented by Formula 1 and the plane including four atoms bonded to metal of Formula 1 is within these ranges, the organometallic compound may have excellent planarity. Accordingly, a thin film formed using the organometallic compound may have excellent electrical properties.

In one or more embodiments, the horizontal orientation rate of the transition dipole moment of the organometallic compound may be, for example, from 80% to 100%, from 81% to 100%, from 82% to 100%, from 83% to 100%, from 84% to 100%, from 85% to 100%, from 86% to 100%, from 87% to 100%, from 88% to 100%, from 89% to 100%, from 90% to 100%, from 91% to 100%, from 92% to 100%, from 93% to 100%, from 94% to 100%, from 95% to 100%, from 96% to 100%, from 97% to 100%, from 98% to 100%, from 99% to 100%, or 100%.

In this regard, the horizontal orientation ratio of the transition dipole moment refers to the ratio of the organometallic compound having a transition dipole moment which is horizontal to the film compared to the total organometallic compound in the film including the organometallic compound.

The horizontal orientation ratio of the transition dipole moment may be evaluated using an angle-dependent PL measurement apparatus. For a description of the angle-dependent PL measurement apparatus may refer to, for example, the angle-dependent PL measurement apparatus described in Korean Patent Application No. 2013-0150834.

The Korean Patent Application No. 2013-0150834 may be incorporated herein.

Since the organometallic compound has a high horizontal orientation ratio of the transition dipole moment as described above, a large horizontal orientation transition dipole moment (that is, a large horizontal optical orientation) may be obtained.

Accordingly, a large amount of electric field traveling in a direction which is perpendicular to the film containing the organometallic compound may be emitted. The light emitted according to this mechanism may have high external extraction efficiency (that is, the external extraction efficiency of light emitted from the organometallic compound from a device (for example, an organic light-emitting device) including a film (for example, an emission layer to be described later) containing the organometallic compound).

Accordingly, an electronic device including the organometallic compound, for example, an organic light-emitting device including the organometallic compound may have high luminescence efficiency.

In one or more embodiments, A₅₁ may be a linear or branched C₄-C₁₀ alkyl group, and A₅₂ may be a hydrogen-free deuterated C₁-C₁₀ alkyl group.

In one or more embodiments, A₅₁ may be an n-butyl group, a sec-butyl group, an isobutyl group, a tert-butyl group, an n-pentyl group, a tert-pentyl group, a neopentyl group, an isopentyl group, a sec-pentyl group, a 3-pentyl group, or a sec-isopentyl group, and A₅₂ may be a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, or a sec-isopentyl group, each substituted with at least one deuterium, (or, a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, or a sec-isopentyl group, each substituted with at least one deuterium and being hydrogen-free).

In one or more embodiments, Formula 1 may satisfy Condition A, and the group represented by *-[(L₇)_{b7}-(R₇)_{c7}] may be a phenyl group that is simultaneously substituted with 1) at least one C₄-C₁₀ alkyl group and 2) at least one phenyl group.

In one or more embodiments, Formula 1 may satisfy Condition A, and the group represented by *-[(L₇)_{b7}-(R₇)_{c7}] may be a phenyl group that is simultaneously substituted with 1) at least one tert-butyl group and 2) at least one phenyl group.

a51 and a52 in Formula N51 respectively indicate the number of A₅₁(s) and the number of A₅₂(s), and may each independently be an integer from 0 to 10. When a51 is 2 or more, two or more of A₅₁(s) may be identical to or different from each other, and when a52 is 2 or more, two or more of A₅₂(s) may be identical to or different from each other.

For example, a51 and a52 in Formula N51 may each independently be 0, 1, 2, 3, 4, 5, or 6.

The sum of a51 and a52 in Formula N51 is an integer of 1 or more. That is, ring CY₅₁ in Formula N51 may be essentially substituted with a group represented by A₅₁, a group represented by A₅₂, or a combination thereof. As such, although not intending to be limited by a particular theory, since ring CY₅₁ is essentially substituted with at least one electron-donating group, an electronic device, for example, an organic light-emitting device, including the organometallic compound represented by Formula 1 including the group represented by Formula N51 may have increased luminescence efficiency and lifespan.

For example, the sum of a51 and a52 may be 1, 2, or 3. In one or more embodiments, the sum of a51 and a52 may be 1.

a53 in Formula N51 indicates the number of groups represented by

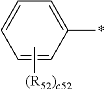

and may be an integer of 1 to 10. That is, since a53 in Formula N51 is not 0, ring CY₅₁ in Formula N51 may be essentially substituted with at least one group represented by

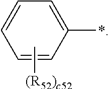

As such, although not intended to be limited by a particular theory, due to the resonance effect of the group represented by

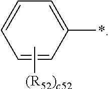

an electronic device, for example, an organic light-emitting device, including the organometallic compound represented by Formula 1 satisfying Condition A may have increased luminescence efficiency and lifespan. Also, although not intended to be limited by a particular theory, since due to the group represented by

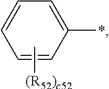

a group represented by:

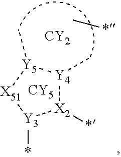

for example, a benzimidazole group in Formula 1 satisfying Condition A may be protected from electrons, heat, or the like, an electronic device, for example, an organic light-emitting device, including the organometallic compound represented by Formula 1 may have improved luminescence efficiency and lifespan.

In one or more embodiments, a51 and a52 in Formula N51 may each independently be 0, 1, or 2 (for example, 0 or 1), the sum of a51 and a52 may be 1 or 2 (for example, 1), and a53 may be 1 or 2 (for example, 1).

* in Formula N51 indicates a binding site to a neighboring atom.

In one or more embodiments, a group represented by

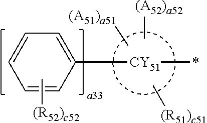

in Formula N51 may be a group represented by one of Formulae 51-1 to 51-20:

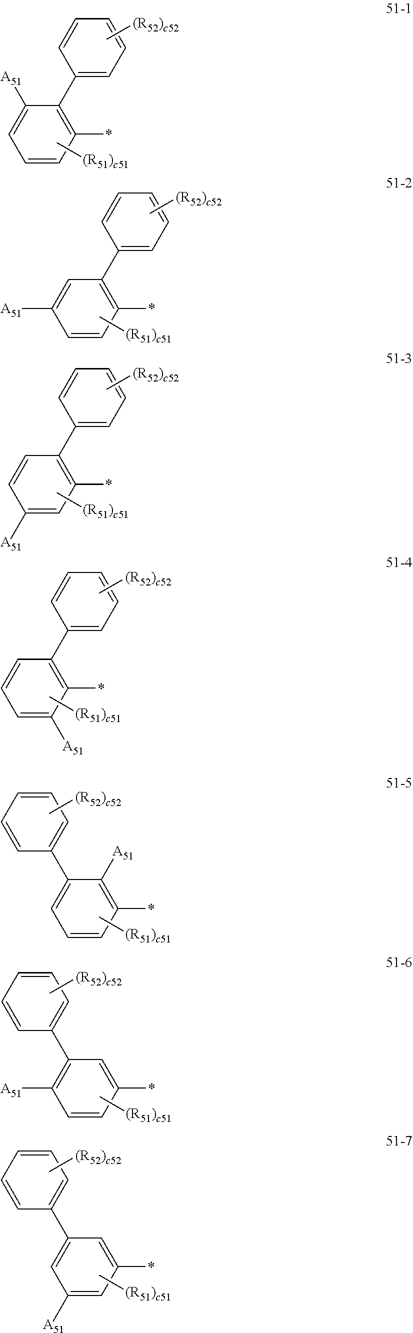

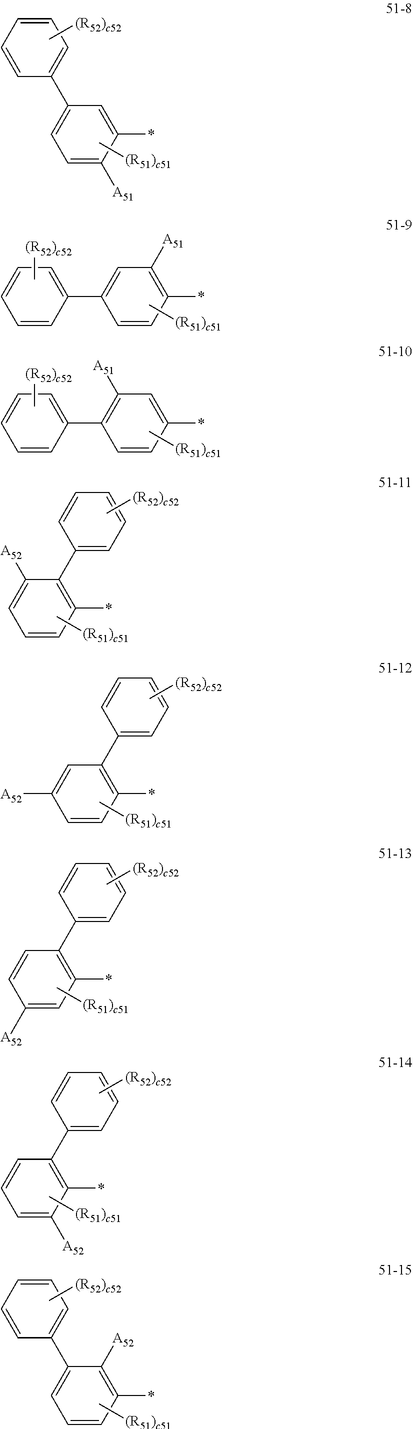

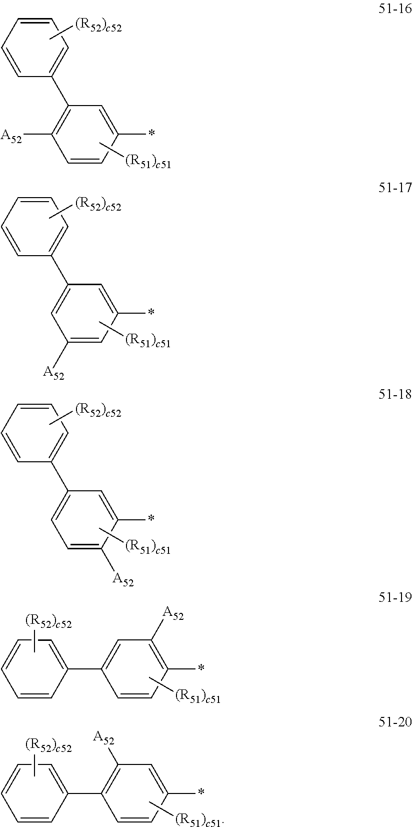

In Formulae 51-1 to 51-20, R₅₁, R₅₂, c51, c52, A₅₁, and A₅₂ are as described in the present specification, and * indicates a binding site to L₅₁.

In one or more embodiments, Formula 1 may satisfy Condition B.

In one or more embodiments, Formula 1 may satisfy Condition B and ring CY₁ may not be a fluorene group and a carbazole group.

In one or more embodiments, Formula 1 may satisfy Condition B and ring CY₁ may be a naphthalene group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group.

In one or more embodiments, Formula 1 may satisfy Condition C.

In one or more embodiments,

i) Formula 1 may satisfy Condition C,

ii) ring CY₃ may be a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group,

iii) a4 may be 1, 2, or 3, and

iv) at least one of R₄ may be:

a C₁-C₂₀ alkyl group substituted with at least one phenyl group; or

a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

In one or more embodiments, Formula 1 may satisfy Condition D.

In one or more embodiments,

i) Formula 1 may satisfy Condition D,

ii) ring CY₄ may be an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group,

iii) a3 may be 1, 2, or 3, and

iv) at least one of R₃ may be:

a C₁-C₂₀ alkyl group substituted with at least one phenyl group; or

a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

In one or more embodiments, Formula 1 may be i) Condition A and ii) one of Condition B, Condition C and Condition D, simultaneously. For example, Compound 149 is a compound satisfying Condition A and Condition B and Compound 339 is a compound satisfying Condition A and Condition C.

In one or more embodiments, a3 in Formula 1 may be 1, 2, 3, or 4, and the group represented by *-(L₃)_{b3}-(R₃)_{c3} may not be hydrogen.

In one or more embodiments, a4 in Formula 1 may be 1, 2, 3, or 4, and the group represented by *-(L₄)_{b4}-(R₄)_{c4} may not be hydrogen.

In one or more embodiments, a3 and a4 in Formula 1 may each independently be 1, 2, 3, or 4, and the group represented by *-(L₃)_{b3}-(R₃)_{c3} and group represented by *-(L₄)_{b4}-(R₄)_{c4} may not be hydrogen.

In one or more embodiments, regarding Formula 1,

a3 may be 1, 2, 3, 4, or 5,

L₃ may be a single bond, and

R₃ may be a substituted or unsubstituted C₁-C₆₀ alkyl group. In this regard, detailed examples of the R₃ may be understood by referring to the description provided in the present specification.

In one or more embodiments, regarding Formula 1,

a3 may be 1, 2, 3, 4, or 5,

at least one of a plurality of R₃(s) may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group. In this regard, detailed examples of the R₃ may be understood by referring to the description provided in the present specification.

In one or more embodiments, regarding Formula 1,

a4 may be 1, 2, 3, 4, or 5, and

at least one of a plurality of R₄(s) may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group. In this regard, detailed examples of the R₄ may be understood by referring to the description provided in the present specification.

In one or more embodiments, R₁ to R₇, R′, and R″ in Formulae 1 may each independently be hydrogen, deuterium, —F, a cyano group, a nitro group, —SF₅, —CH₃, —CD₃, —CD₂H, —CDH₂, —CF₃, —CF₂H, —CFH₂, —OCH₃, —OCDH₂, —OCD₂H, —OCD₃, —SCH₃, —SCDH₂, —SCD₂H, —SCD₃, a group represented by one of Formulae 9-1 to 9-39, a group represented by one of Formulae 9-1 to 9-39 wherein at least one hydrogen is substituted with deuterium, a group represented by one of Formulae 9-1 to 9-39 wherein at least one hydrogen is substituted with —F, a group represented by one of Formulae 9-201 to 9-236, a group represented by one of Formulae 9-201 to 9-236 wherein at least one hydrogen is substituted with deuterium, a group represented by one of Formulae 9-201 to 9-236 wherein at least one hydrogen is substituted with —F, a group represented by one of Formulae 10-1 to 10-132, a group represented by one of Formulae 10-1 to 10-132 wherein at least one hydrogen is substituted with deuterium, a group represented by one of Formulae 10-1 to 10-132 wherein at least one hydrogen is substituted with —F, a group represented by one of Formulae 10-201 to 10-353, a group represented by one of Formulae 10-201 to 10-353 wherein at least one hydrogen is substituted with deuterium, a group represented by one of Formulae 10-201 to 10-353 wherein at least one hydrogen is substituted with —F, —Si(Q₃)(Q₄)(Q₅), or —Ge(Q₃)(Q₄)(O₅)(where O₃ to O₅ are as described in the present specification).

In one or more embodiments, A₅₁ in Formula N51 may be a group represented by one of Formulae 9-4 to 9-39.

In one or more embodiments, A₅₂ in Formula N51 may be —CD₃, —CD₂H, —CDH₂, or a group represented by one of Formulae 9-1 to 9-39 wherein at least one hydrogen is substituted with deuterium (or, —CD₃ or a group represented by one of Formulae 9-1 to 9-39 wherein all hydrogen is substituted with deuterium).

In one or more embodiments, the group represented by

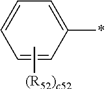

in Formula N51 may be a group represented by one of Formulae 10-12 to 10-205.

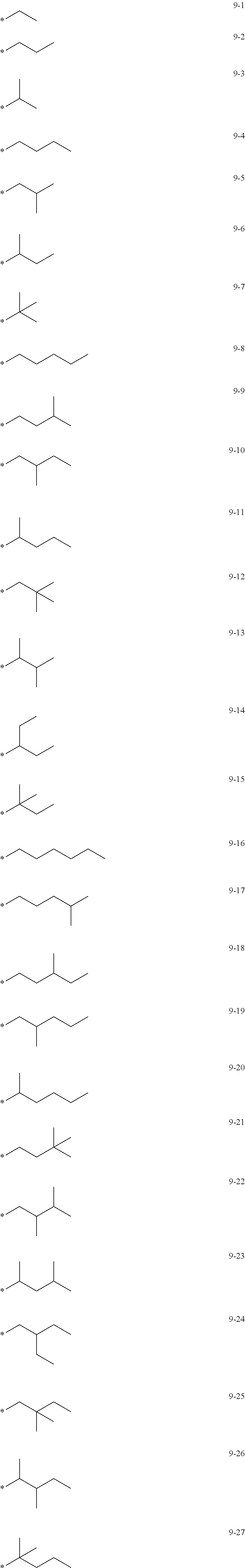

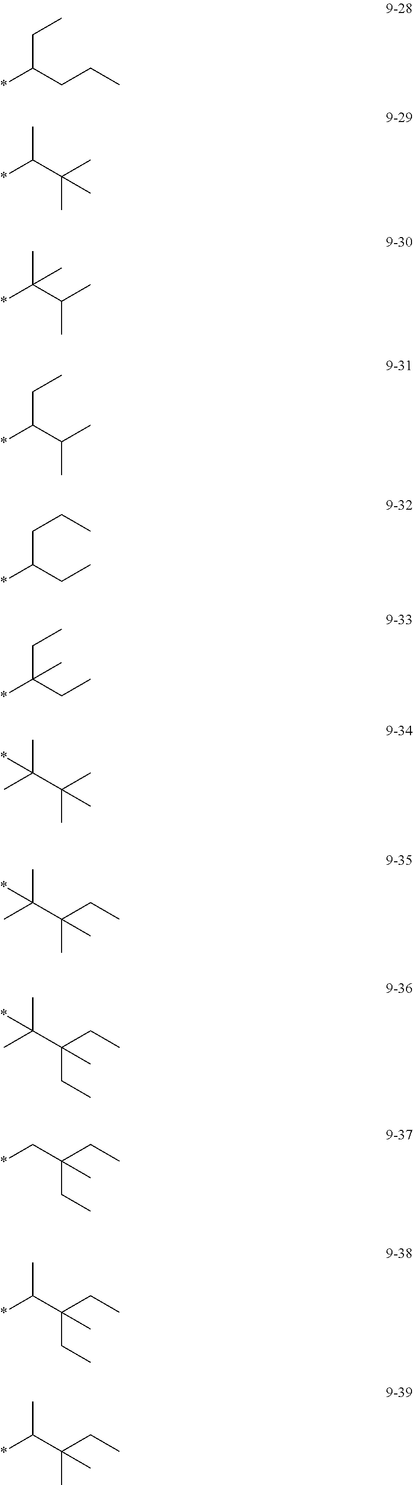

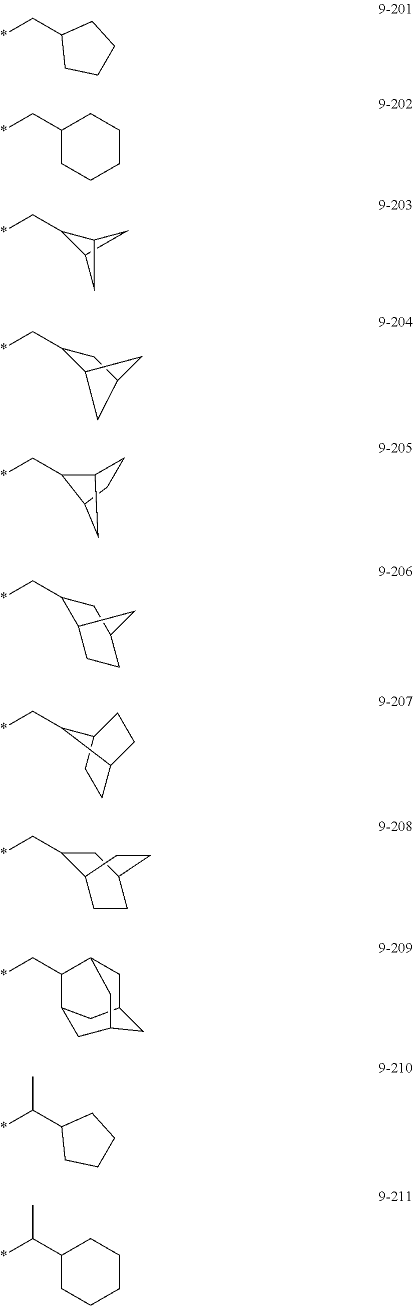

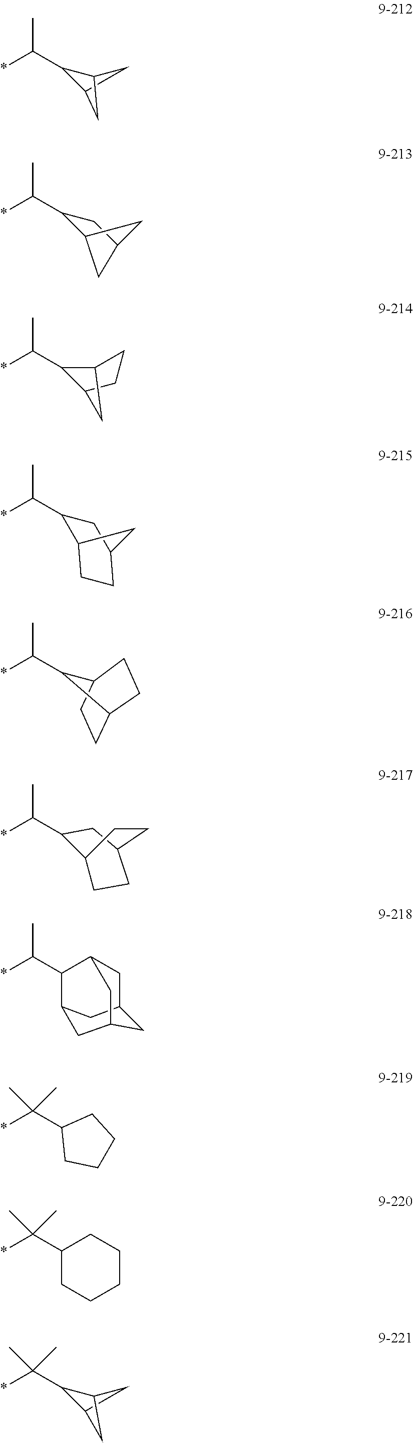

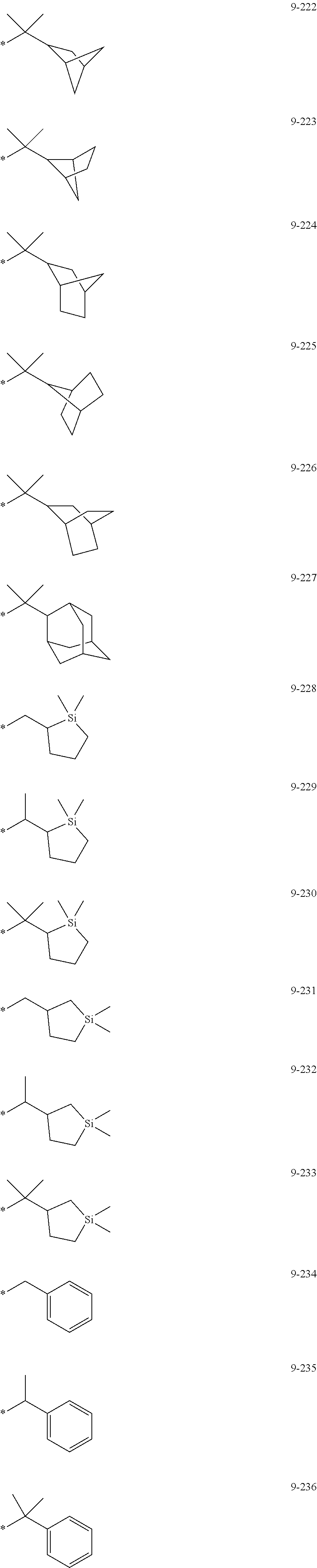

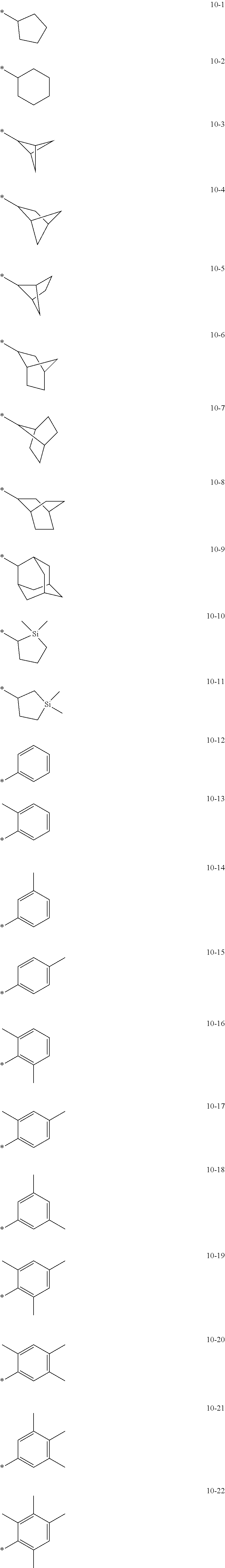

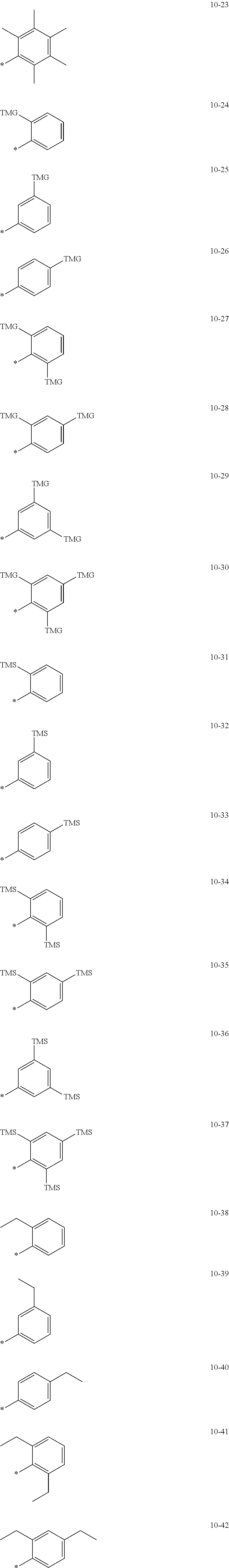

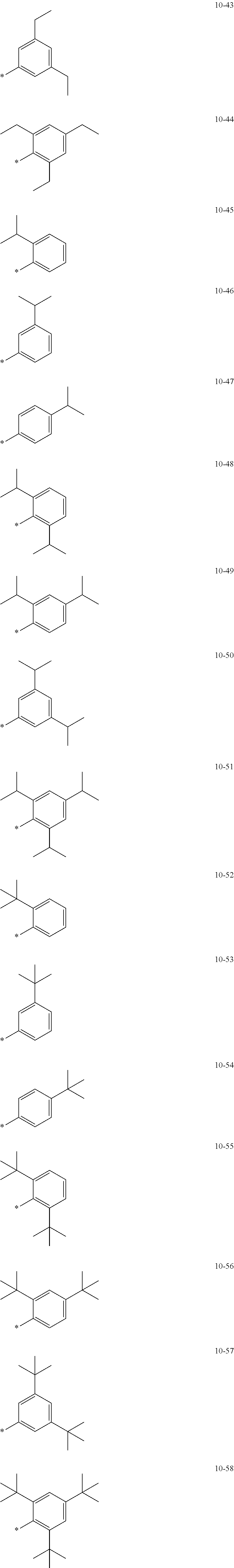

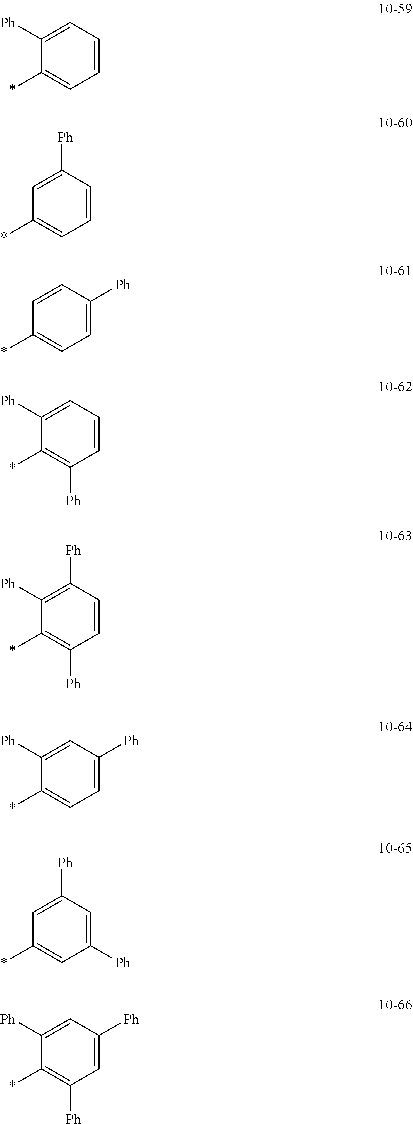

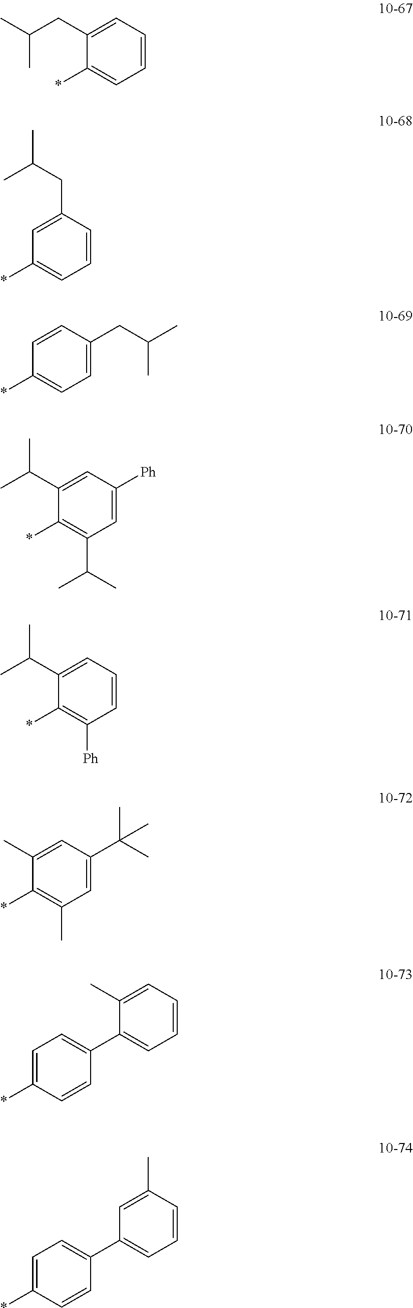

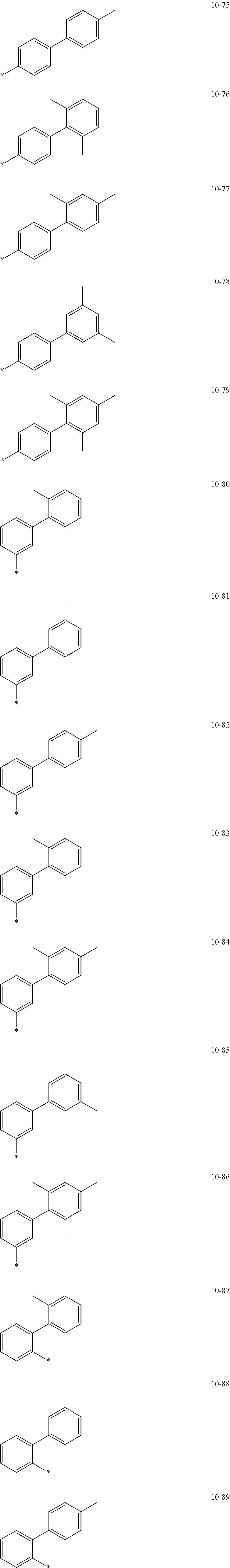

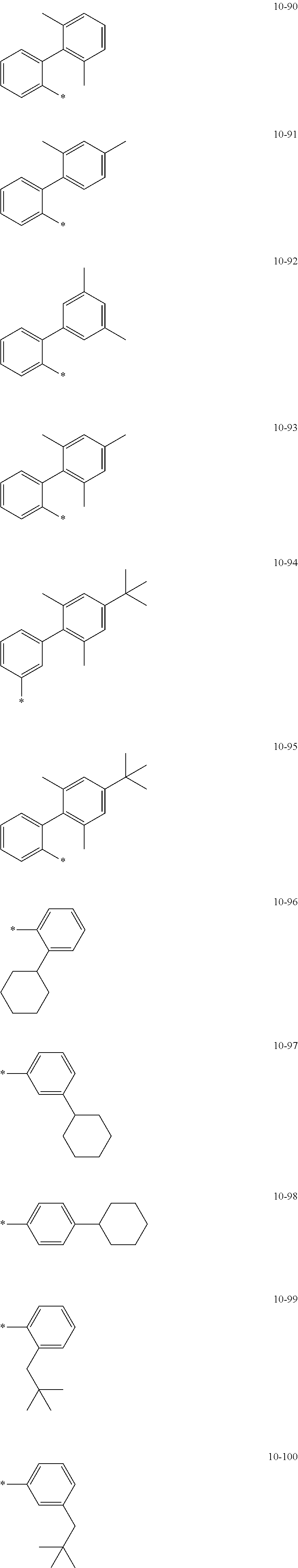

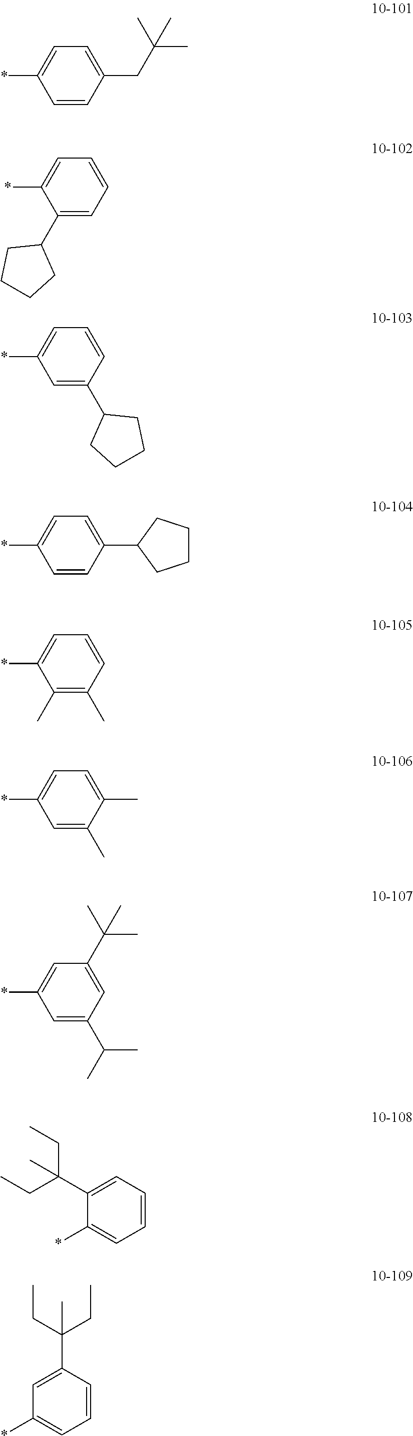

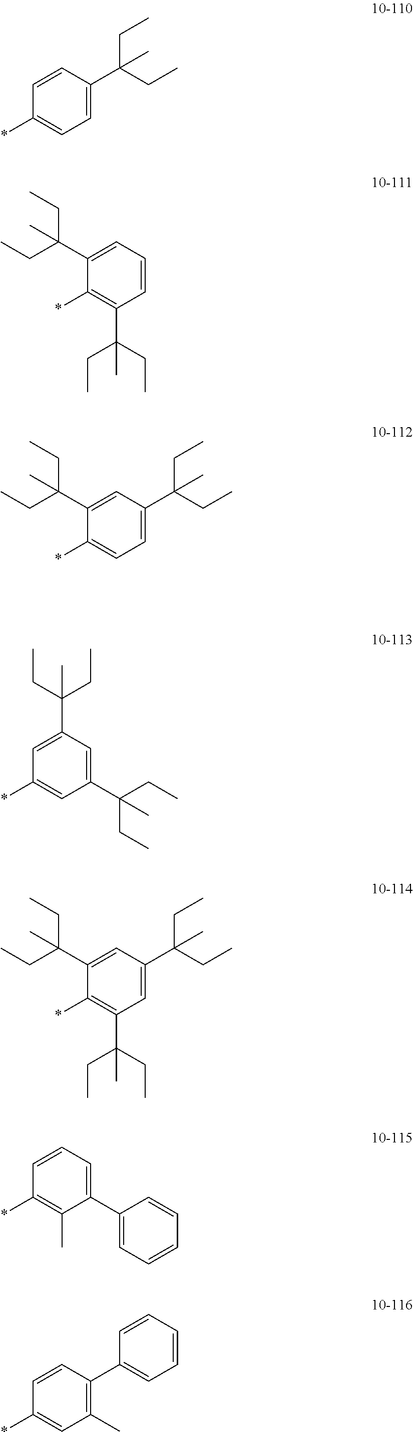

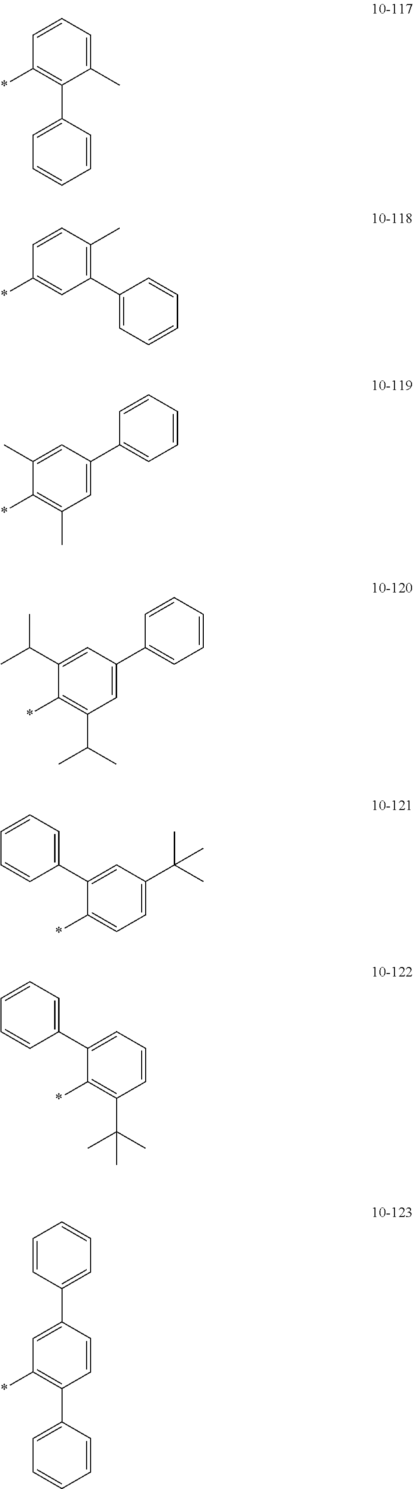

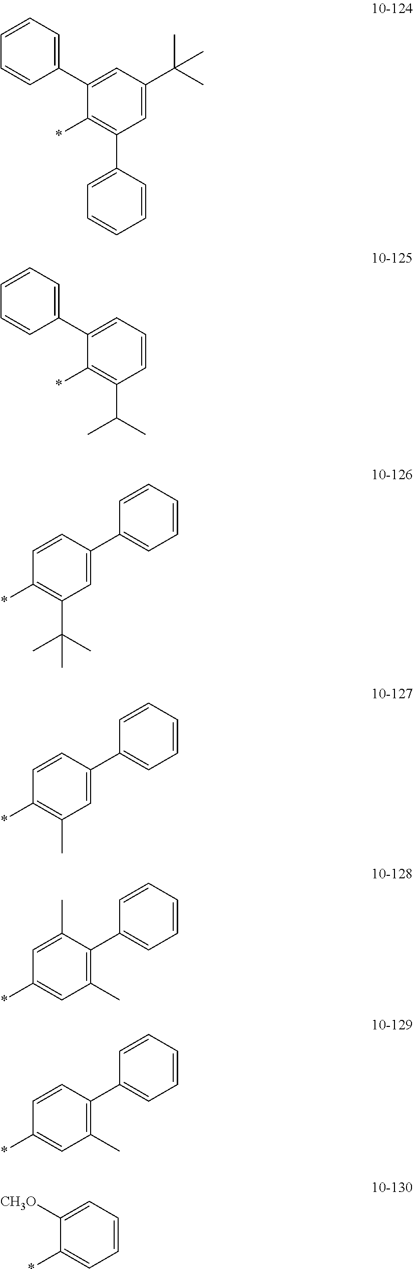

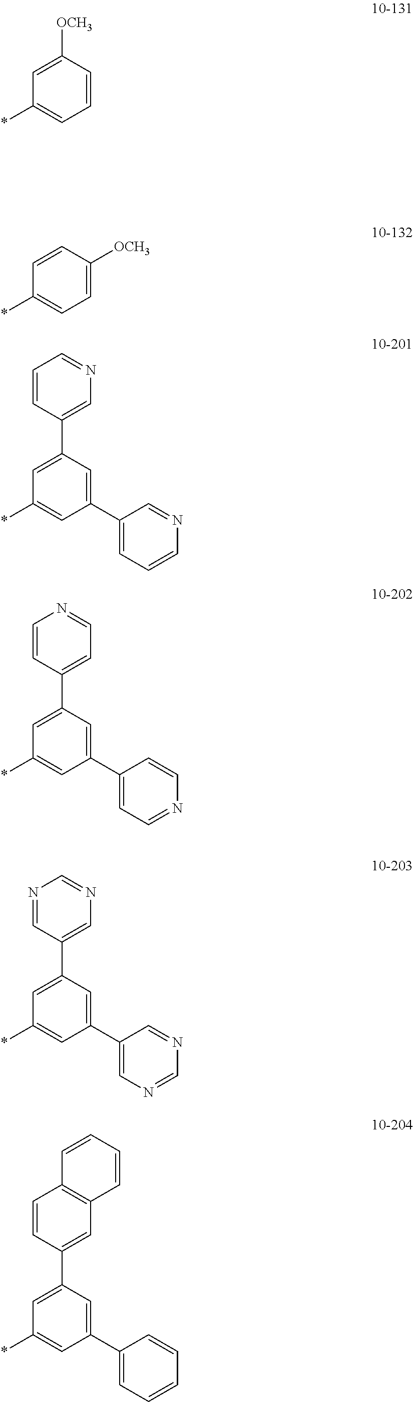

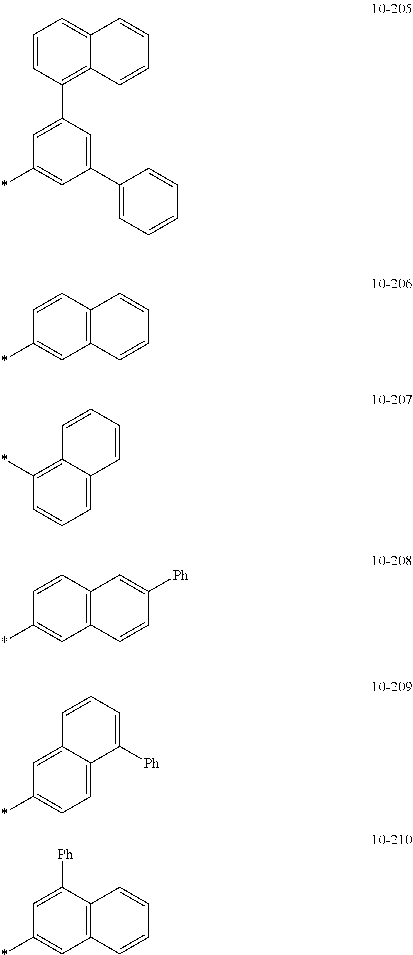

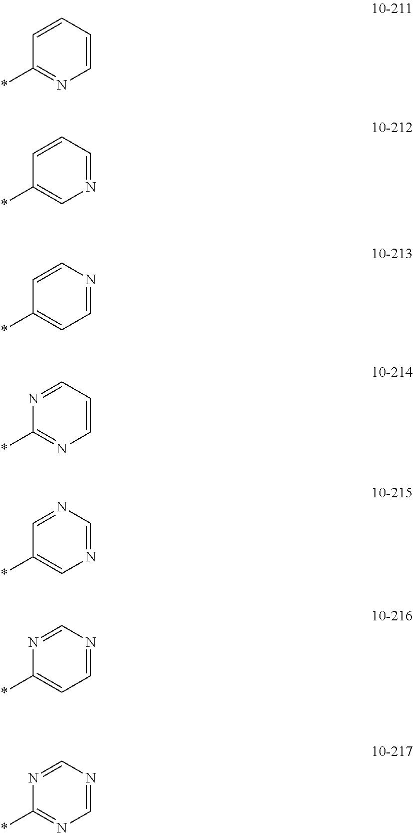

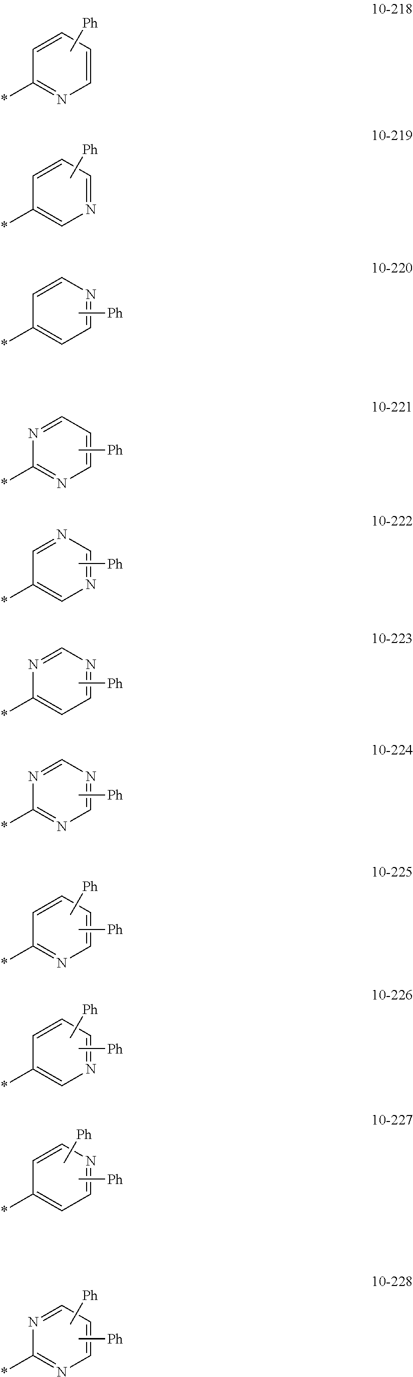

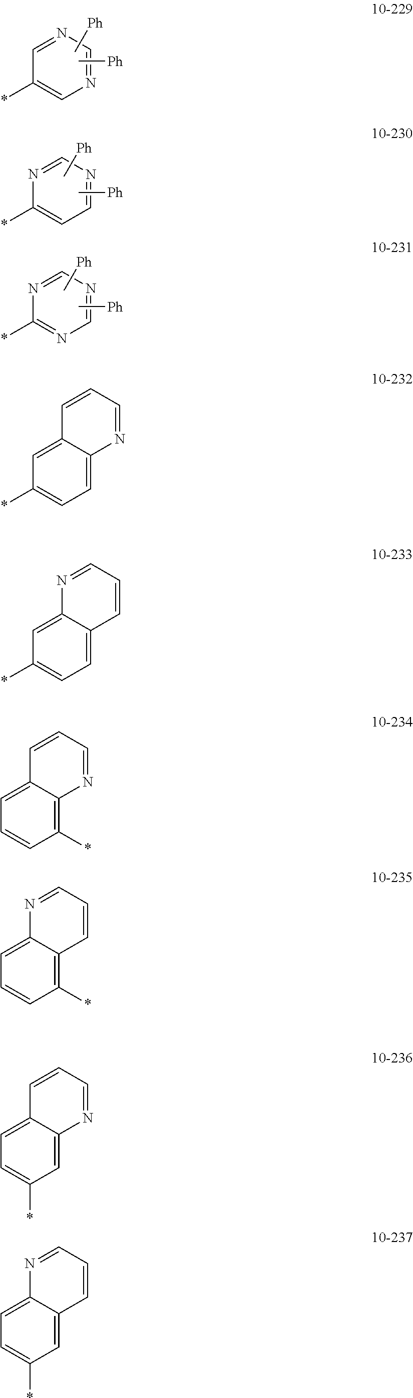

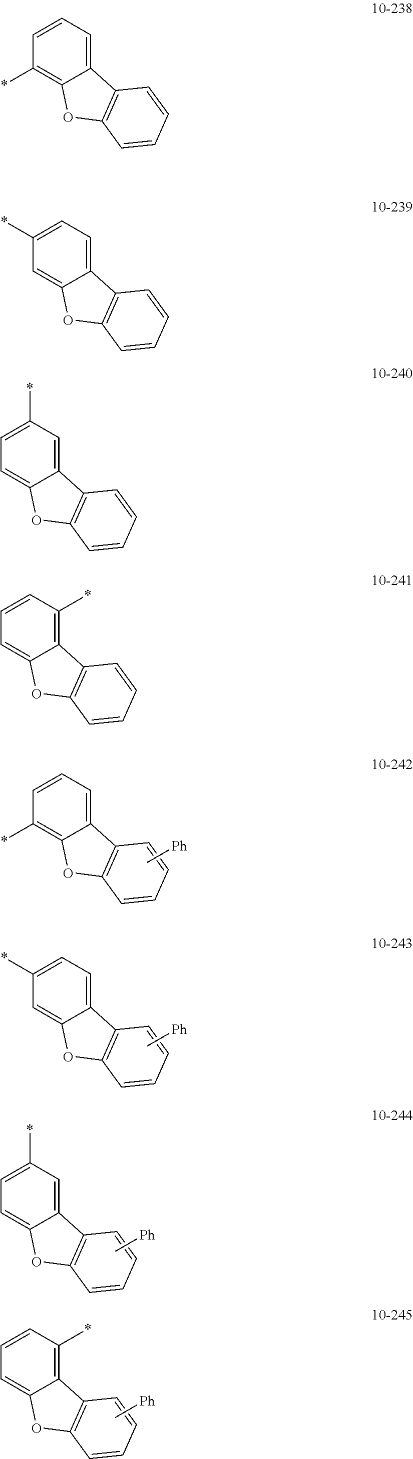

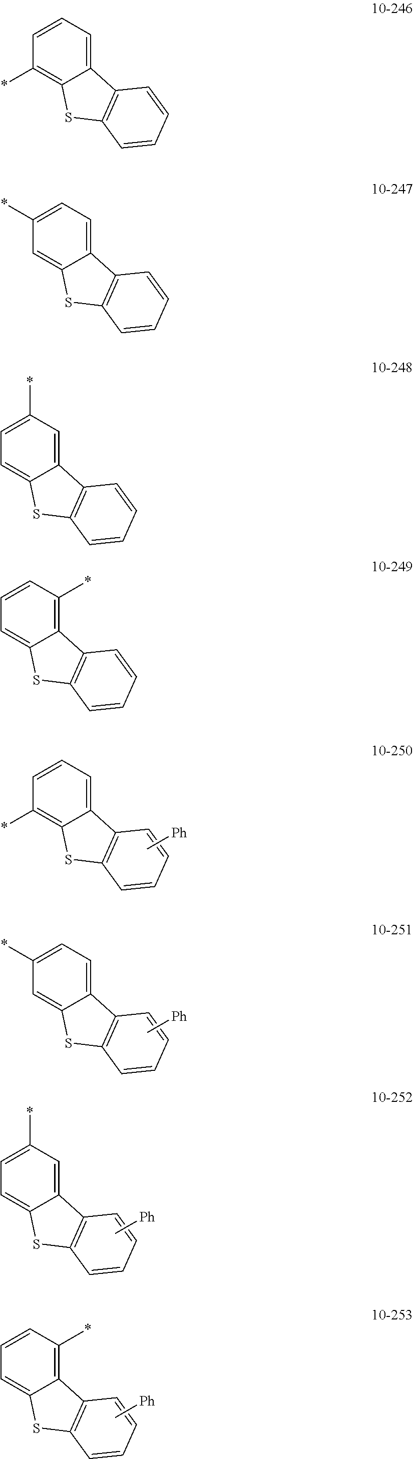

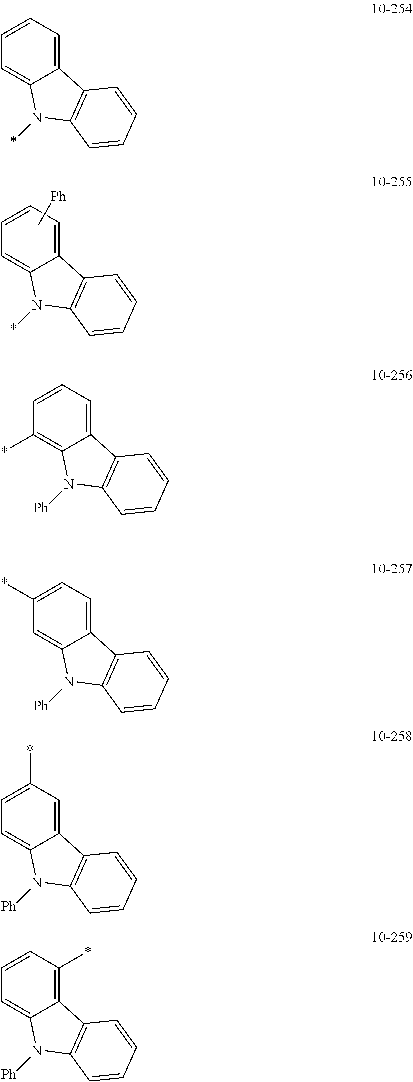

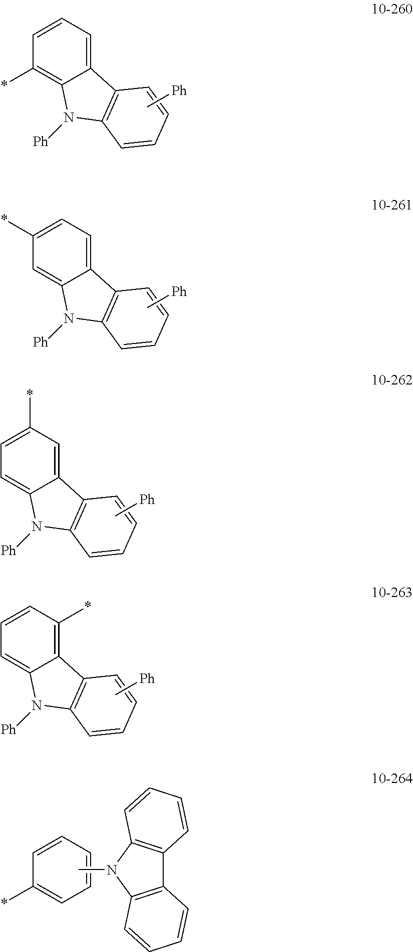

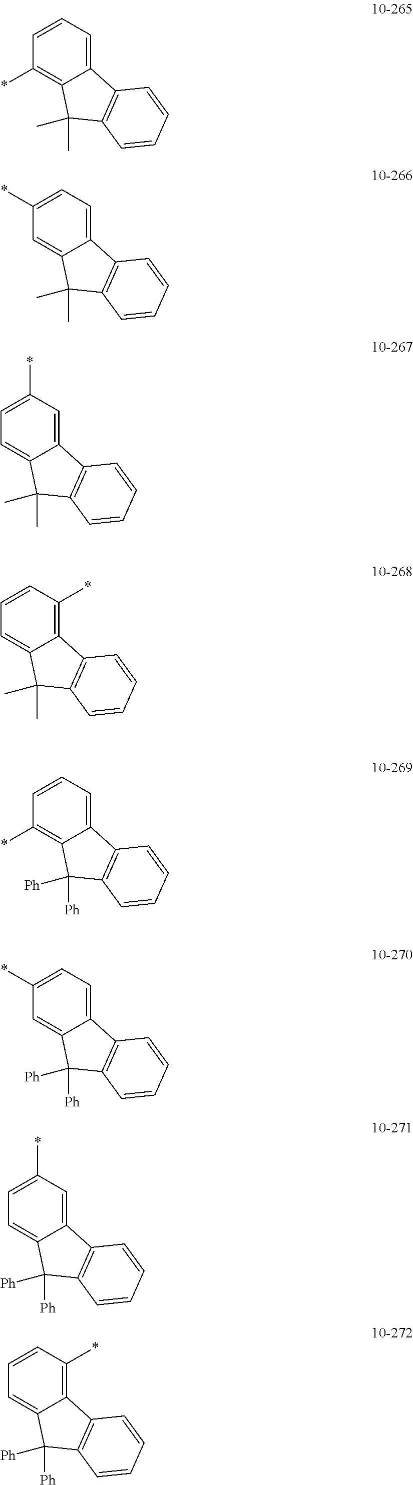

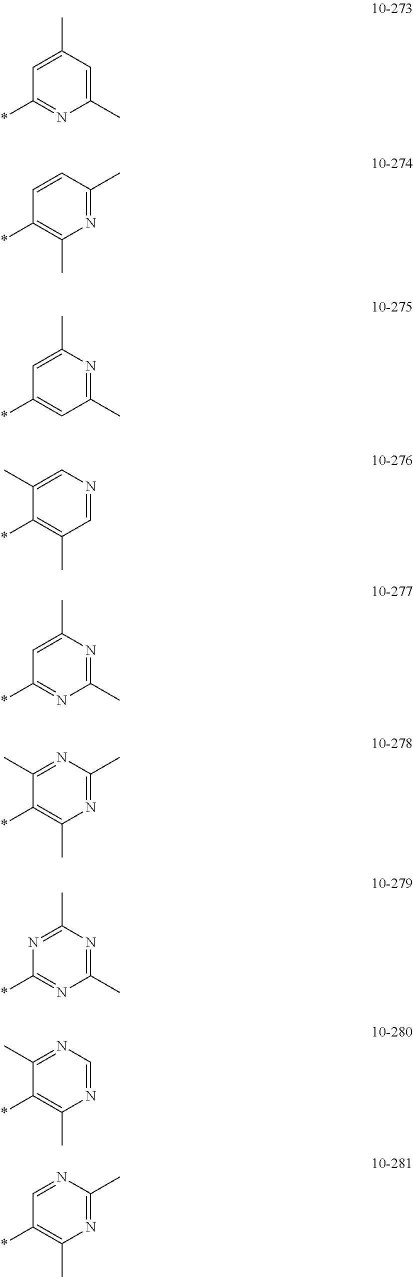

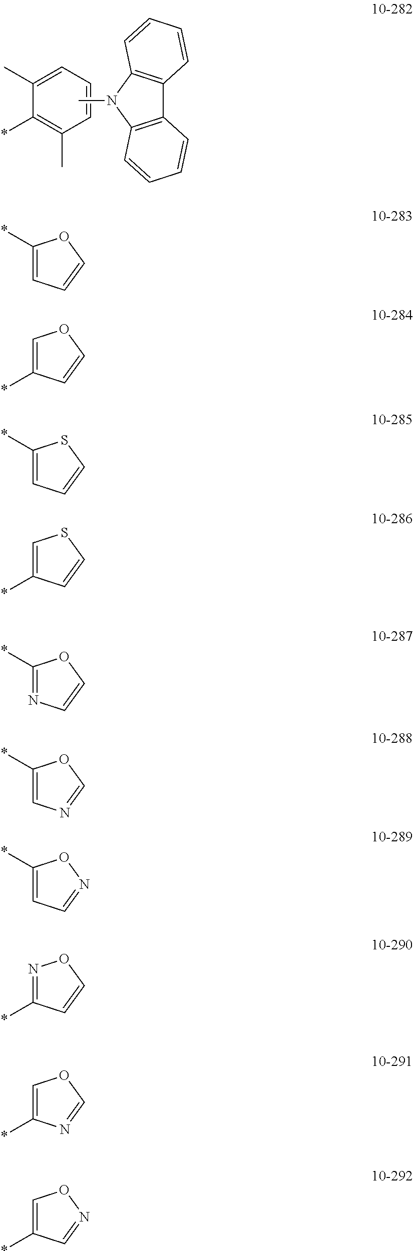

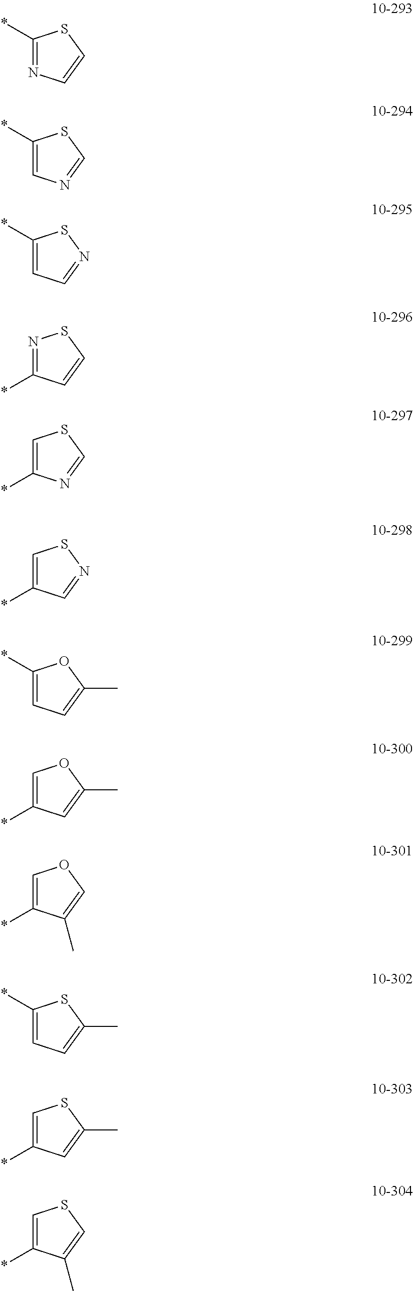

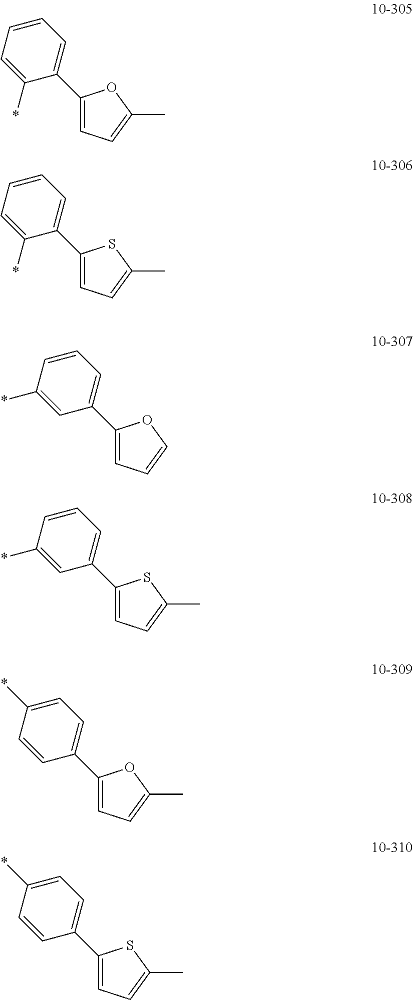 [SMILES: *c1ccccc1-c1ccc(C)o1 ; *c1ccccc1-c1ccc(C)s1 ; *c1cccc(-c2ccco2)c1 ; *c1cccc(-c2ccc(C)s2)c1 ; *c1ccc(-c2ccc(C)o2)cc1 ; *c1ccc(-c2ccc(C)s2)cc1]

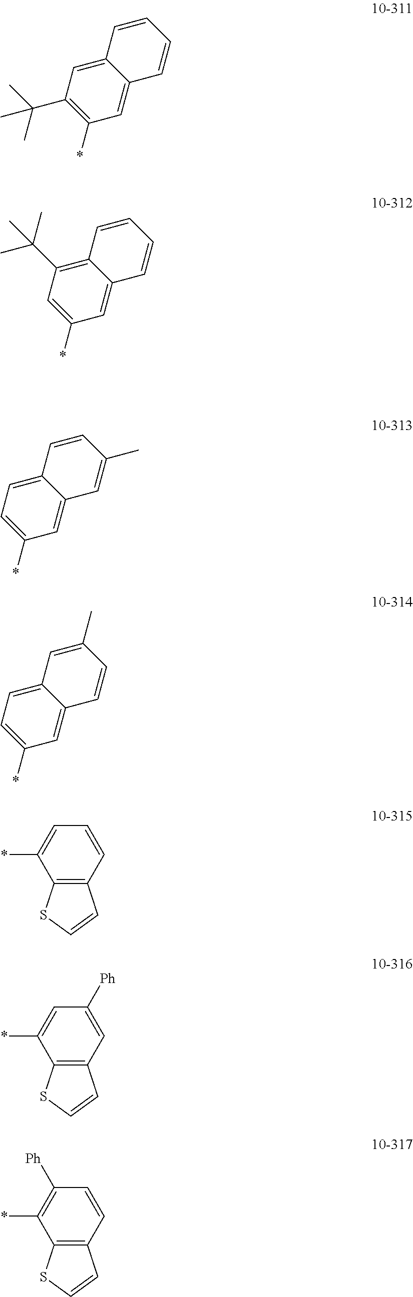

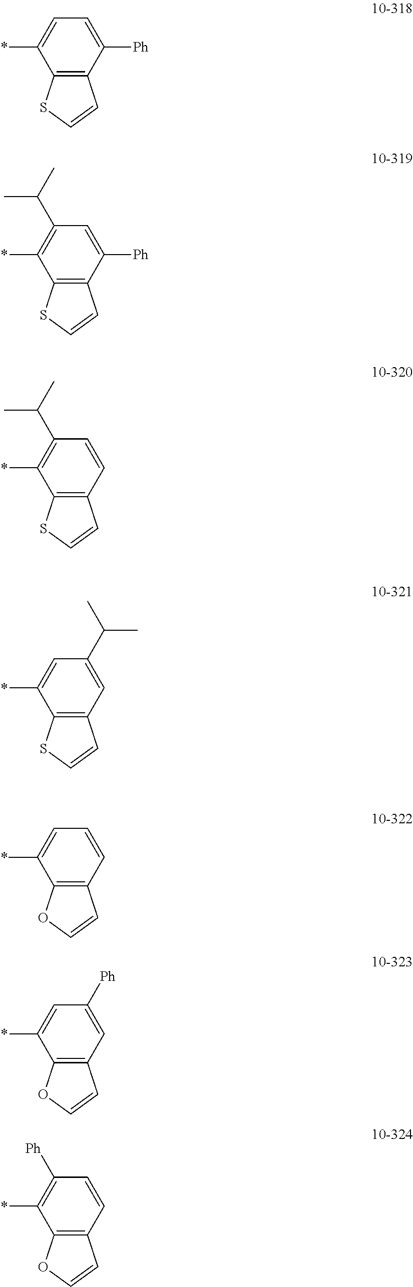

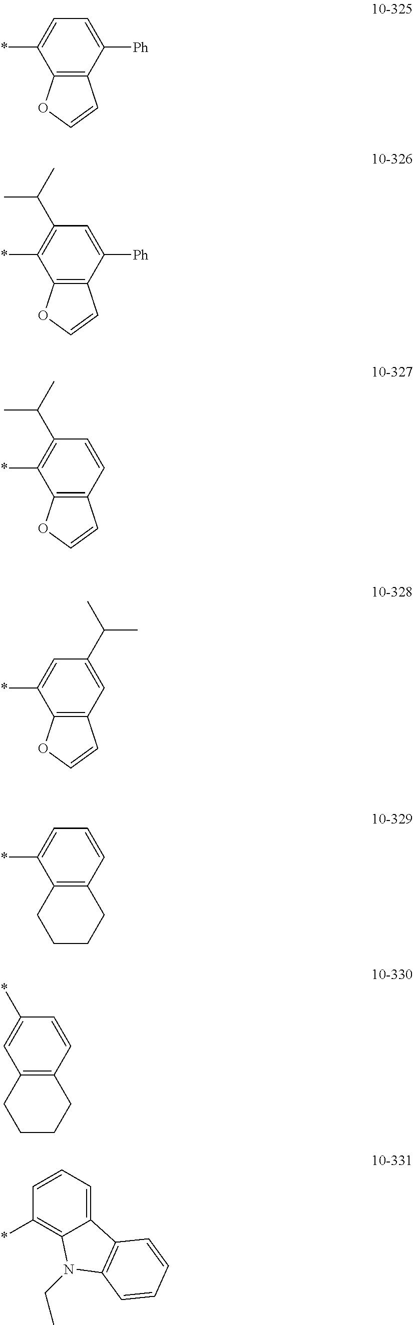

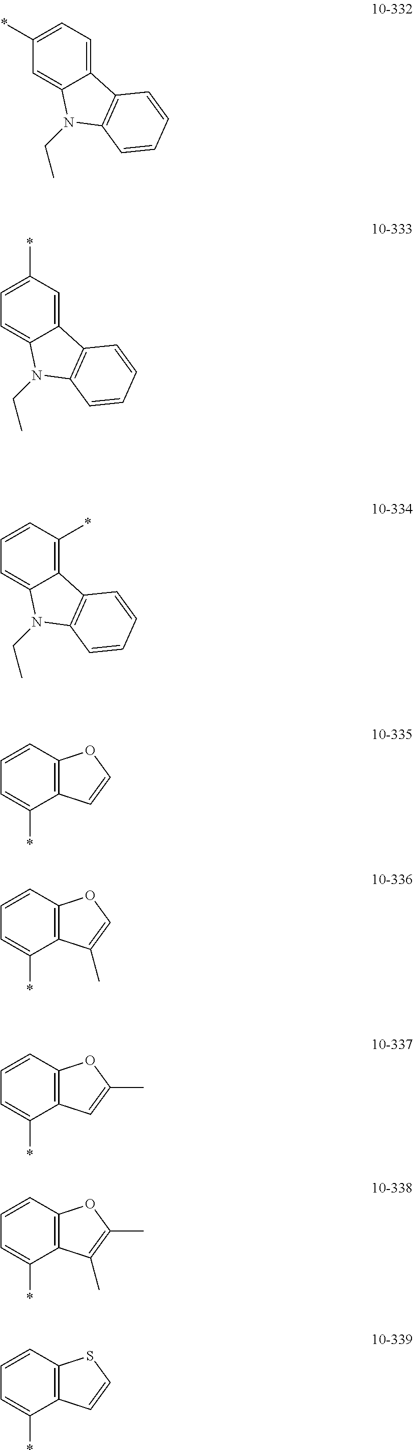

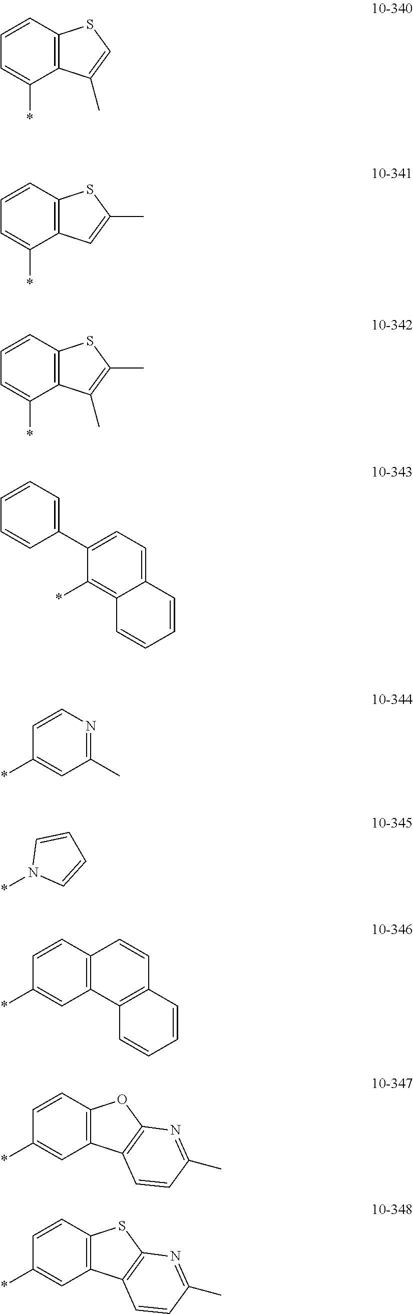

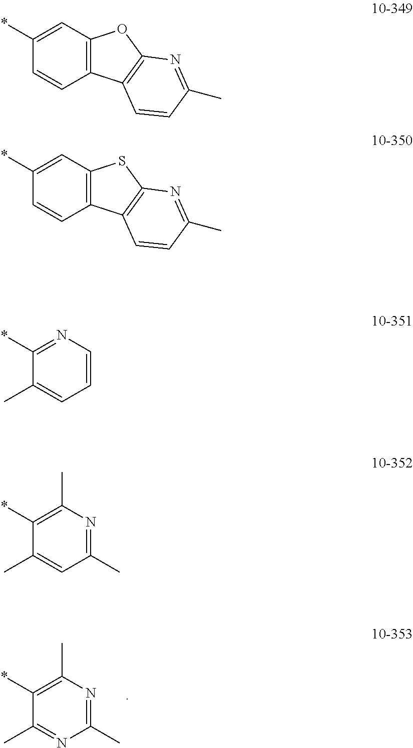

In Formulae 9-1 to 9-39, 9-201 to 9-236, 10-1 to 10-132, and 10-201 to 10-353, * indicates a binding site to a neighboring atom, Ph is a phenyl group, TMS is a trimethylsilyl group, TMG is a trimethylgermyl group, and OMe is a methoxy group.

The “group represented by one of Formulae 9-1 to 9-39 wherein at least one hydrogen is substituted with deuterium” and the “group represented by one of Formulae 9-201 to 9-236 wherein at least one hydrogen is substituted with deuterium” may be, for example, a group represented by one of Formulae 9-501 to 9-514 and 9-601 to 9-635:

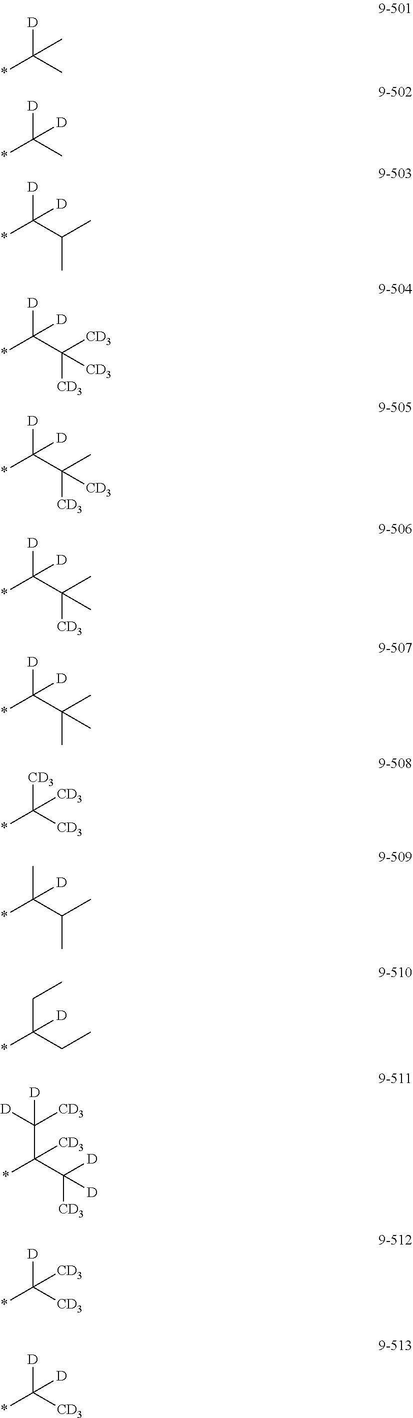

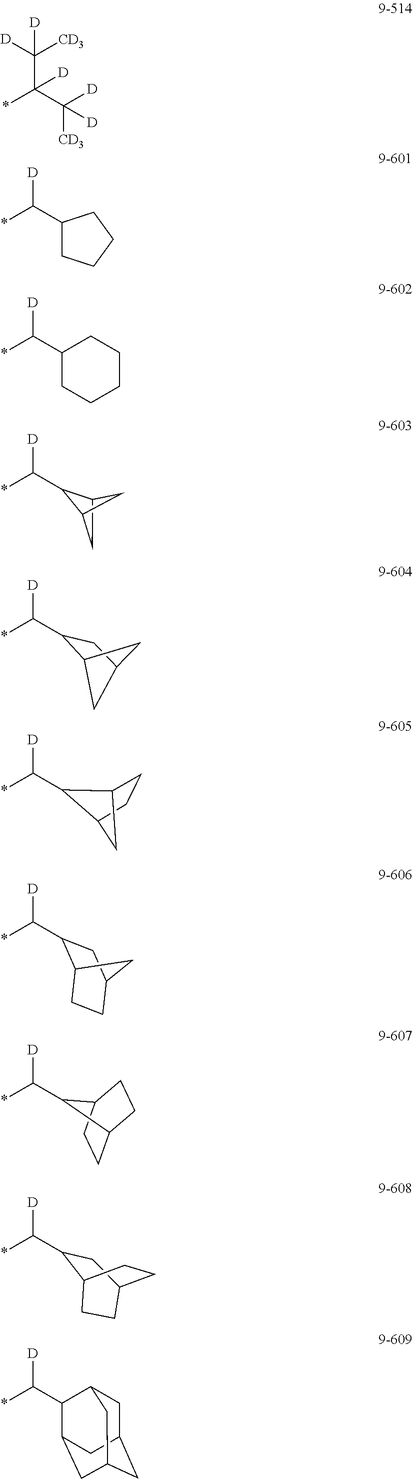

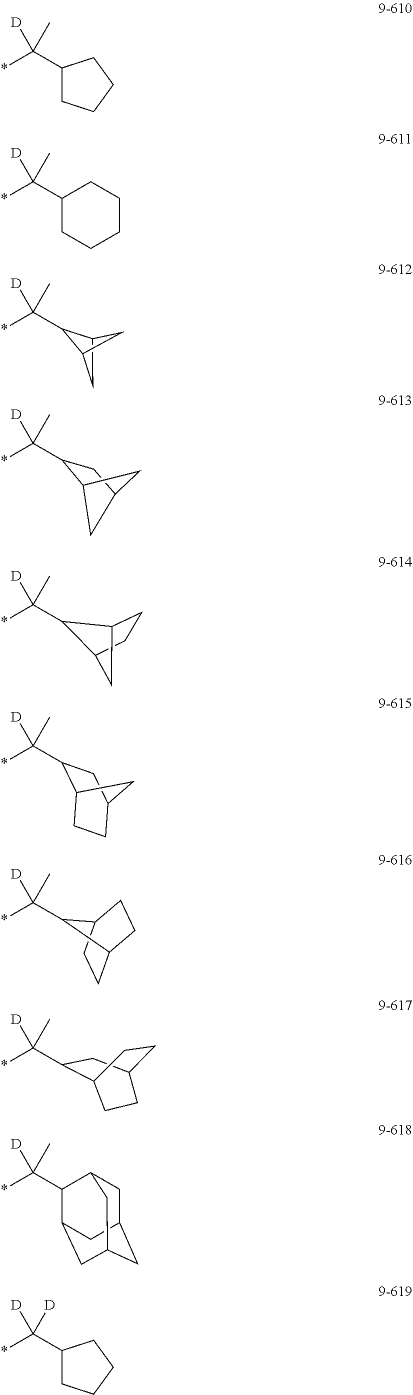

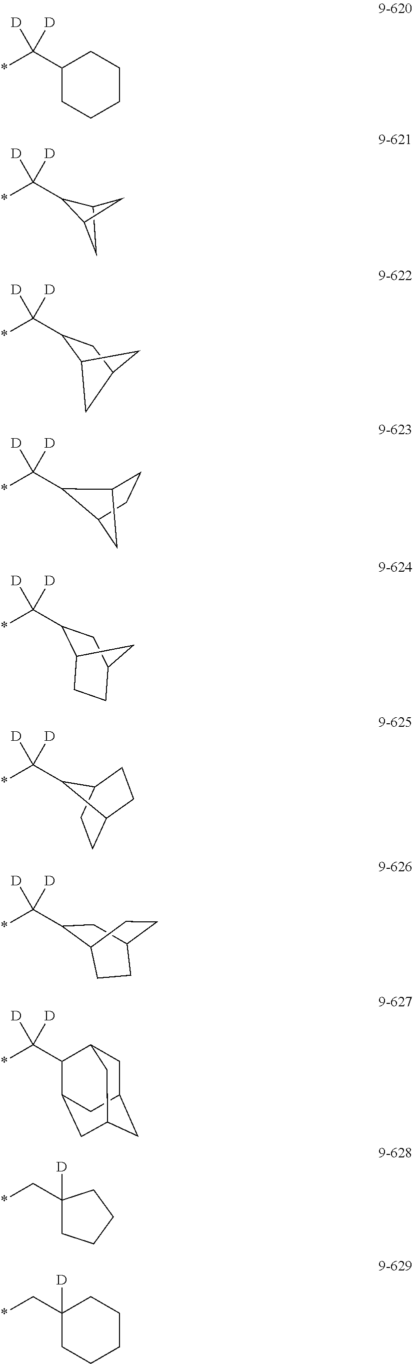

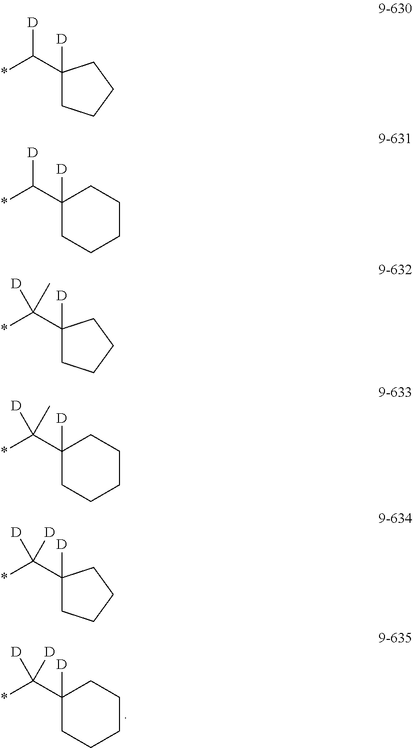

The “group represented by one of Formulae 9-1 to 9-39 wherein at least one hydrogen is substituted with —F” and the “group represented by one of Formulae 9-201 to 9-236 wherein at least one hydrogen is substituted with —F” may be, for example, a group represented by one of Formulae 9-701 to 9-710:

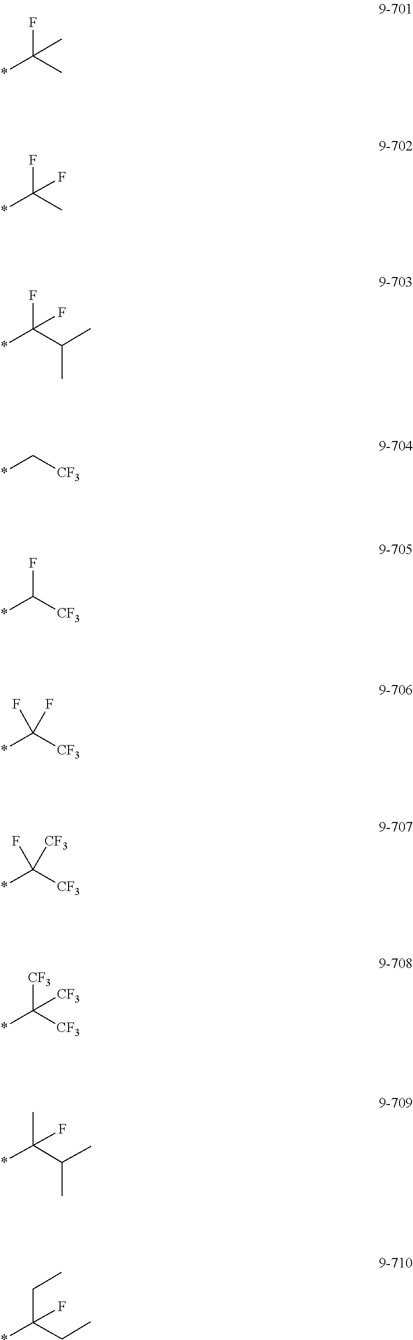

The “group represented by one of Formulae 10-1 to 10-132 wherein at least one hydrogen is substituted with deuterium” and the “group represented by one of Formulae 10-201 to 10-353 wherein at least one hydrogen is substituted with deuterium” may be, for example, a group represented by one of Formulae 10-501 to 10-553:

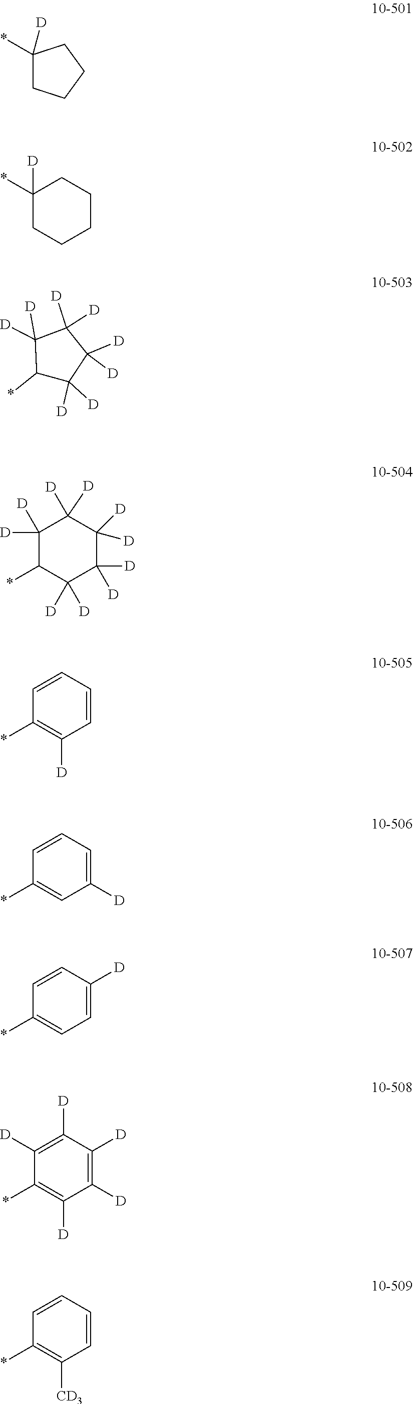

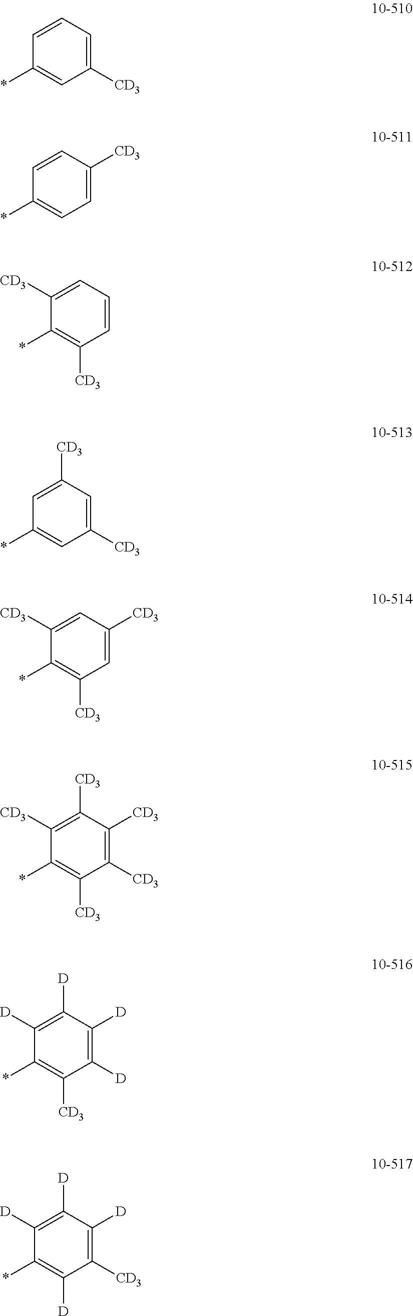

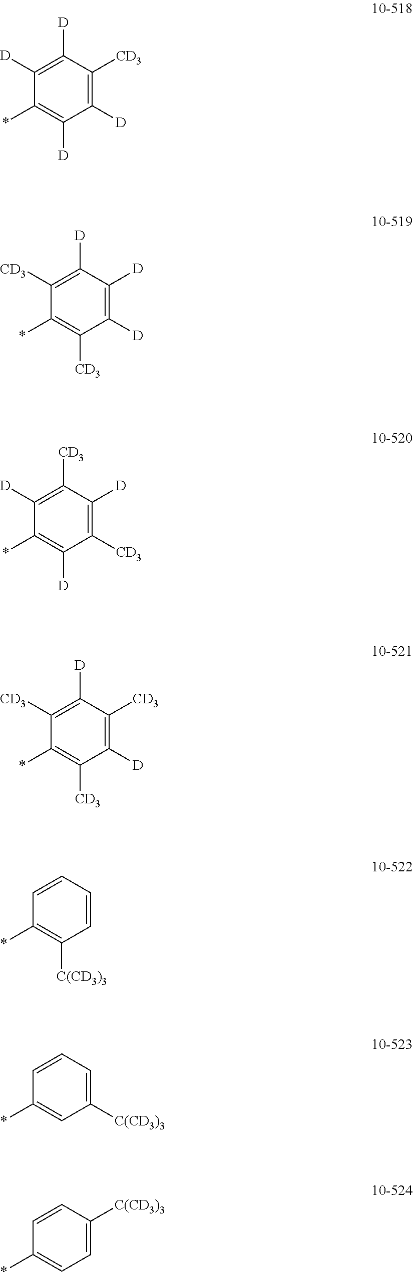

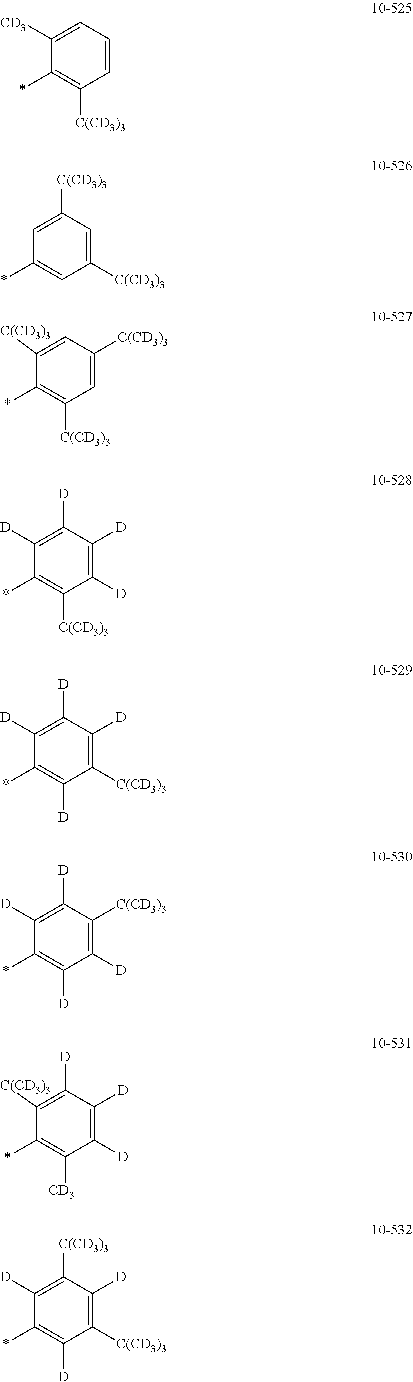

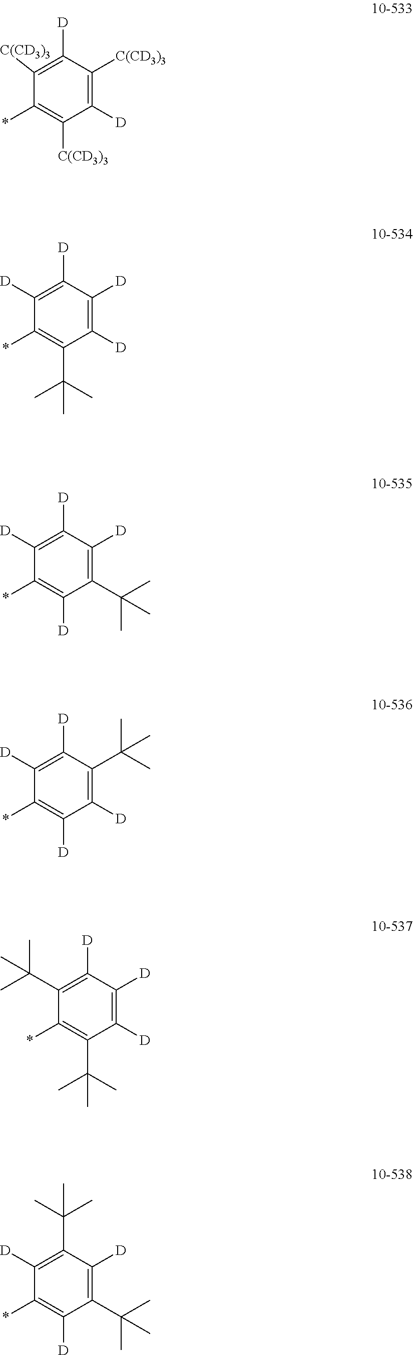

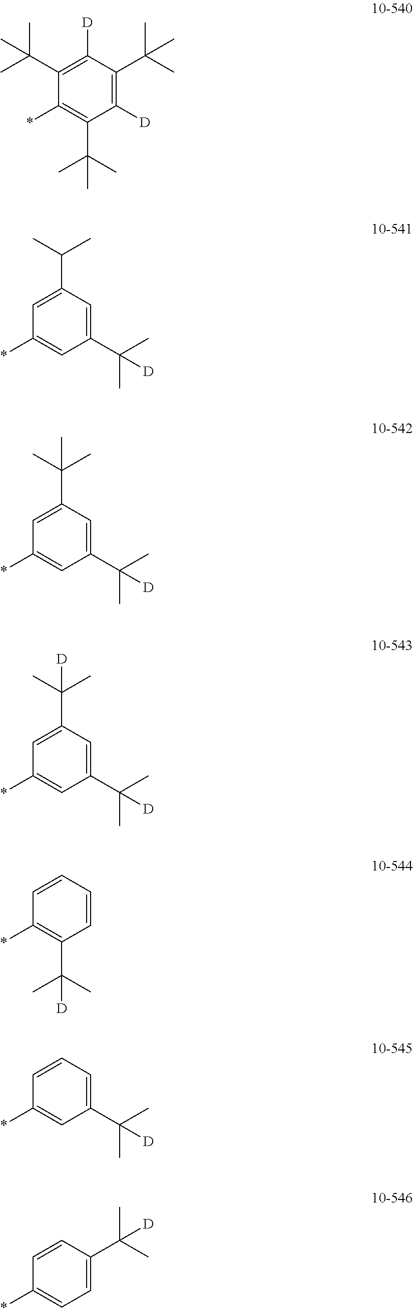

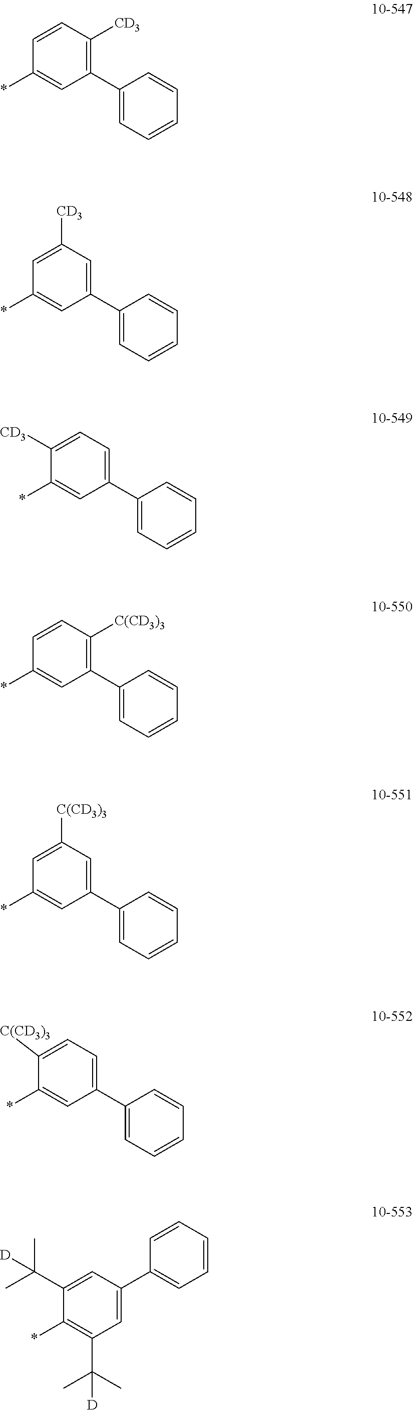

The “group represented by one of Formulae 10-1 to 10-132 wherein at least one hydrogen is substituted with —F” and the “group represented by one of Formulae 10-201 to 10-353 wherein at least one hydrogen is substituted with —F” may be, for example, a group represented by one of Formulae 10-601 to 10-620:

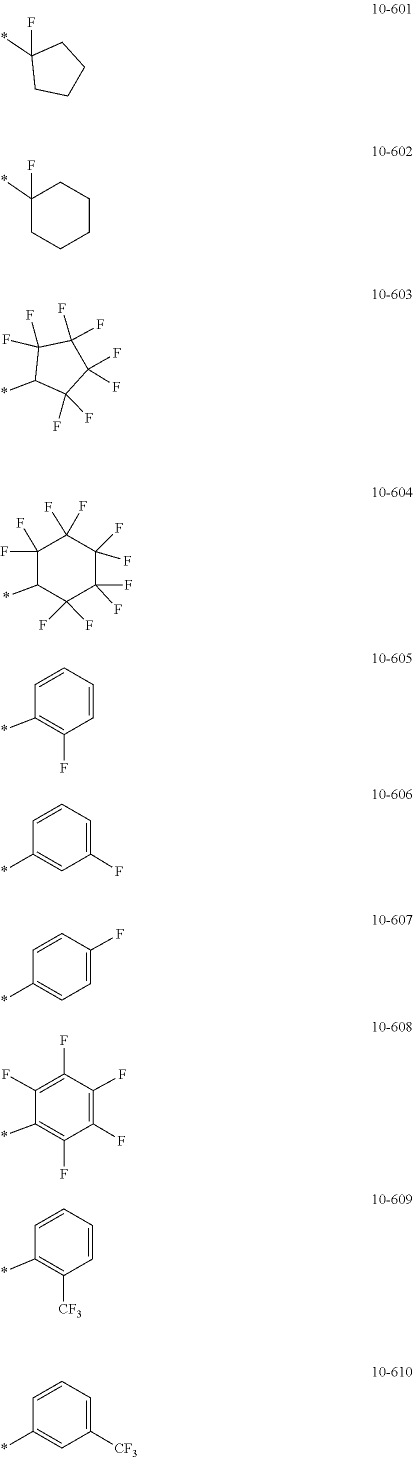

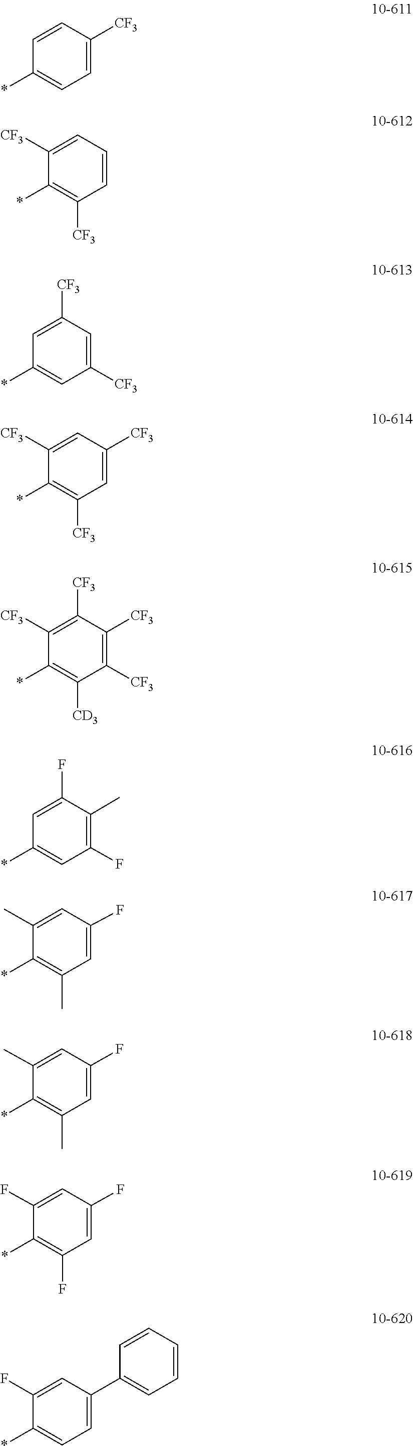

In Formula 1, i) two or more of a plurality of Ri(s) may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, ii) two or more of a plurality of R₂(s) may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, iii) two or more of a plurality of R₃(s) may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, iv) two or more of a plurality of R₄(s) may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, and v) two or more of R₁ to R₄ may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ. R₁₀ₐ is as described in connection with R₁.

In one or more embodiments, the organometallic compound may be represented by Formula 1-1:

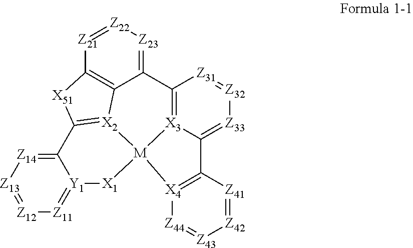

wherein, in Formula 1-1,

M, X₁ to X₄, Y₁ and X₅₁ are each as described in the present specification,

Z₁₁ may be N or C-[(L₁₁)_{b11}-(R₁₁)_{c11}], Z₁₂ may be N or C-[(L₁₂)_{b12}-(R₁₂)_{c12}], Z₁₃ may be N or C-[(L₁₃)_{b13}-(R₁₃)_{c13}], and Z₁₄ may be N or C-[(L₁₄)_{b14}-(R₁₄)_{c14}],

L₁₁ to L₁₄, b11 to b14, R₁₁ to R₁₄, and c11 to c14 are as described in connection with L₁, b1, R₁, and c1, respectively,

Z₂₁ may be N or C-[(L₂₁)_{b21}-(R₂₁)_{c21}], Z₂₂ may be N or C-[(L₂₂)_{b22}-(R₂₂)_{c22}], and Z₂₃ may be N or C-[(L₂₃)_{b23}-(R₂₃)_{c23}],

L₂₁ to L₂₃, b21 to b23, R₂₁ to R₂₃, and c21 to c23 are as described in connection with L₂, b2, R₂, and c2, respectively,

Z₃₁ may be N or C-[(L₃₁)_{b31}-(R₃₁)_{c31}], Z₃₂ may be N or C-[(L₃₂)_{b32}-(R₃₂)_{c32}], and Z₃₃ may be N or C-[(L₃₃)_{b33}-(R₃₃)_{c33}],

L₃₁ to L₃₃, b31 to b33, R₃₁ to R₃₃, and c31 to c33 are as described in connection with L₃, b3, R₃, and c3, respectively,

Z₄₁ may be N or C-[(L₄₁)_{b41}-(R₄₁)_{c41}], Z₄₂ may be N or C-[(L₄₂)_{b42}-(R₄₂)_{c42}], Z₄₃ may be N or C-[(L₄₃)_{b43}-(R₄₃)_{c43}], and Z₄₄ may be N or C-[(L₄₄)_{b44}-(R₄₄)_{c44}],

L₄₁ to L₄₄, b41 to b44, R₄₁ to R₄₄, and c41 to c44 are as described in connection with L₄, b4, R₄, and c4, respectively,

two or more of R₁₁ to R₁₄ may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of R₂₁ to R₂₃ may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of R₃₁ to R₃₃ may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,

two or more of R₄₁ to R₄₄ may optionally be linked together to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, and

each of i) two or more of R₁₁ to R₁₄, ii) two or more of R₂₁ to R₂₃, iii) two or more of R₃₁ to R₃₃, and iv) two or more of R₄₁ to R₄₄ may be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ.

In one or more embodiments, the organometallic compound may be represented by Formula 1-1A, 1-1B or 1-1C:

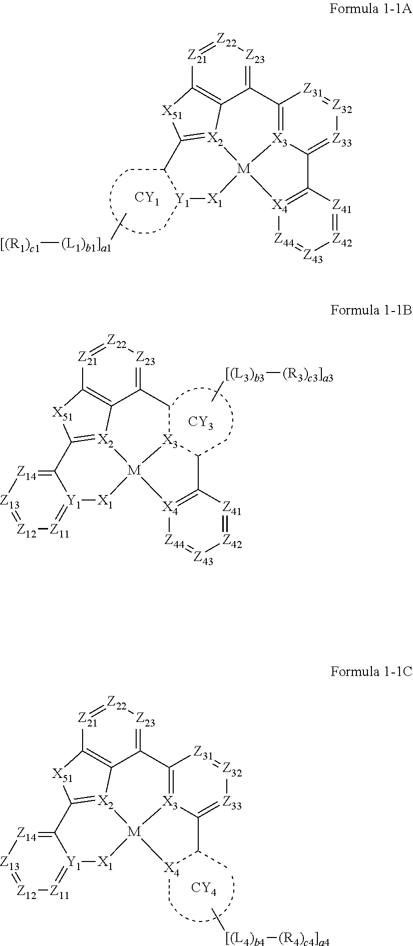

wherein, in Formulae 1-1A, 1-1B and 1-1C,

M, X₁ to X₄, Y₁, X₅₁, Z₁₁ to Z₁₄, Z₂₁ to Z₂₃, Z₃₁ to Z₃₃, Z₄₁ to Z₄₄, L₁, L₃, L₄, b1, b3, b4, R₁, R₃, R₄, c1, c3, c4, a1, a3 and a4 are each as described in the present specification, and

ring CY₁, ring CY₃ and ring CY₄ may each independently be a condensed cyclic group wherein two or more rings are condensed with each other as described in the present specification.

The descriptions for Formula 1 as provided herein are applicable to Formulae 1-1, 1-1A, 1-1B and 1-1C.

In one or more embodiments, Formulae 1-1A, 1-1B and 1-1C, L₁, L₃, L₄, L₂₁ to L₂₃, L₃₁ to L₃₃, L₄₁ to L₄₄ and L₇ may each independently be:

a single bond; or

a benzene group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

In one or more embodiments, Formulae 1-1A, 1-1B and 1-1C, b1, b3, b4, b21 to b23, b31 to b33, b41 to b44 and b7 may each independently be 1, 2, or 3.

In one or more embodiments, Formulae 1-1A, 1-1B and 1-1C, R₁, R₂, R₁₁ to R₁₄ and R₂₁ to R₂₃ may each independently be hydrogen, deuterium, a C₁-C₂₀ alkyl group, or a deuterated C₁-C₂₀ alkyl group.

In one or more embodiments, Formulae 1-1A, 1-1B and 1-1C, c1, c2, c11 to c14 and c21 to c23 may each independently be 1, 2 or 3.

In one or more embodiments, Formulae 1-1A, 1-1B and 1-1C, R₃, R₄, R₃₁ to R₃₃ and R₄₁ to R₄₄ may each independently be:

hydrogen, deuterium, a C₁-C₂₀ alkyl group, or a deuterated C₁-C₂₀ alkyl group; a C₁-C₂₀ alkyl group substituted with at least one phenyl group; or

a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

In one or more embodiments, Formulae 1-1A, 1-1B and 1-1C, c3, c4, c31 to c33 and c41 to c44 may each independently be 1, 2 or 3.

In one or more embodiments, Formulae 1-1A, 1-1B and 1-1C, a1, a3, and a4 may each independently be 0, 1, 2 or 3.

In one or more embodiments, Formulae 1-1A, 1-1B and 1-1C may satisfy Condition A.

In one or more embodiments, at least one of R₄₁ to R₄₄ in Formula 1-1B may be:

a C₁-C₂₀ alkyl group substituted with at least one phenyl group; or

a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

In one or more embodiments, at least one of R₃₁ to R₃₄ in Formula 1-1C may be:

a C₁-C₂₀ alkyl group substituted with at least one phenyl group; or

a phenyl group that is unsubstituted or substituted with deuterium, a C₁-C₂₀ alkyl group, a deuterated C₁-C₂₀ alkyl group, a phenyl group, a deuterated phenyl group, a biphenyl group, a deuterated biphenyl group, or a combination thereof.

In one or more embodiments, a group represented by

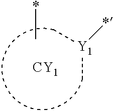

in Formula 1 may be a group represented by one of Formulae CY1-1 to CY1-48 and a group represented by

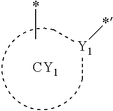

in Formula 1-1A may be a group represented by one of Formulae CY1-9 to CY1-48:

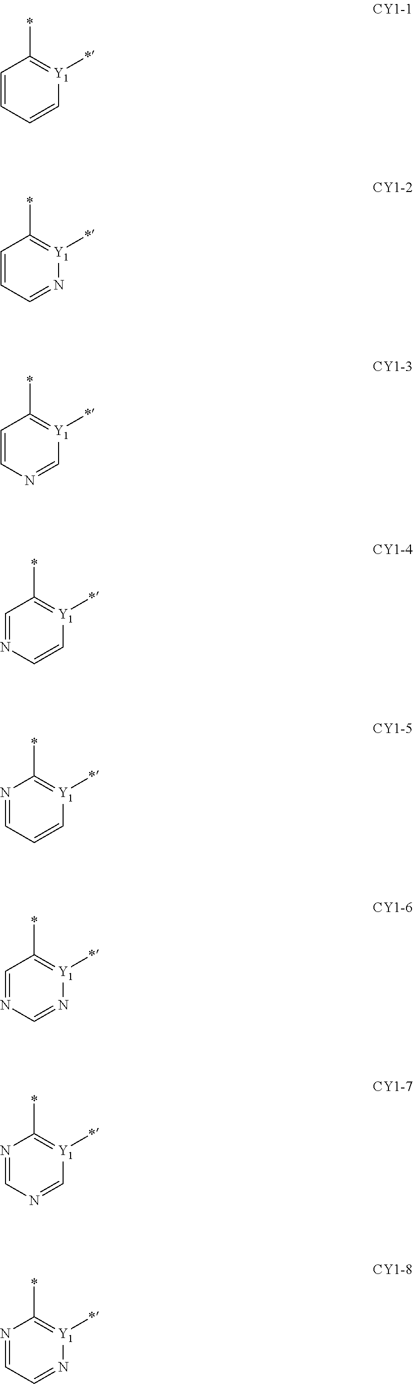

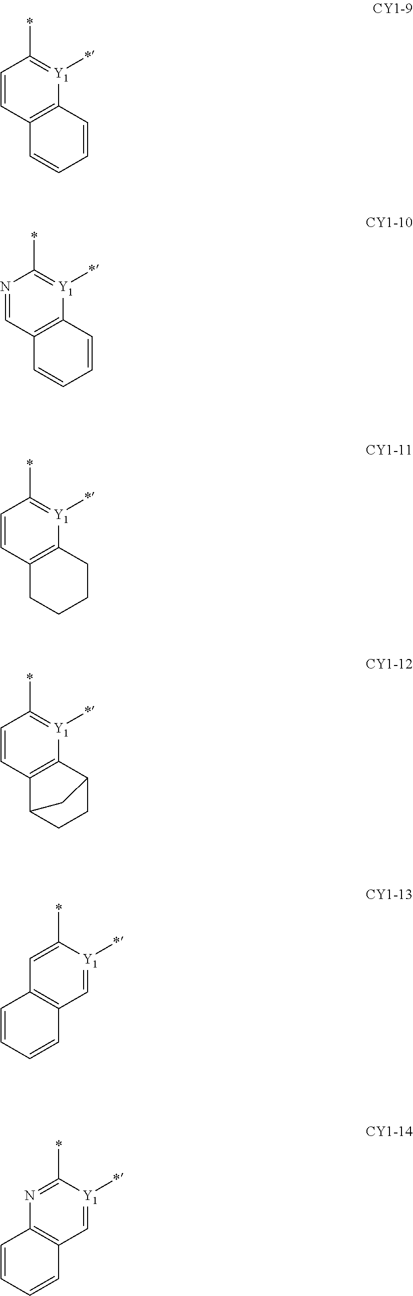

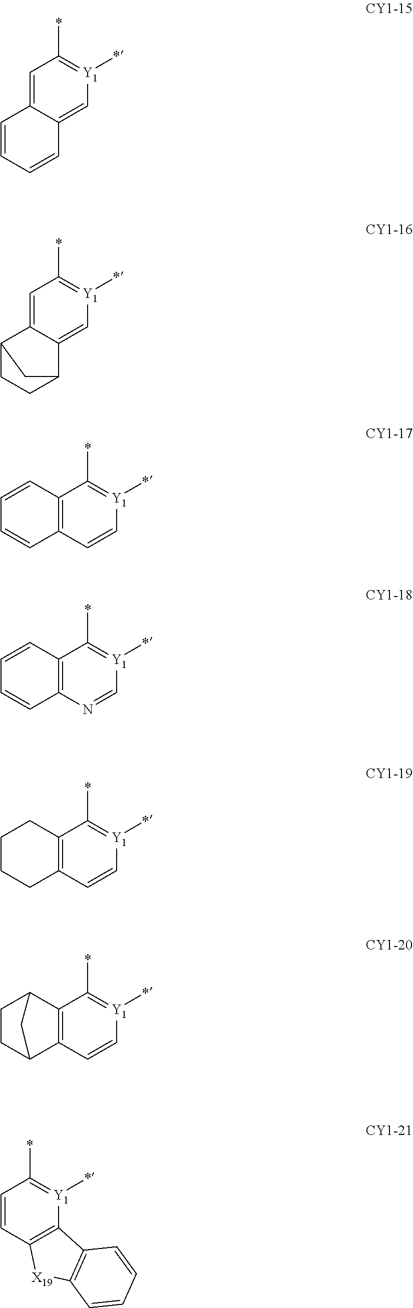

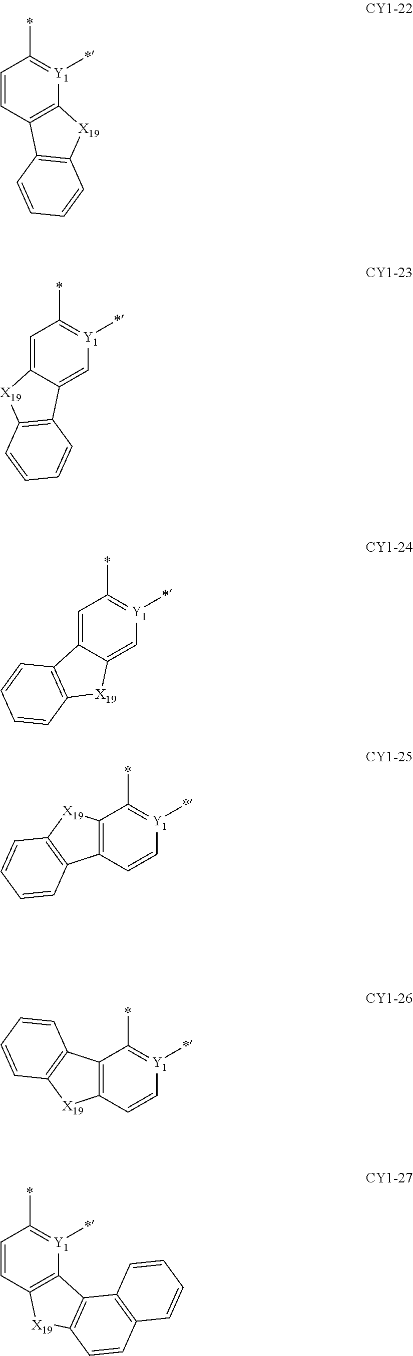

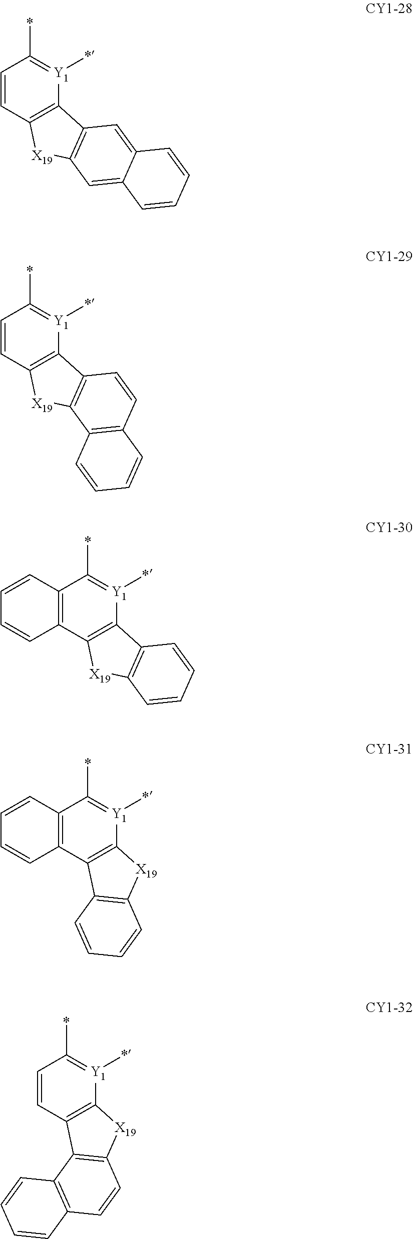

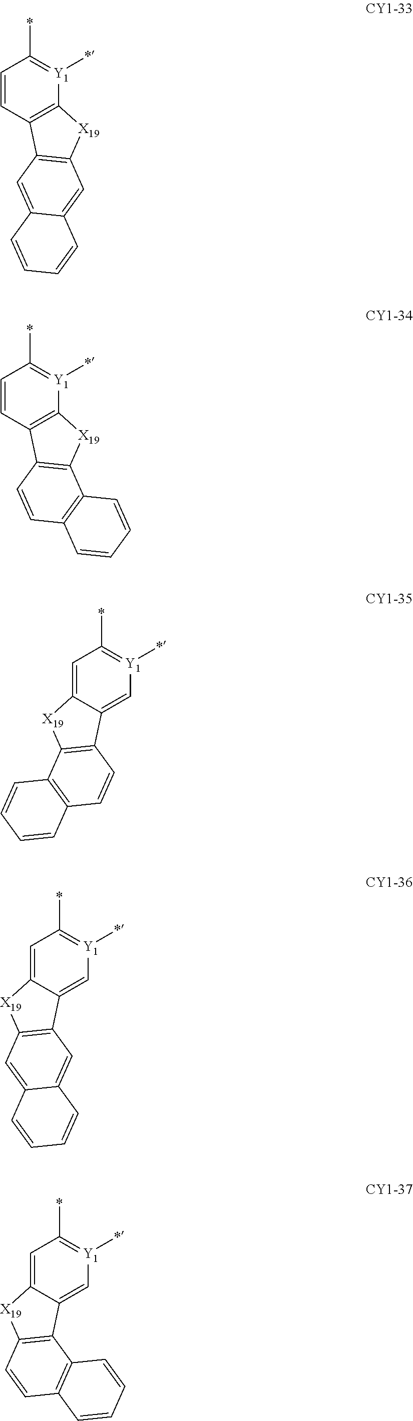

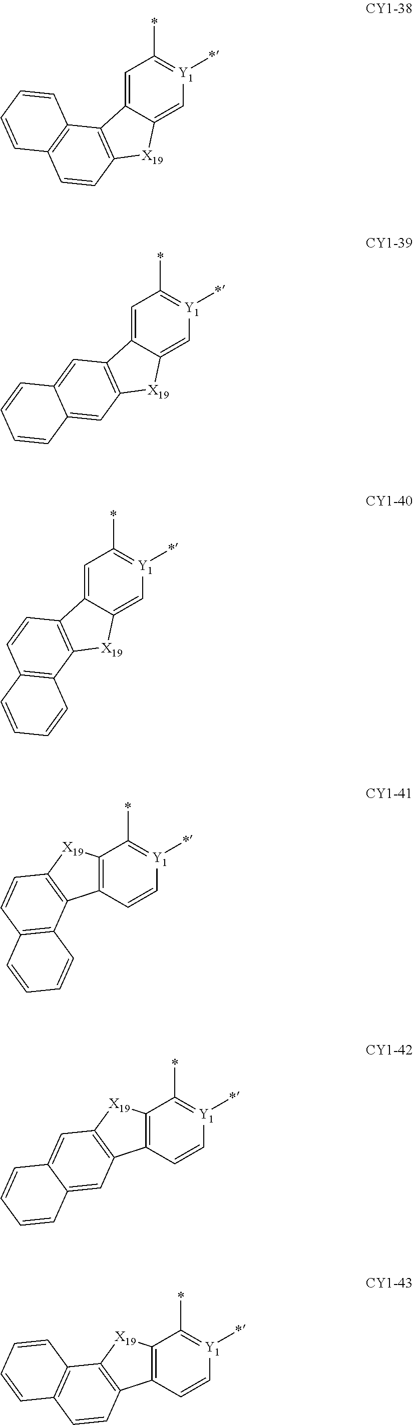

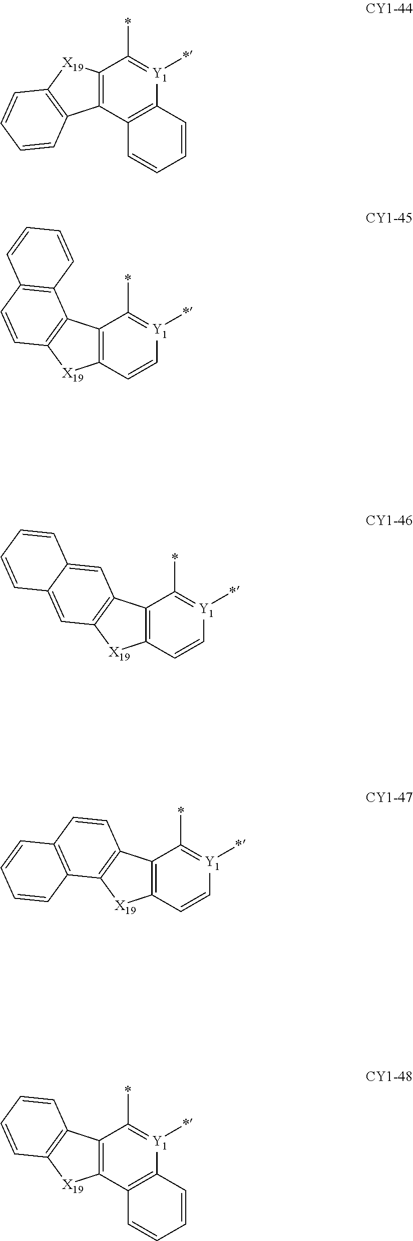

wherein, in Formulae CY1-1 to CY1-48,

Y₁ is as described above,

X₁₉ is C(R₁₉ₐ)(R_{19b}), N[(L₁₉)_{b19}-(R₁₉)_{c19}], O, S, or Si(R₁₉ₐ)(R_{19b}),

L₁₉ may be as described in connection with L₁;

b19 and c19 are as described in connection with b1 and c1,

R₁₉, R₁₉ₐ, and R_{19b} are as described in connection with R₁,

*′ indicates a binding site to X₁ or M in Formula 1, and

* indicates a binding site to ring CY₅ in Formula 1.

In one or more embodiments, the group represented by

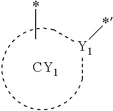

in Formulae 1 and 1-1A may be a group represented by one of Formulae CY1-9, CY1-10, CY1-13, CY1-14, CY1-17, CY1-18, and CY1-21 to CY1-48.

In one or more embodiments, the group represented by

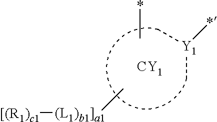

in Formula 1 and a group represented by

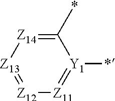

in Formulae 1-1, 1-1B and 1-1C may be a group represented by one of Formulae CY1(1) to CY1(22):

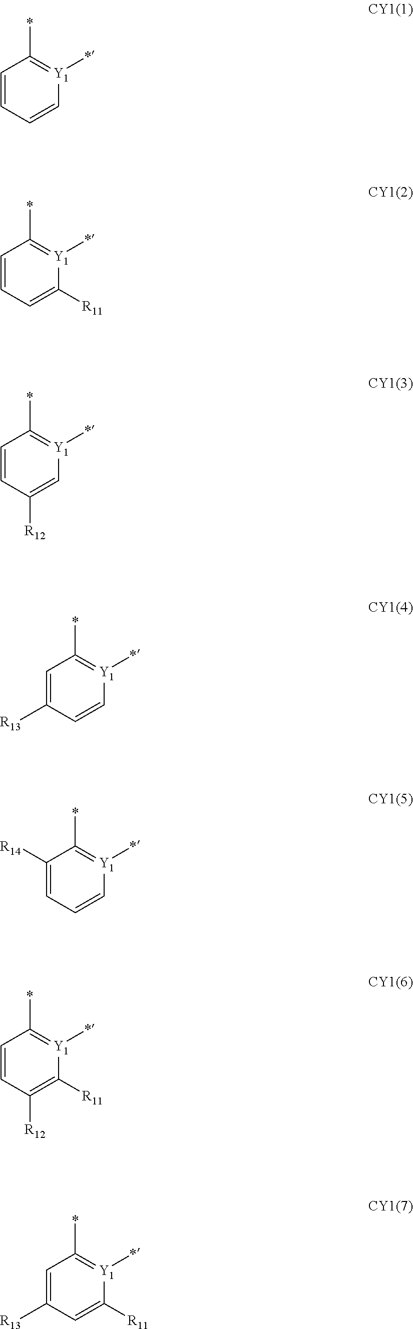

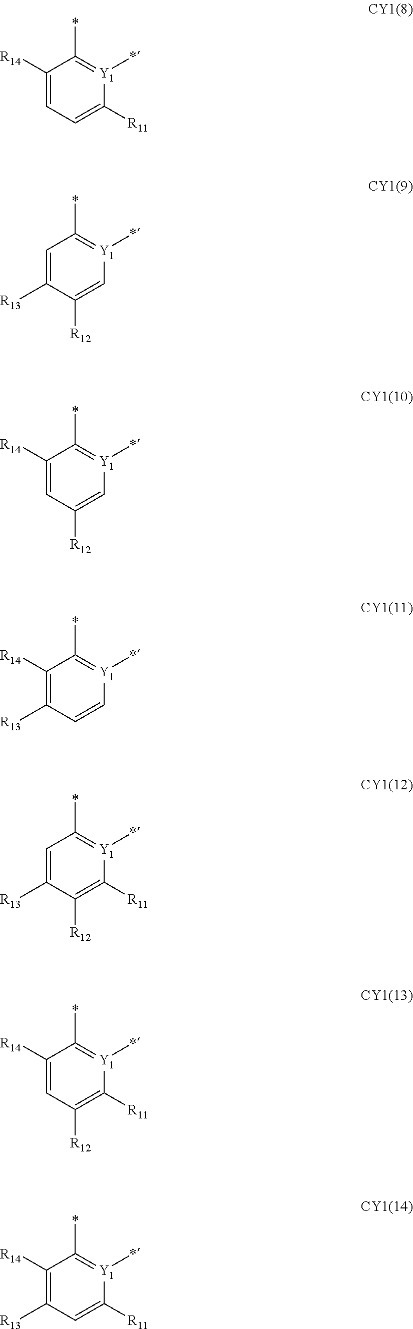

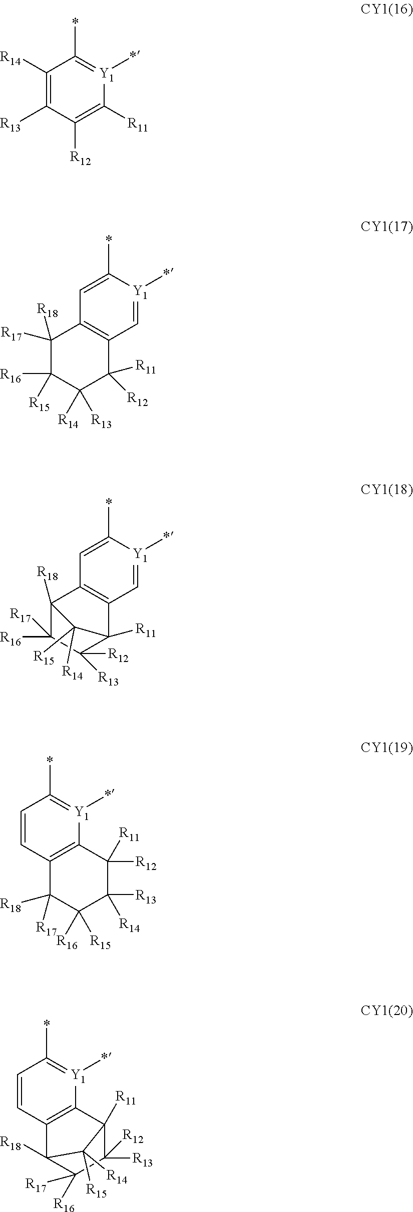

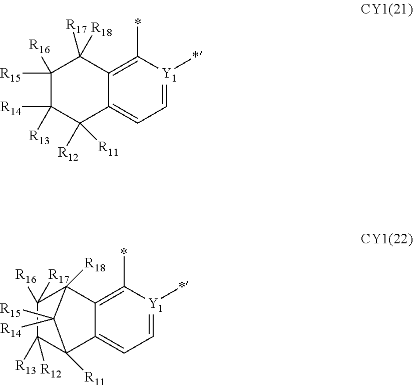

wherein, in Formulae CY1(1) to CY1(22),

Y₁ is as described above,

R₁₁ to R₁₈ are as described in connection with R₁, and each of R₁₁ to R₁₄ in Formula CY1(1) to CY1(16) may not be hydrogen,

*′ in Formulae CY1(1) to CY1(22) is a binding site to X₁ or M in Formula 1, and

* in Formulae CY1(1) to CY1(22) indicates a binding site to ring CY₅ in Formula 1.

In one or more embodiments, a group represented by

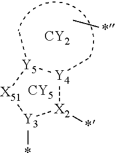

in Formula 1 and a group represented by

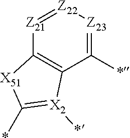

in Formulae 1-1, 1-1A, 1-1B, and 1-1C may be a group represented by one of Formulae CY2-1 to CY2-20:

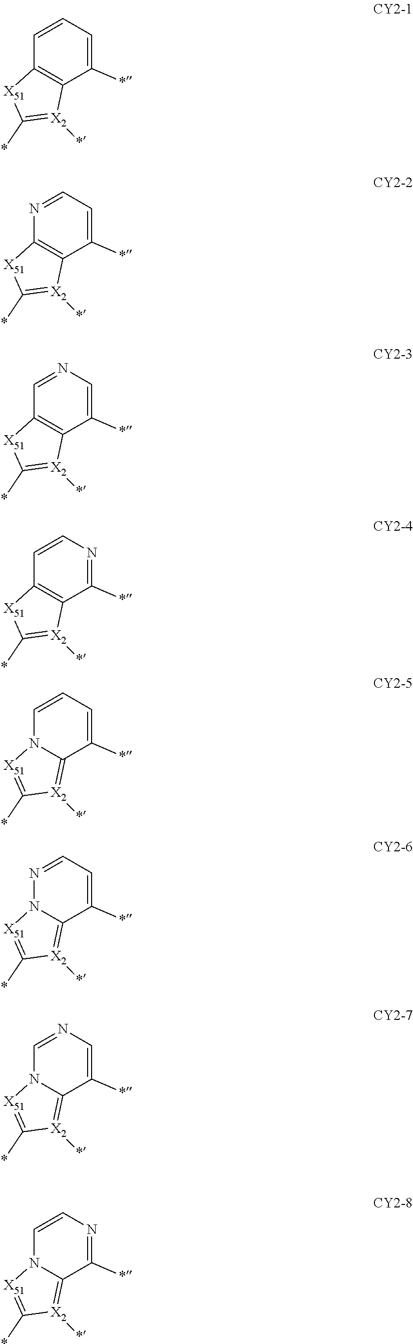

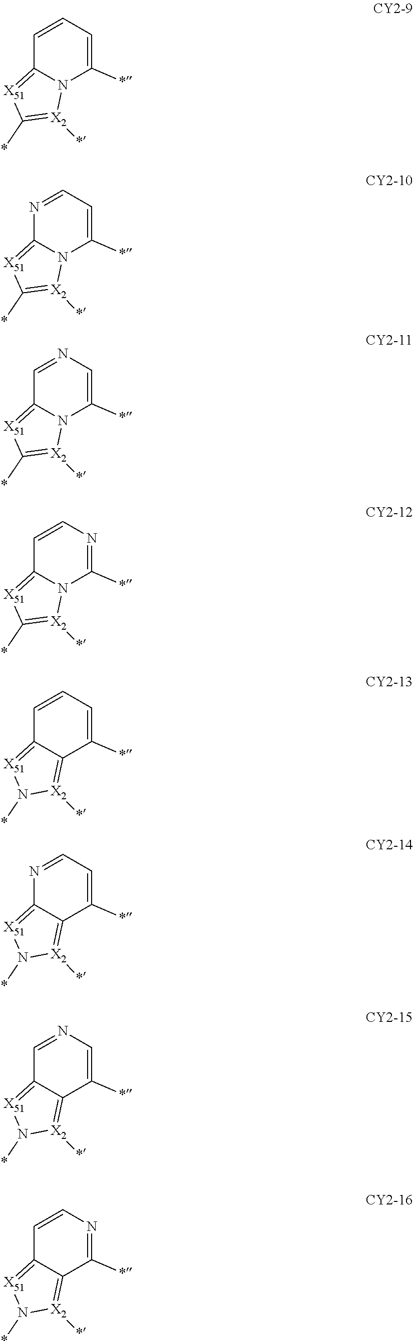

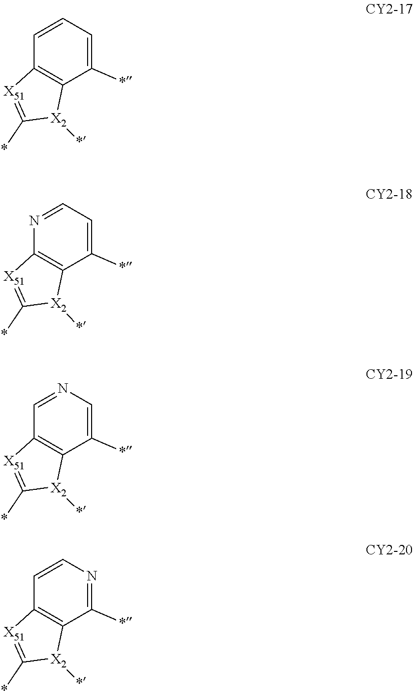

wherein, in Formulae CY2-1 to CY2-20,

X₂ and X₅₁ are as described in the present specification,

* indicates a binding site to ring CY₁ in Formula 1,

*′ indicates a binding site to M in Formula 1, and

*″ indicates a binding site to ring CY₃ in Formula 1.

In one or more embodiments, a group represented by

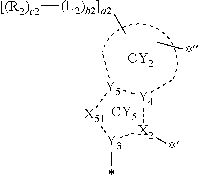

in Formula 1 and a group represented by

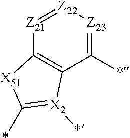

in Formulae 1-1, 1-1A, 1-1B, and 1-1C may be a group represented by one of Formulae CY2(1) to CY2(20):

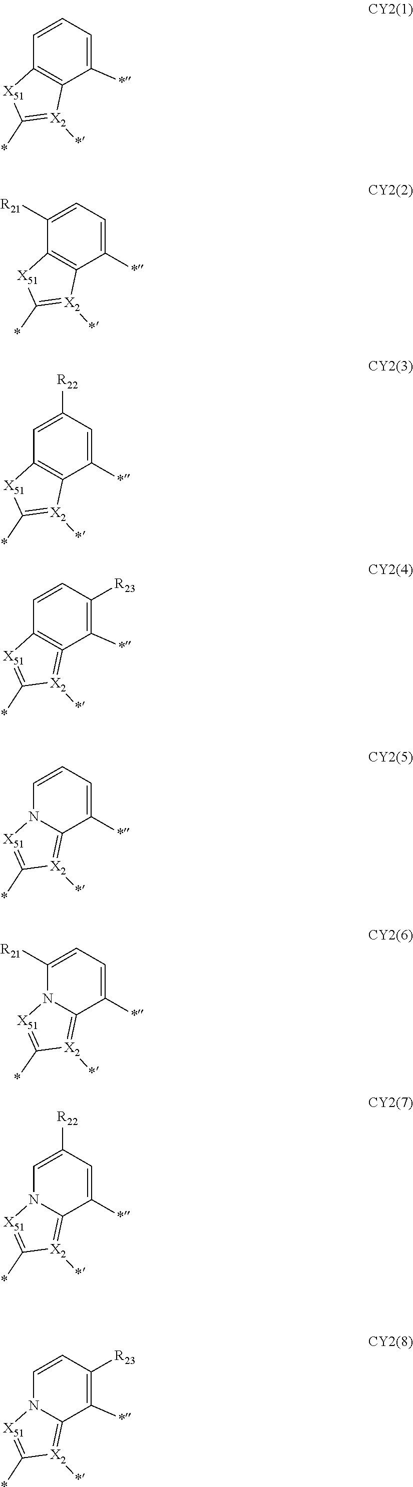

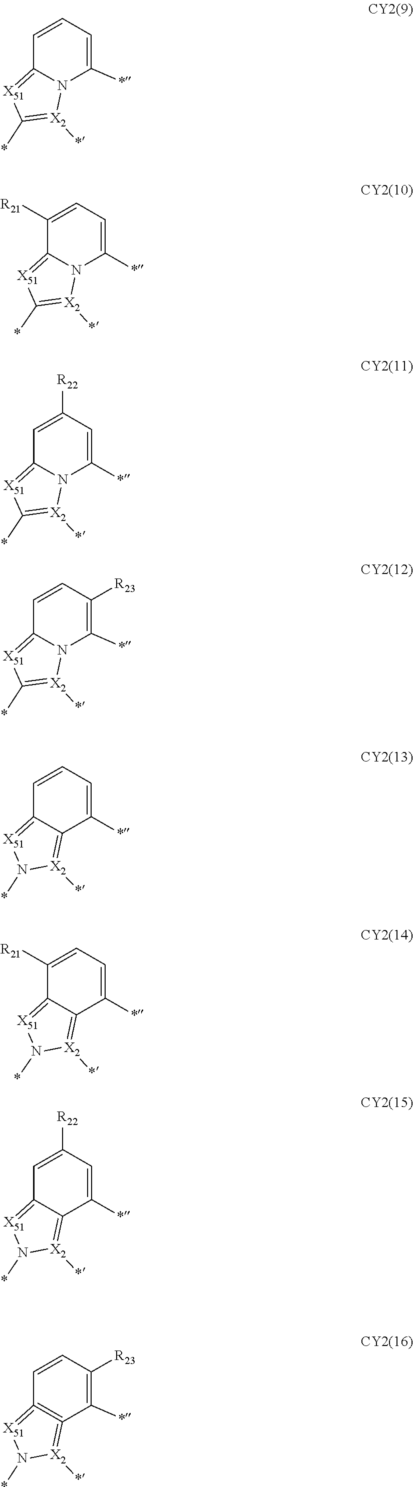

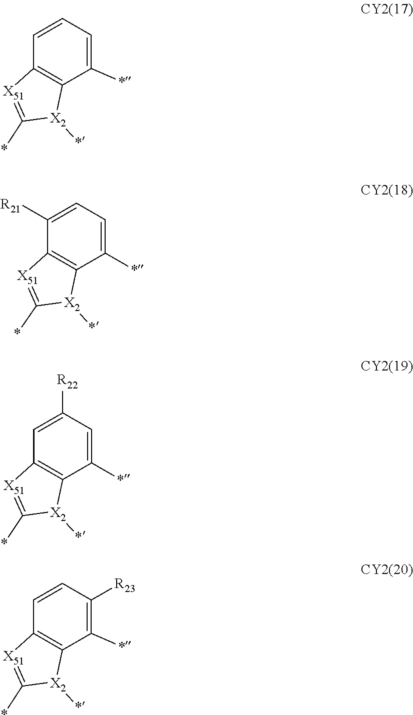

wherein, in Formulae CY2(1) to CY2(20),

X₂ and X₅₁ are as described in the present specification,

R₂₁ to R₂₃ are as described in connection with R₂, and each of R₂₁ to R₂₃ may not be hydrogen,

* indicates a binding site to ring CY₁ in Formula 1,

*′ indicates a binding site to M in Formula 1, and

*″ indicates a binding site to ring CY₃ in Formula 1.

In one or more embodiments, a group represented by

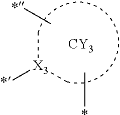

in Formula 1 may be a group represented by one of Formulae CY3-1 to CY3-26 and a group represented by

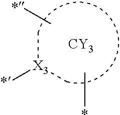

in Formula 1-1B may be a group represented by one of Formulae CY3-5 to CY3-26:

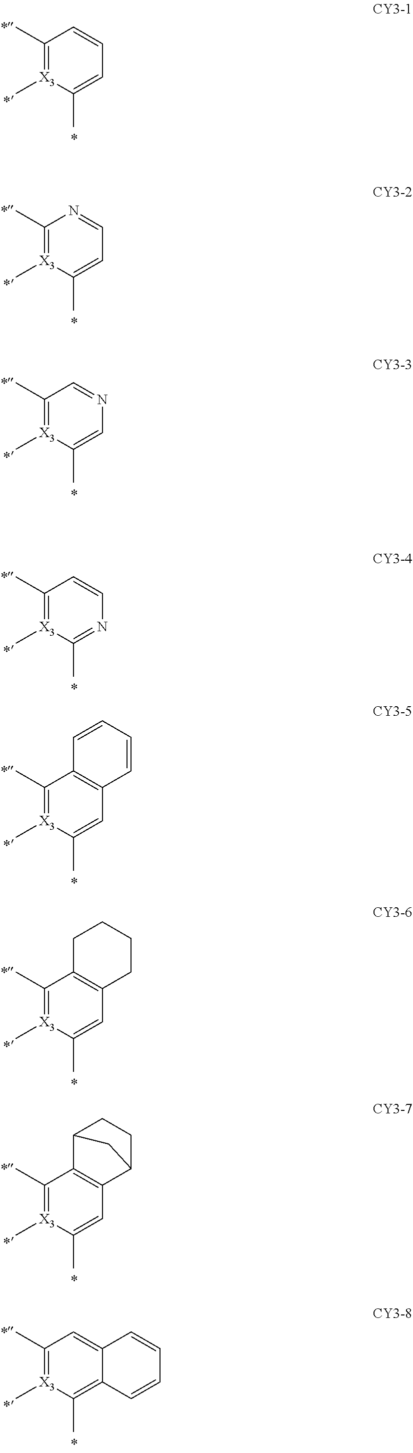

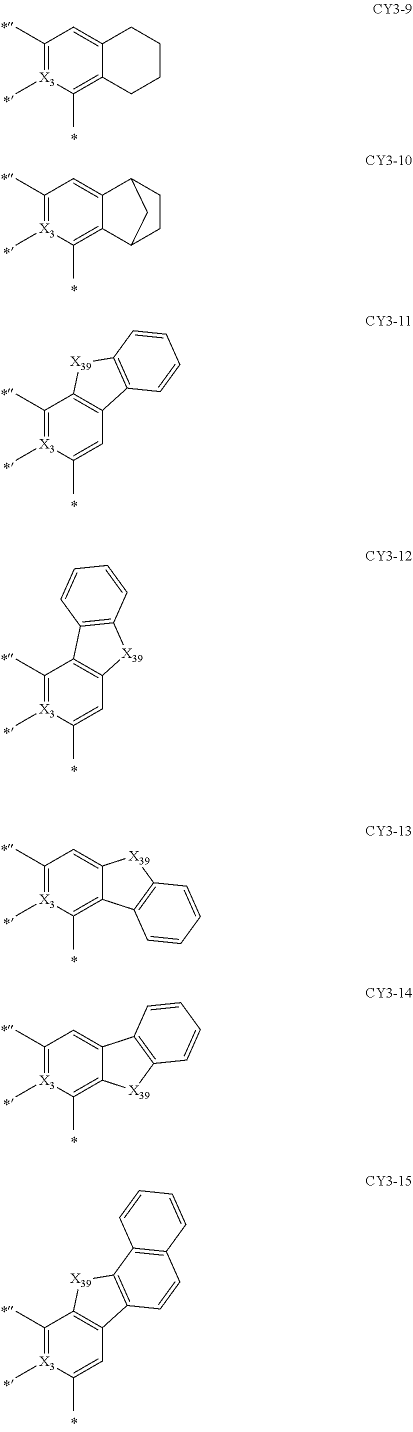

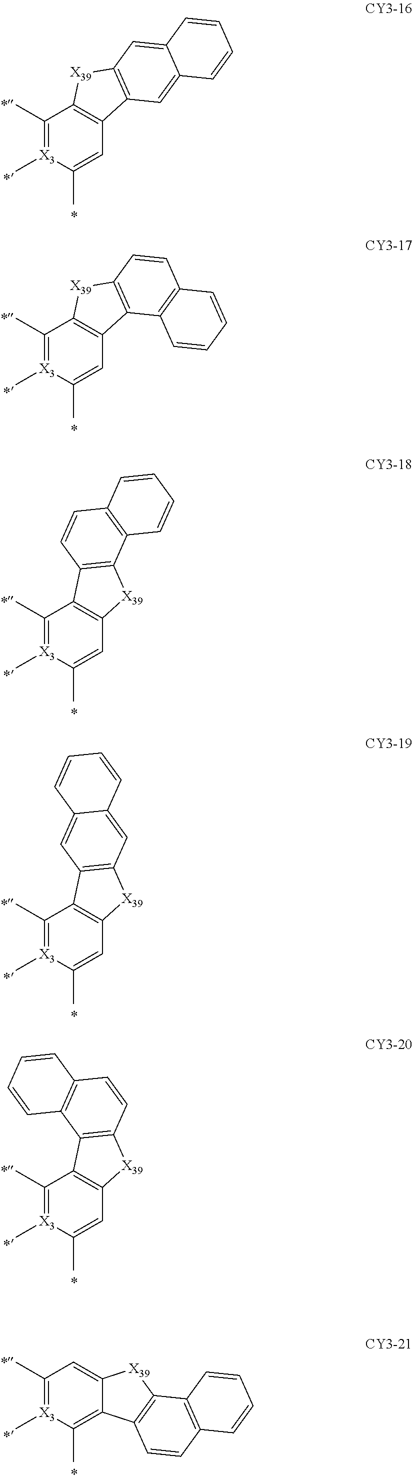

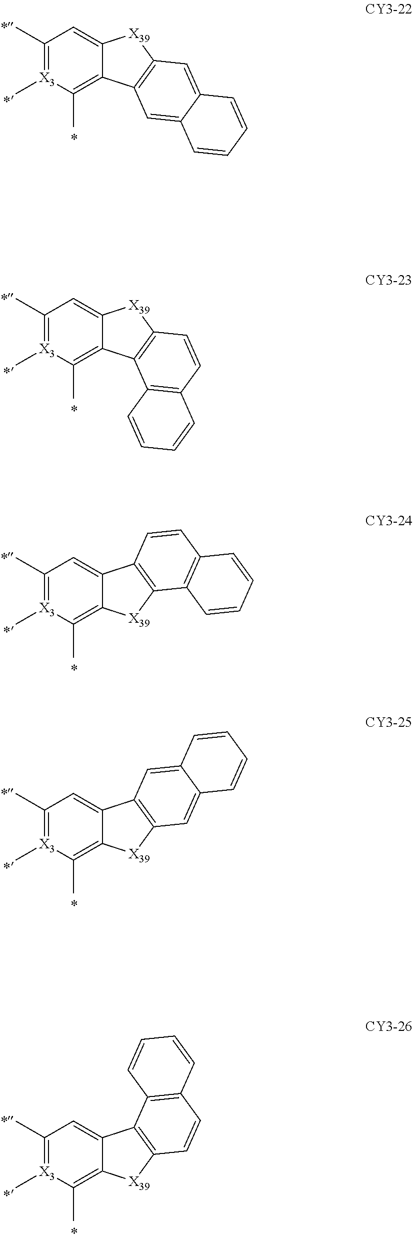

wherein, in Formulae CY3-1 to 3-26,

X₃ is as described in the present specification,

X₃₉ may be C(R₃₉ₐ)(R_{39b}), N[(L₃₉)_{b39}-(R₃₉)_{c39}], O, S, or Si(R₃₉ₐ)(R_{39b}),

L₃₉ may be as described in connection with L₃,

b39 and c39 may be as described in connection with b3 and c3,

R₃₉, R₃₉ₐ, and R_{39b} are each as described in connection with R₃,

* indicates a binding site to T₁ in Formula 1,

*′ indicates a binding site to M in Formula 1, and

*″ indicates a binding site to ring CY₂ in Formula 1.

In one or more embodiments, a group represented by

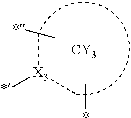

in Formulae 1 and 1-1B may be a group represented by one of Formulae CY3-5, CY3-8 and CY3-11 to CY3-26.

In one or more embodiments, a group represented by

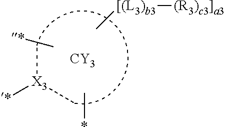

in Formula 1 and a group represented by

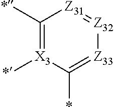

in Formulae 1-1, 1-1A and 1-1C may be a group represented by one of Formulae CY3(1) to CY3(12):

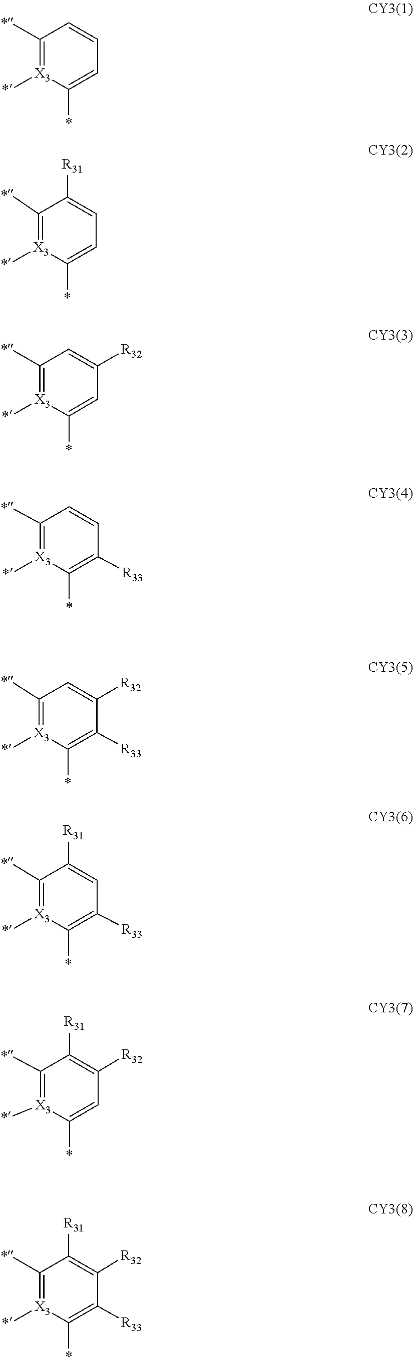

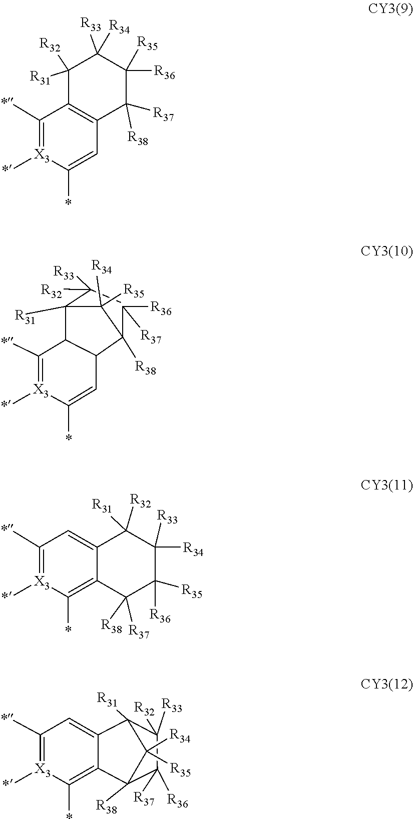

wherein, in CY3(1) to CY3(12),

X₃ is as described in the present specification,

R₃₁ to R₃₈ are each as described in connection with R₃, and each of R₃₁ to R₃₄ in CY3(1) to CY3(8) may not be hydrogen,

* indicates a binding site to T₁ in Formula 1,

*′ indicates a binding site to M in Formula 1, and

*″ indicates a binding site to ring CY₂ in Formula 1.

In one or more embodiments, a group represented by

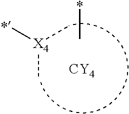

in Formula 1 may be a group represented by one of Formulae CY4-1 to CY4-48 and a group represented by

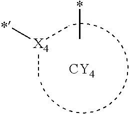

in Formula 1-1C may be a group represented by one of Formulae CY4-9 to CY4-48:

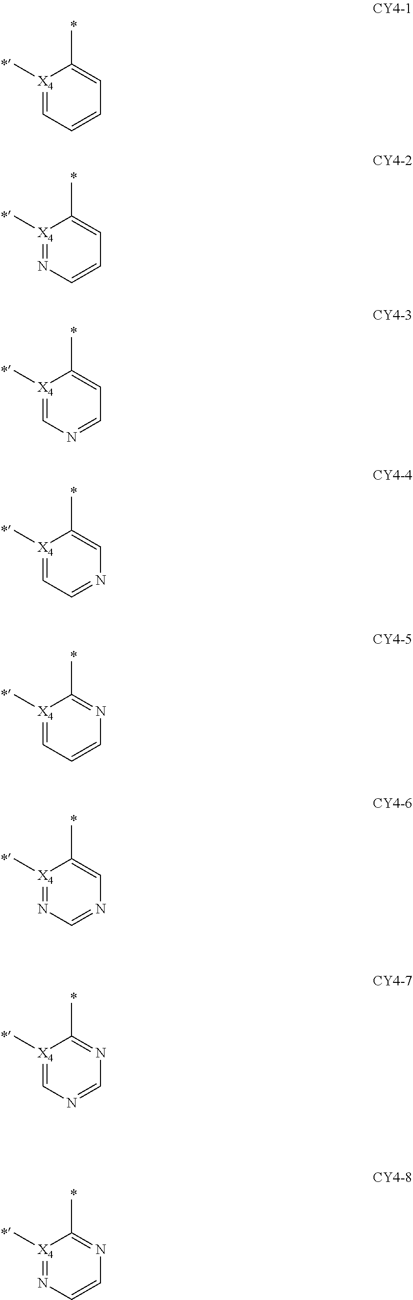

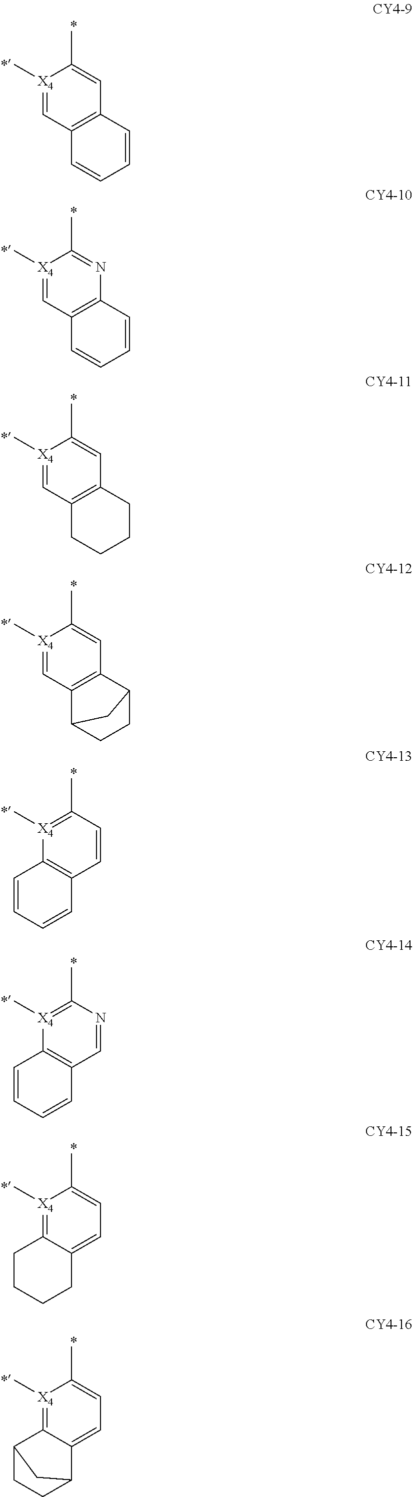

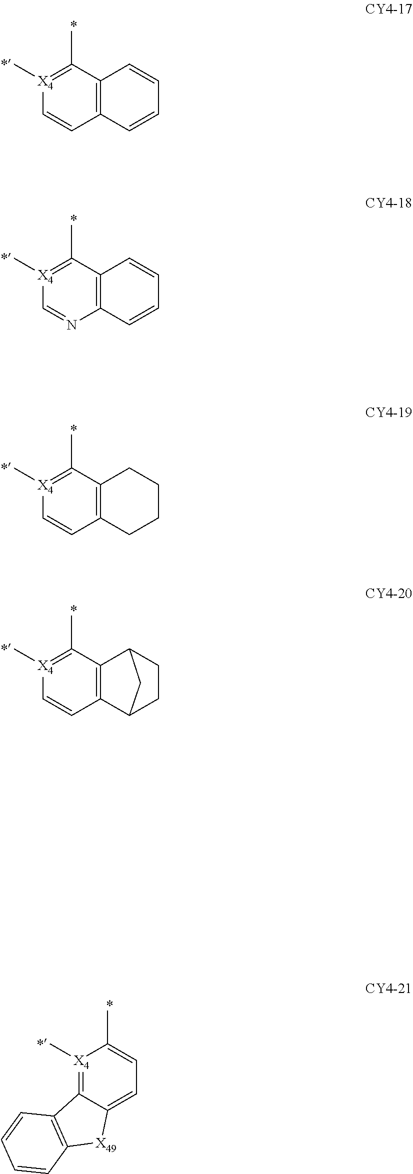

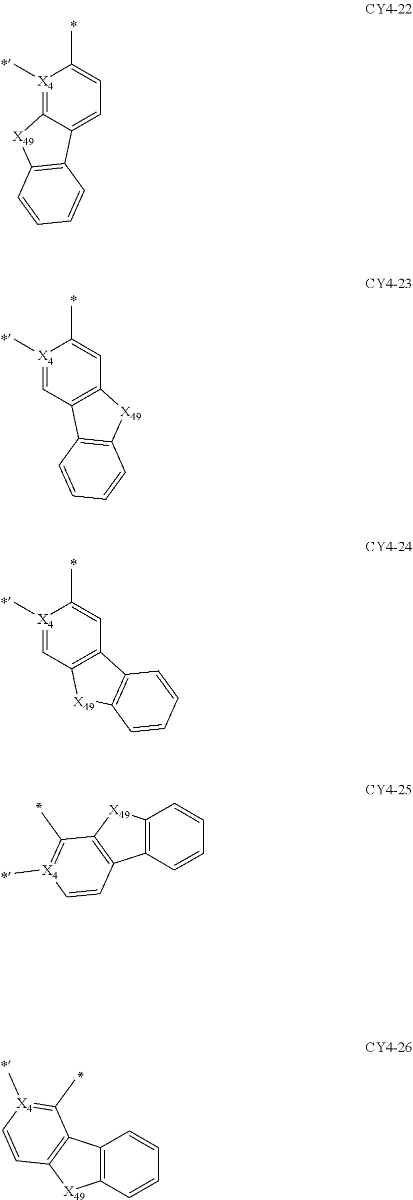

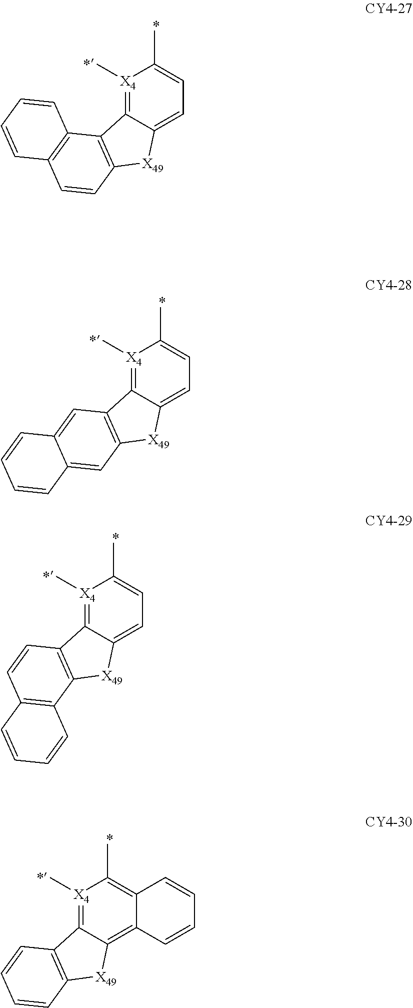

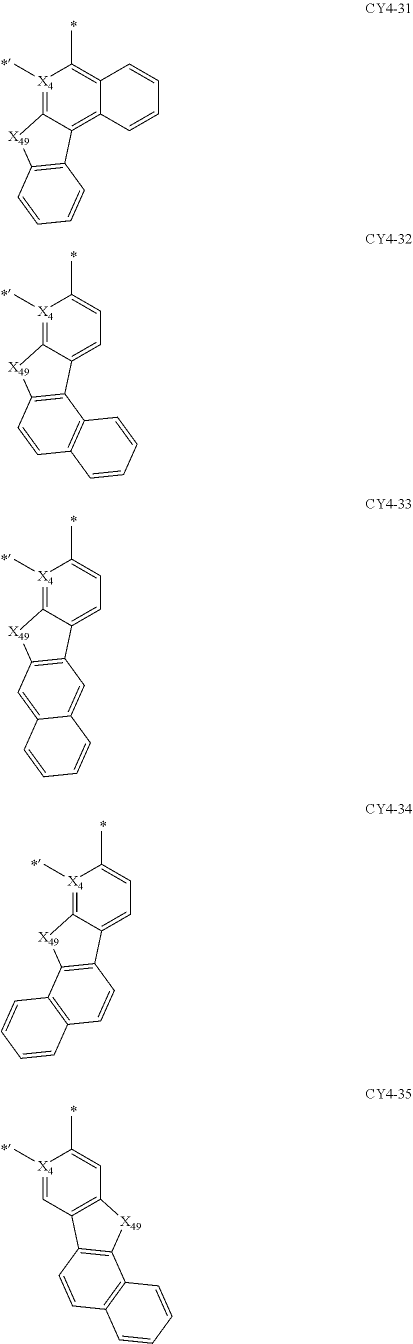

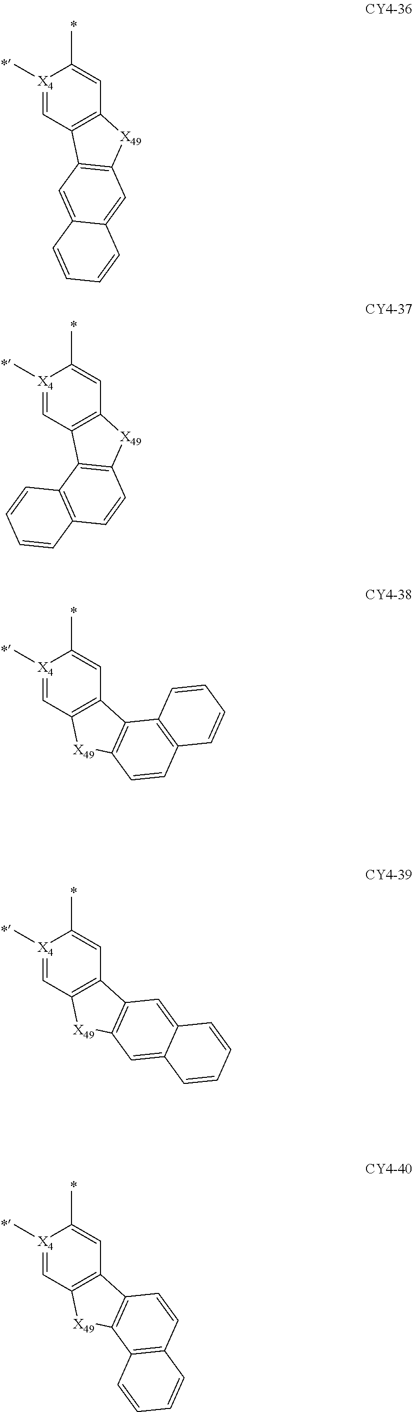

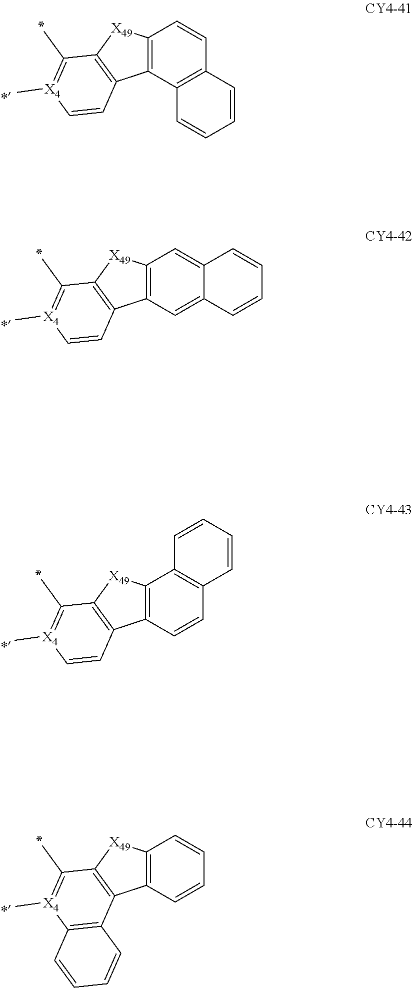

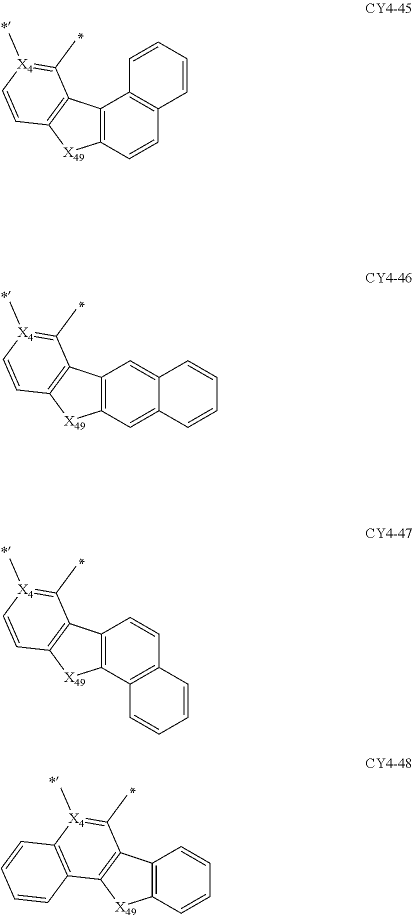

wherein, in Formulae CY4-1 to 4-48,

X₄ is as described in the present specification,

X₄₉ is C(R₄₉ₐ)(R_{49b}), N[(L₄₉)_{b49}-(R₄₉)_{c49}], O, S, or Si(R₄₉ₐ)(R_{49b}),

L₄₉ is as described in connection with L₄,

b49 and c49 are each as described in connection with b4 and c4,

R₄₉, R₄₉ₐ, and R_{49b} are each as described in connection with R₄,

* indicates a binding site to Tₐ in Formula 1n

*′ indicates a binding site to M in Formula 1.

In one or more embodiments, the group represented by

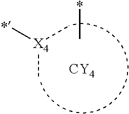

in Formula 1 and 1-1C may be a group represented by one of Formulae CY4-9, CY4-10, CY4-13, CY4-14, CY4-17, CY4-18, and CY4-21 to CY4-48.

In one or more embodiments, the group represented by

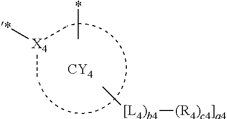

in Formula 1 and a group represented by

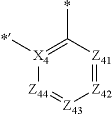

in Formulae 1-1, 1-1A and 1-1B may be a group represented by one of Formulae CY4(1) to CY4(22):

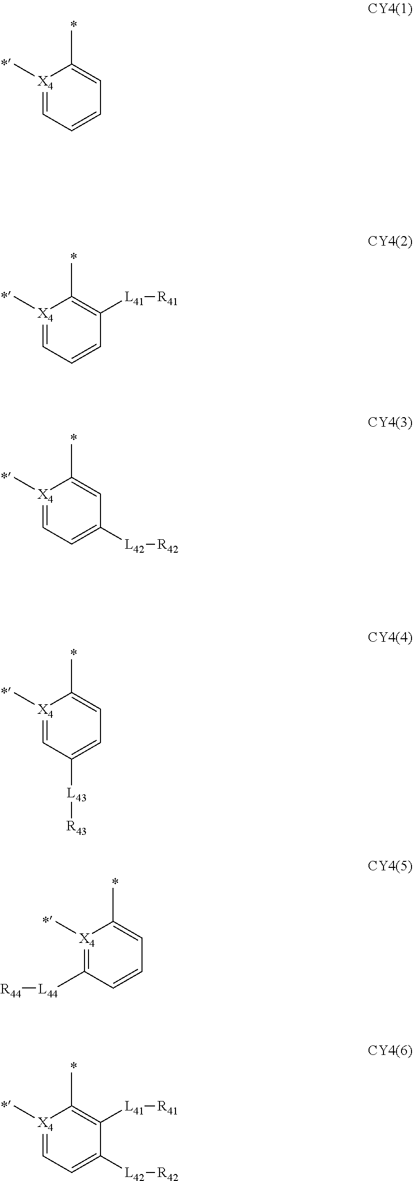

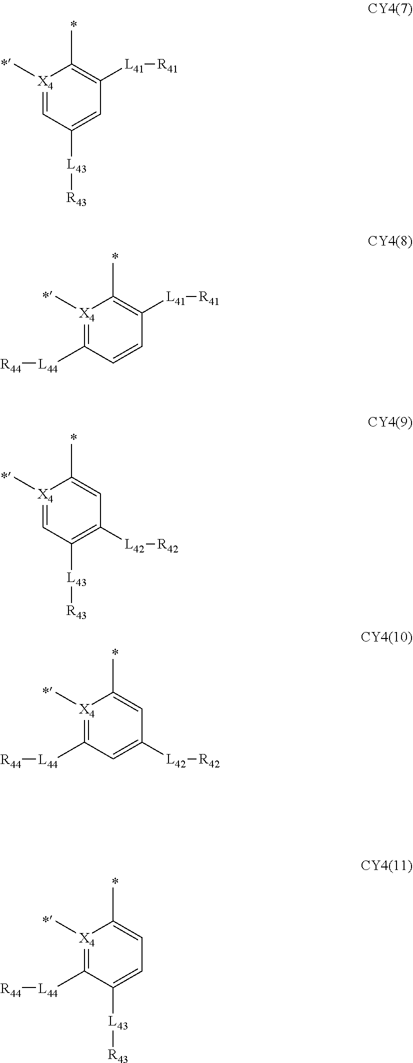

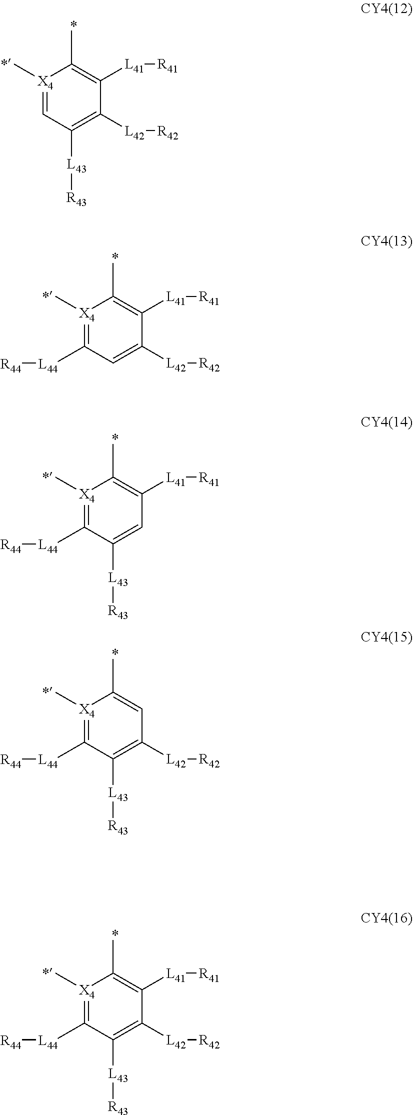

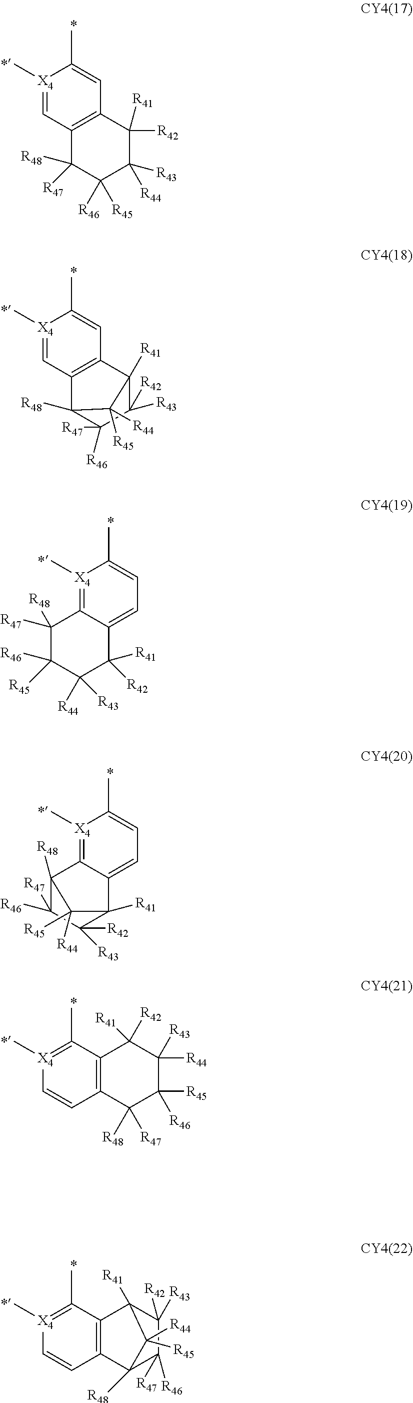

wherein, in Formulae CY4(1) to CY4(22),

X₄ is as described in the present specification,

L₄₁ to L₄₄ are each as described in connection with L₄,

R₄₁ to R₄₈ are each as described in connection with R₄, and each of R₄₁ to R₄₄ in Formulae CY4(1) to CY4(16) may not be hydrogen,

* indicates a binding site to T₁ in Formula 1, and

*′ indicates a binding site to M in Formula 1.

In one or more embodiments, the organometallic compound represented by Formula 1 may satisfy at least one of Condition 1 to Condition 3:

Condition 1

the group represented by

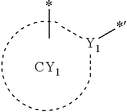

in Formula 1 is a group represented by one of Formulae CY1-9 to CY1-48;

Condition 2

the group represented by

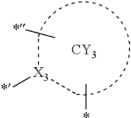

in Formula 1 is a group represented by one of Formulae CY3-5 to CY3-26; and

Condition 3

the group represented by

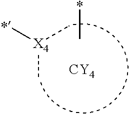

in Formula 1 is a group represented by one of Formulae CY4-9 to CY4-48.

In one or more embodiments, the organometallic compound represented by Formula 1 may satisfy at least one of: Condition 1A or Condition 1B; Condition 2A or Condition 2B; and Condition 3A or Condition 3B:

Condition 1A

the group represented by

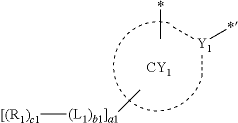

in Formula 1 is a group represented by one of Formulae CY1(17) to CY1(22);

Condition 1B

the group represented by

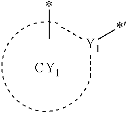

in Formula 1 is a group represented by one of Formulae CY1-9, CY1-10, CY1-13, CY1-14, CY1-17, CY1-18, and CY1-21 to CY1-48;

Condition 2A

the group represented by

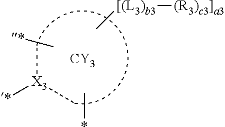

in Formula 1 is a group represented by one of Formulae CY3(9) to CY3(12);

Condition 2B

the group represented by

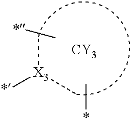

in Formula 1 is a group represented by one of Formulae CY3-5, CY3-8, and CY3-11 to CY3-26;

Condition 3A

the group represented by

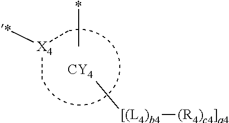

in Formula 1 may be a group represented by one of Formulae CY4(17) to CY4(22);

Condition 3B

the group represented by

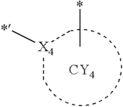

in Formula 1 may be a group represented by one of Formulae CY4-9, CY4-10, CY4-13, CY4-14, CY4-17, CY4-18, and CY4-21 to CY4-48.

In one or more embodiments, the organometallic compound represented by Formula 1 may include at least one deuterium.

The organometallic compound represented by Formula 1 may be one of Compounds 1 to 804:

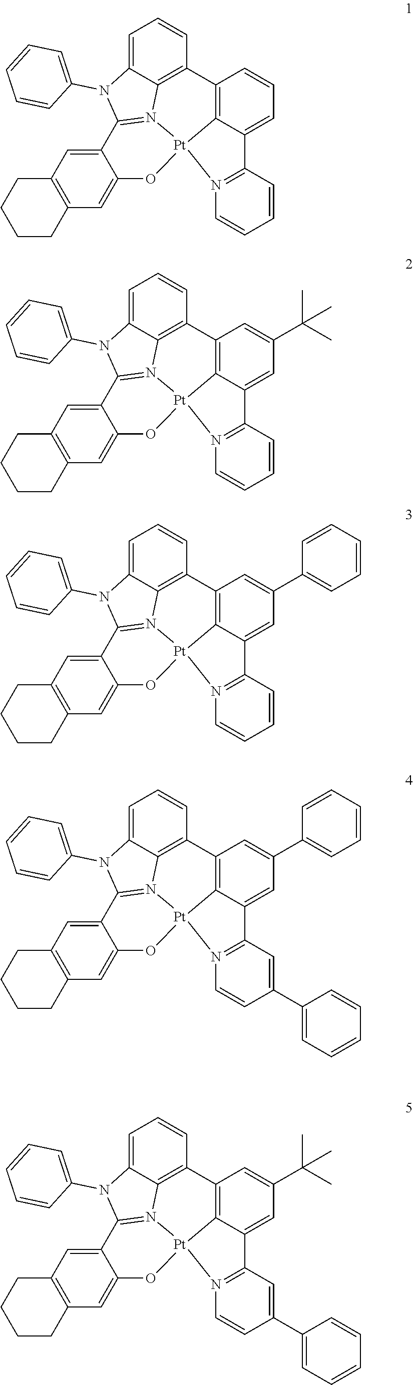

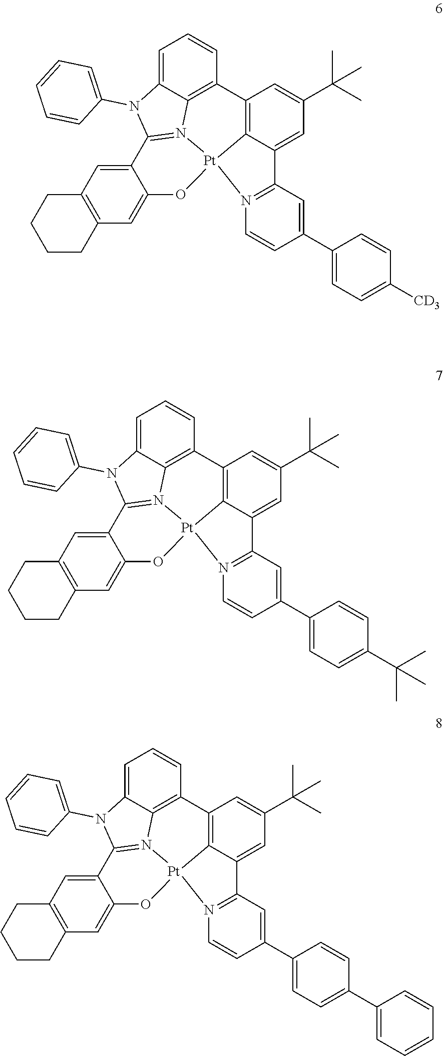

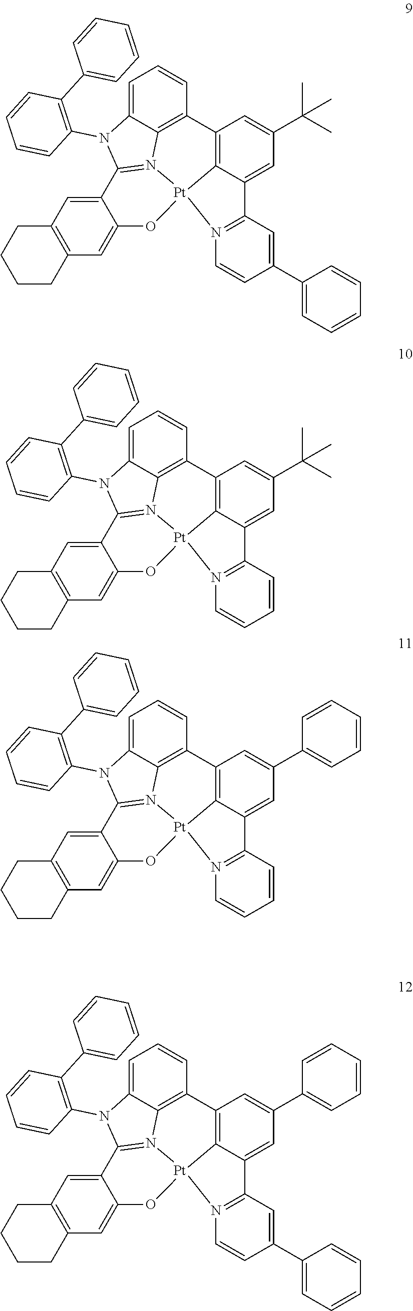

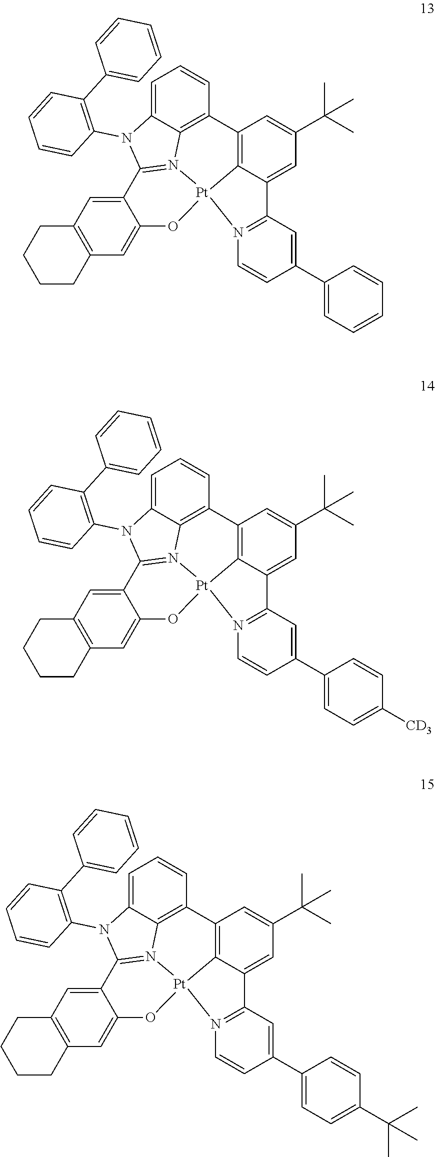

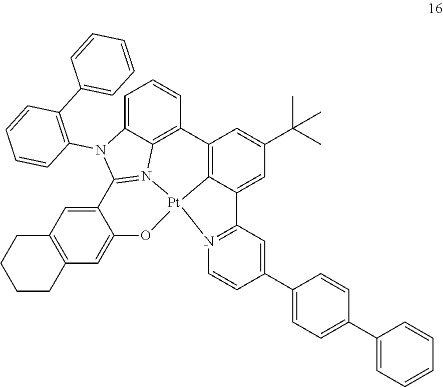

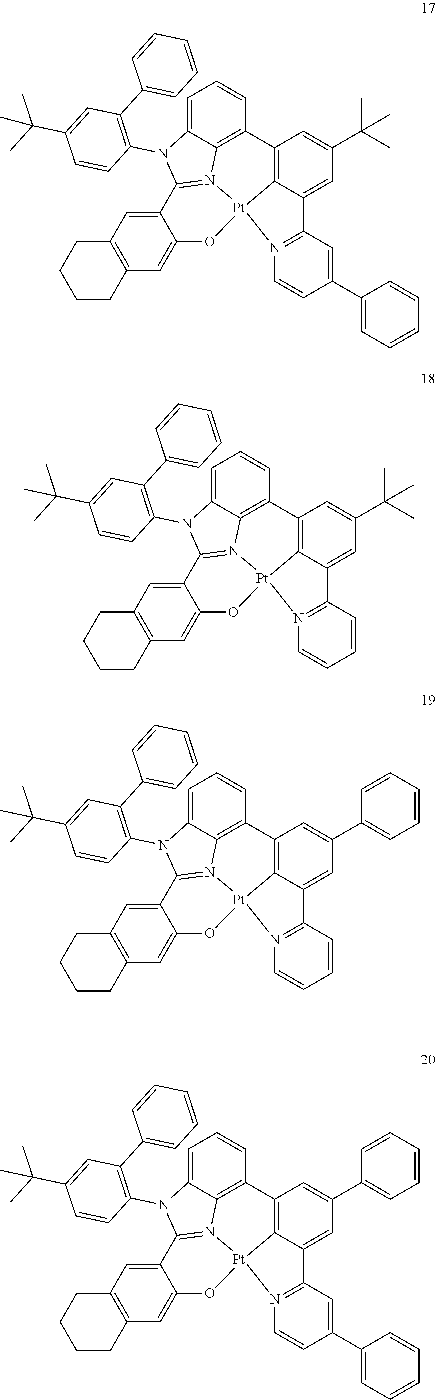

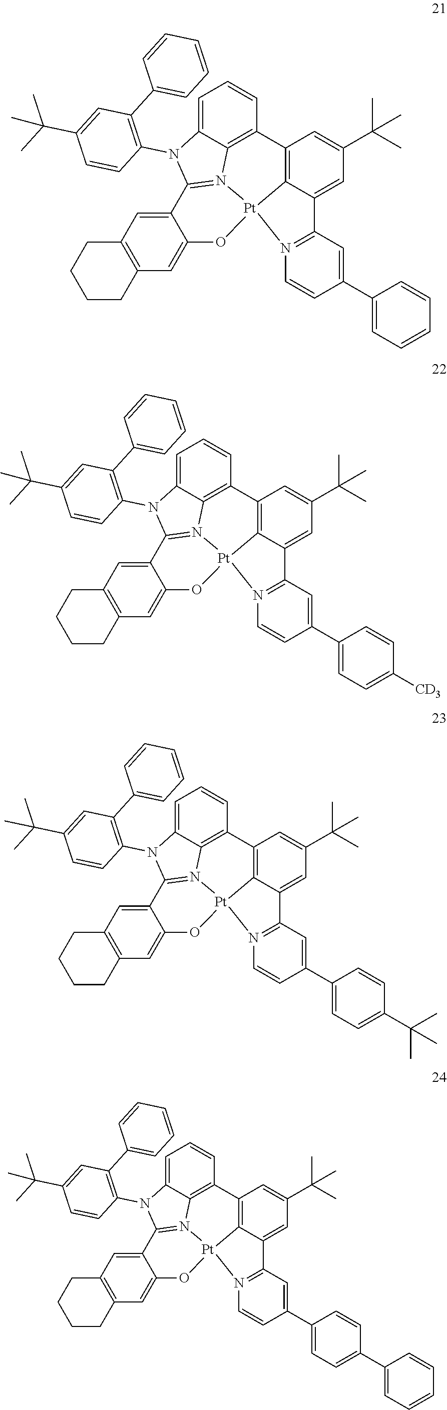

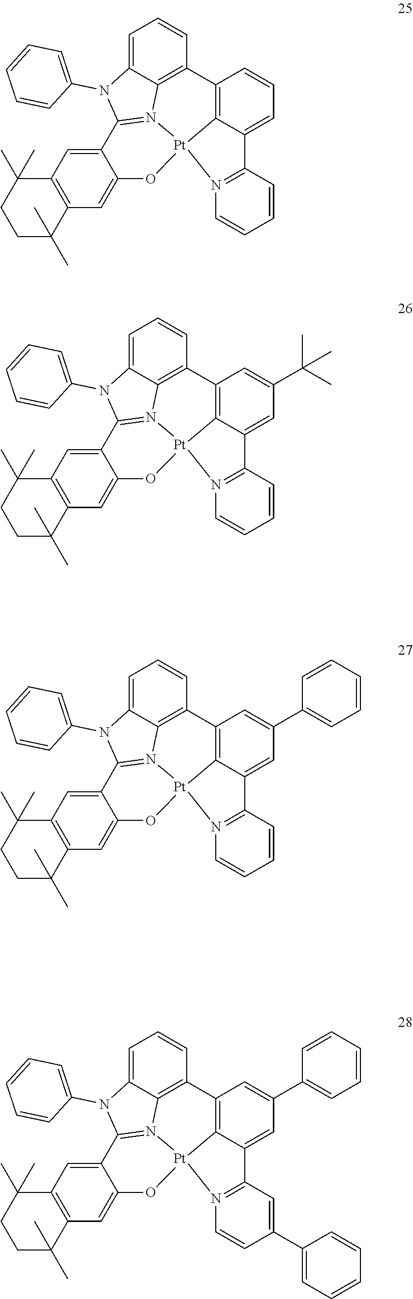

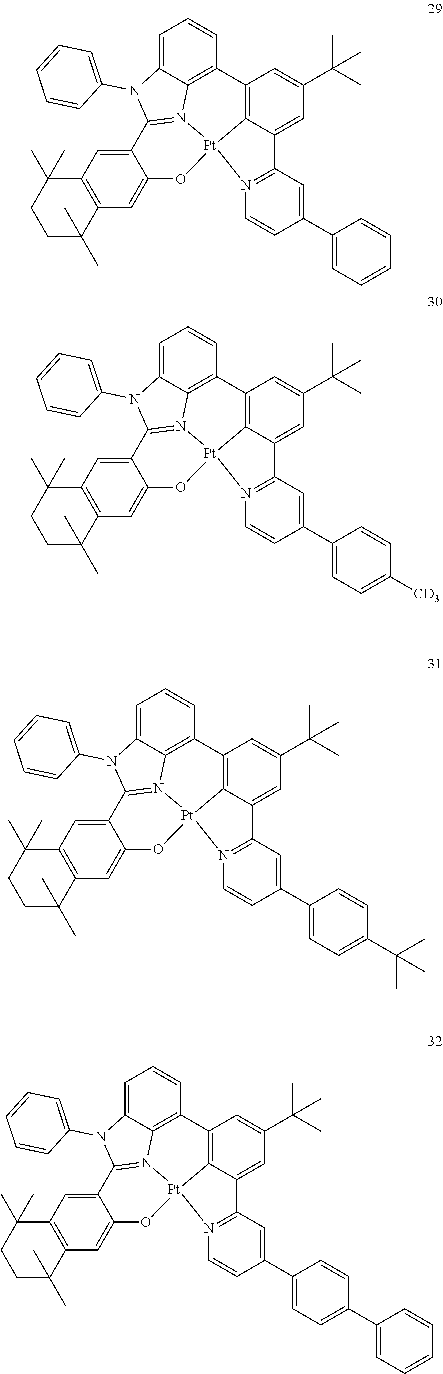

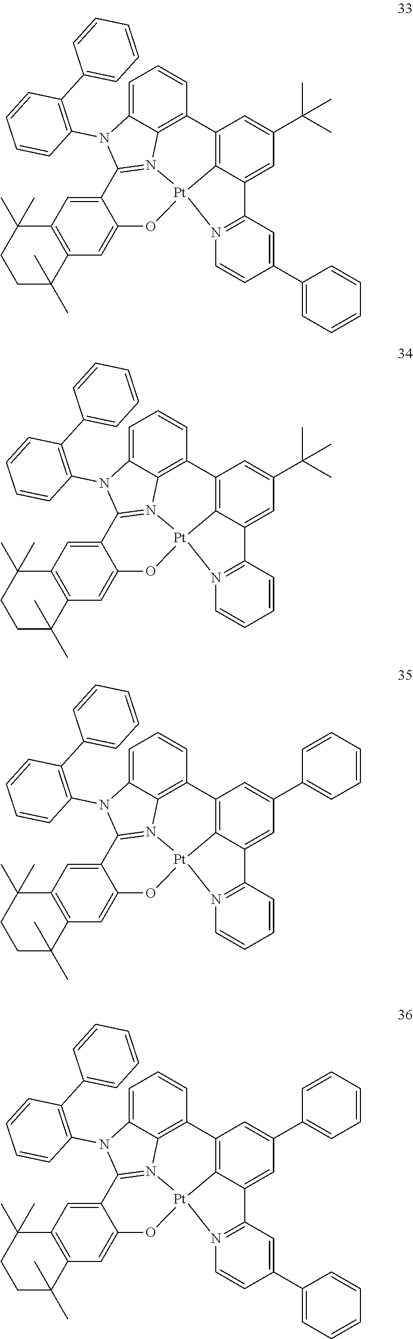

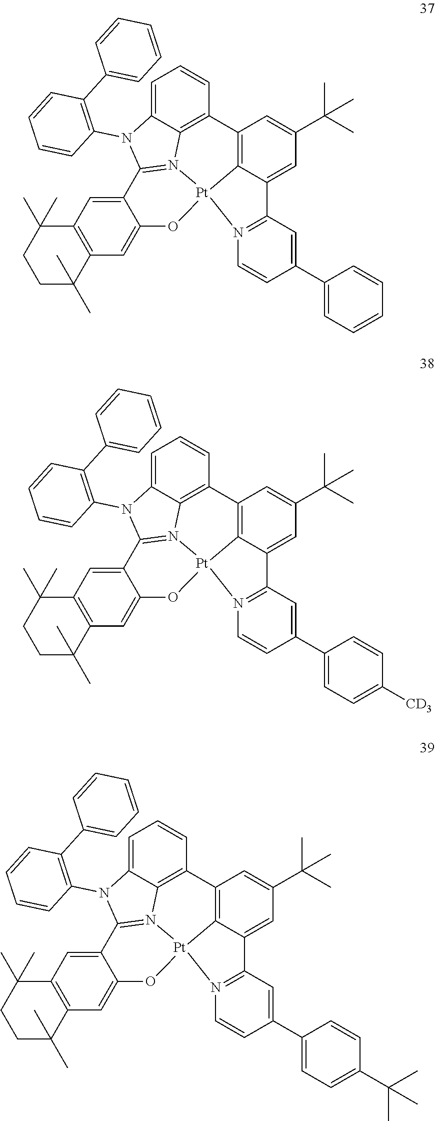

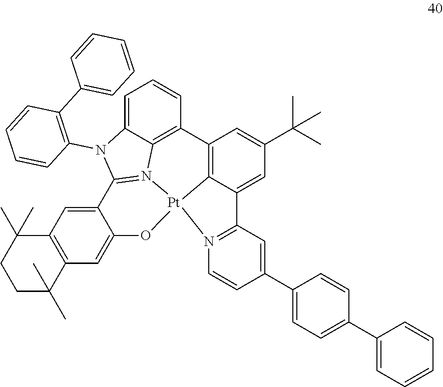

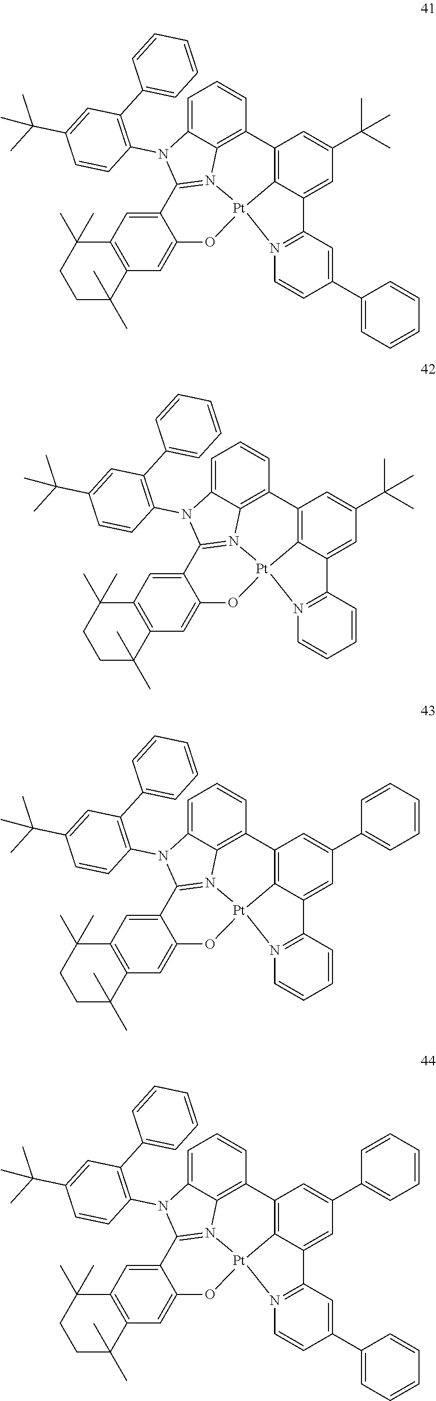

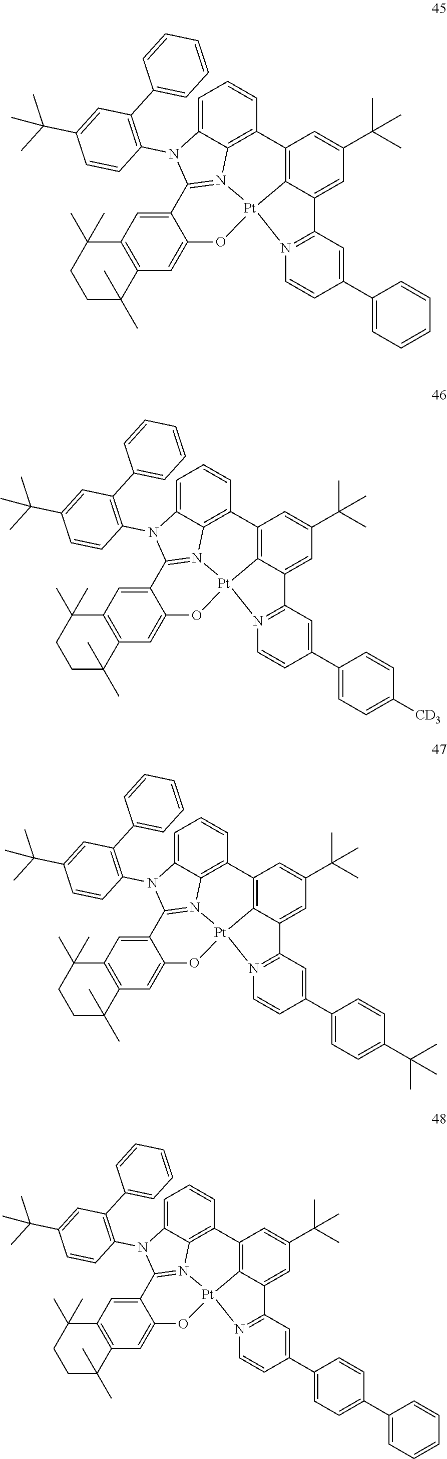

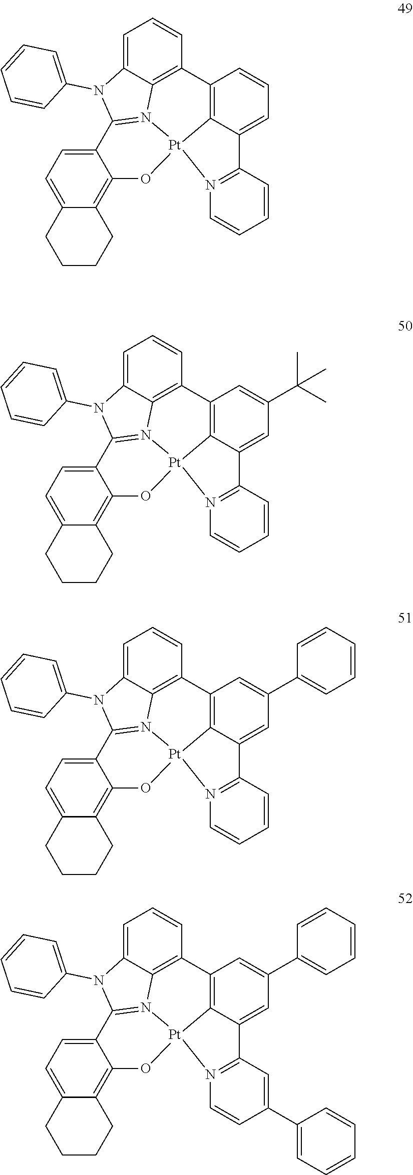

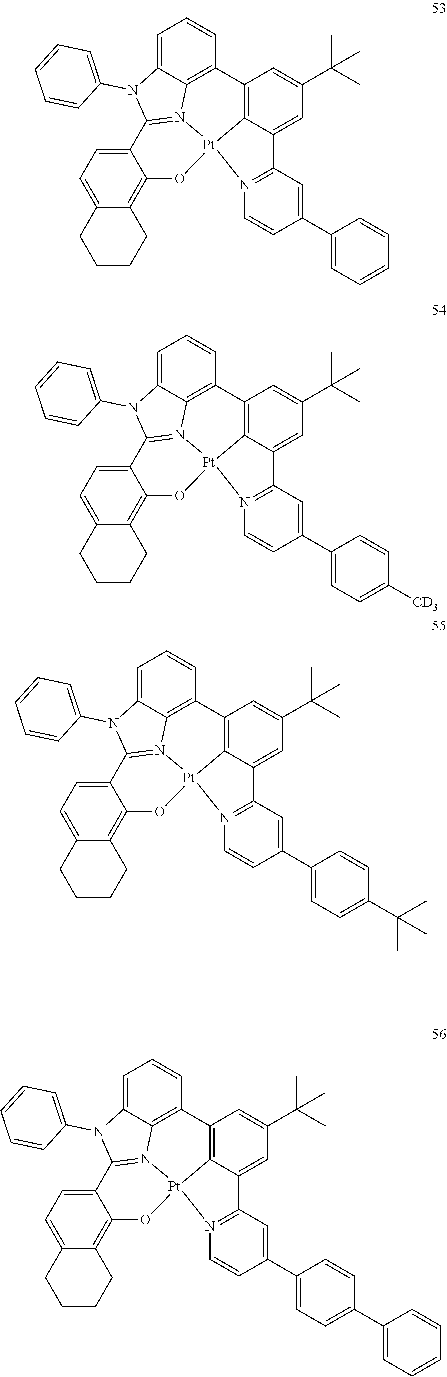

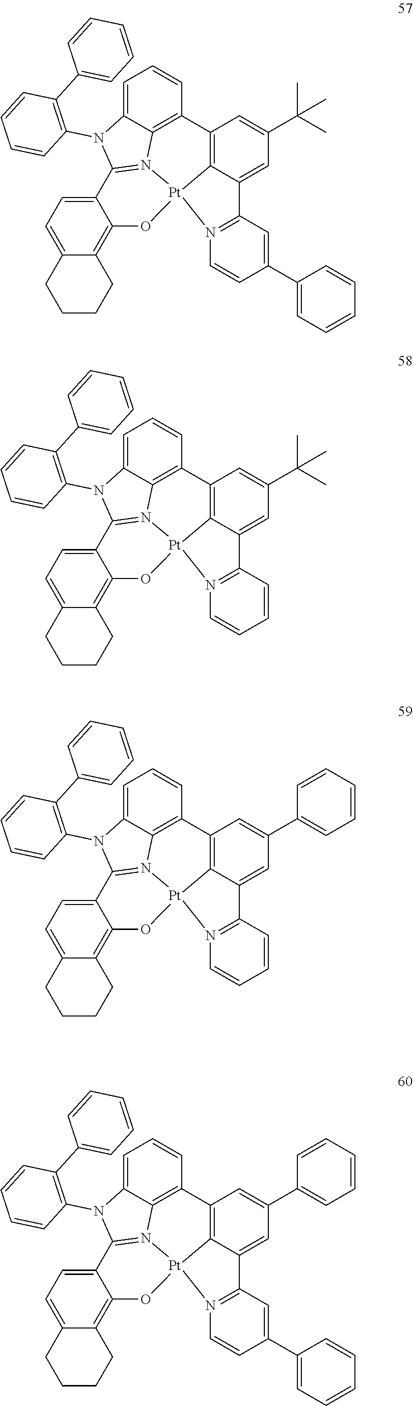

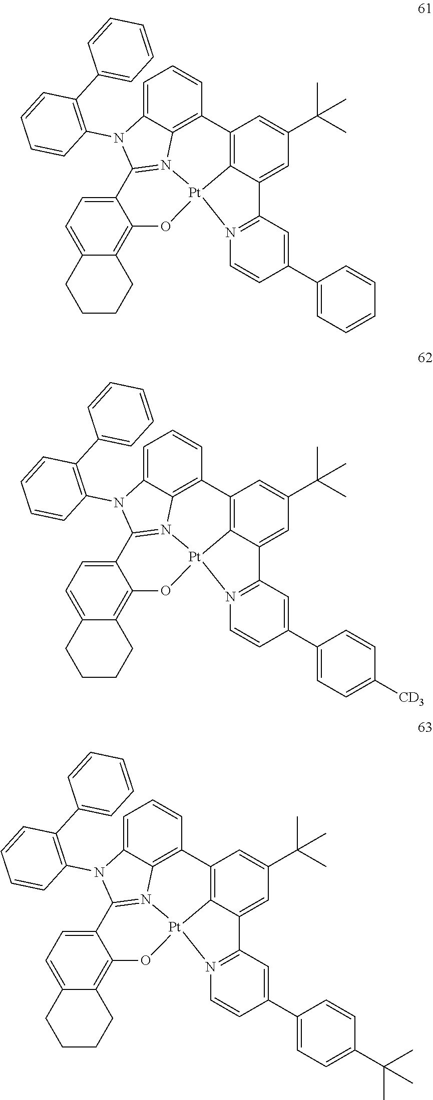

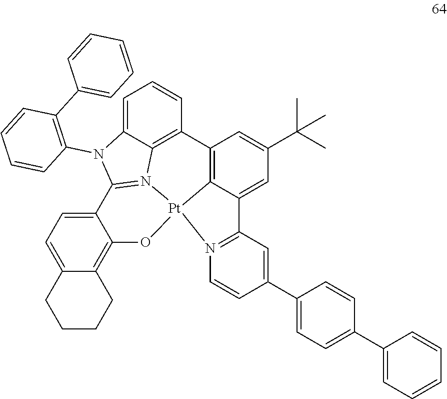

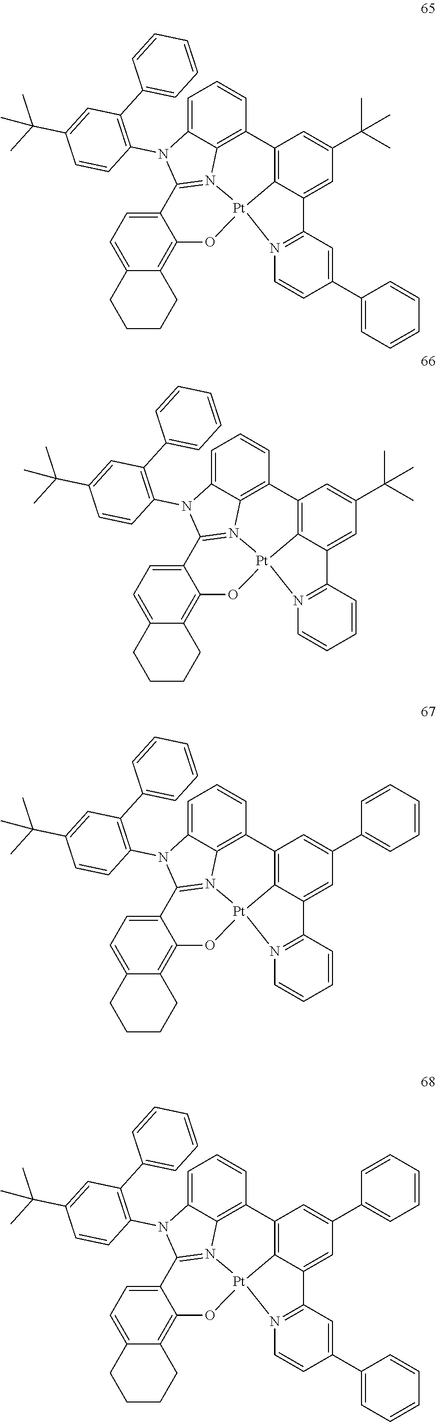

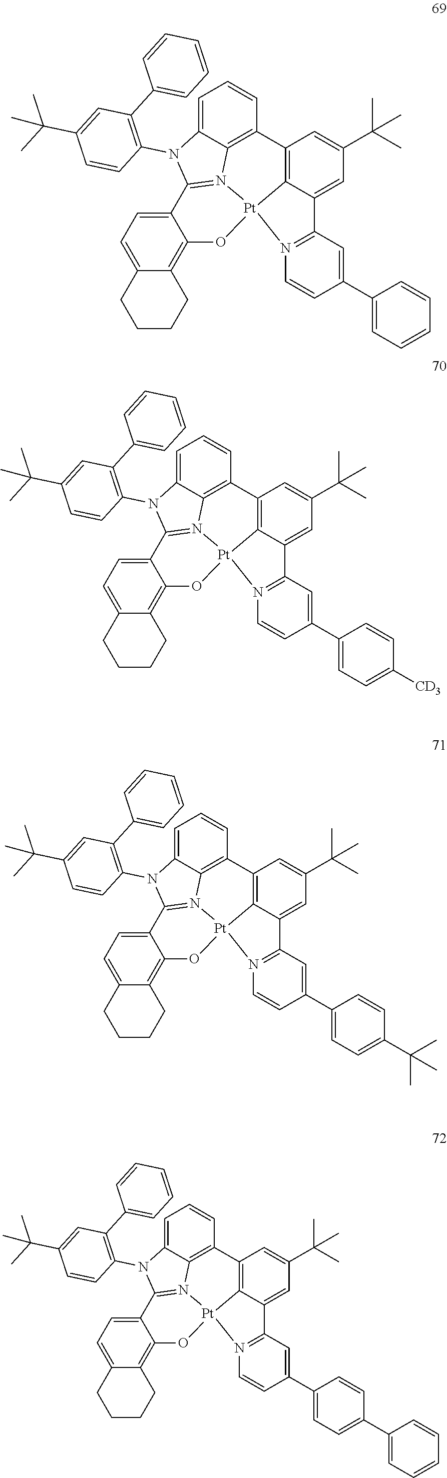

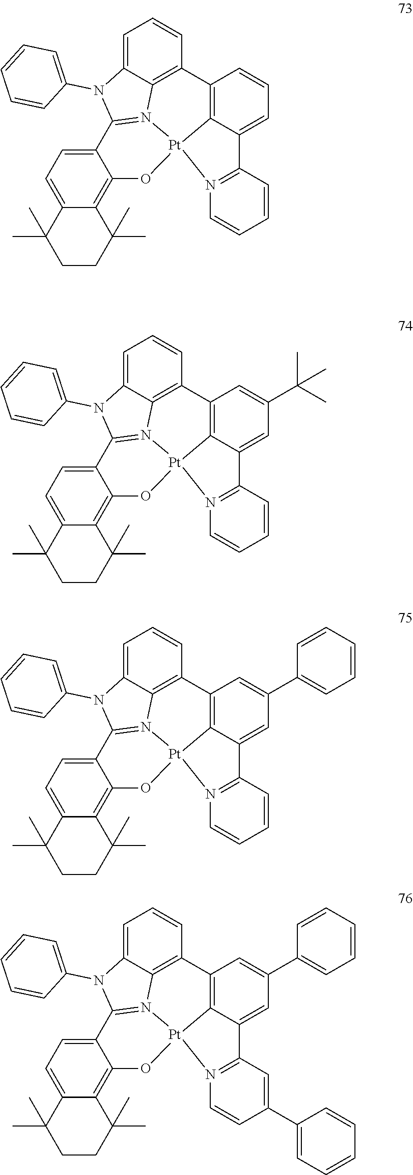

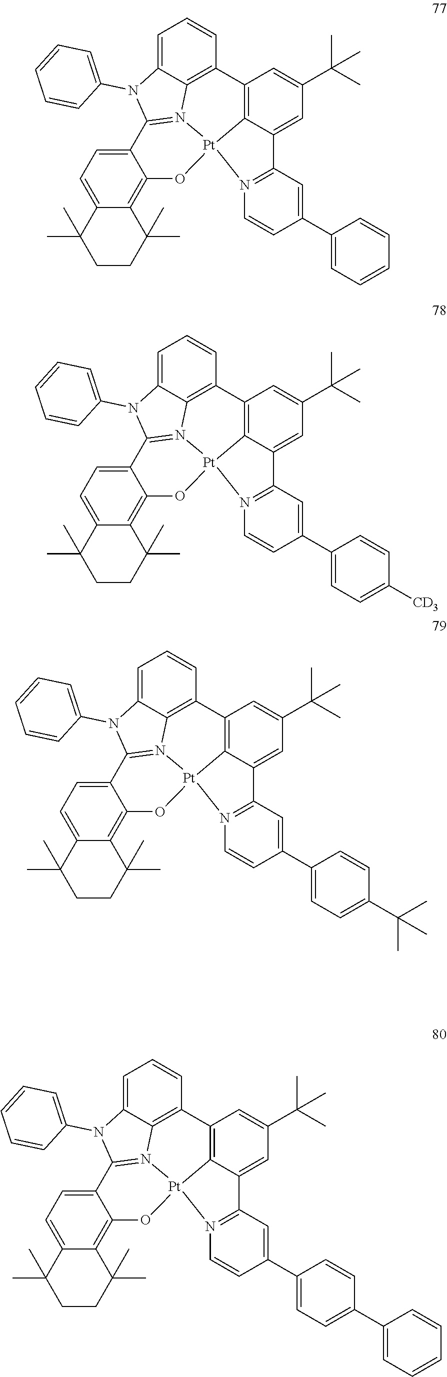

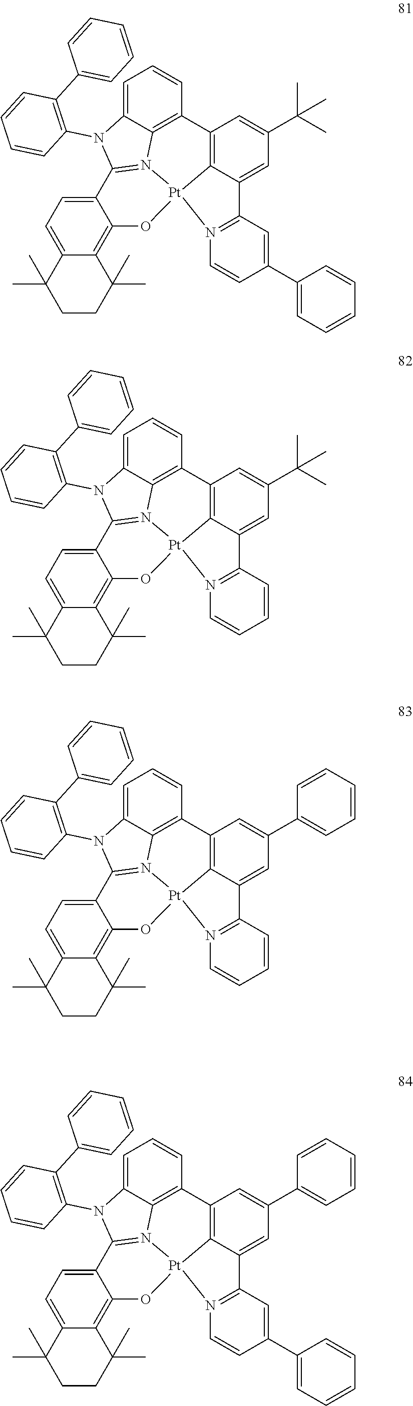

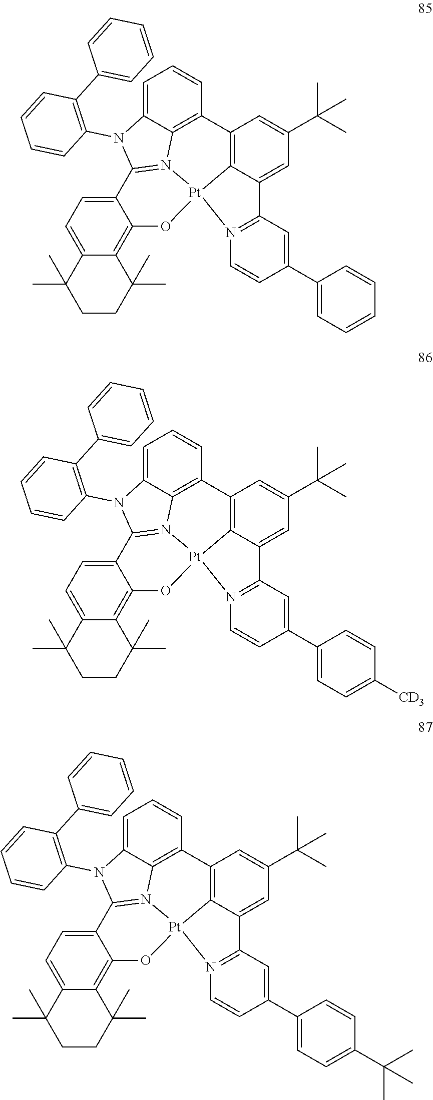

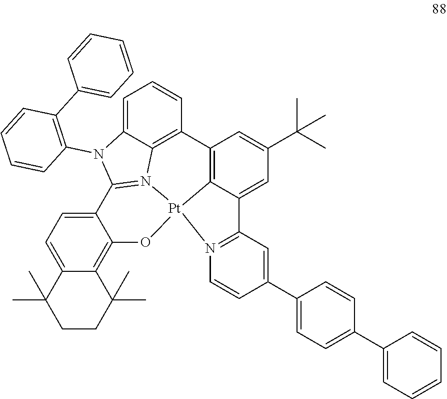

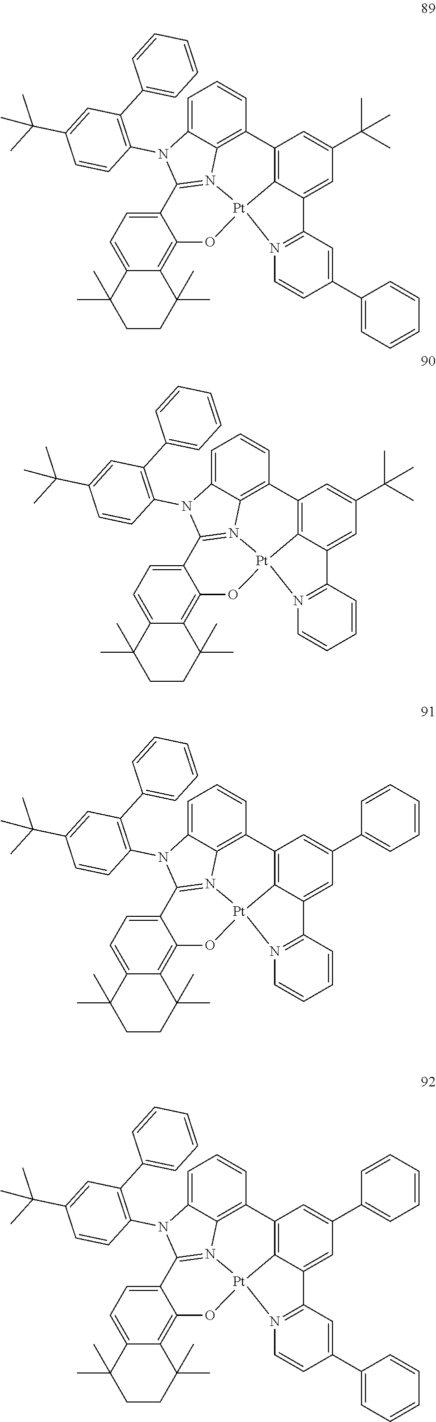

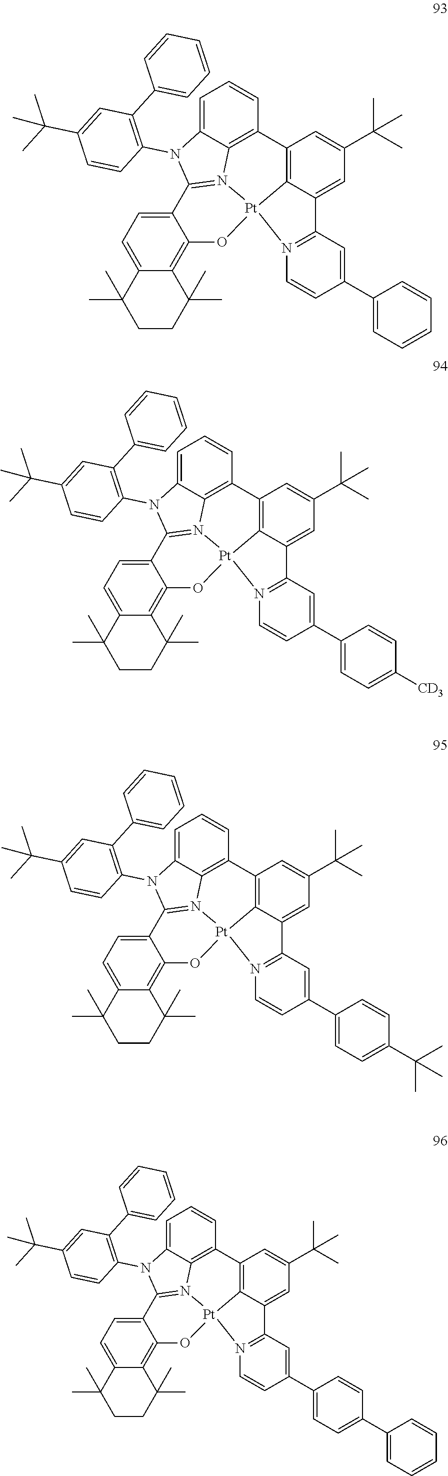

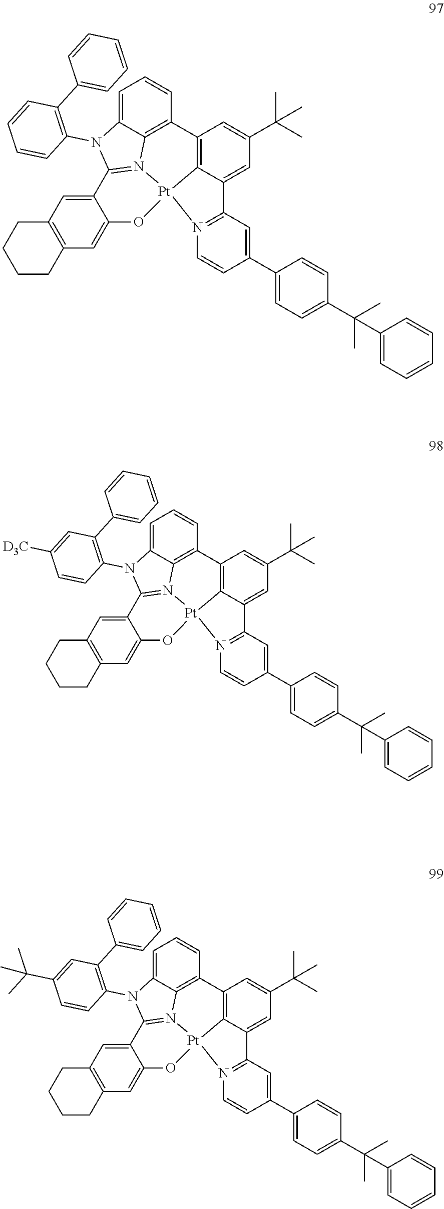

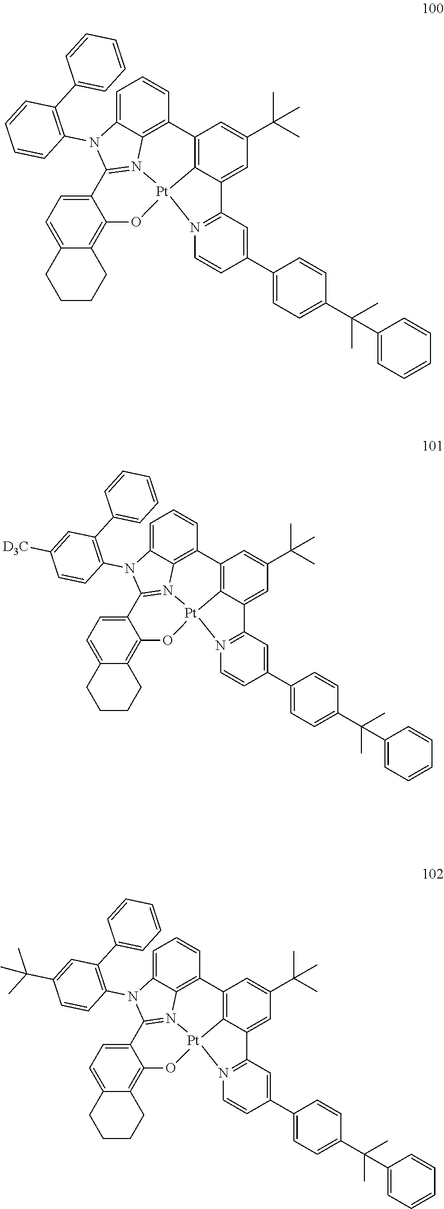

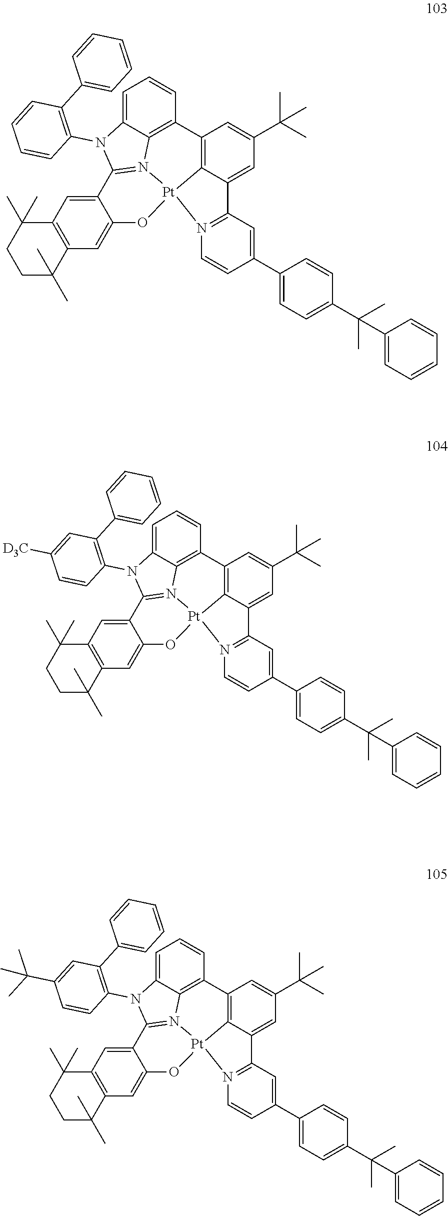

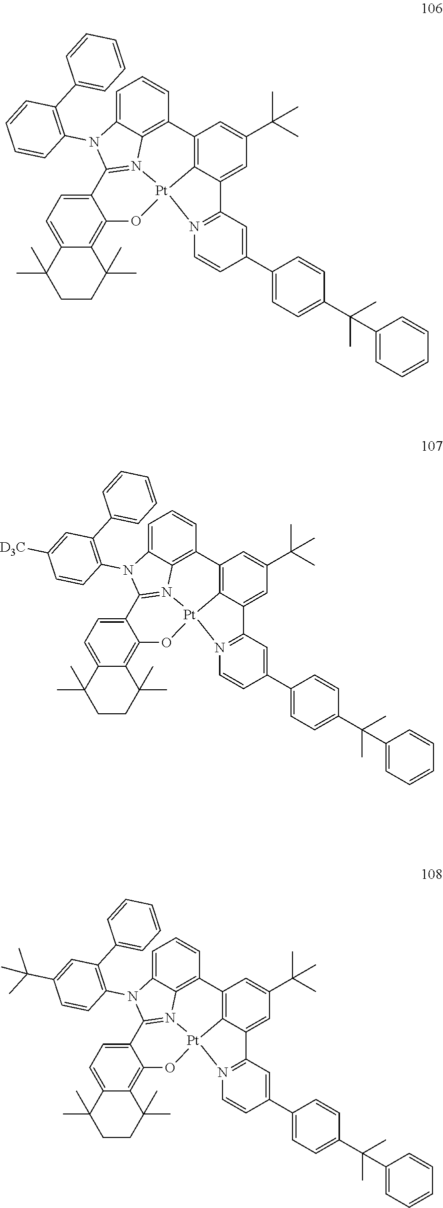

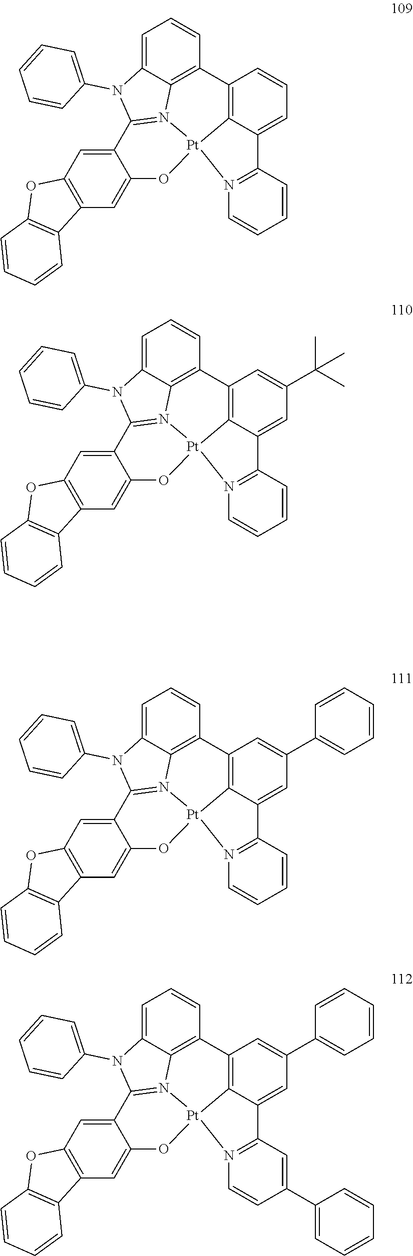

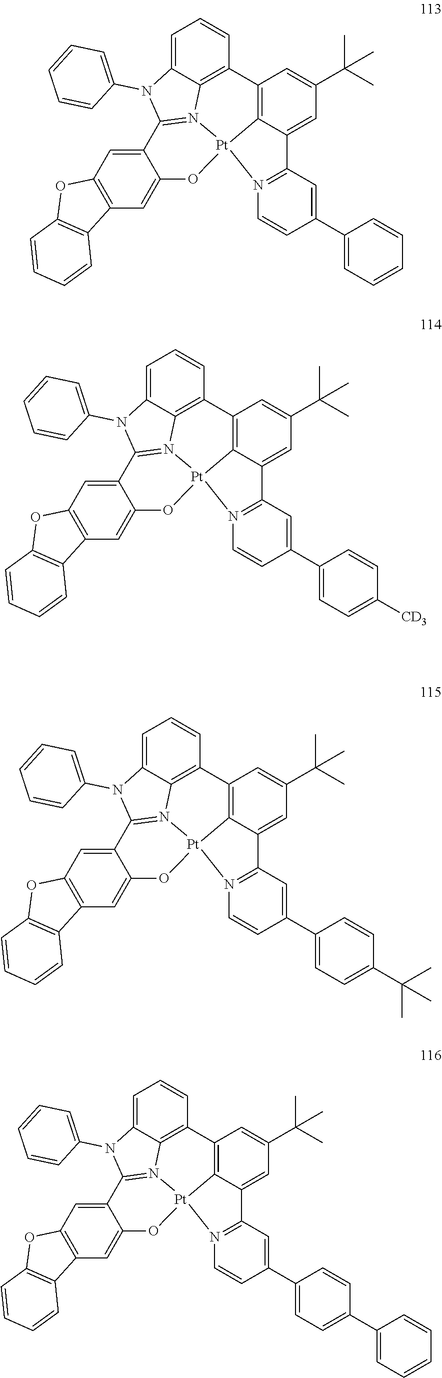

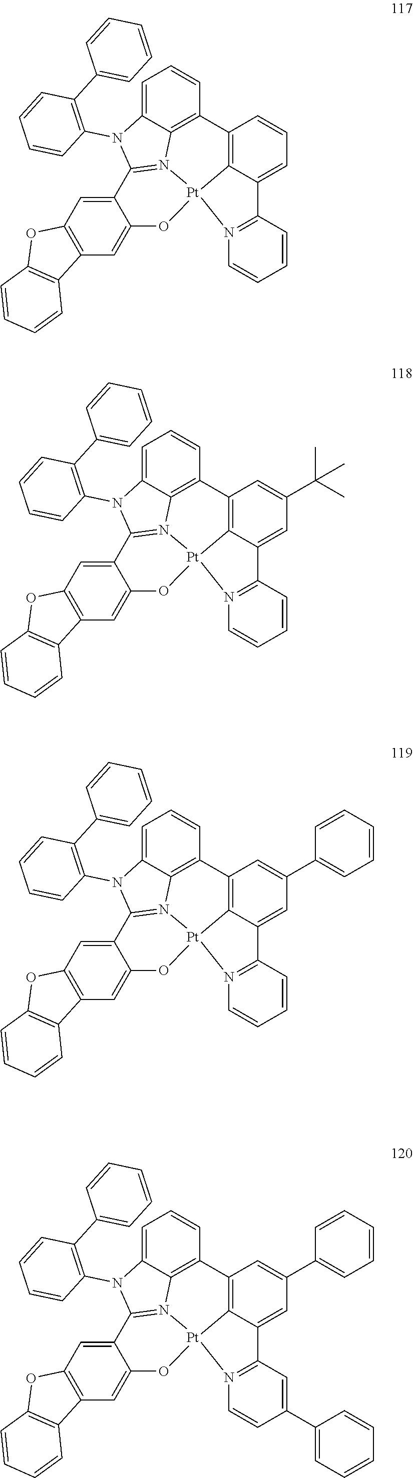

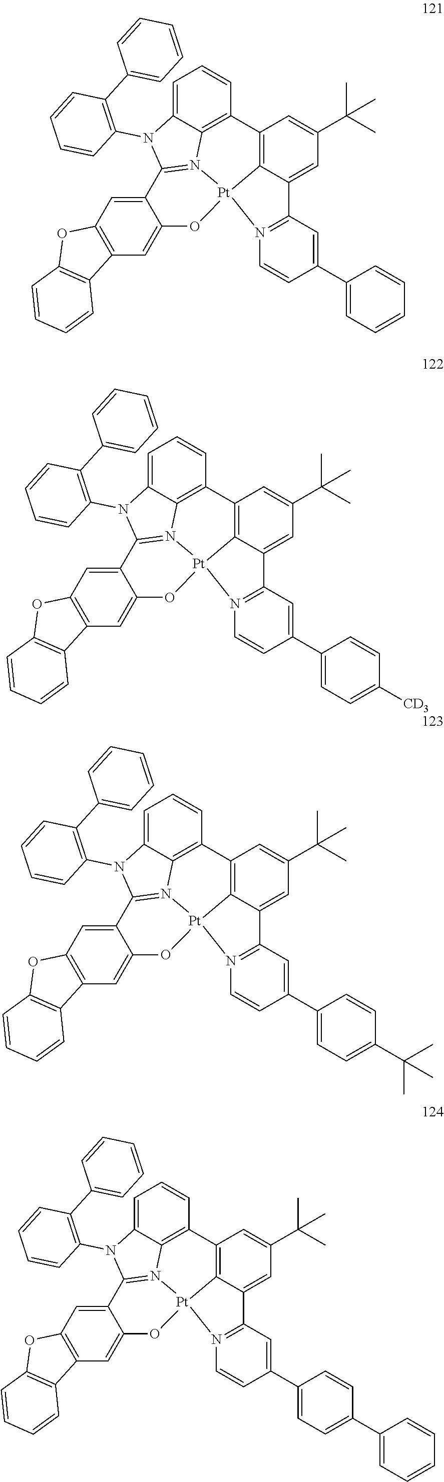

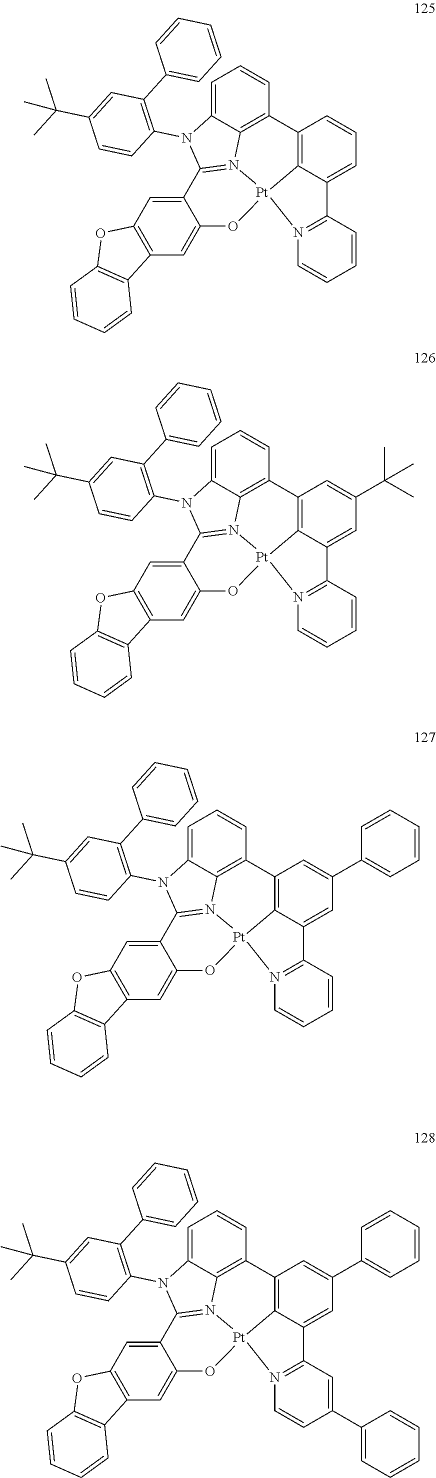

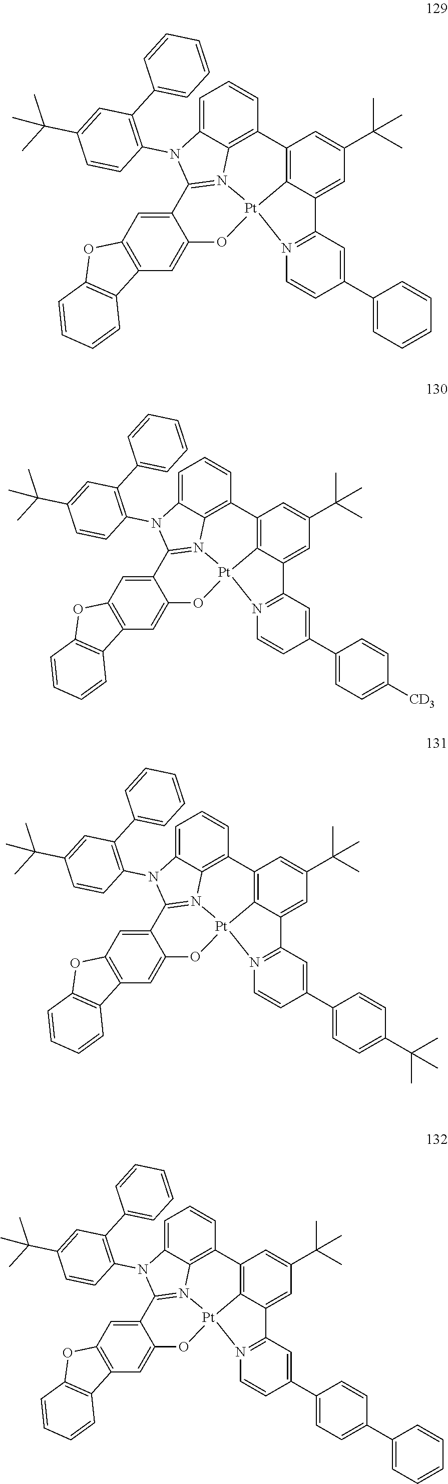

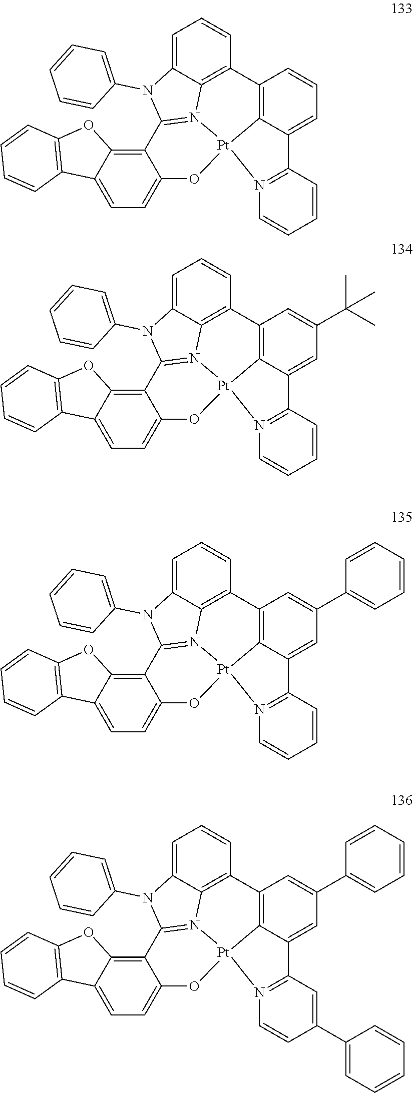

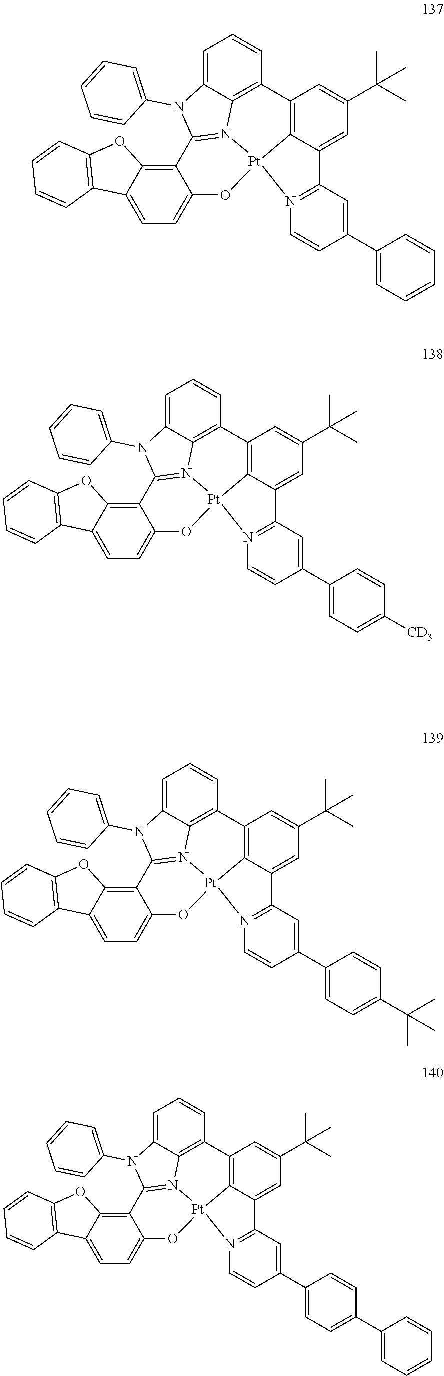

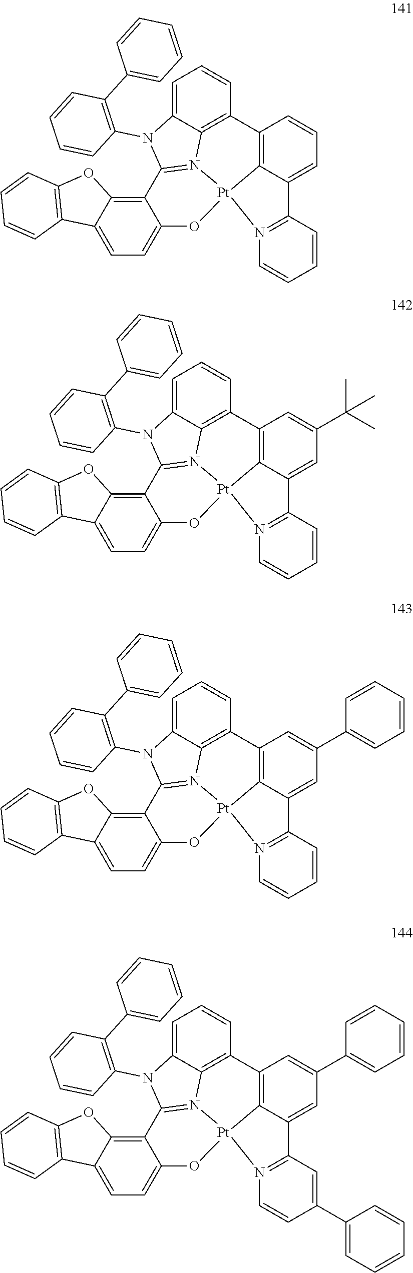

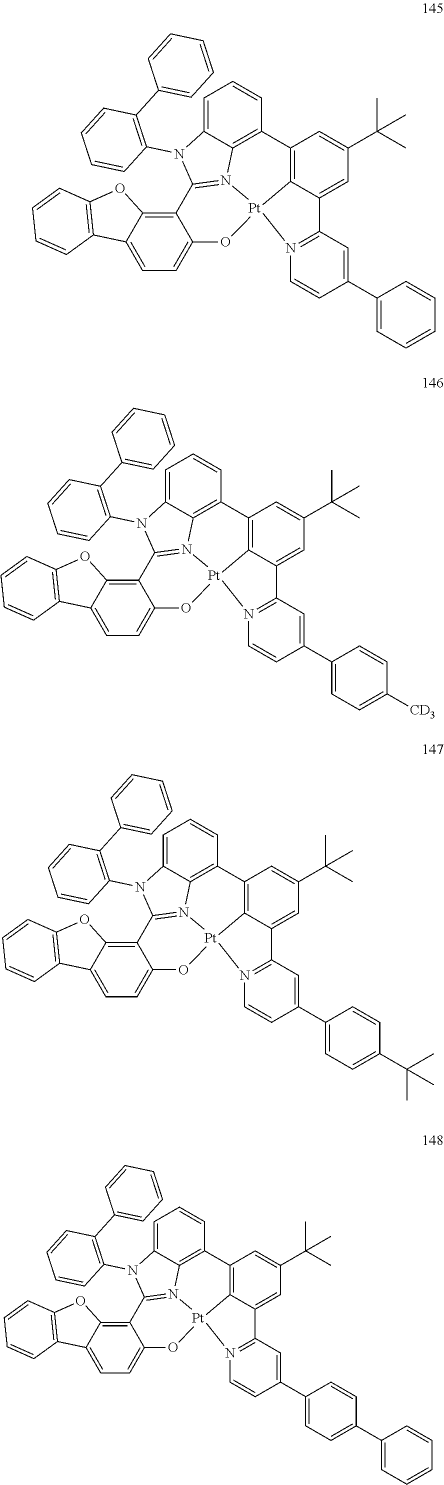

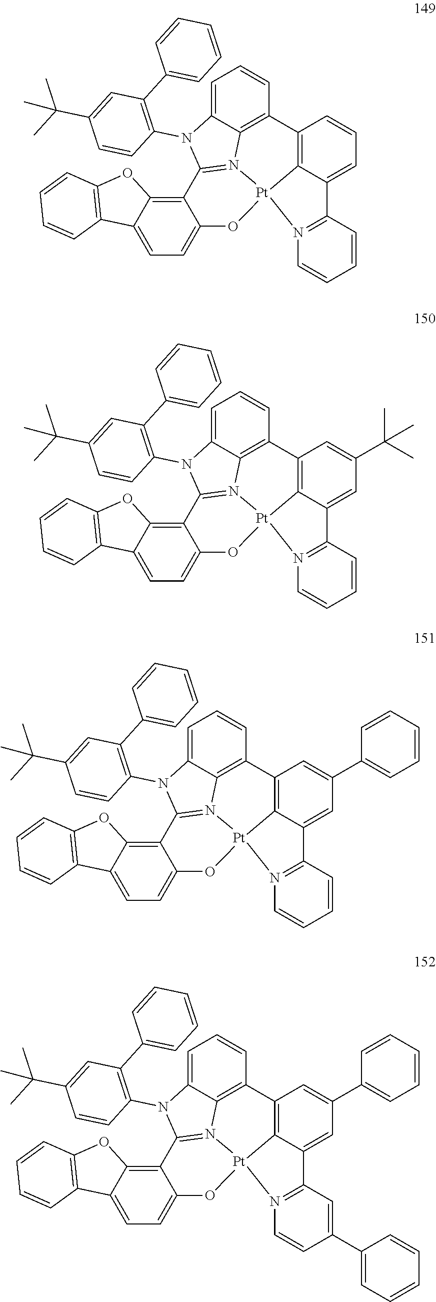

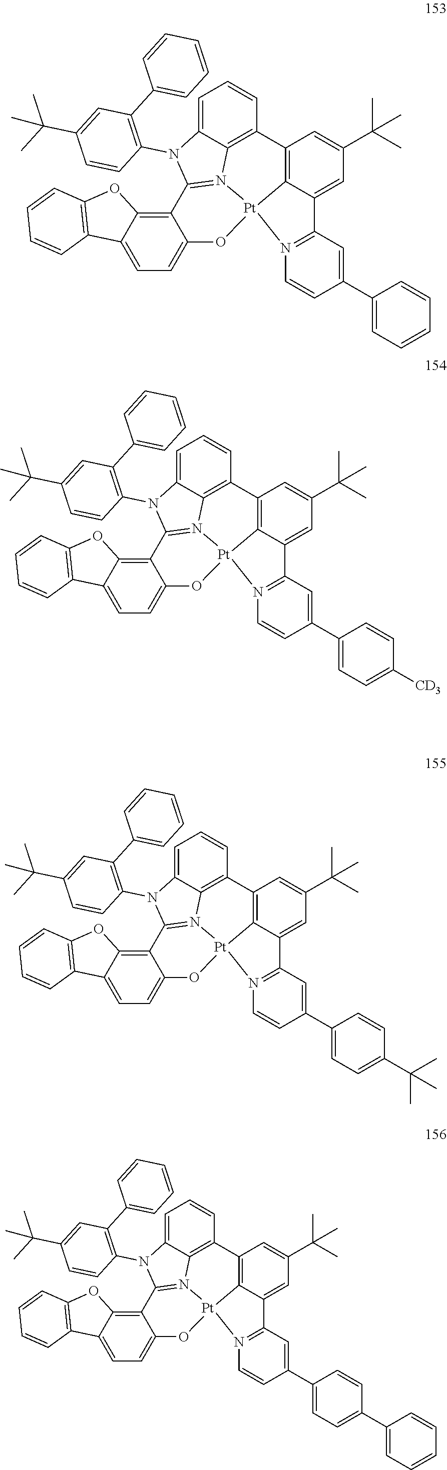

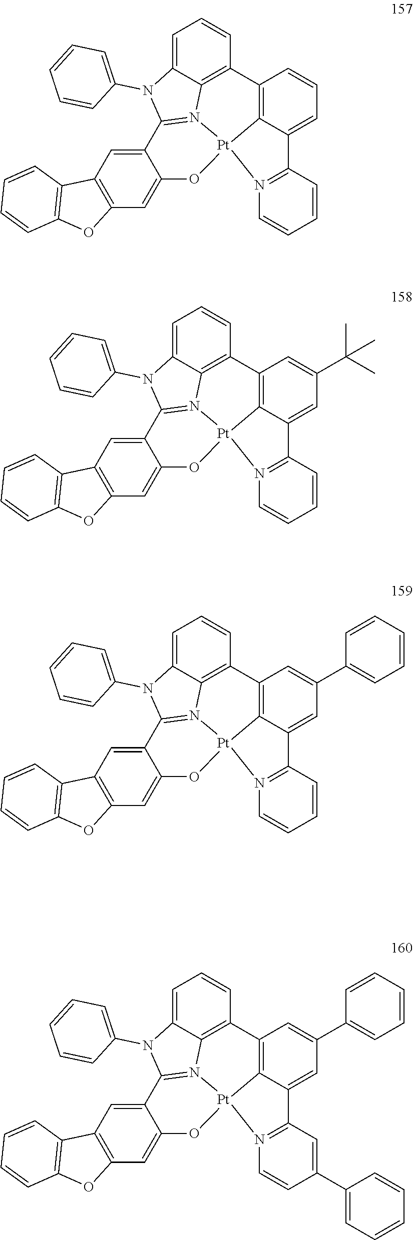

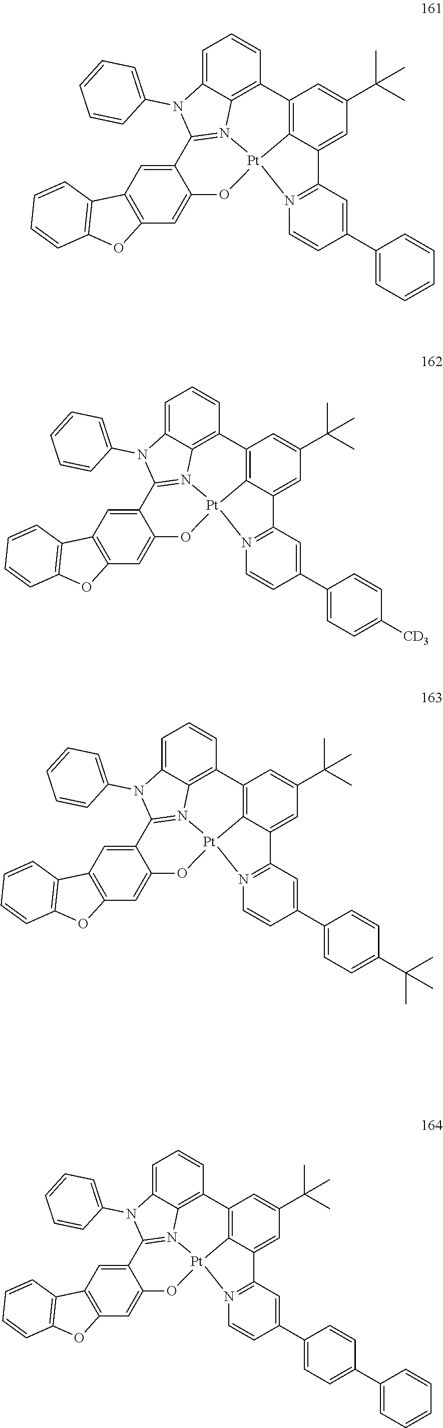

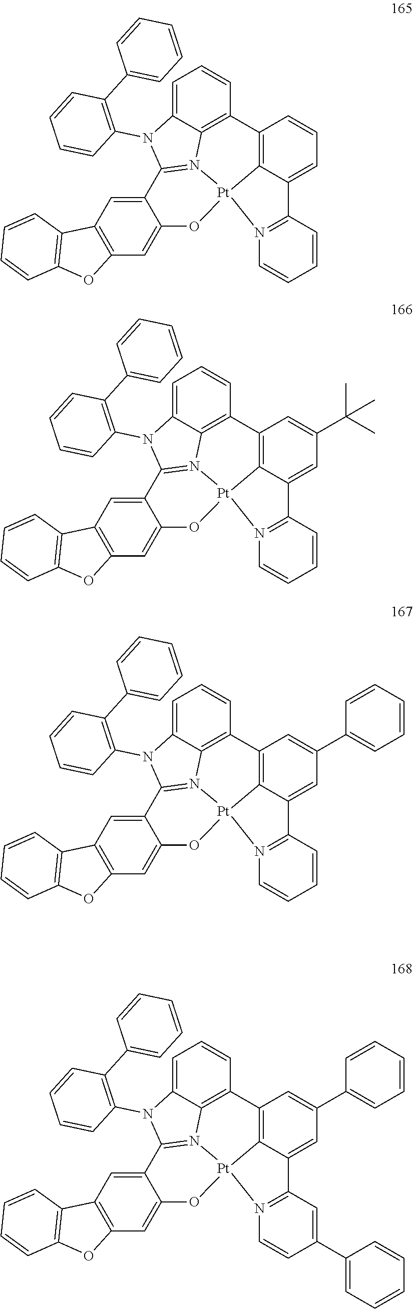

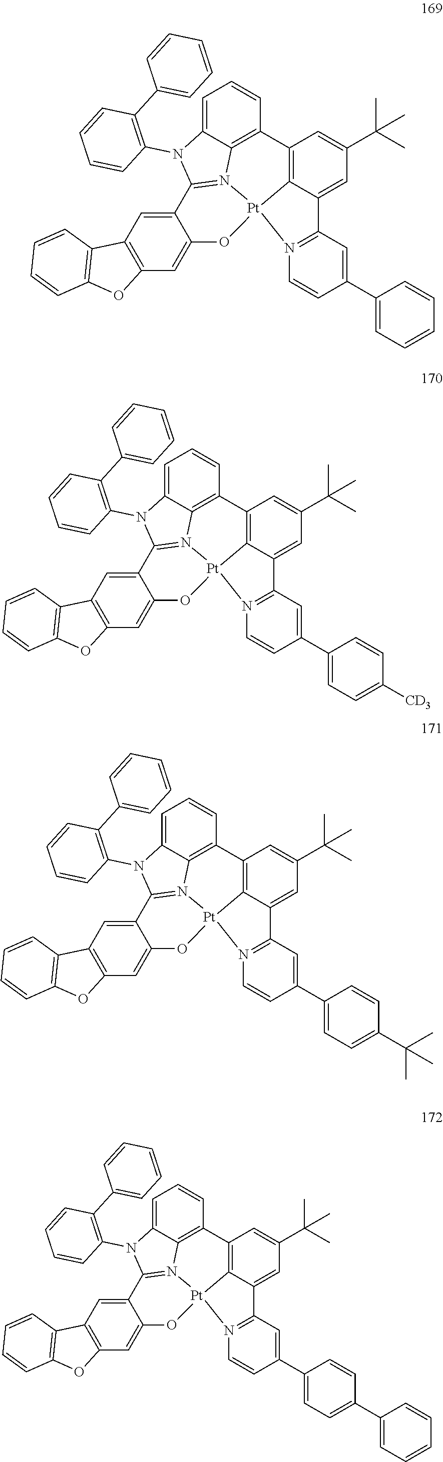

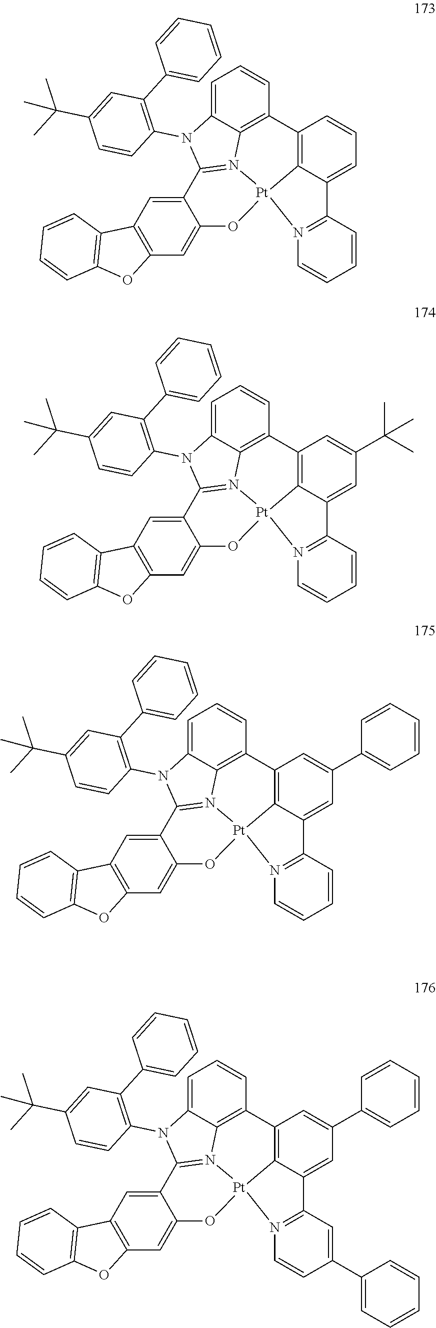

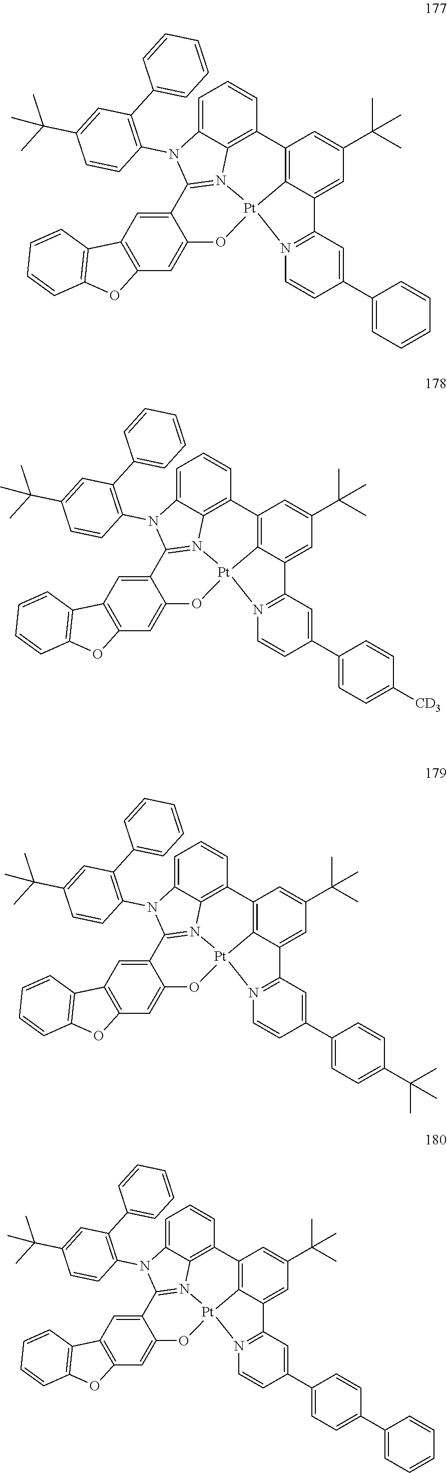

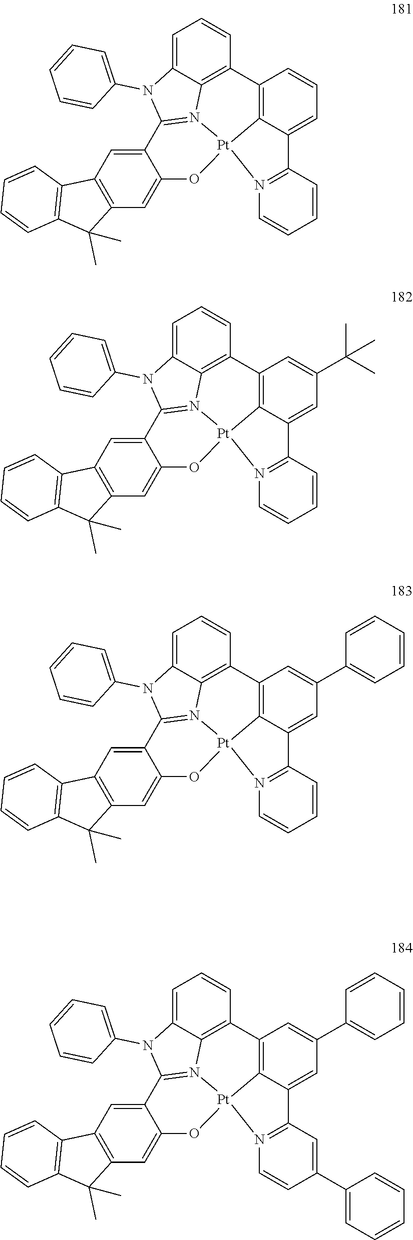

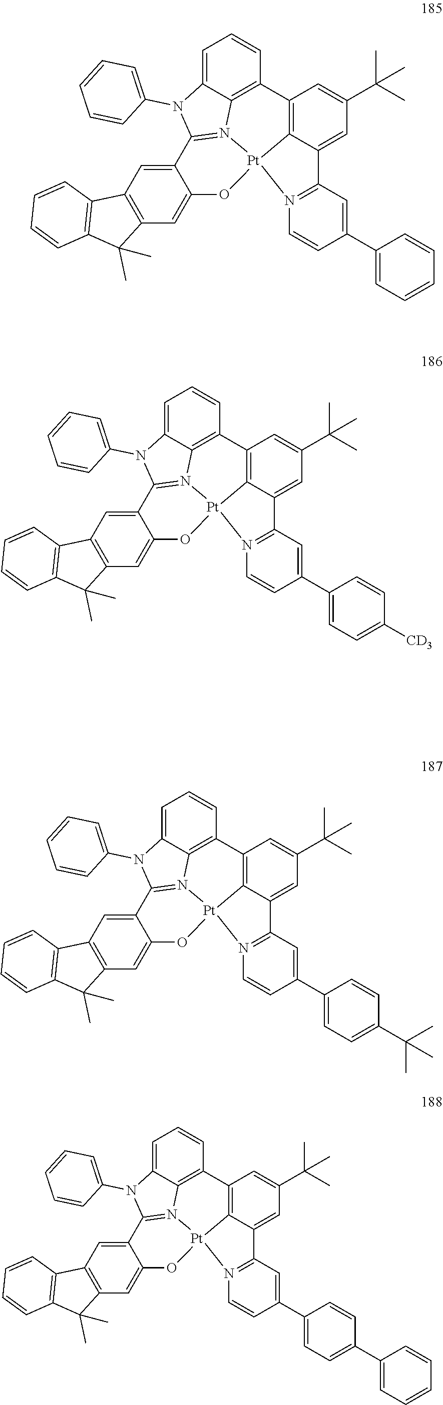

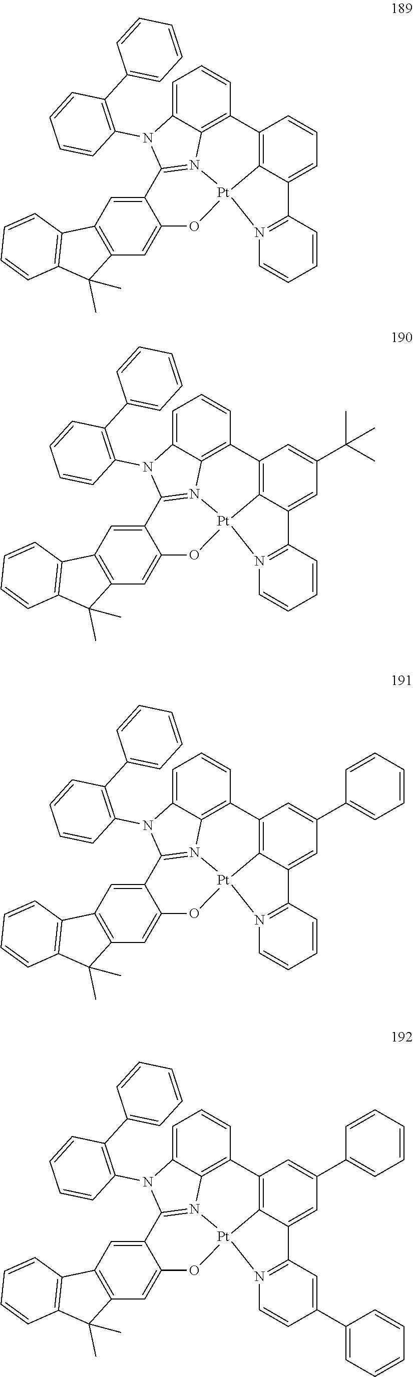

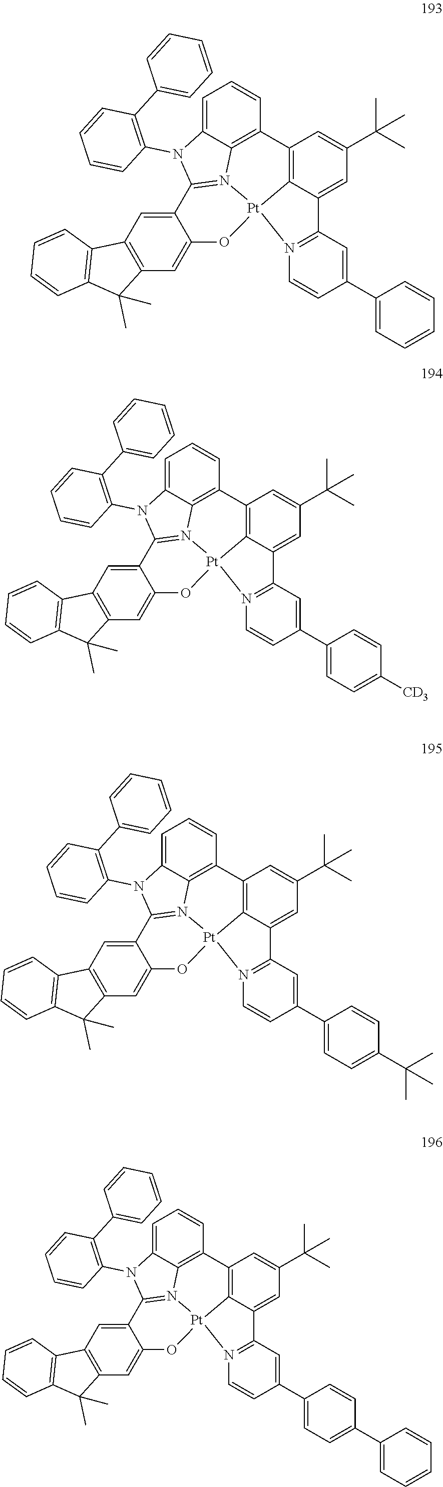

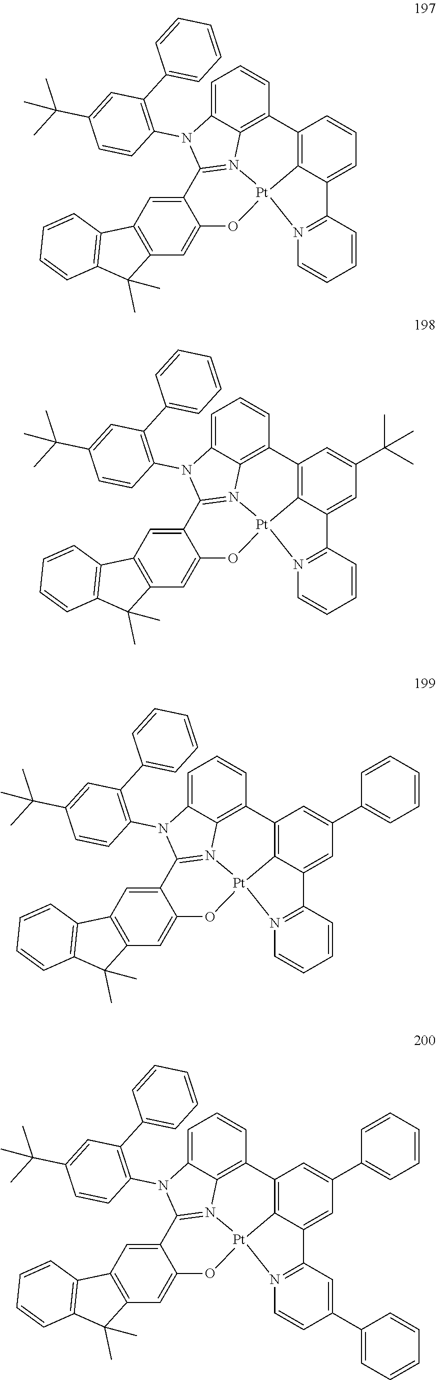

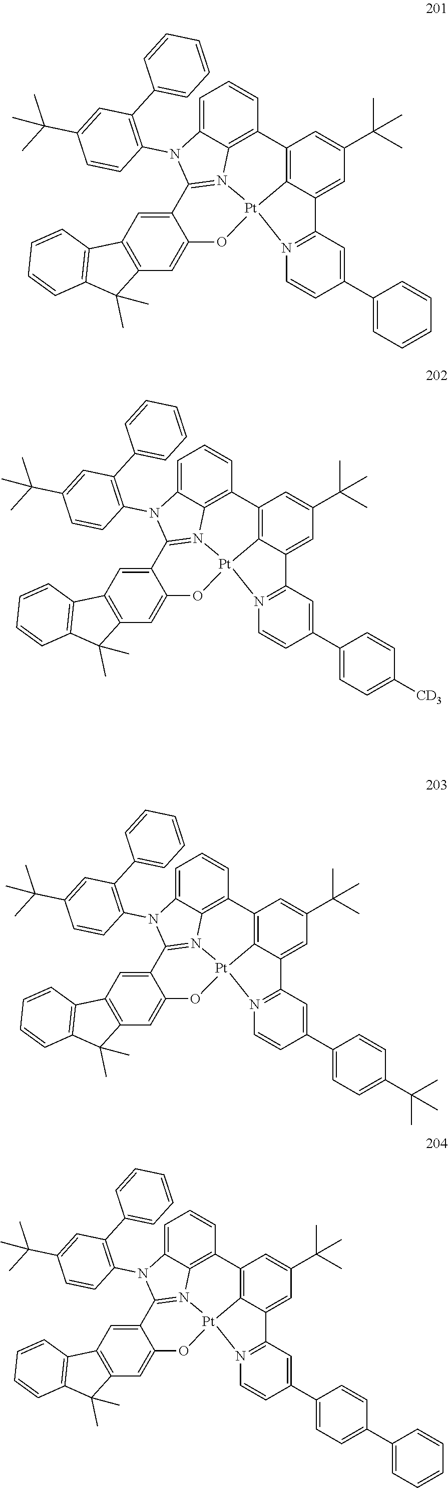

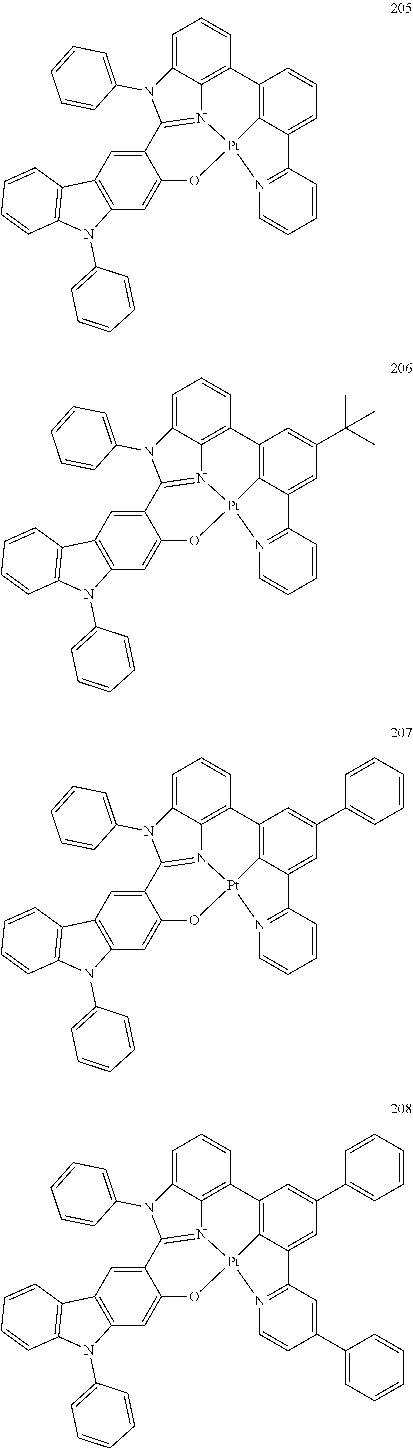

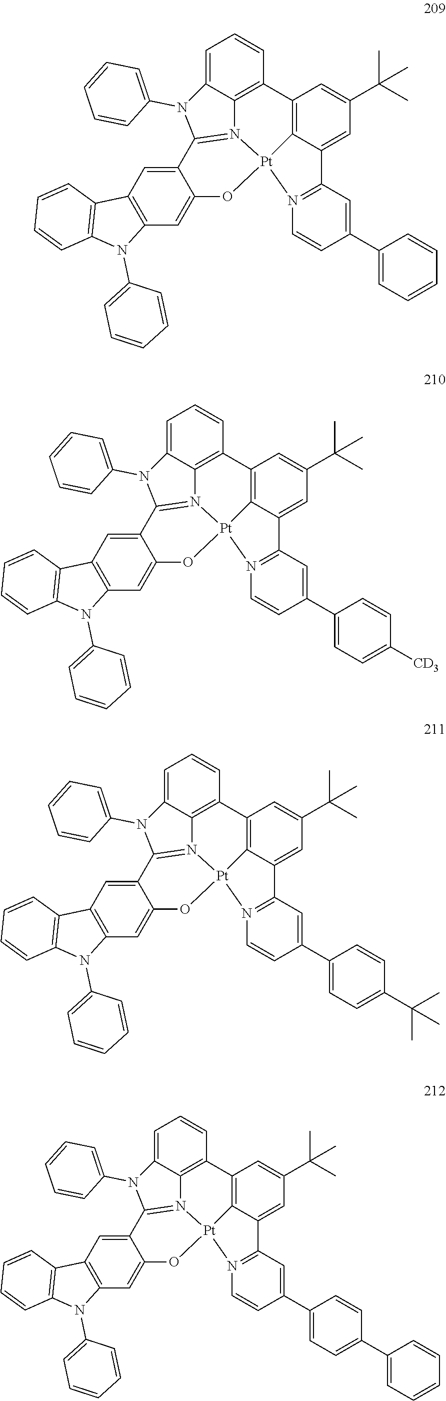

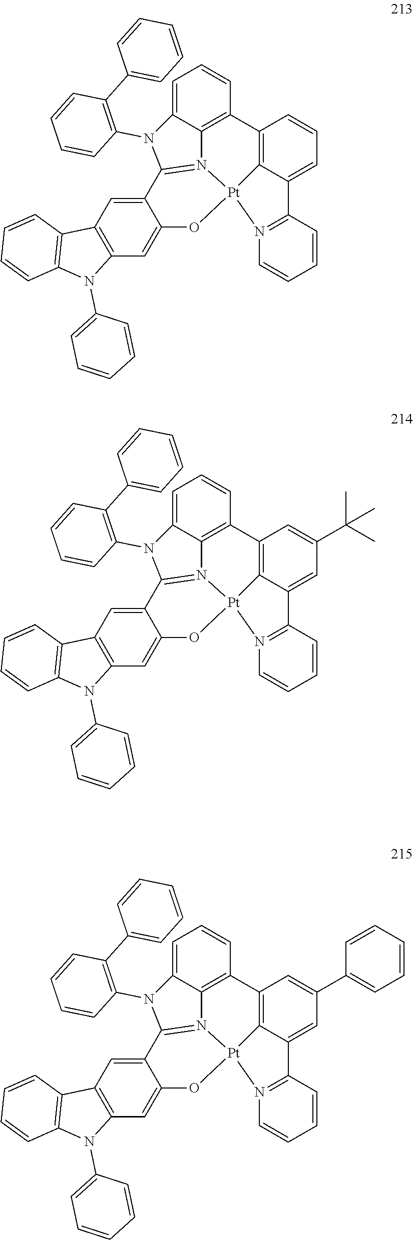

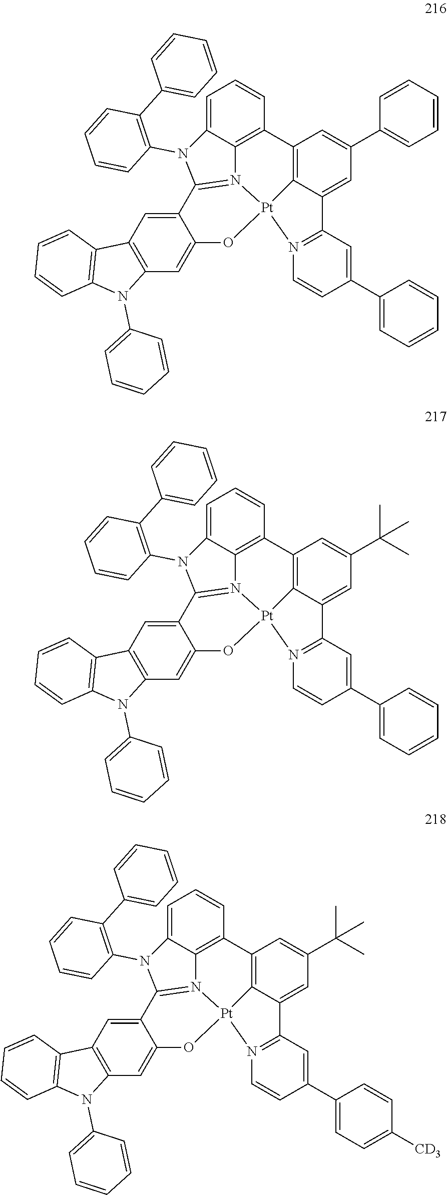

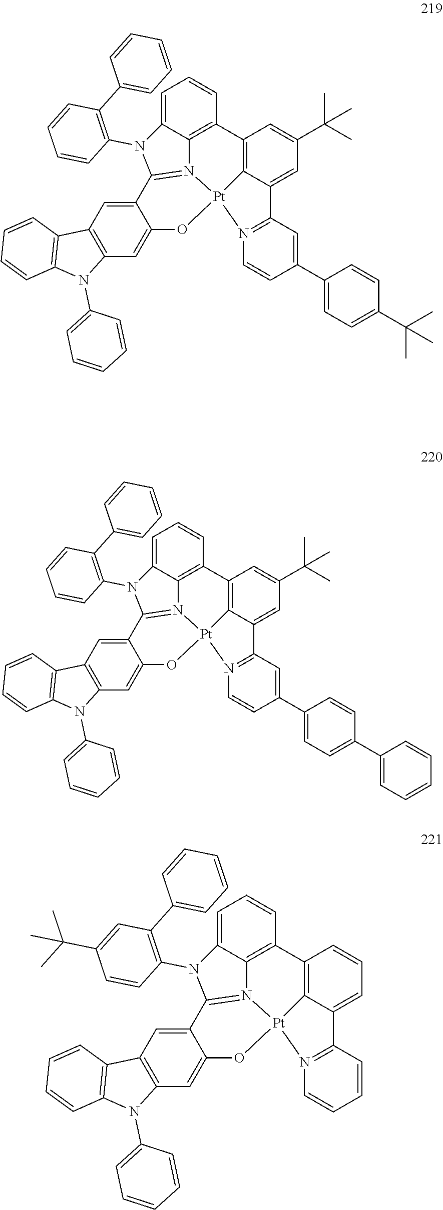

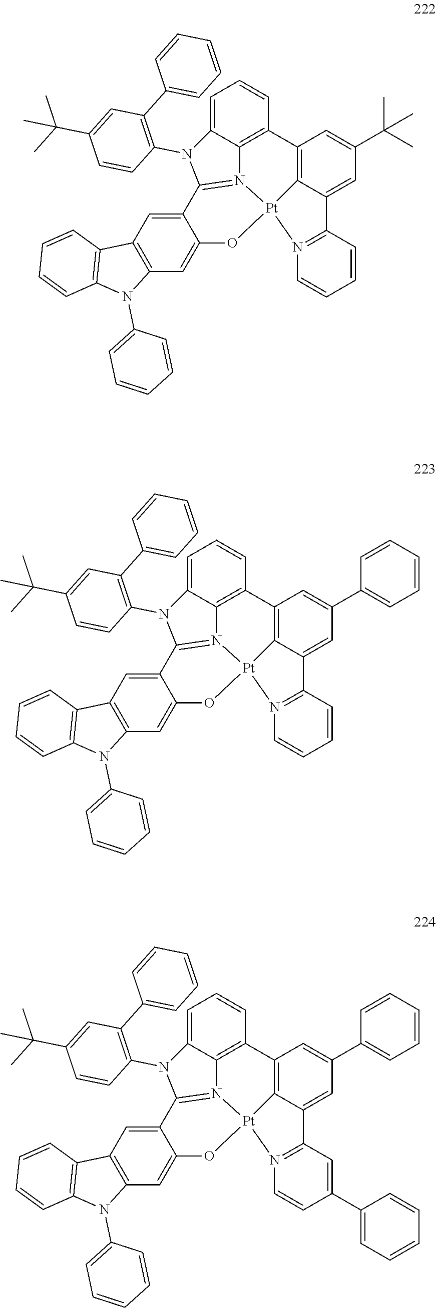

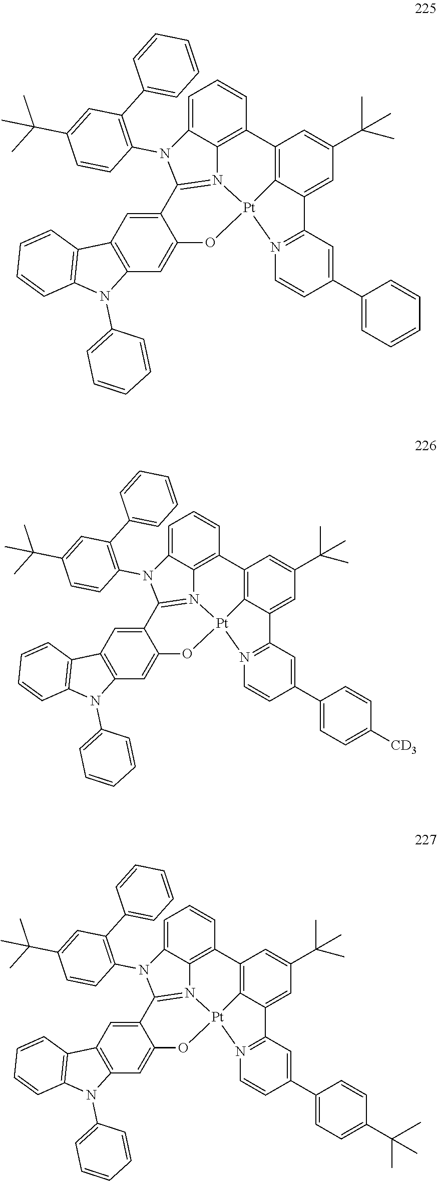

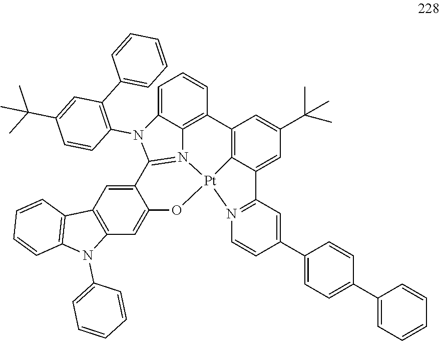

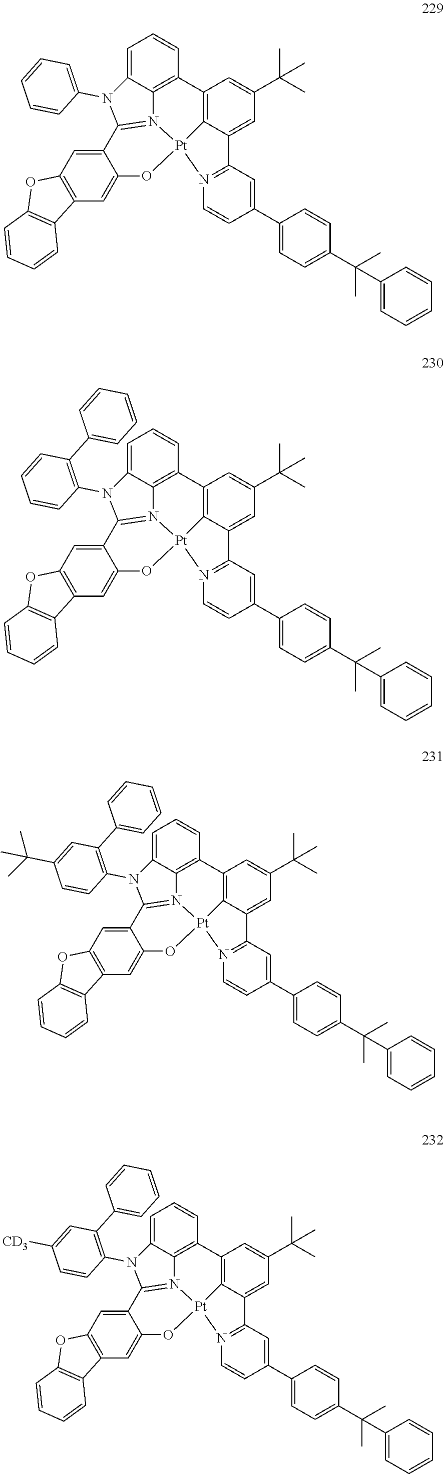

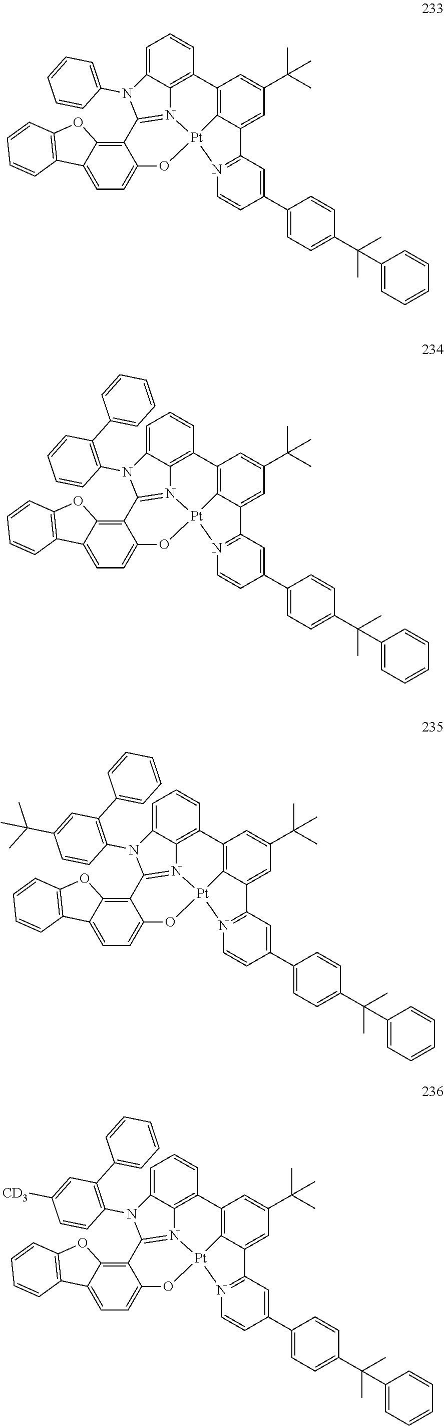

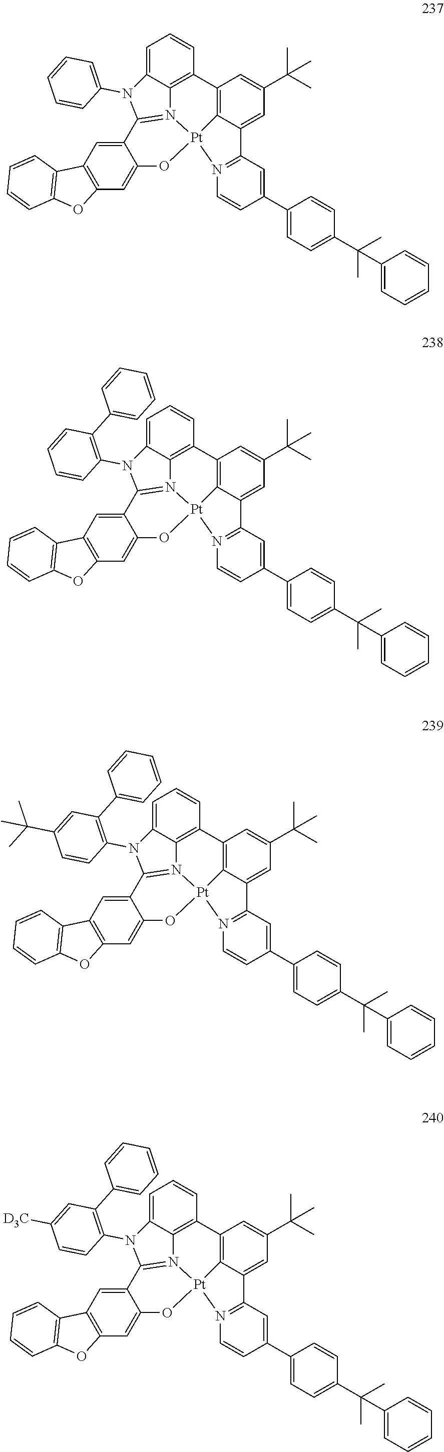

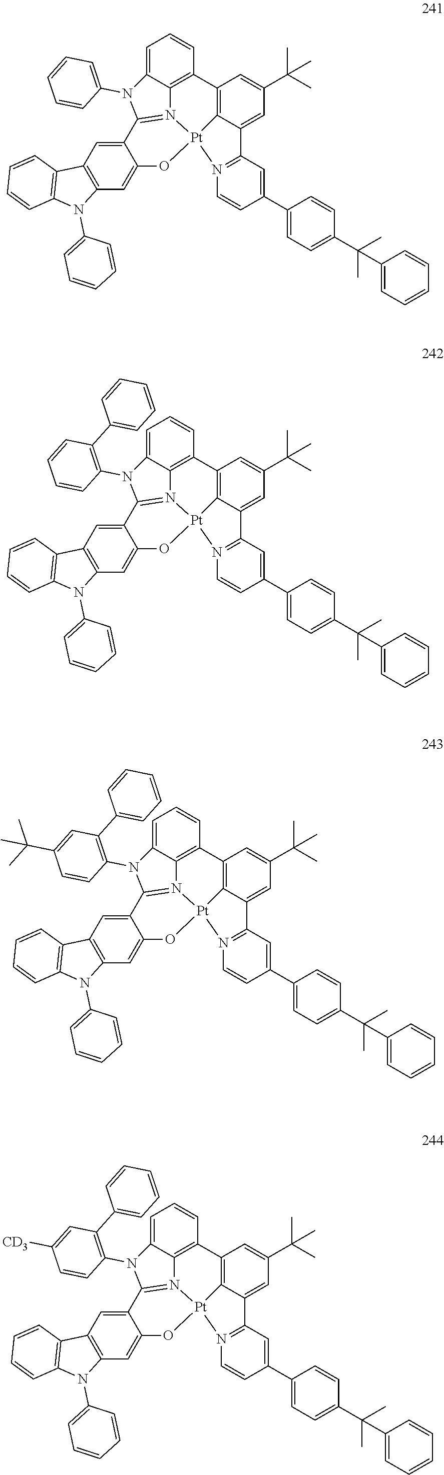

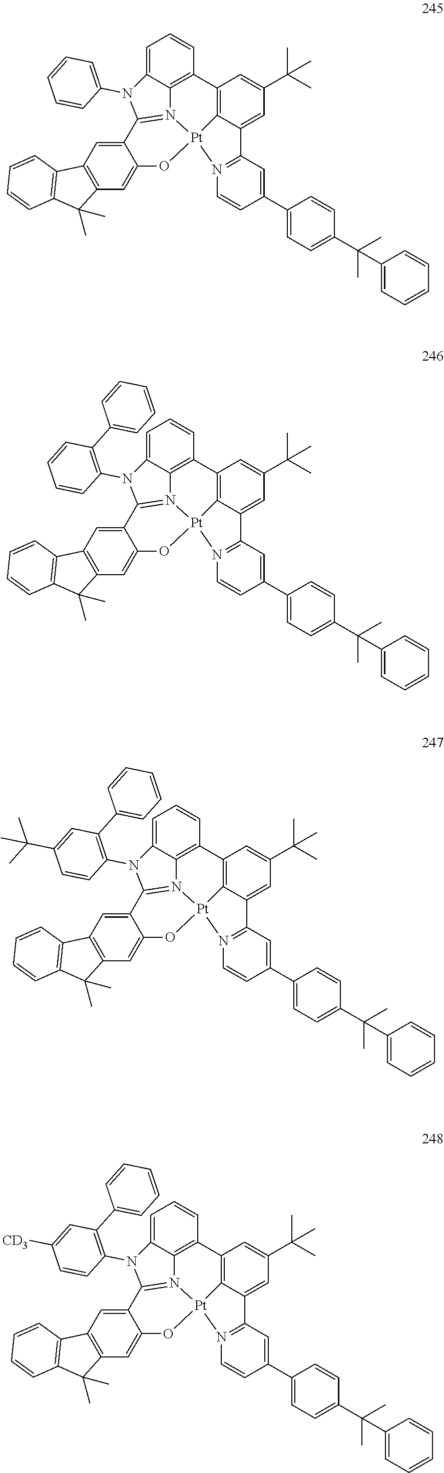

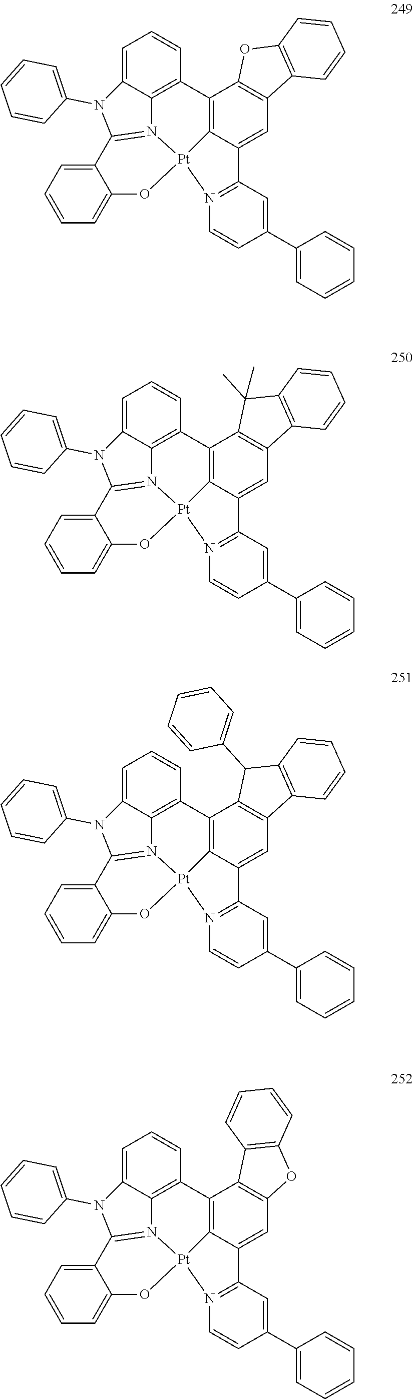

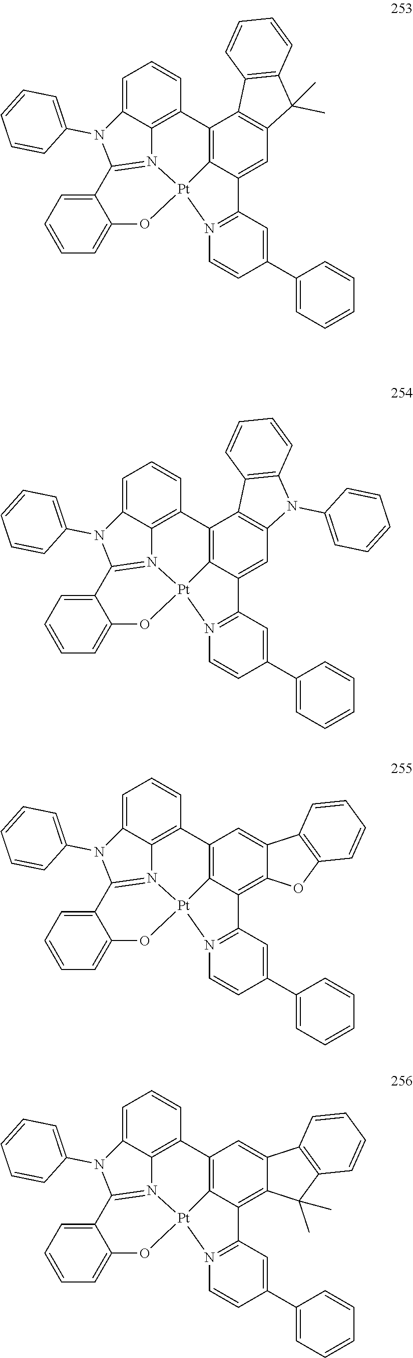

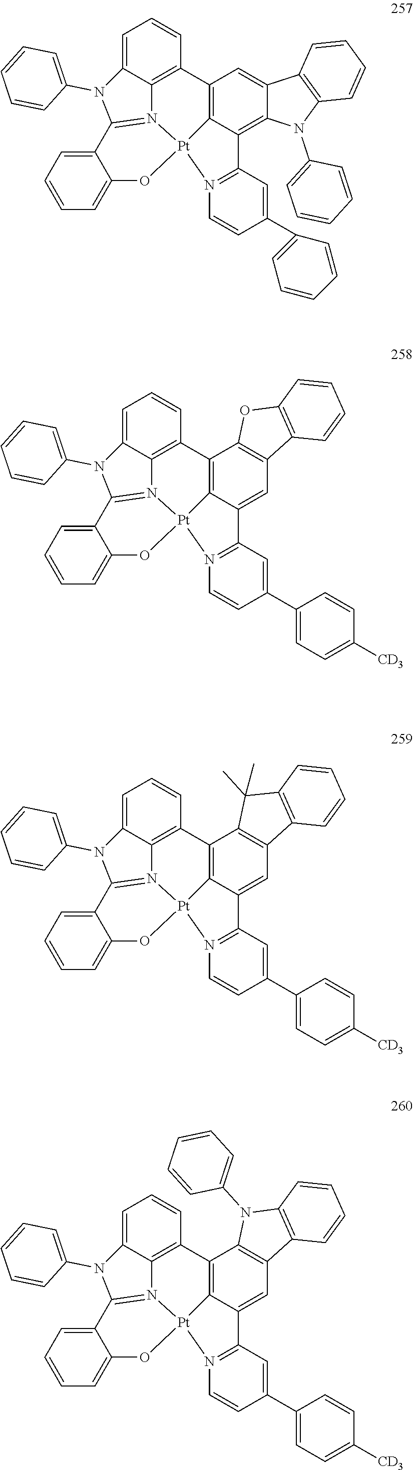

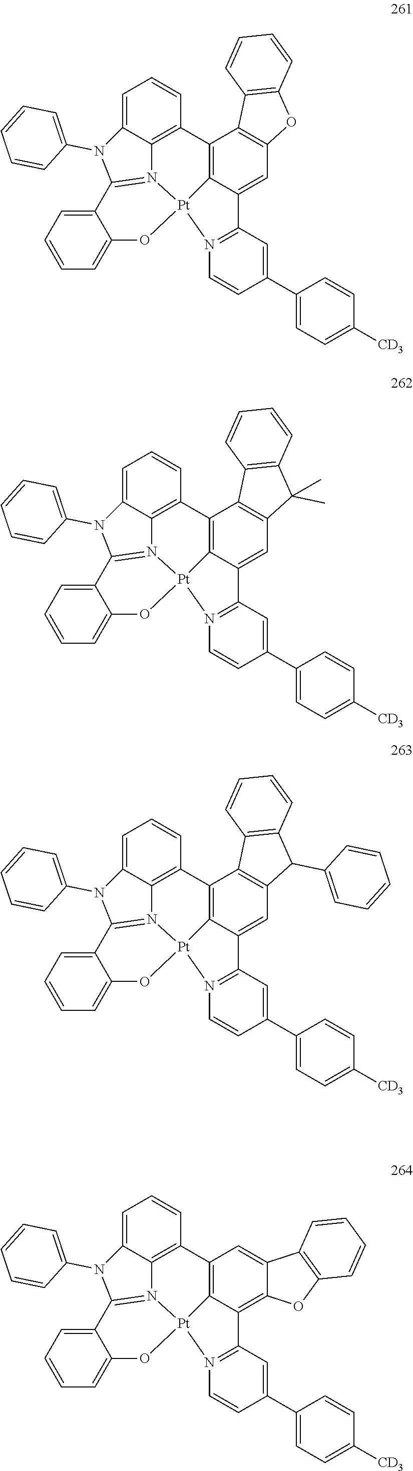

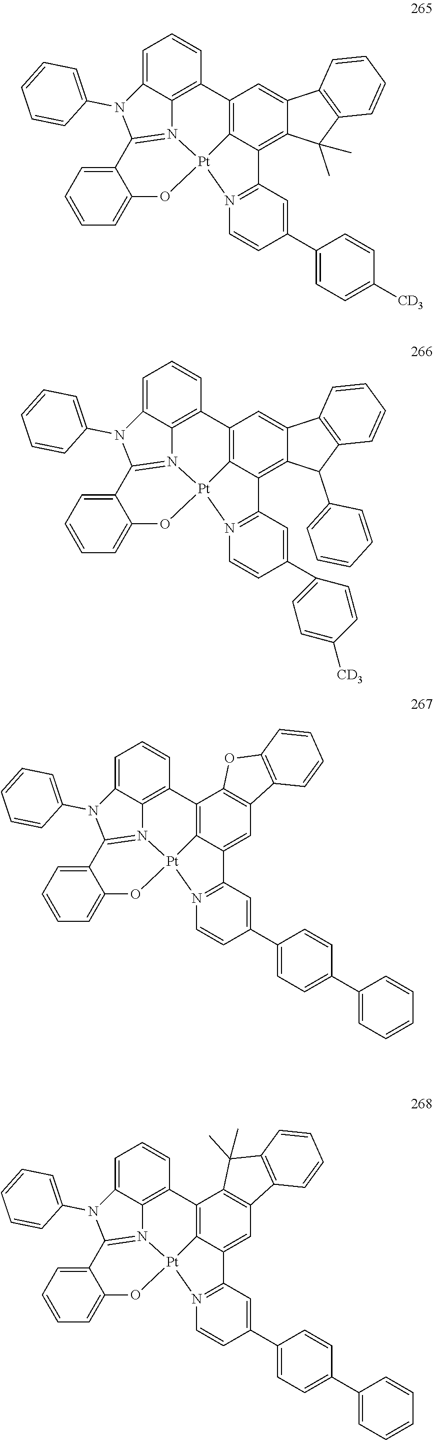

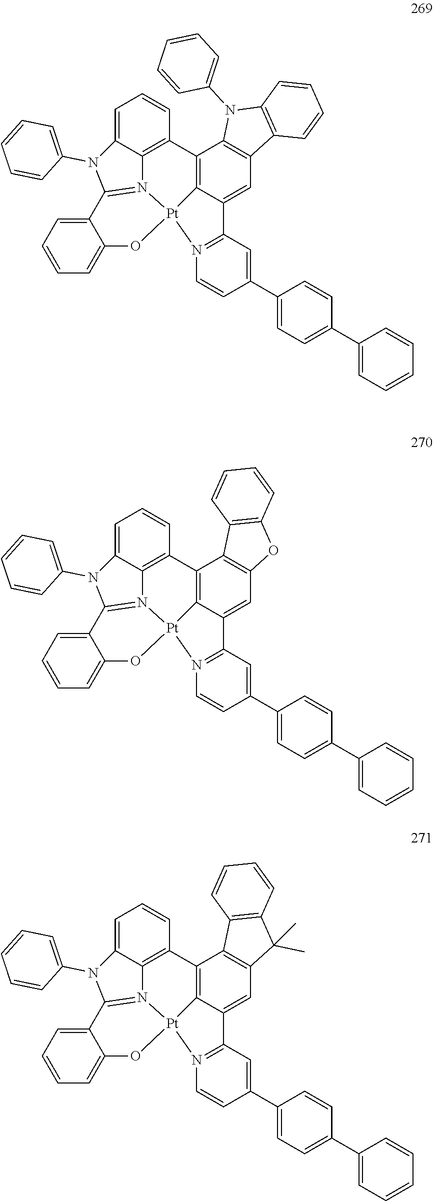

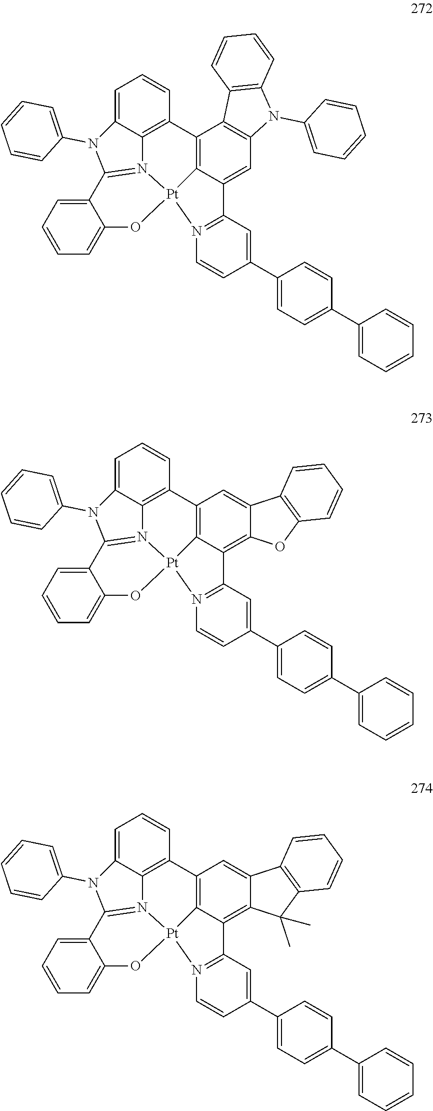

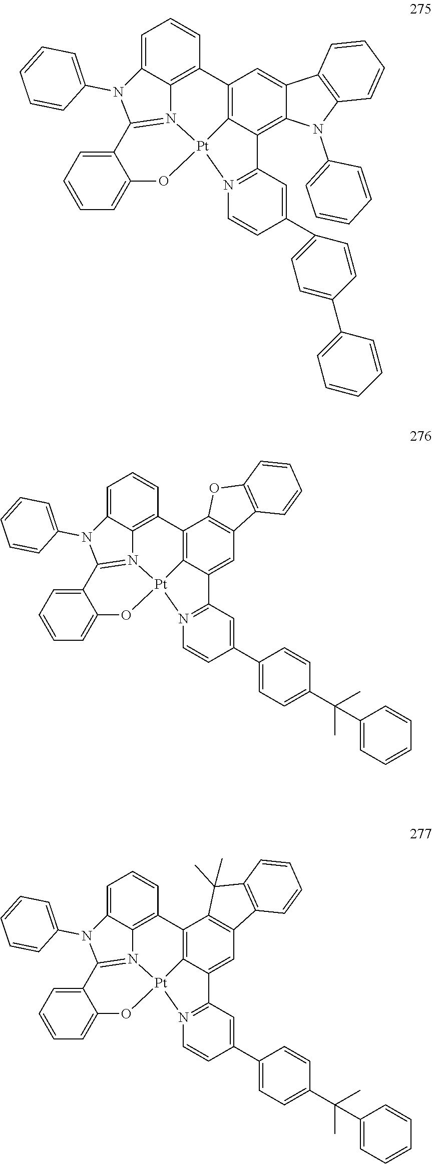

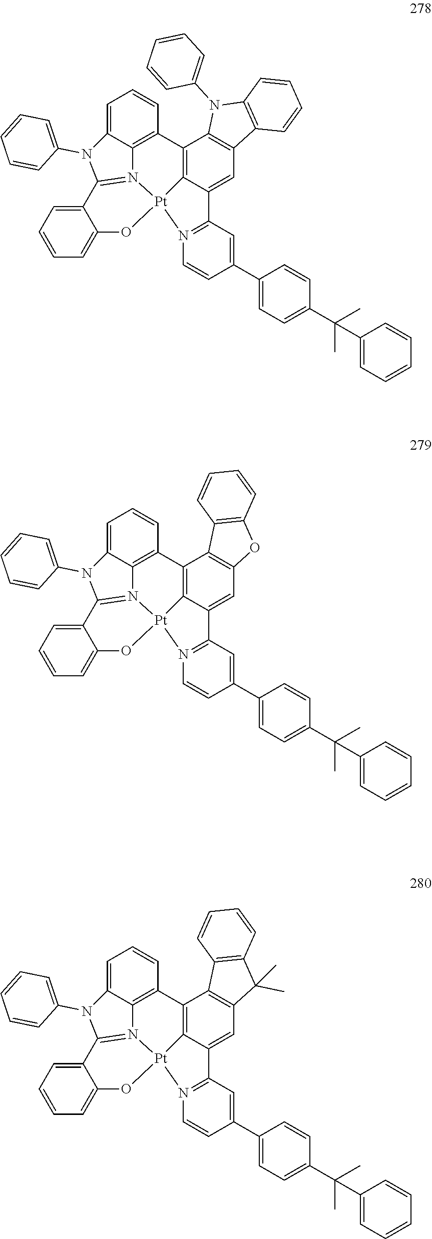

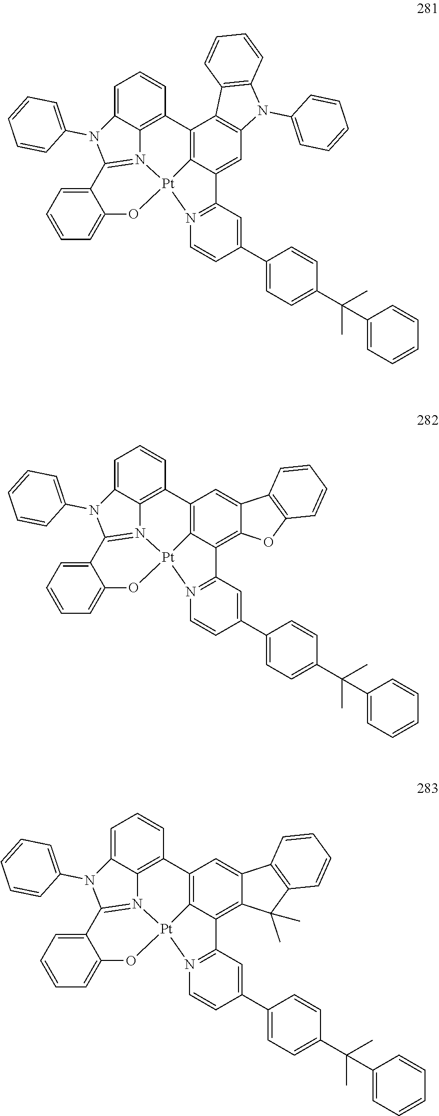

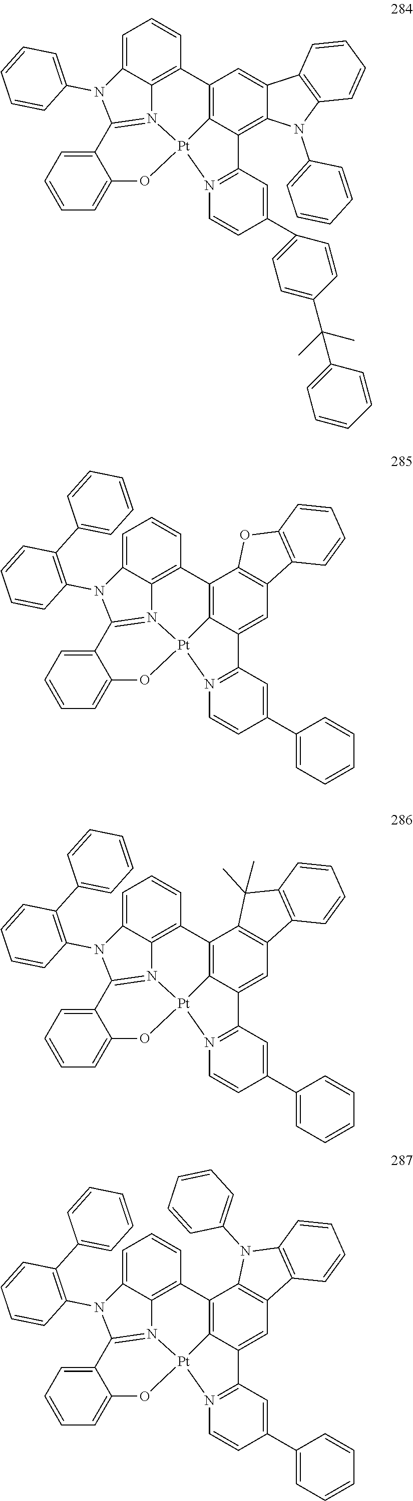

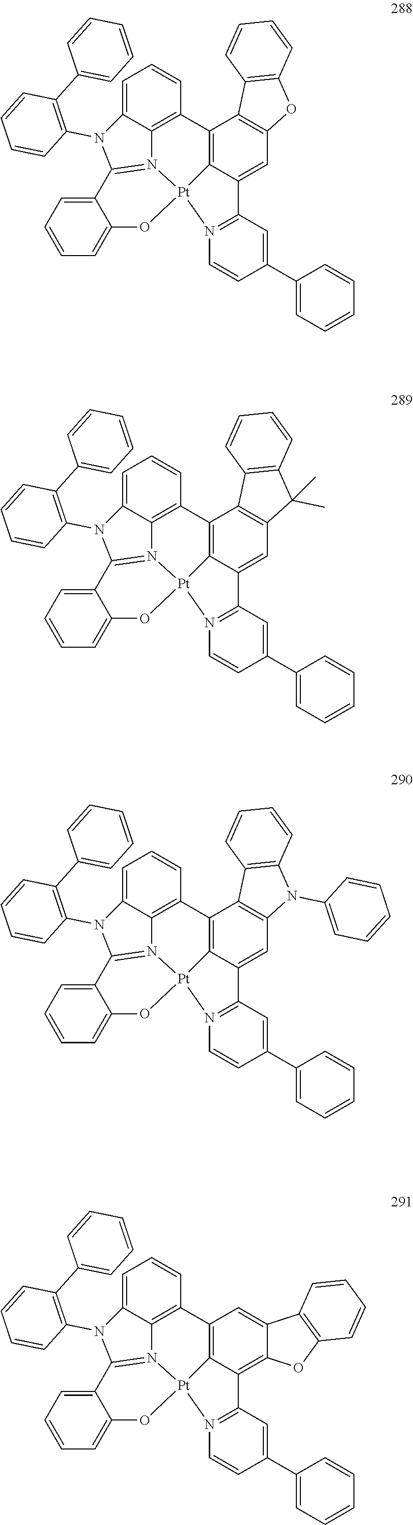

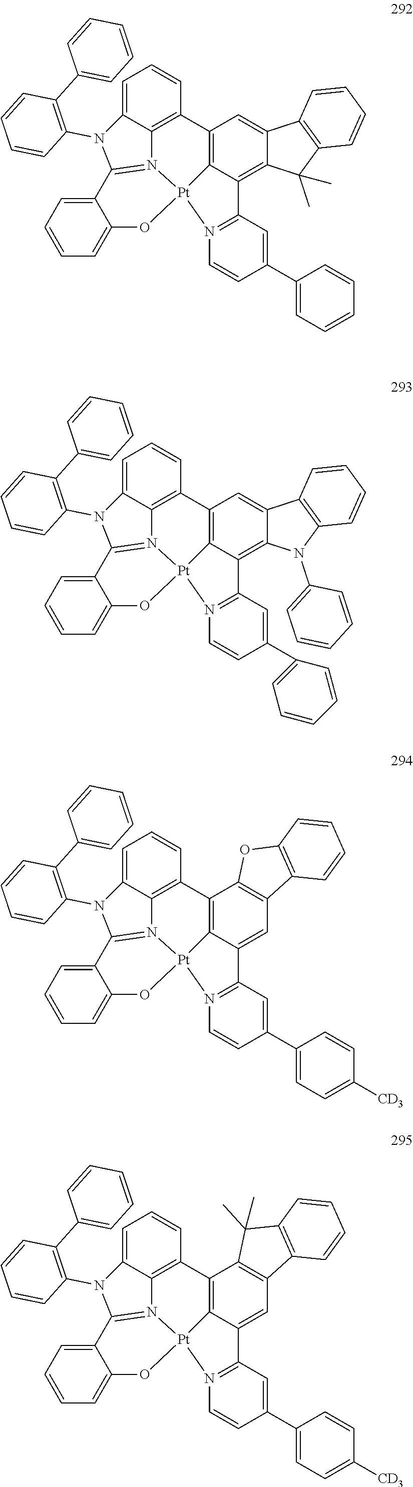

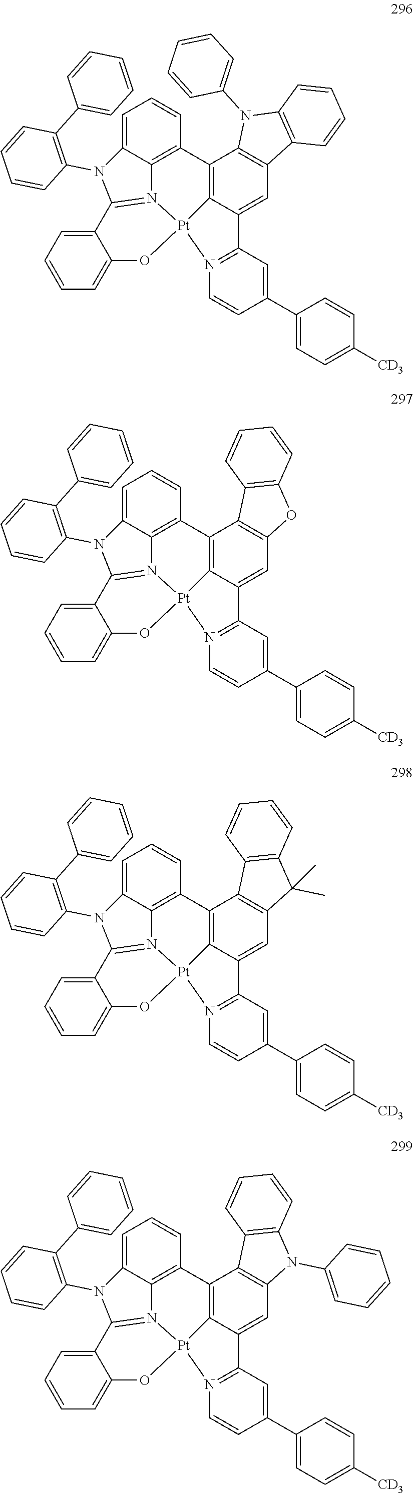

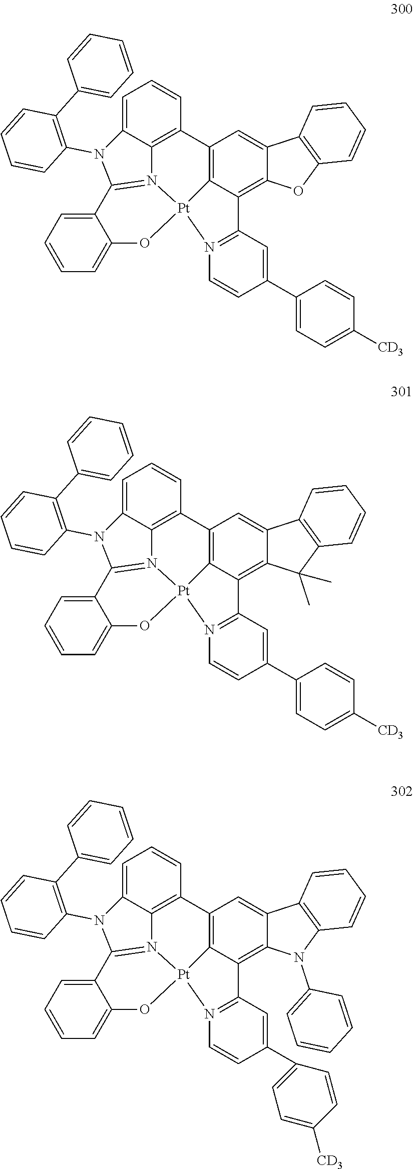

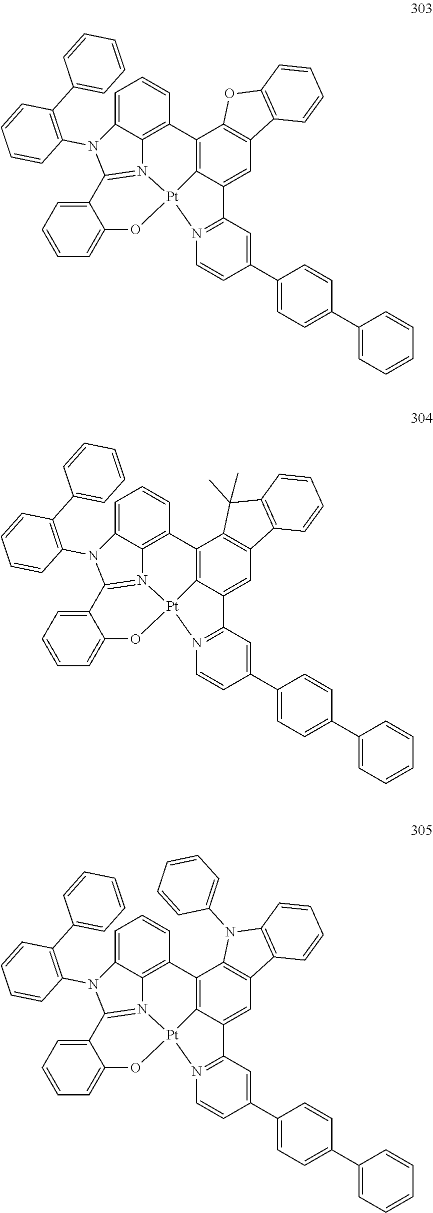

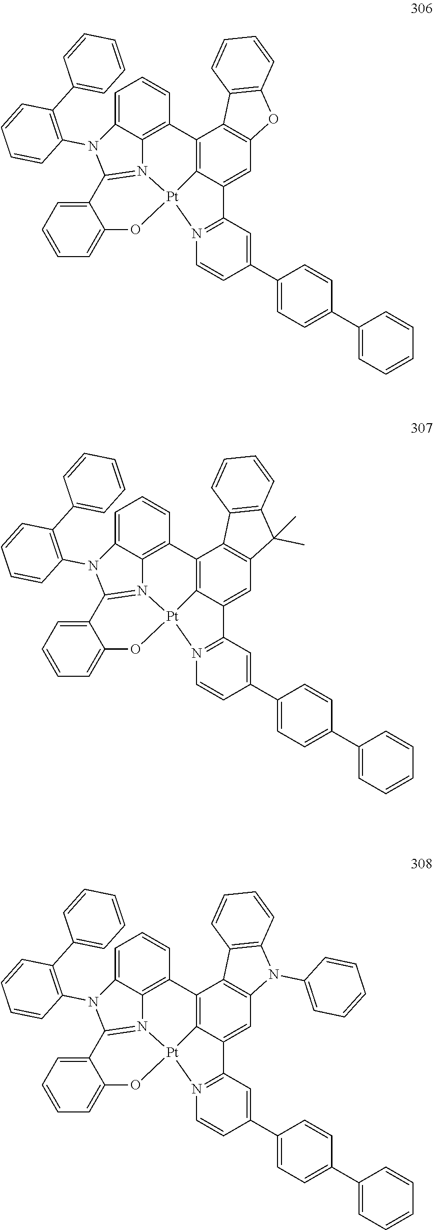

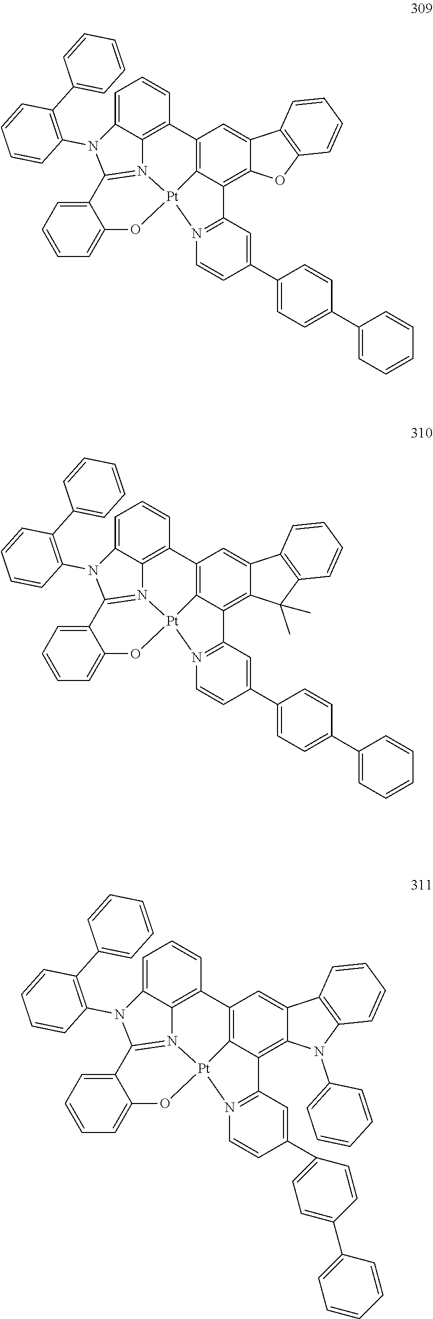

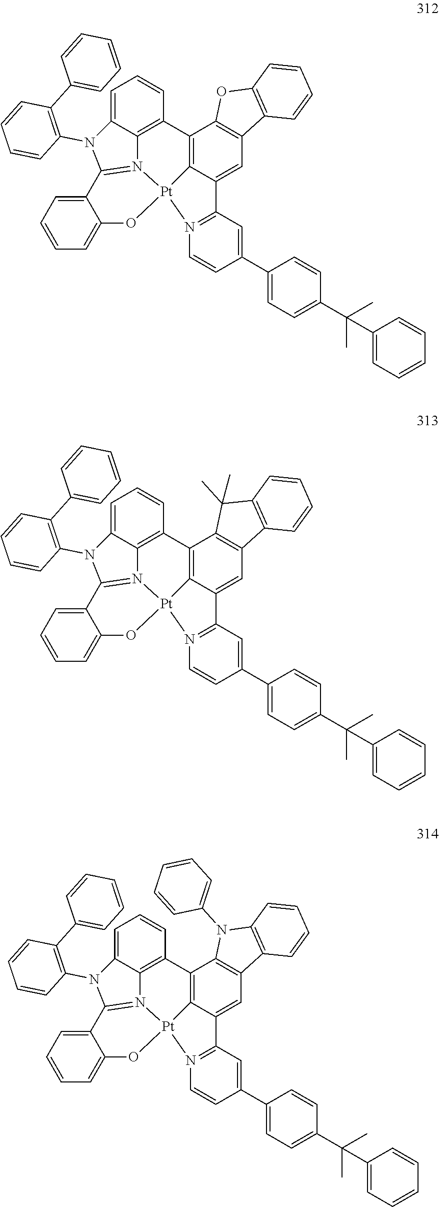

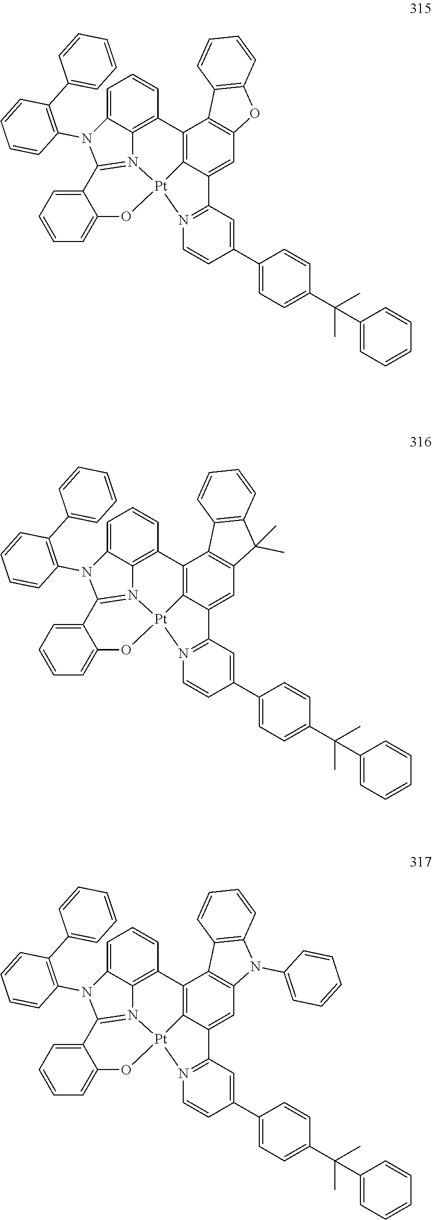

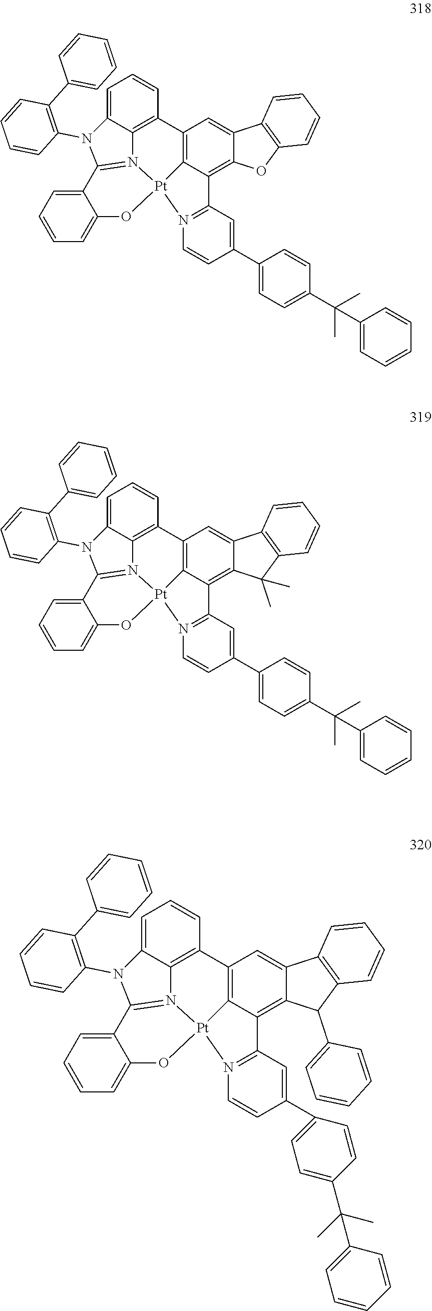

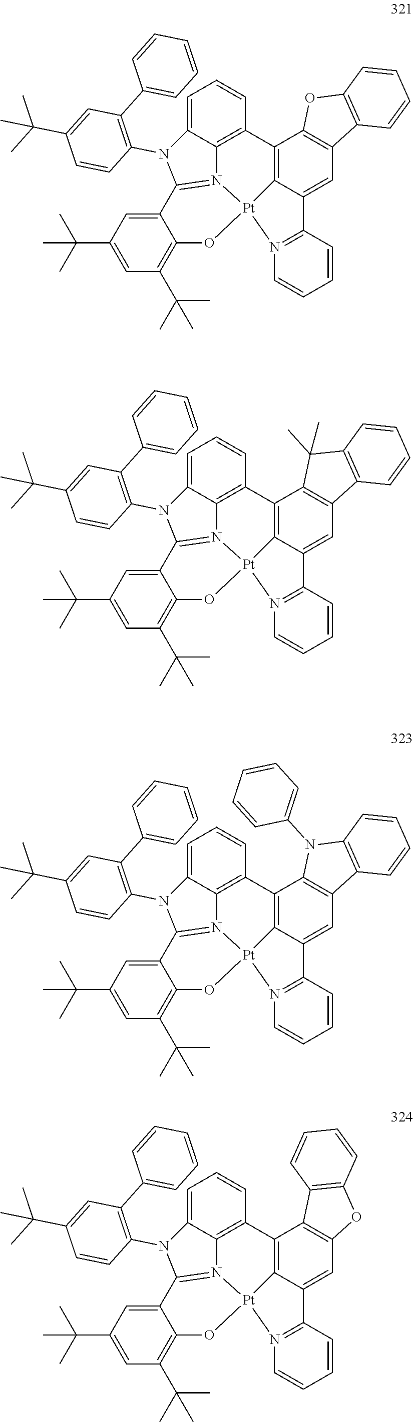

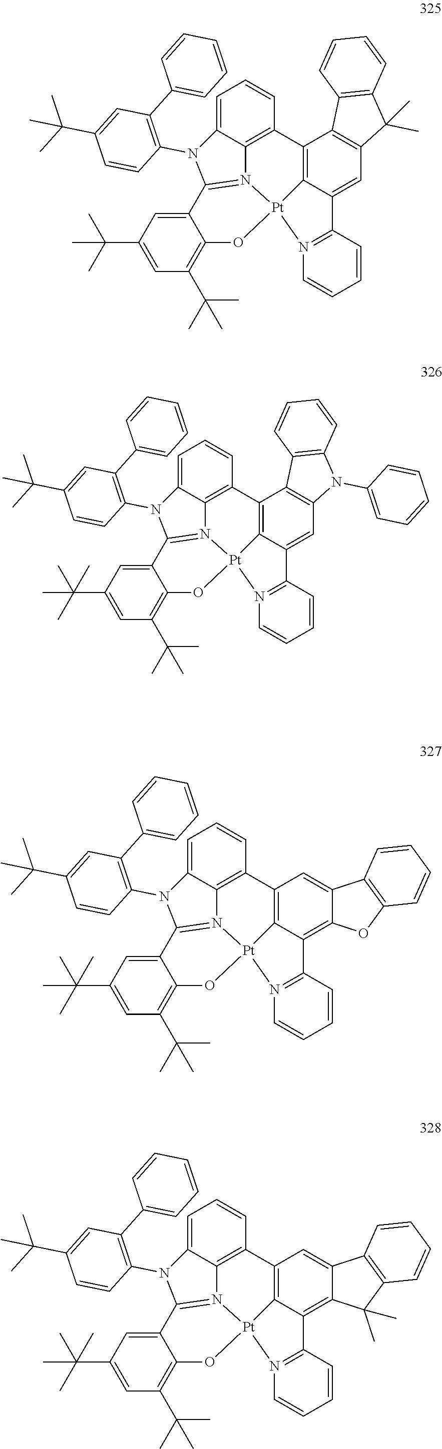

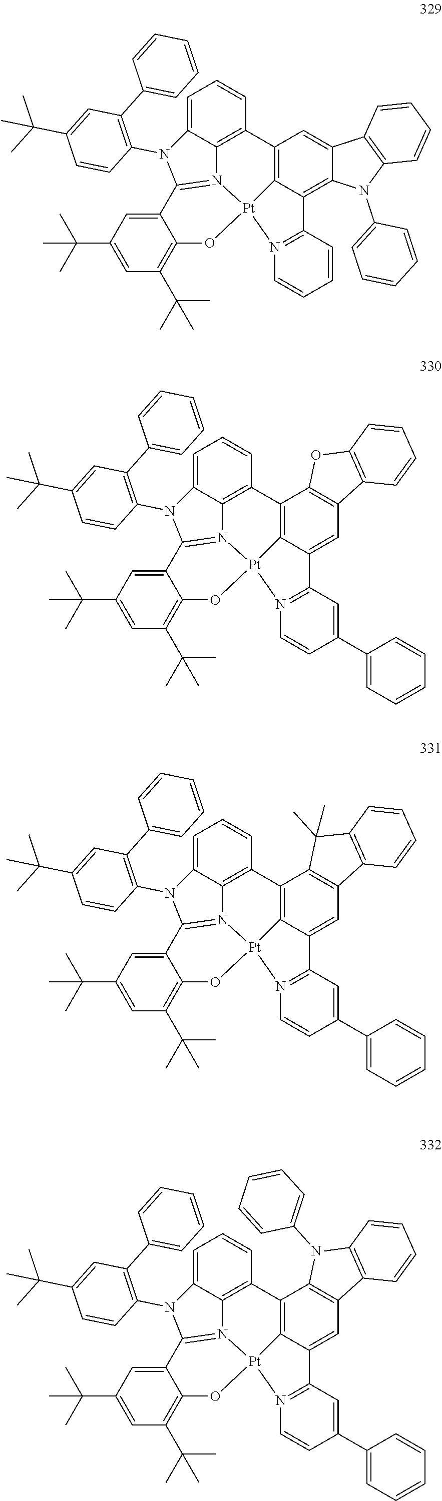

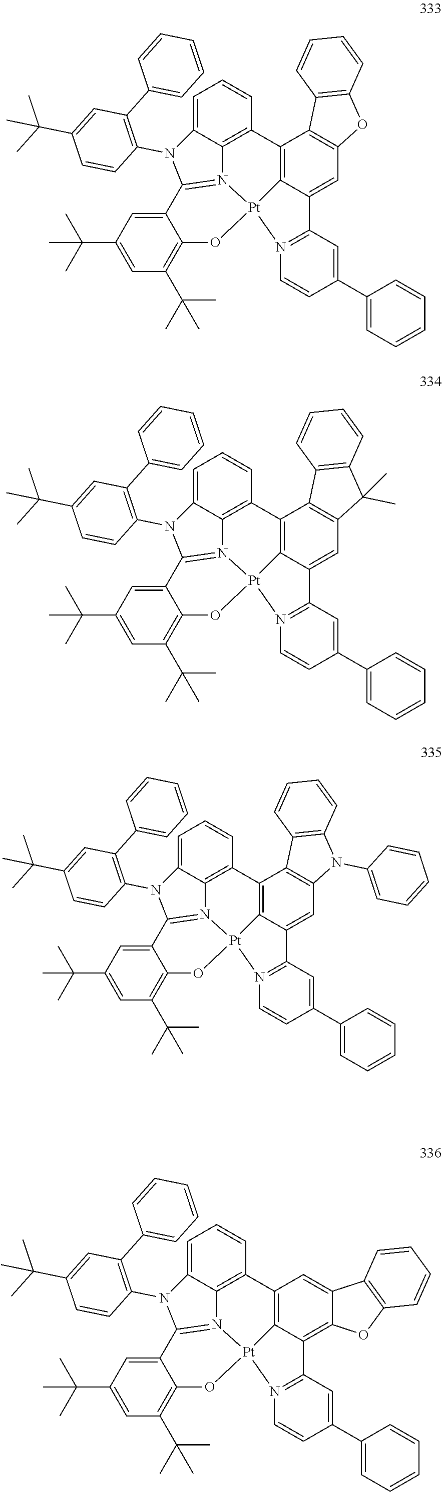

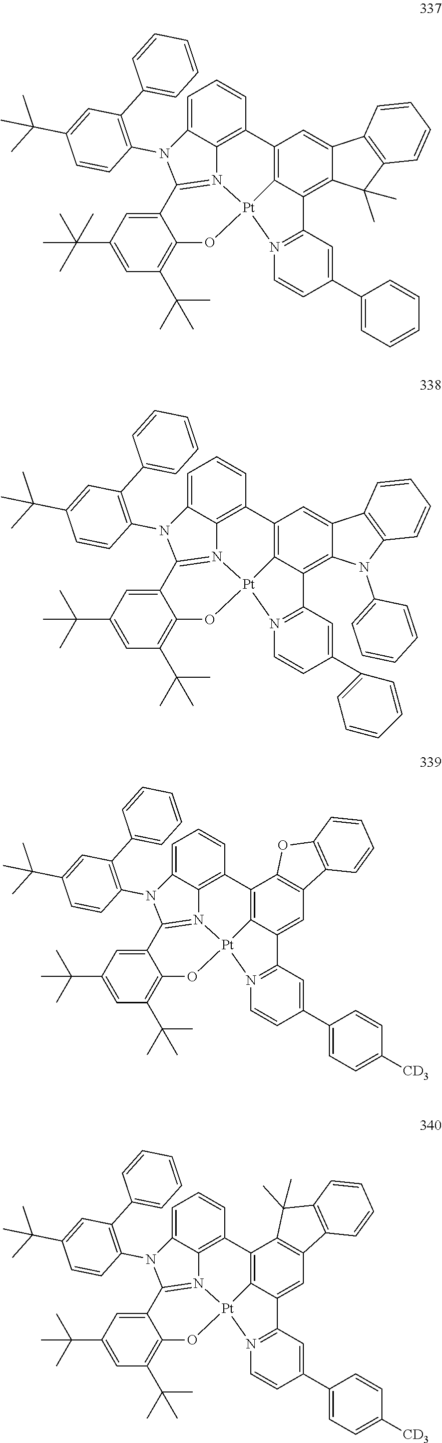

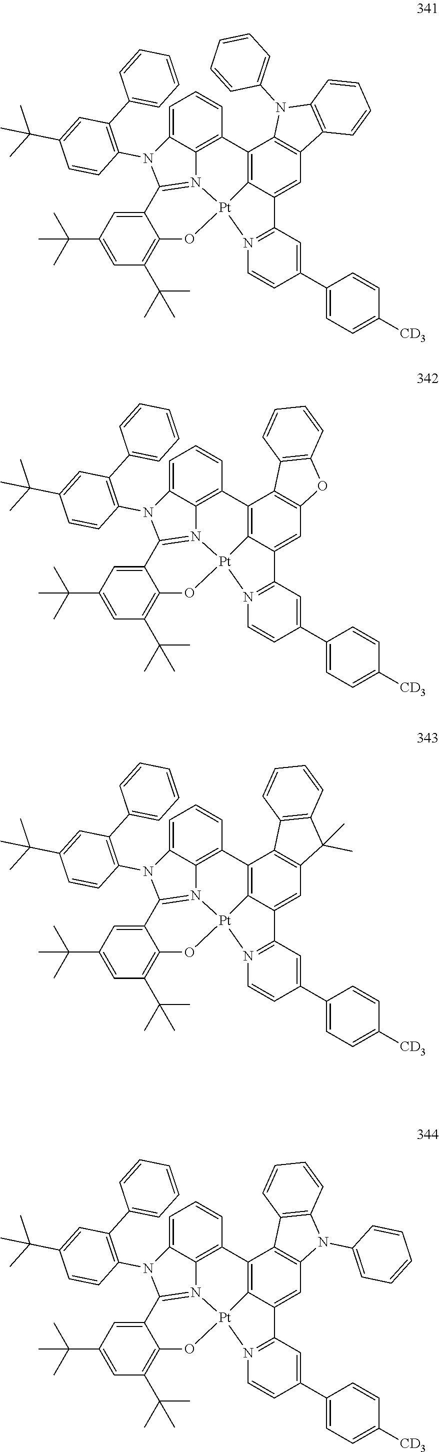

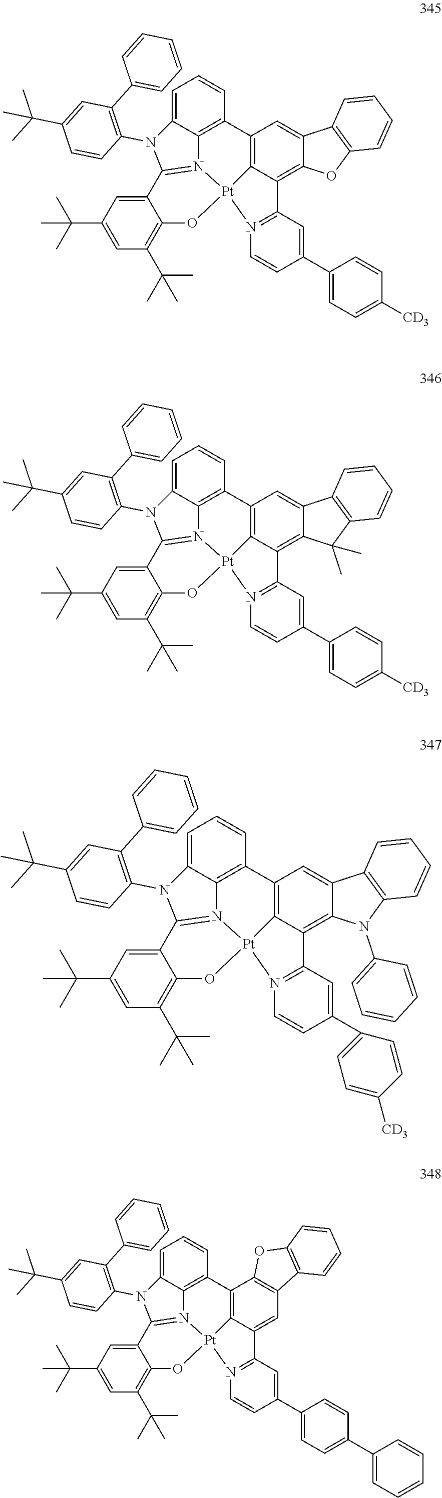

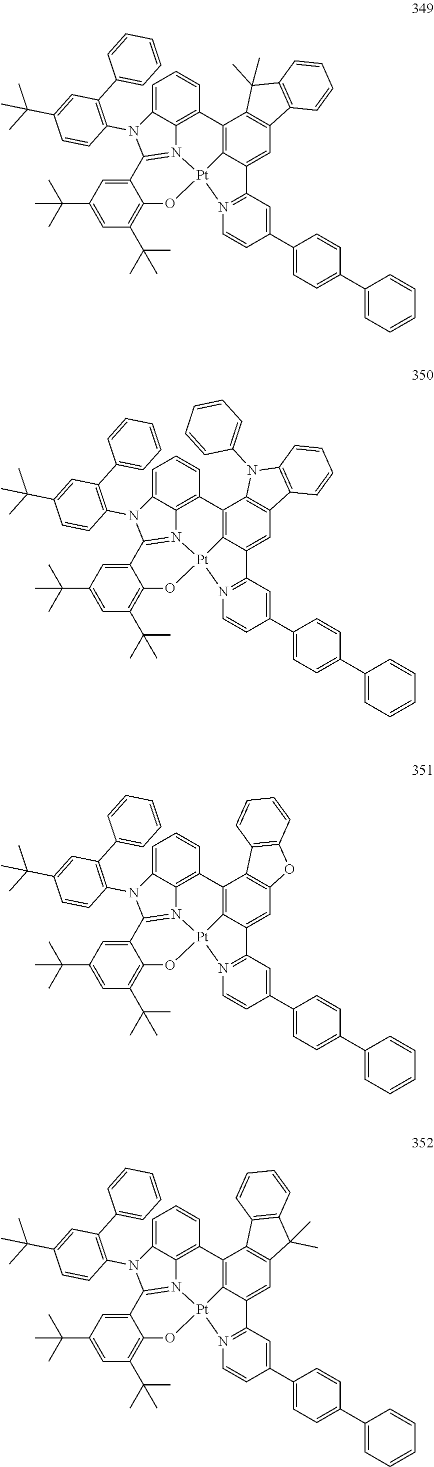

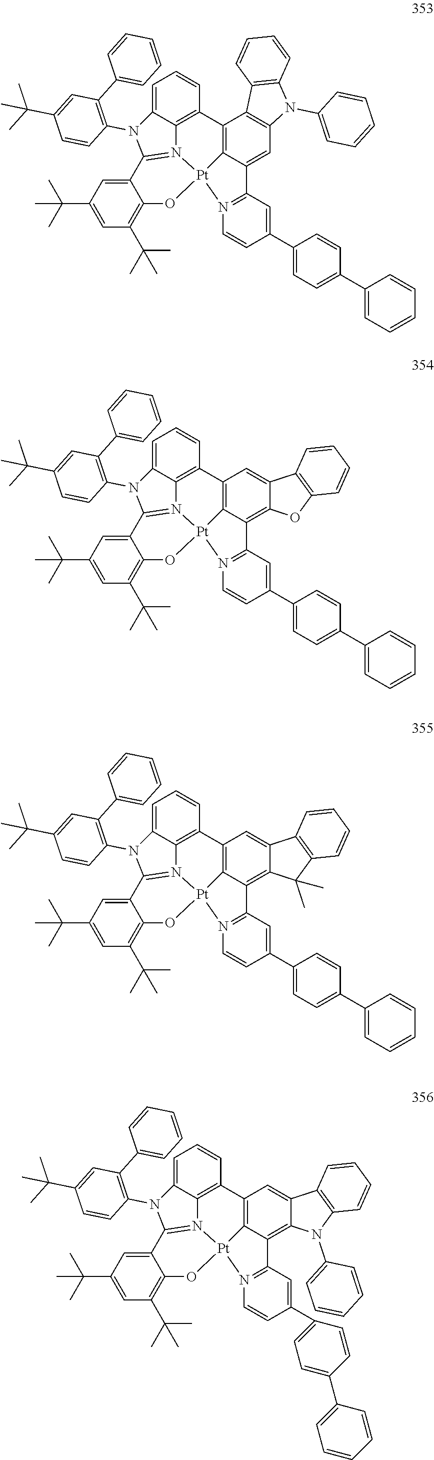

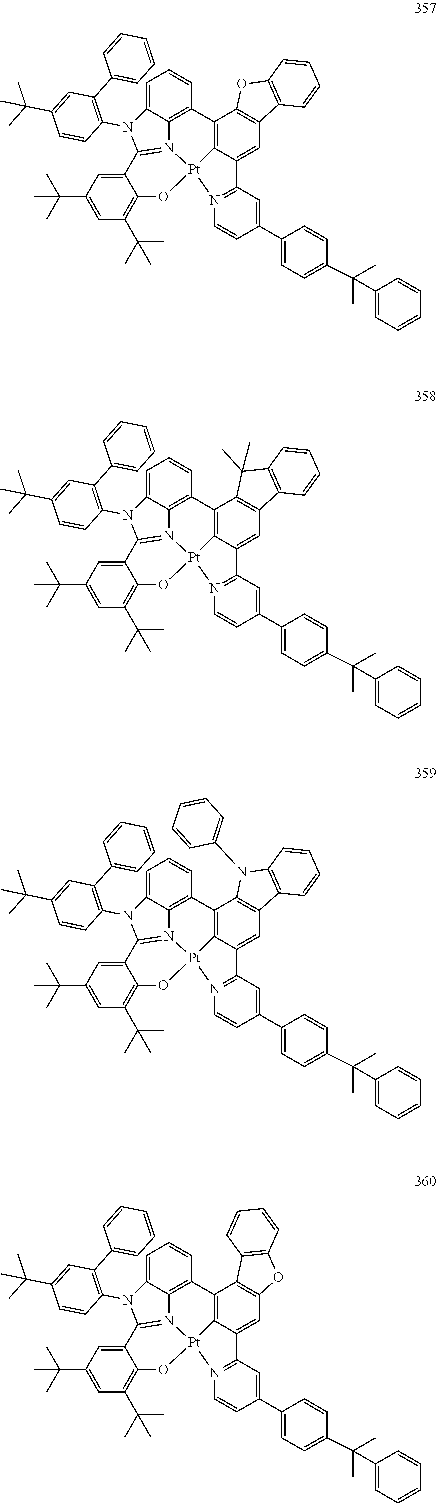

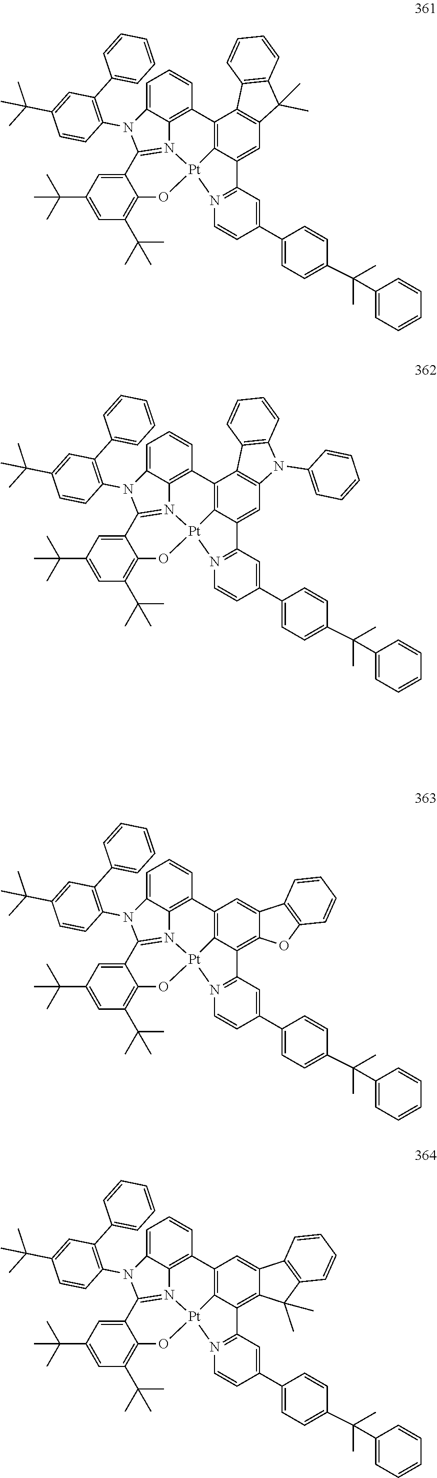

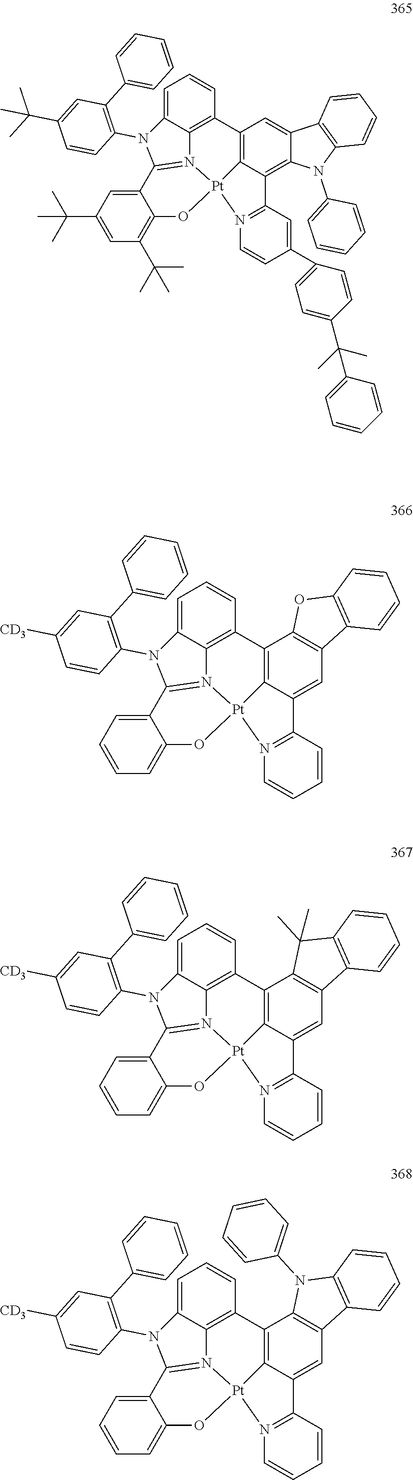

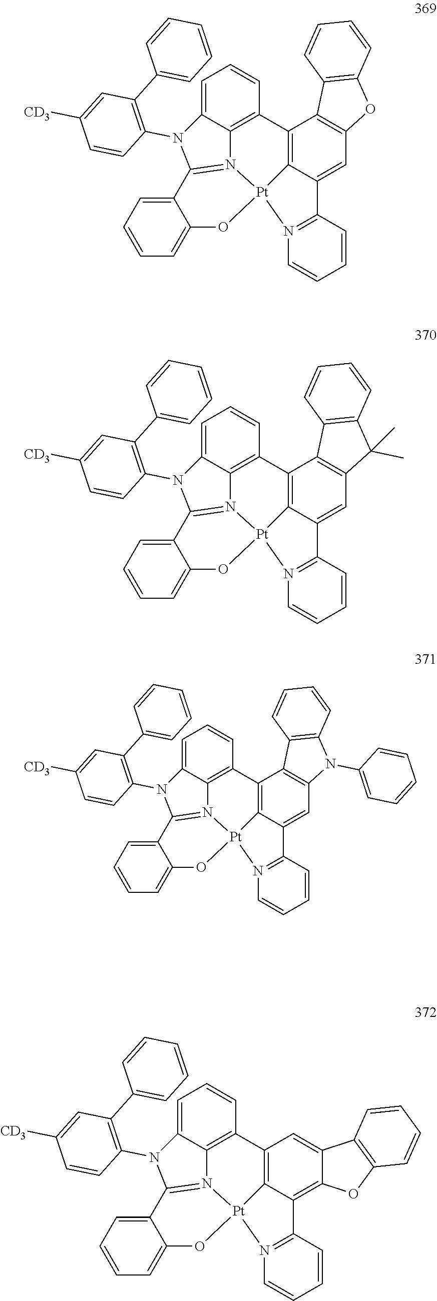

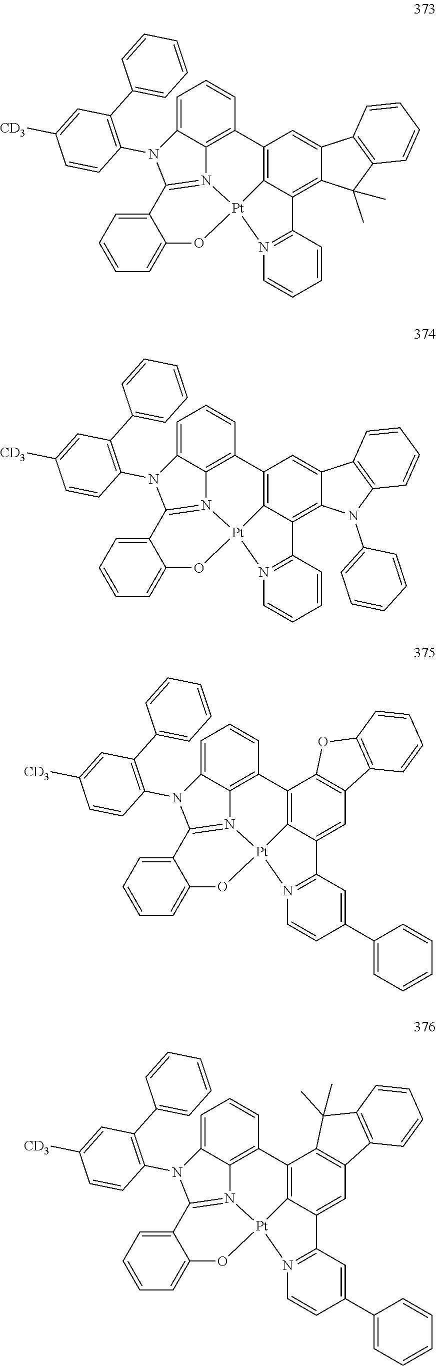

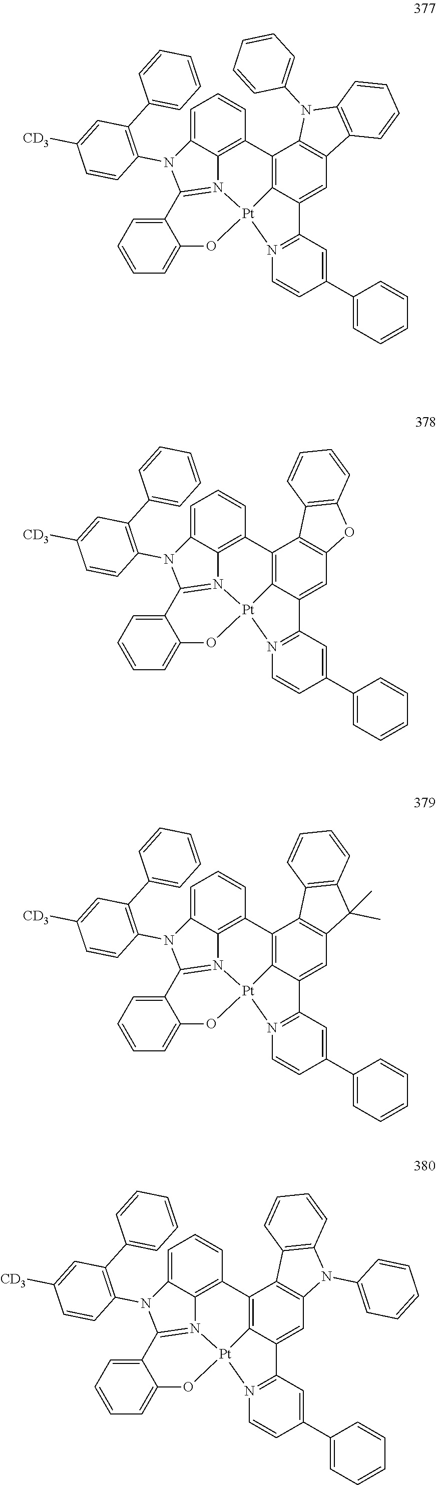

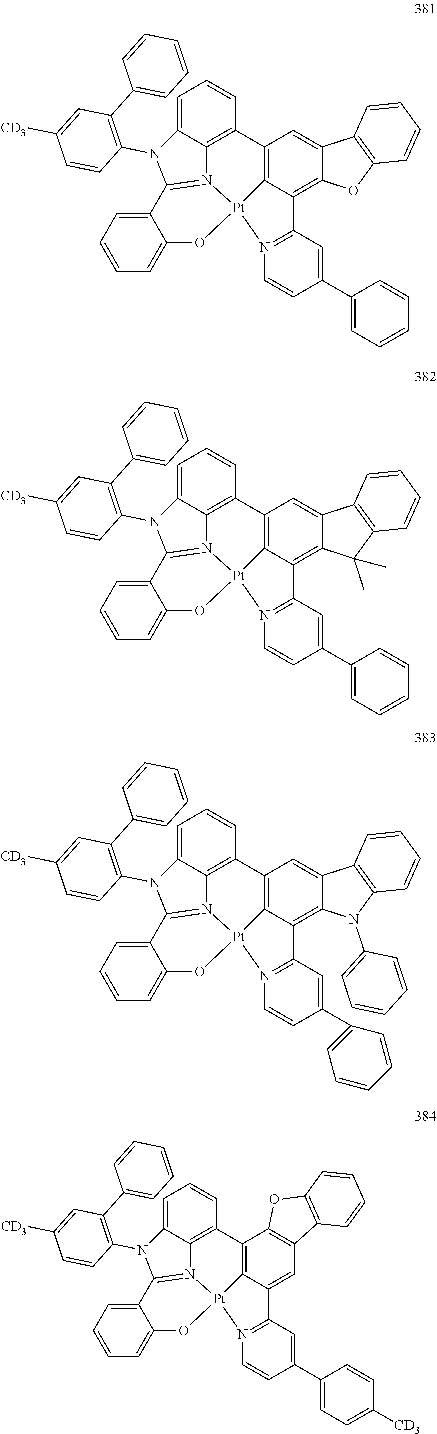

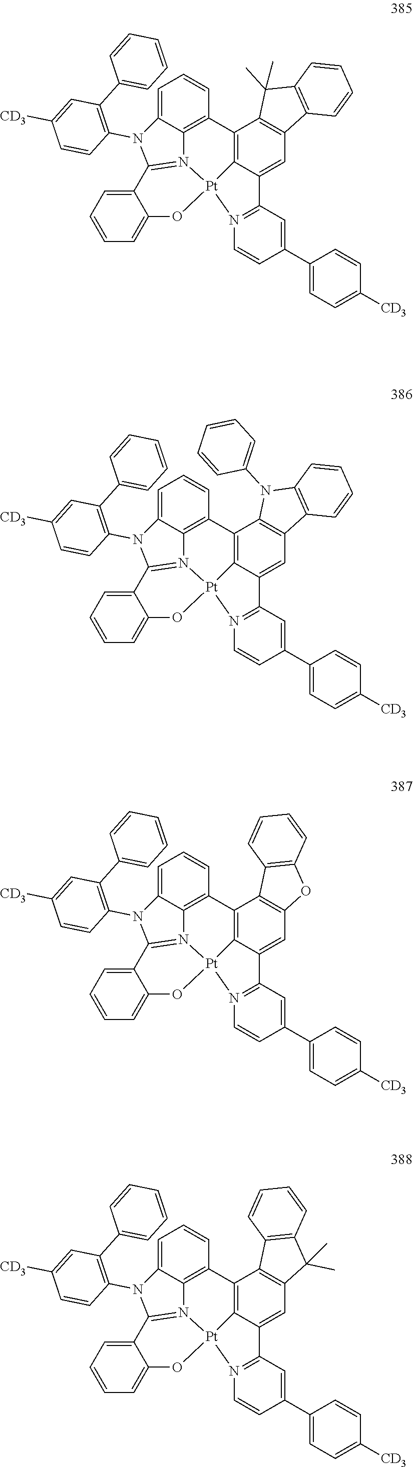

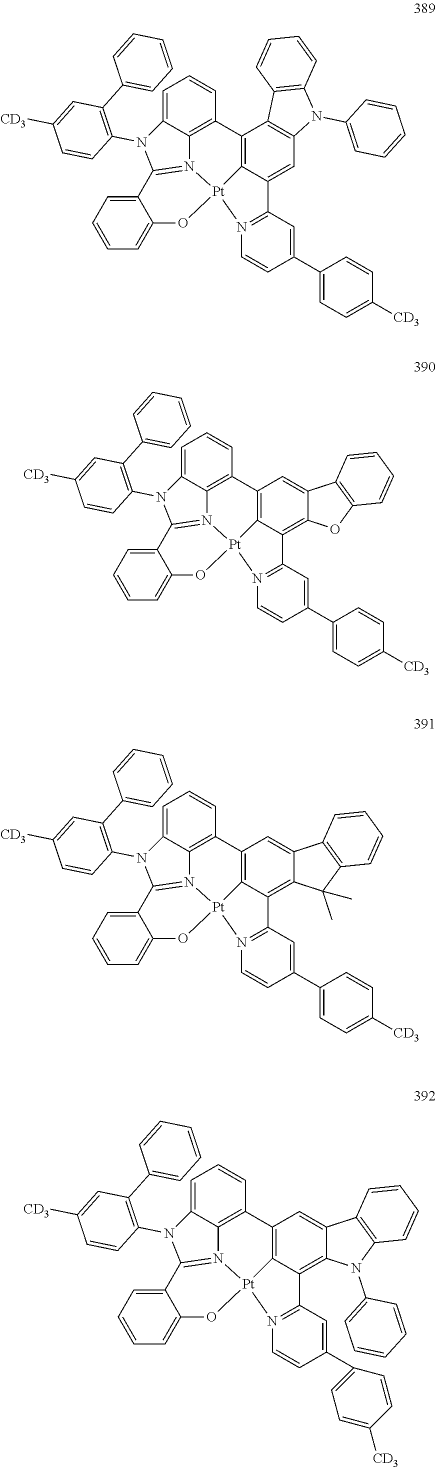

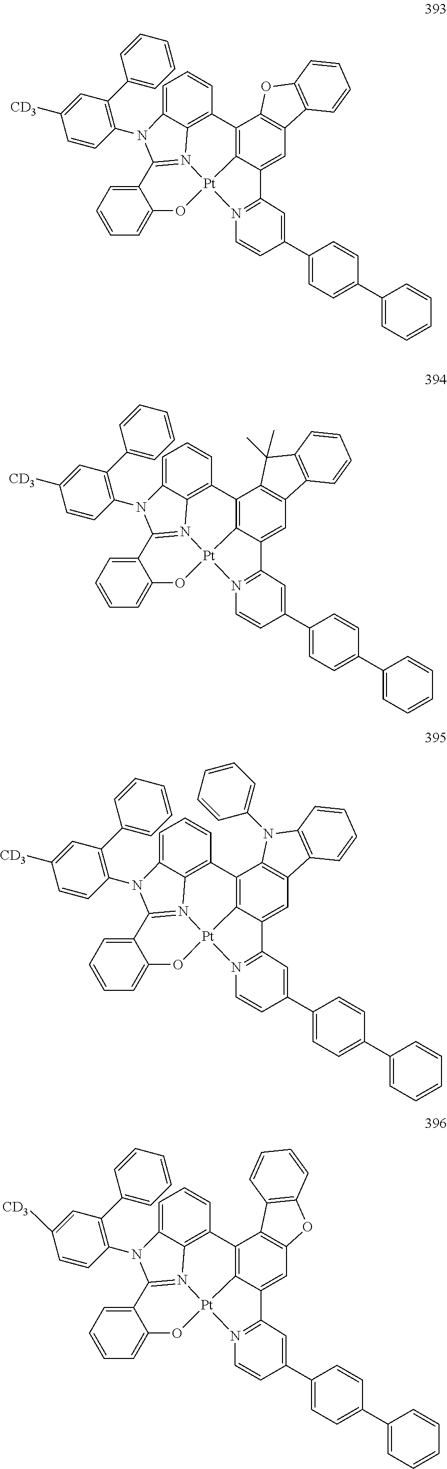

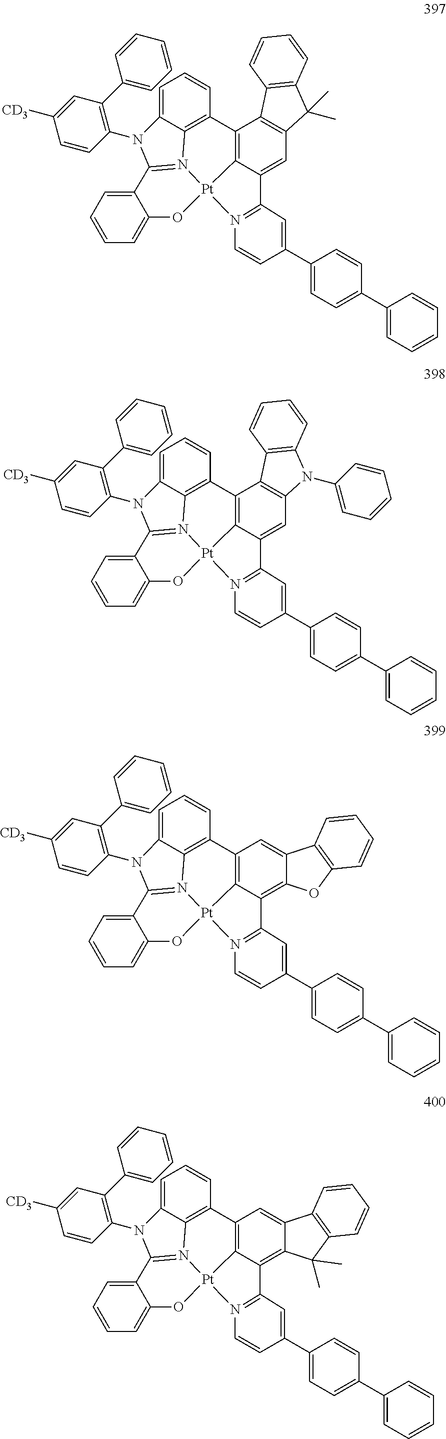

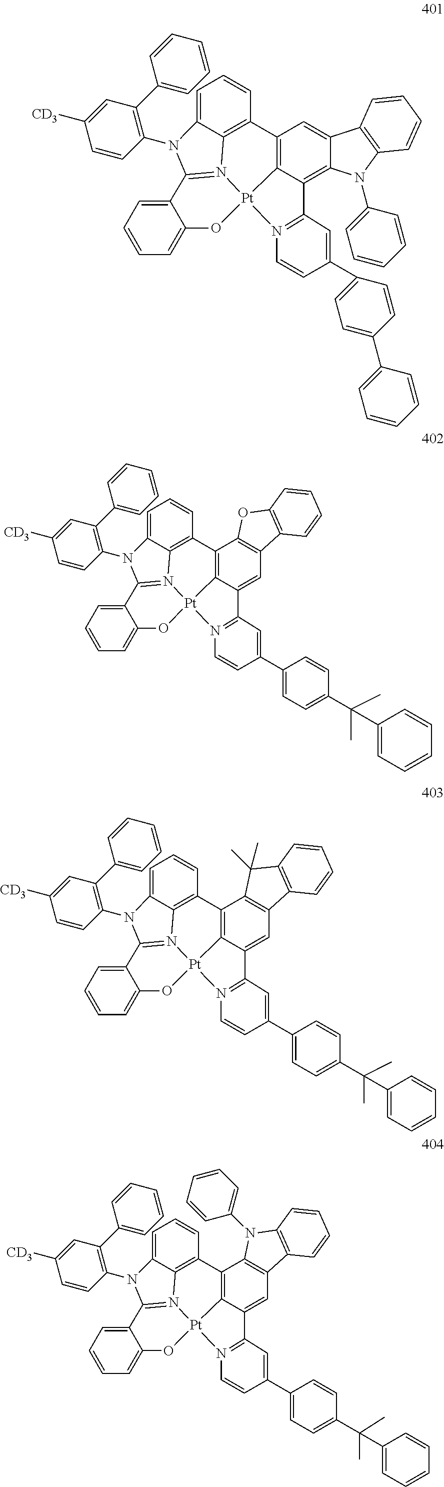

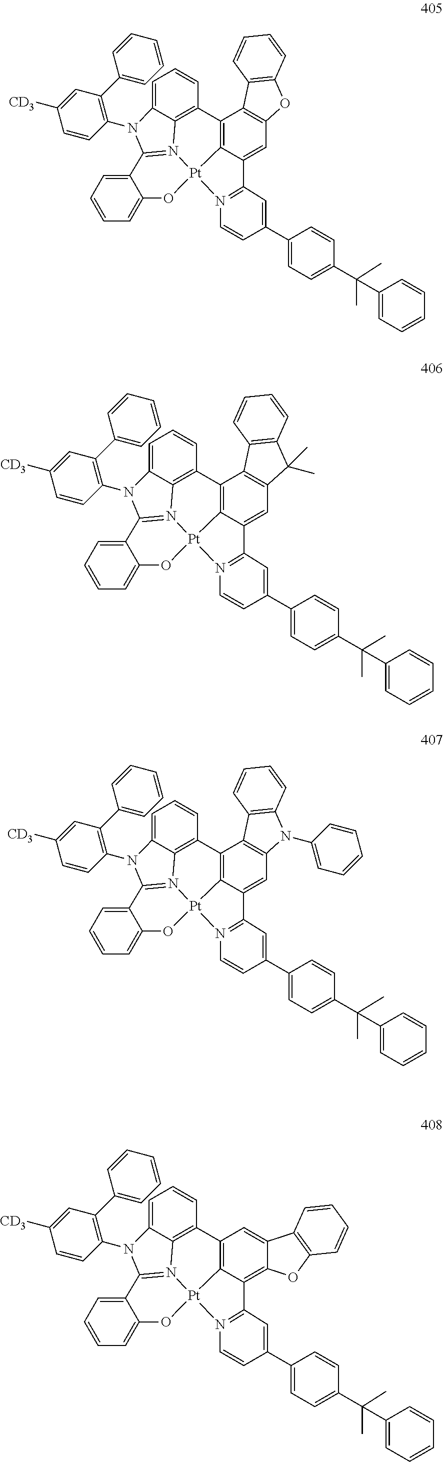

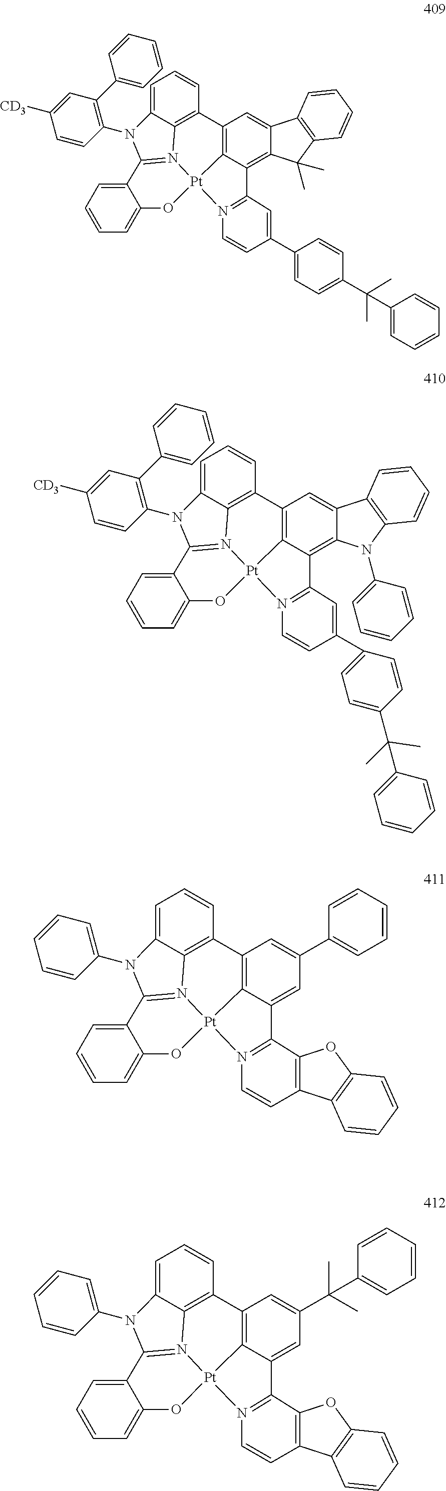

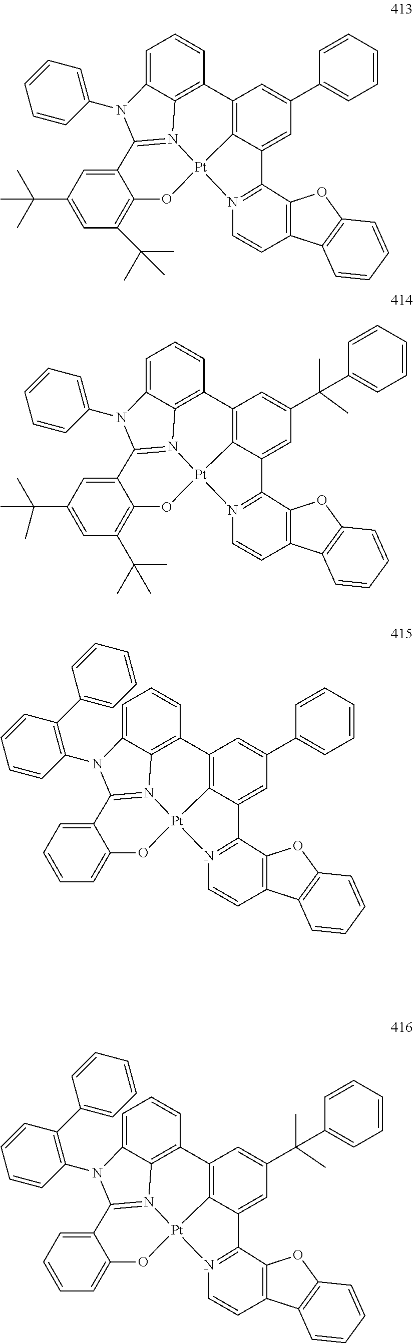

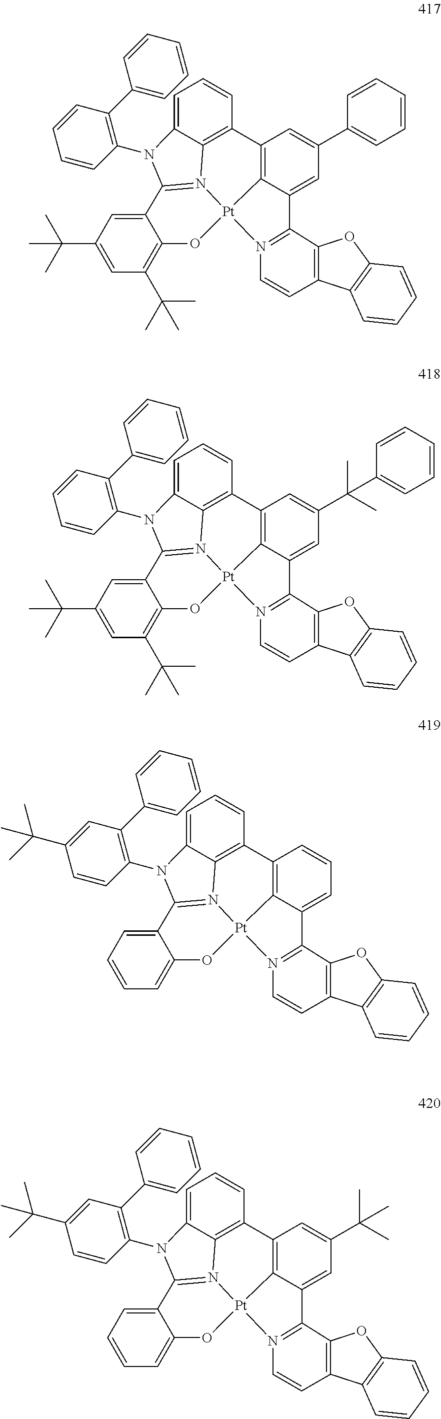

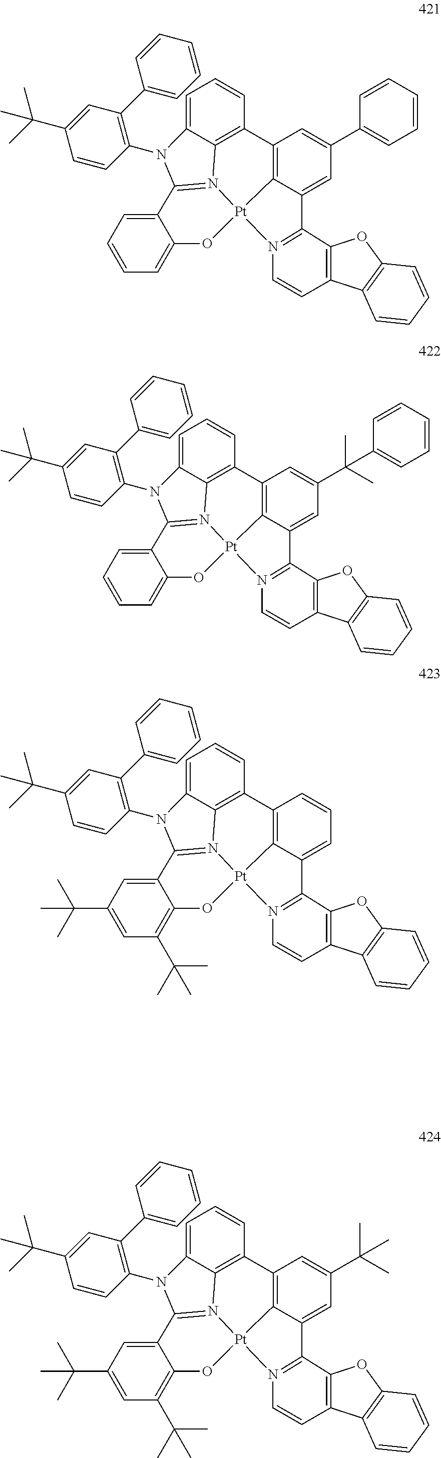

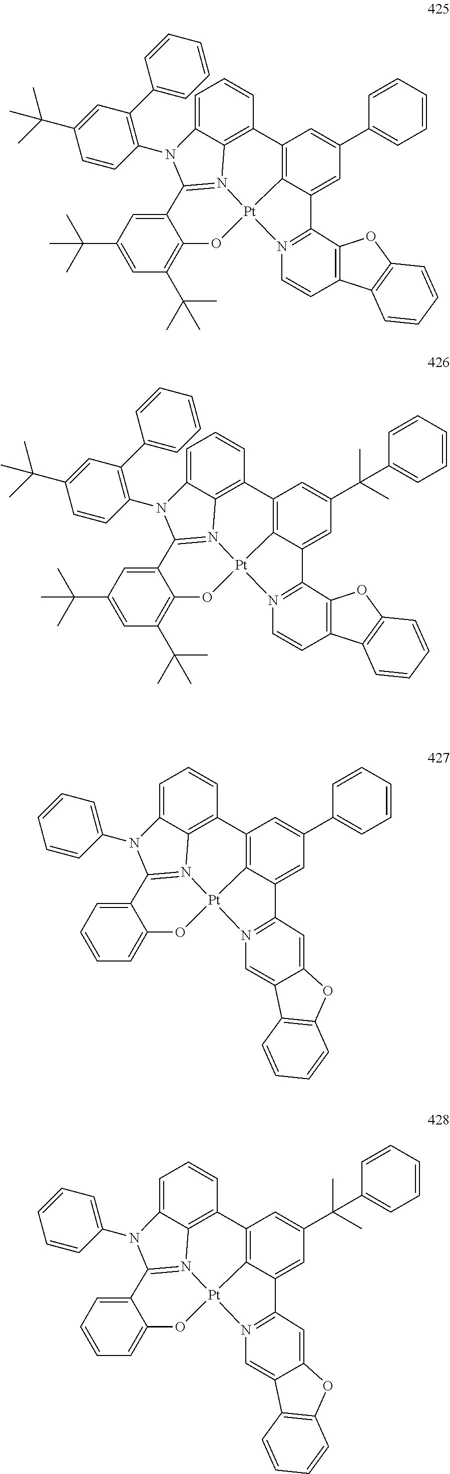

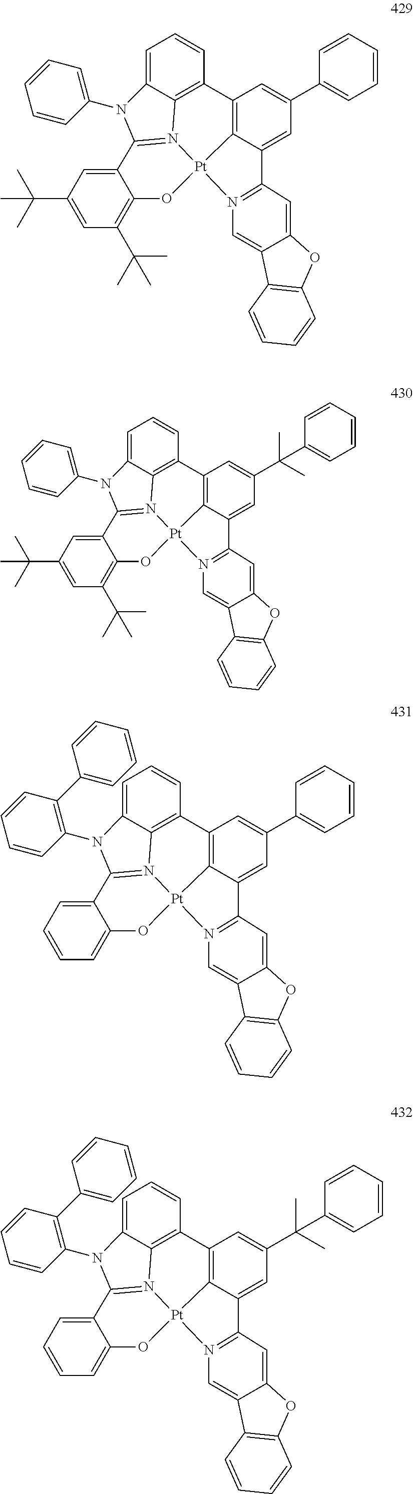

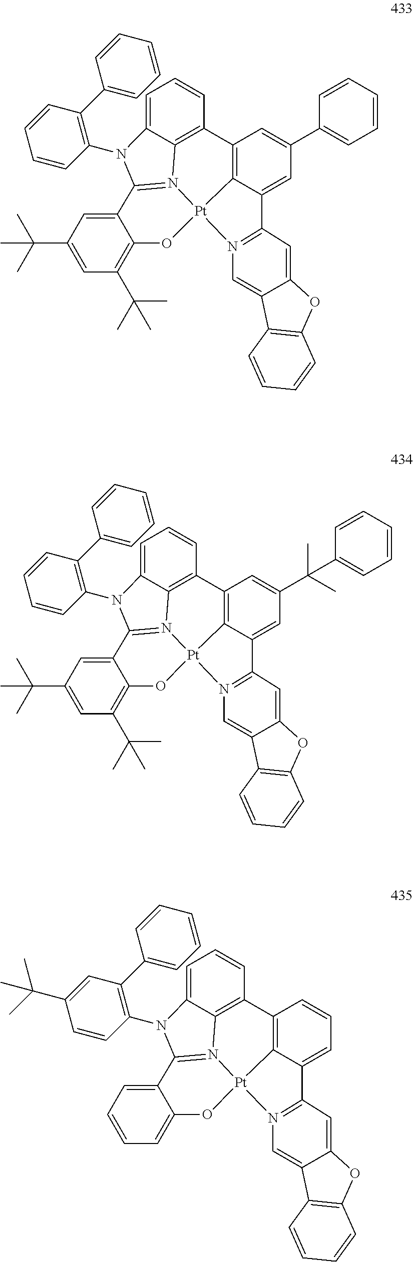

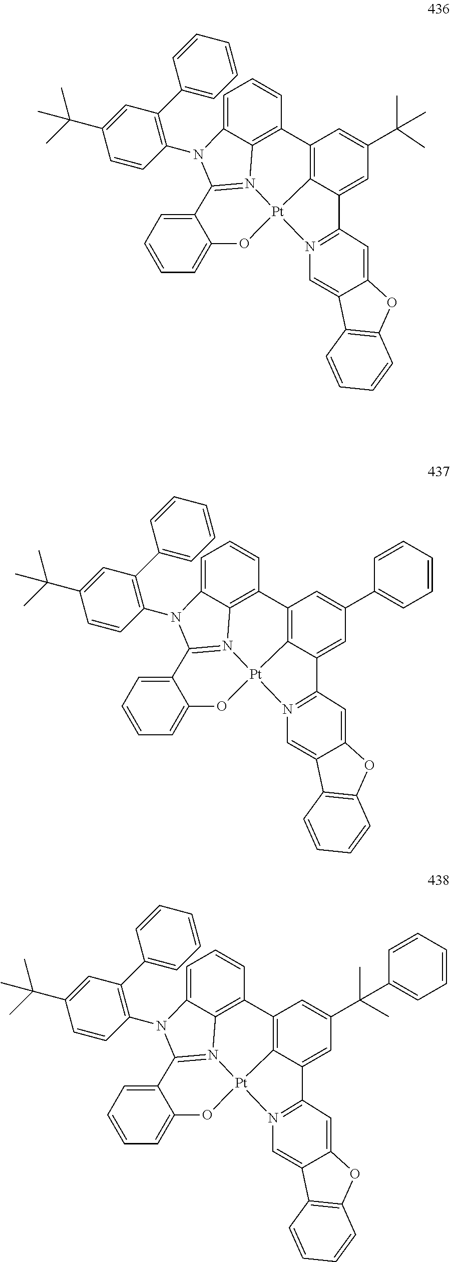

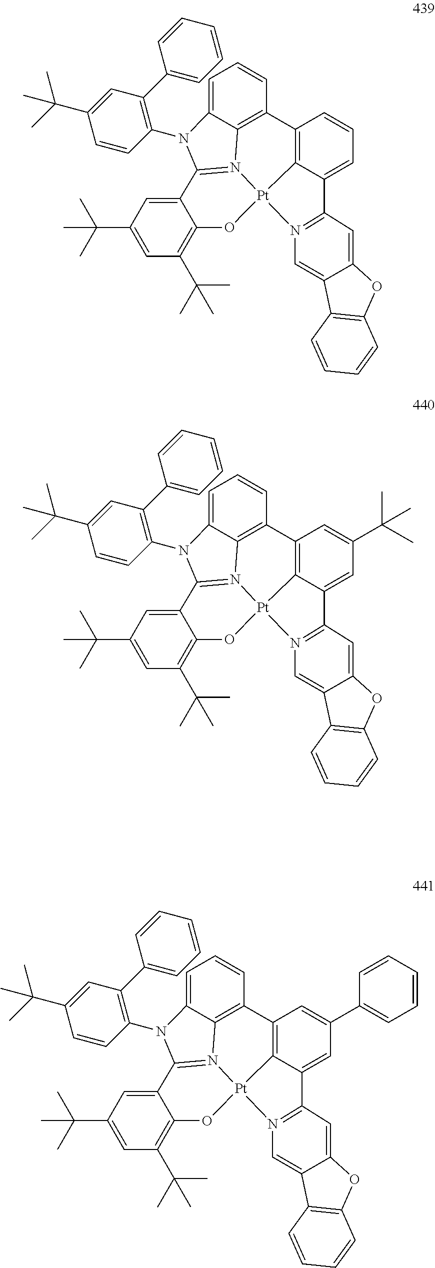

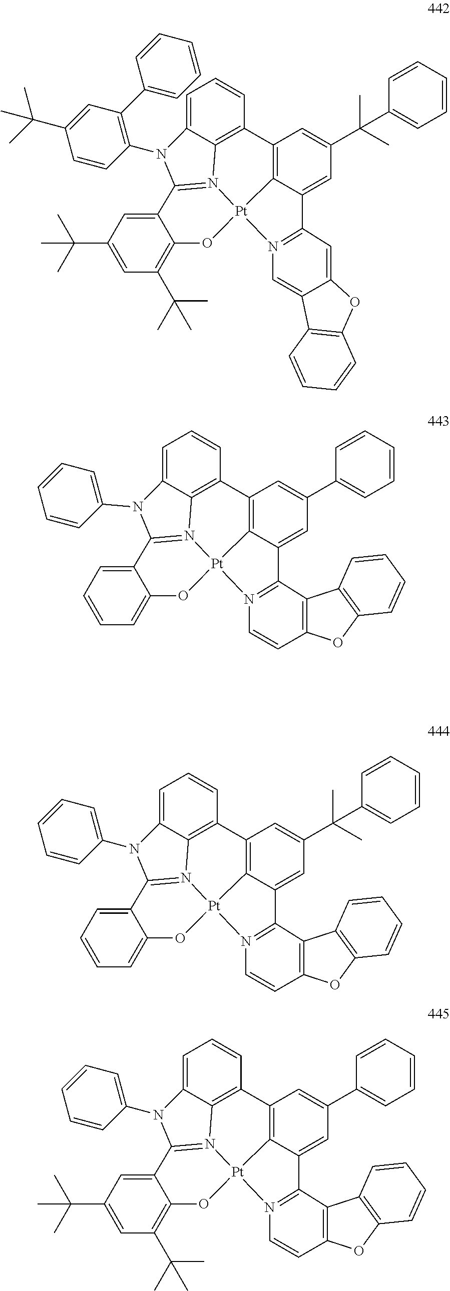

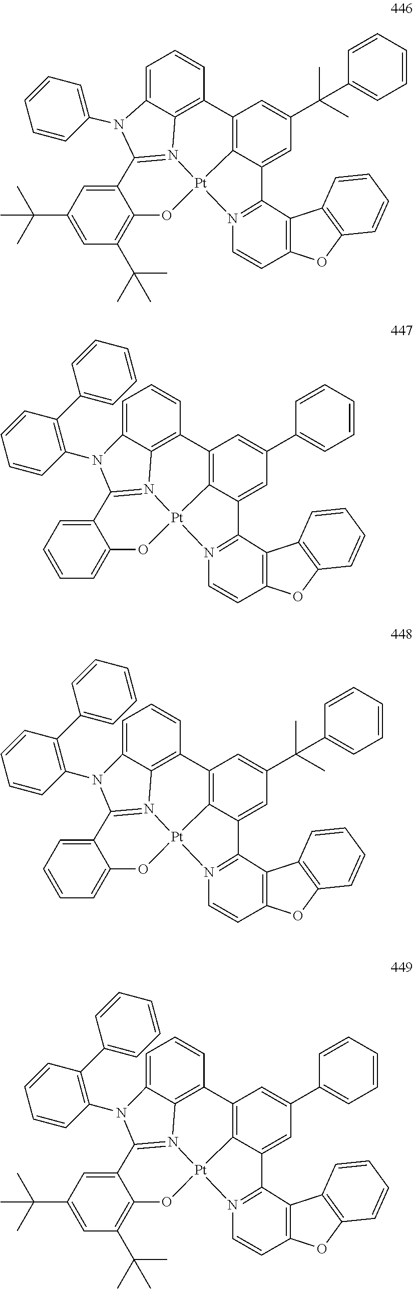

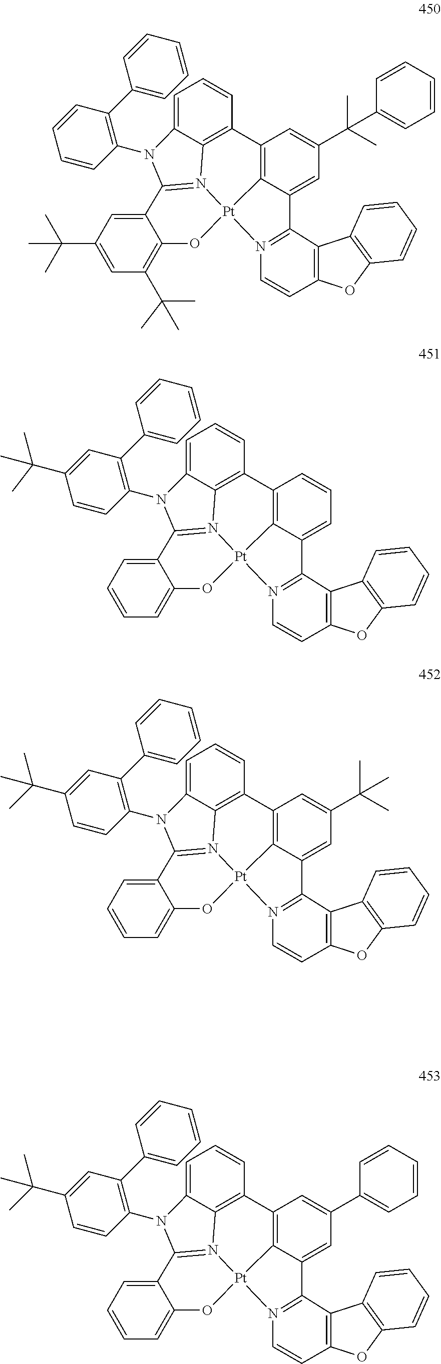

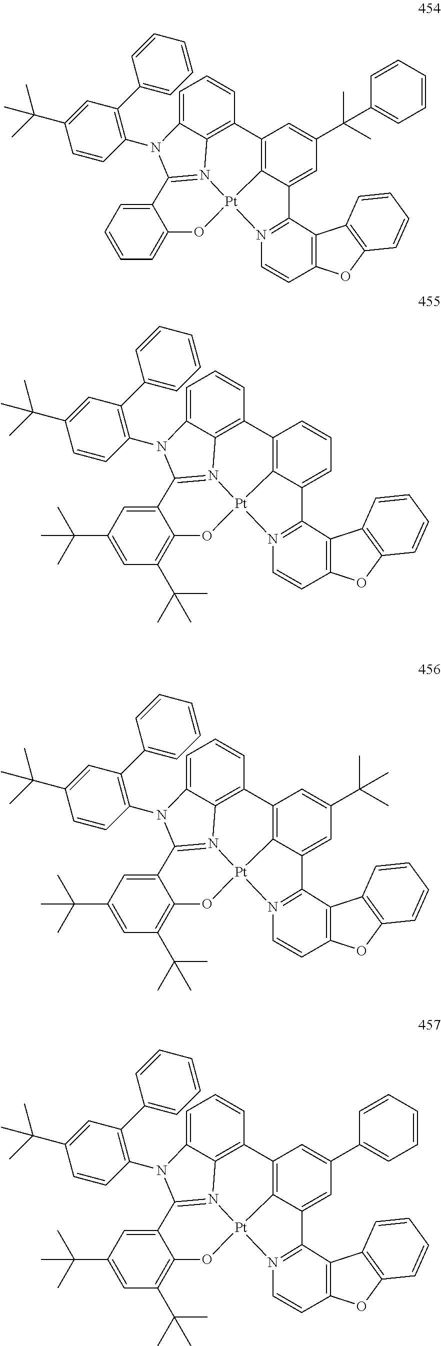

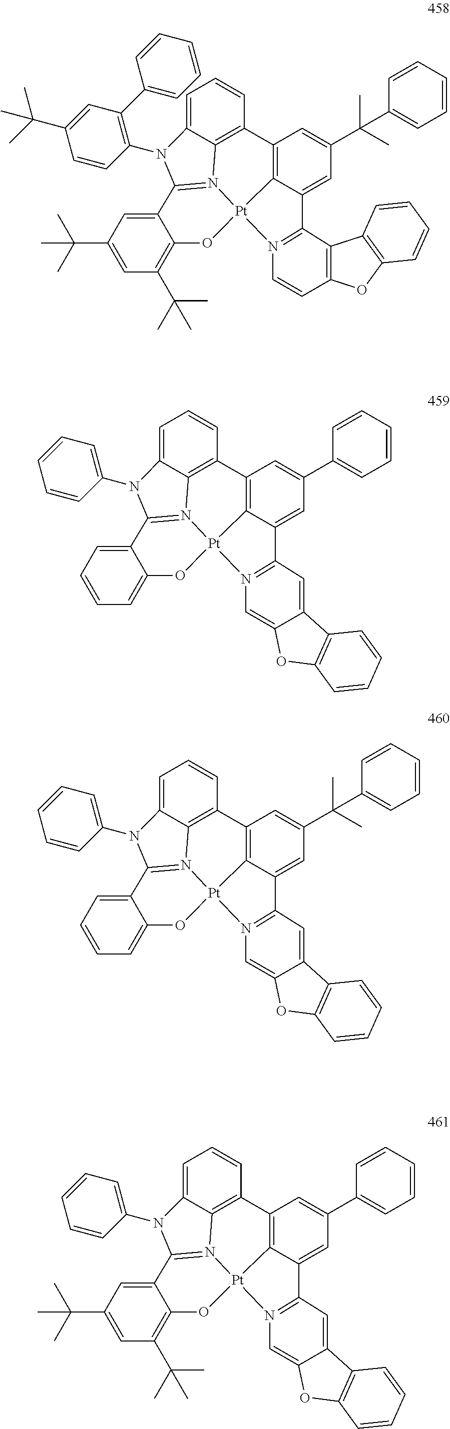

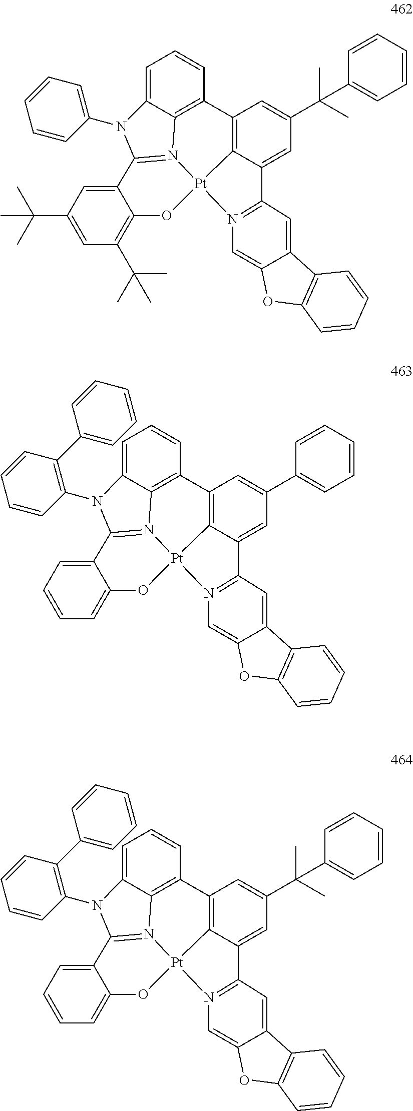

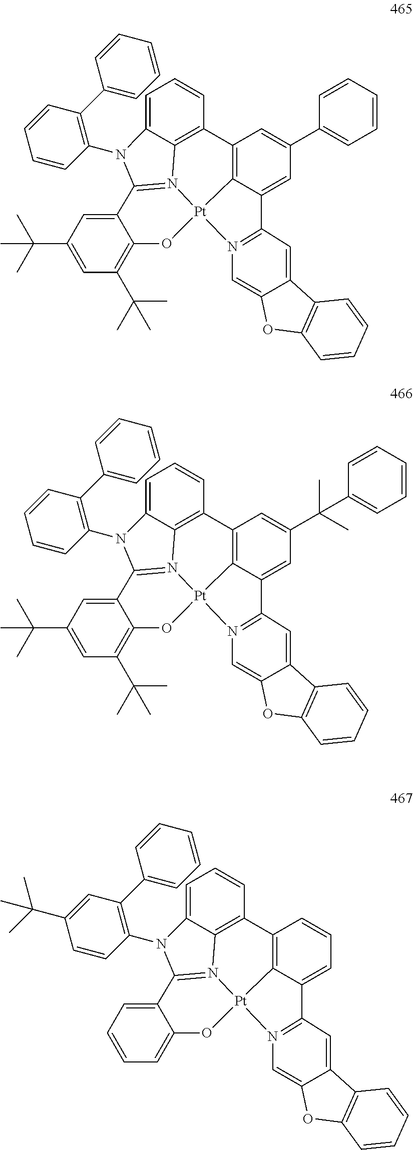

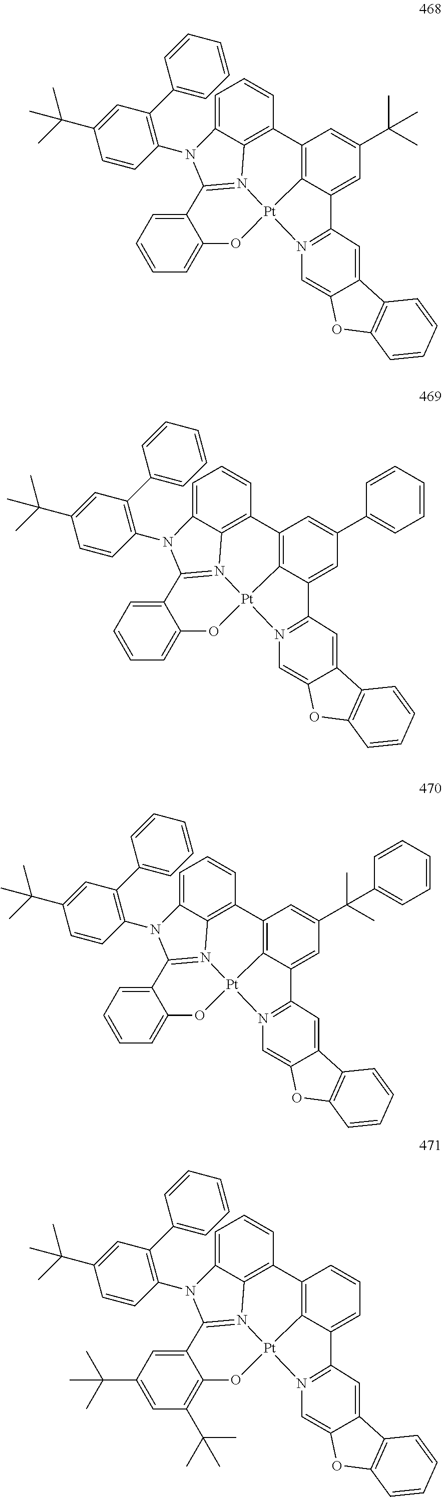

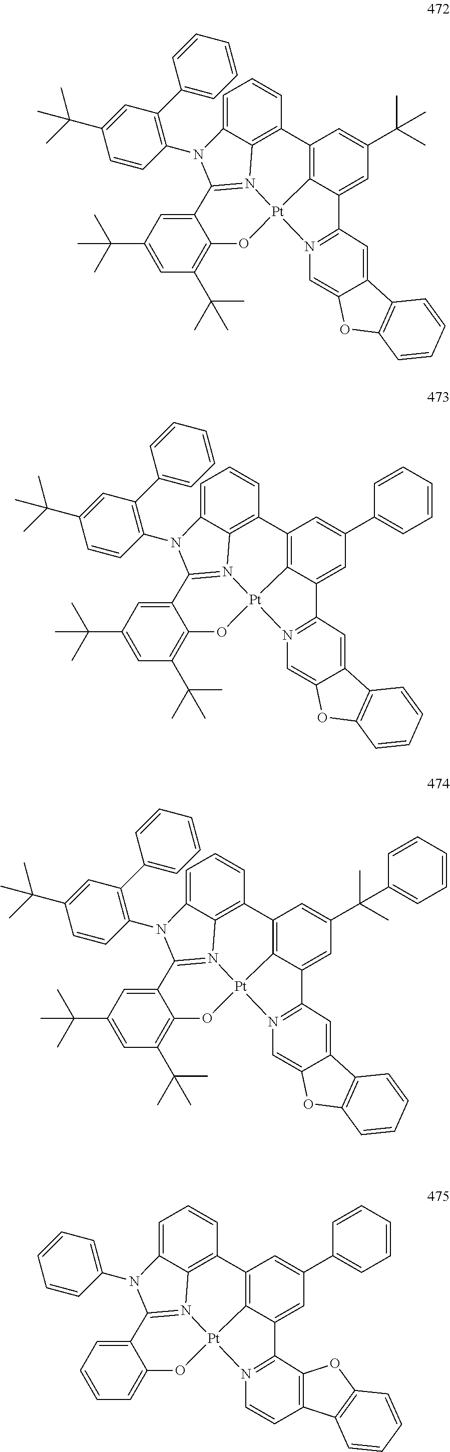

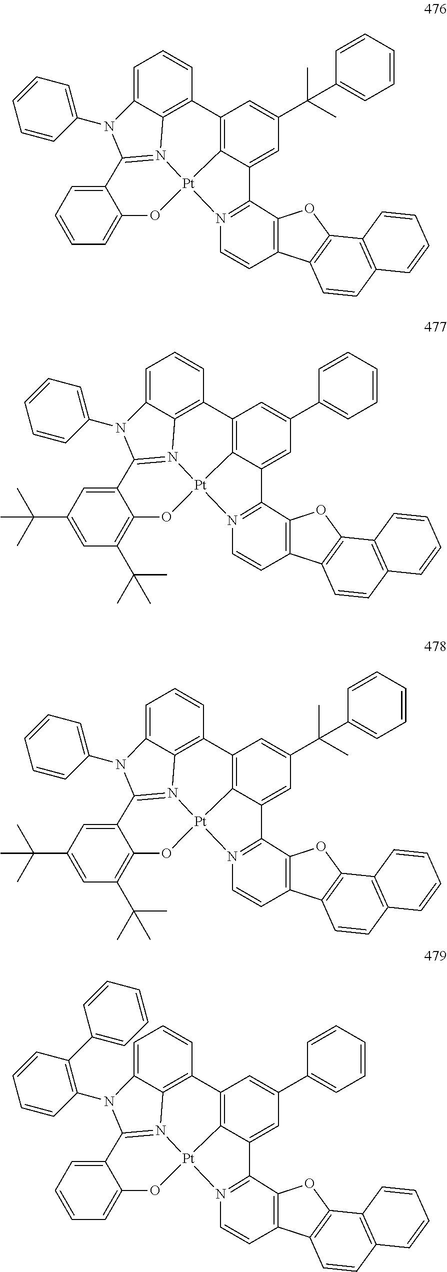

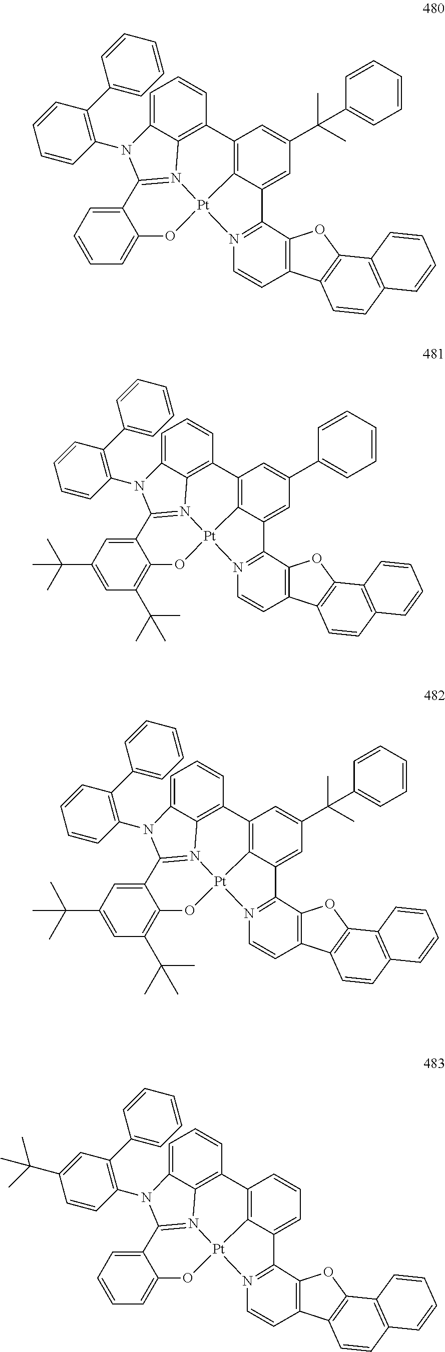

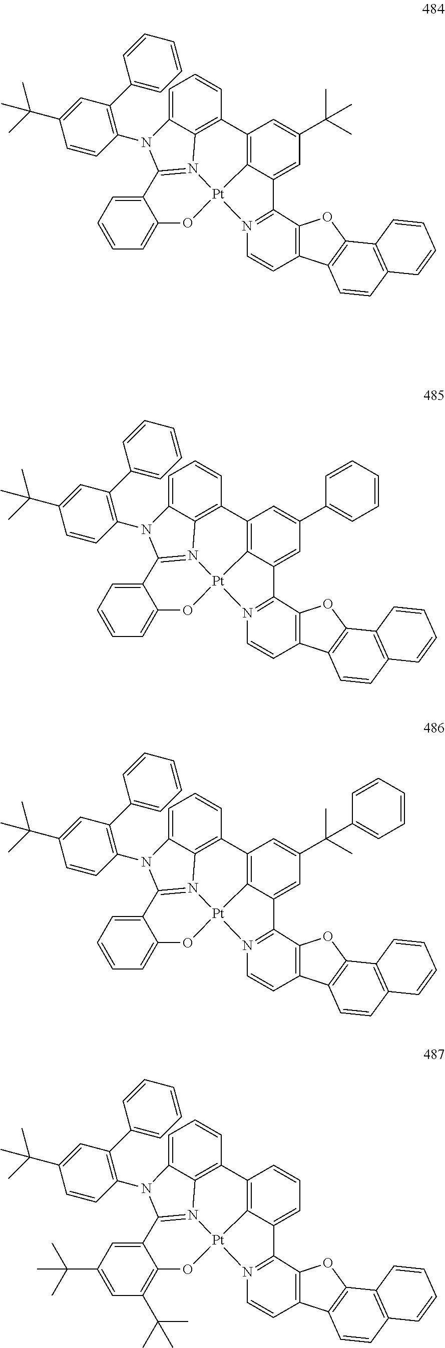

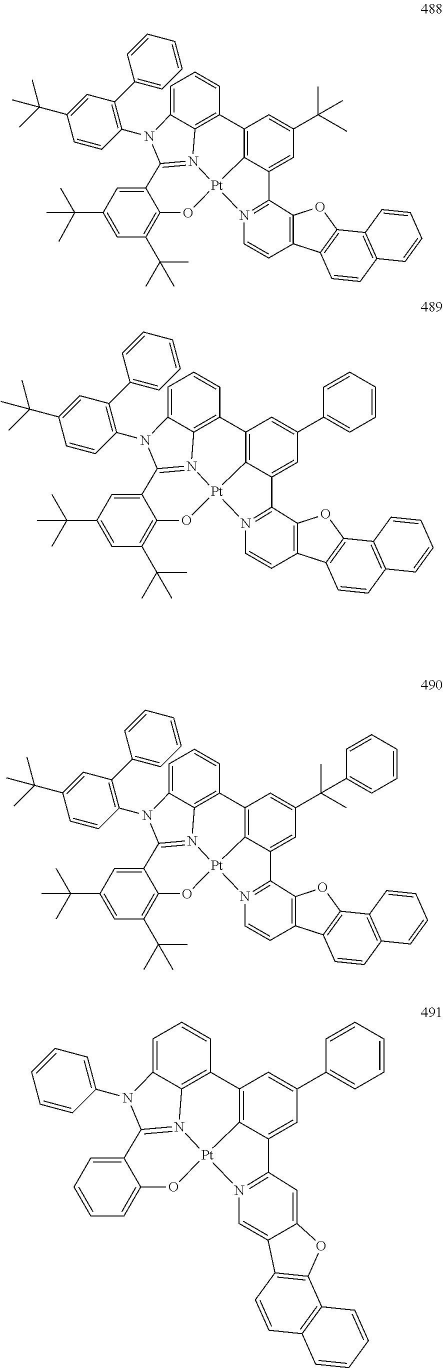

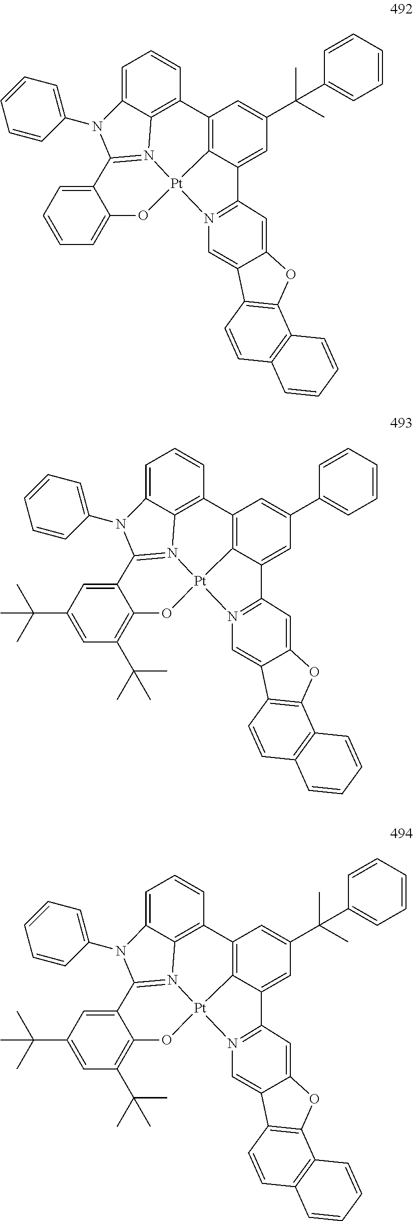

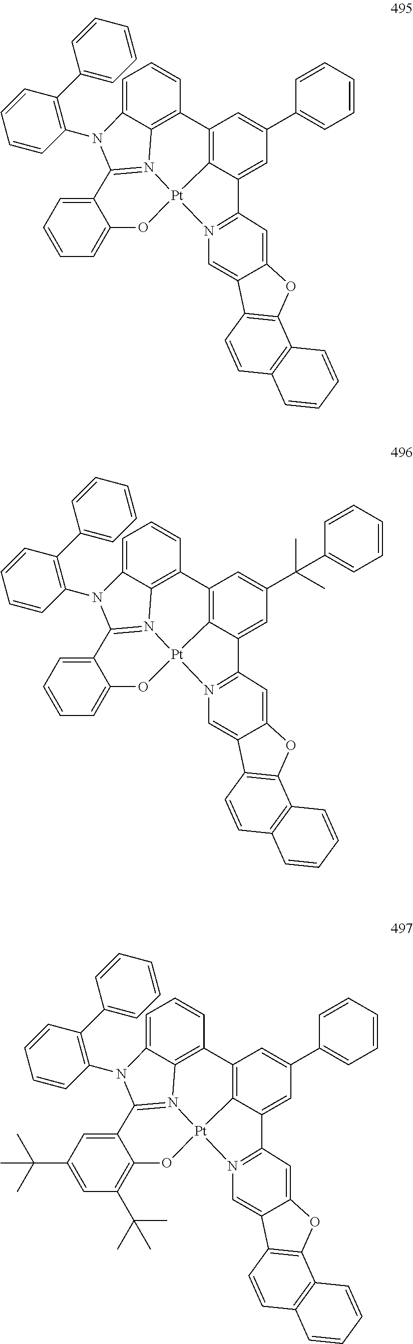

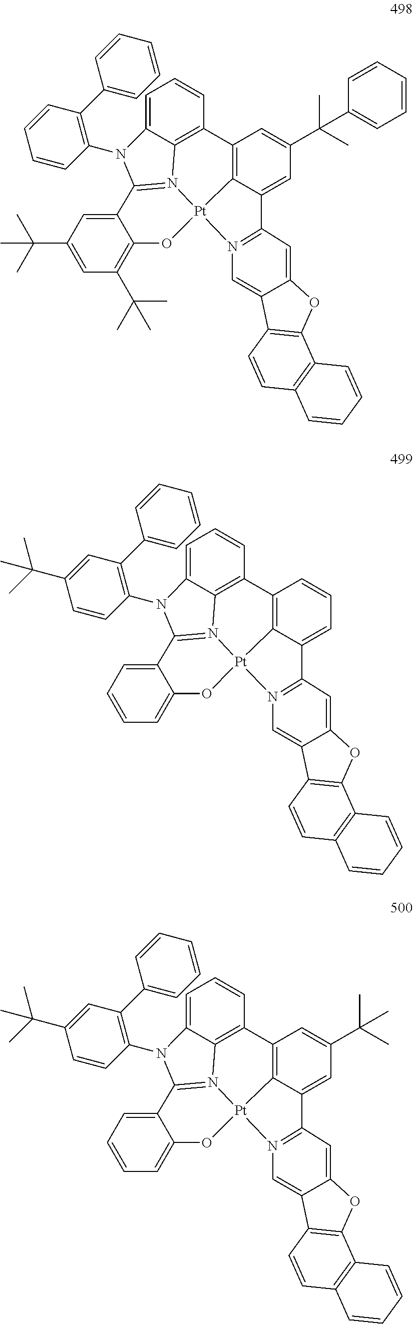

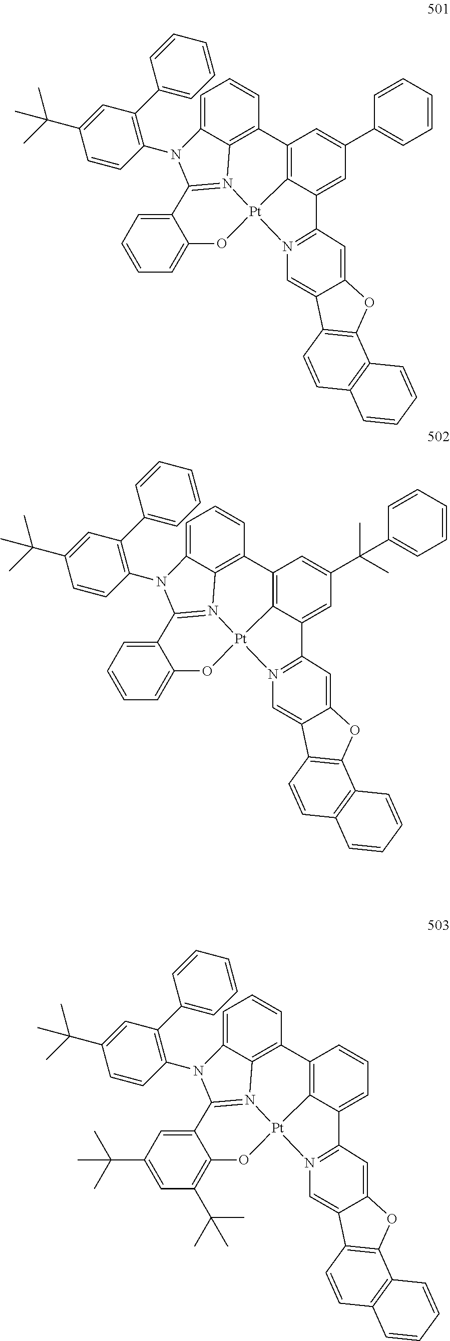

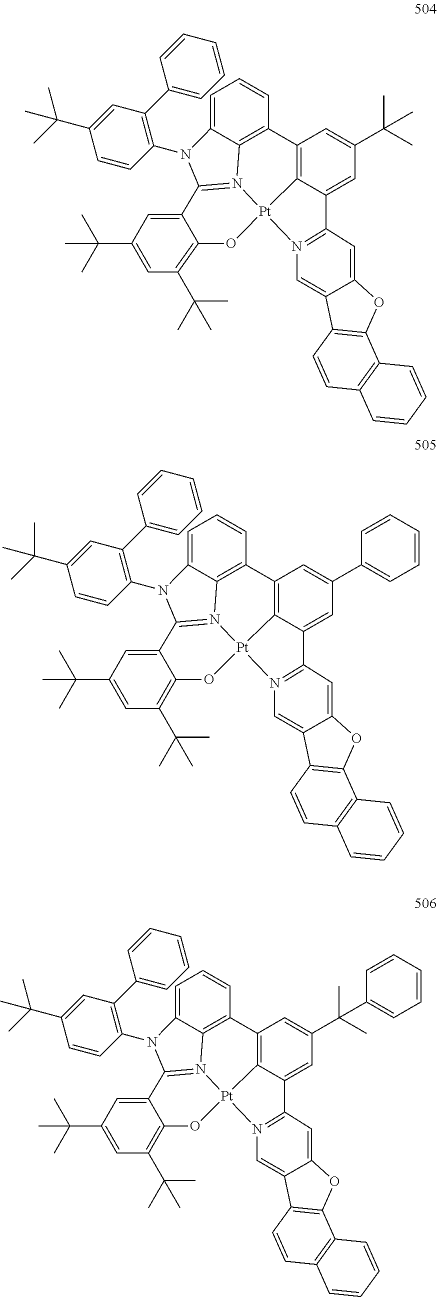

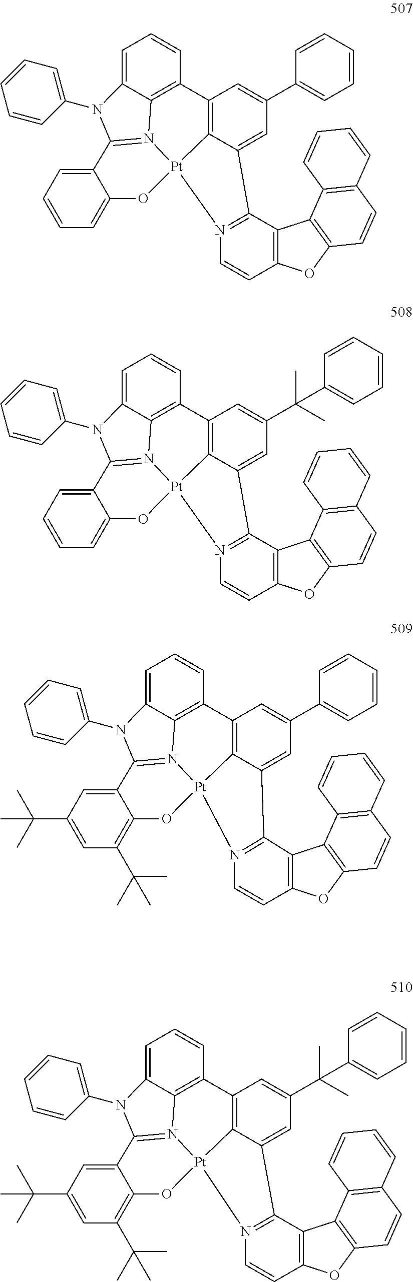

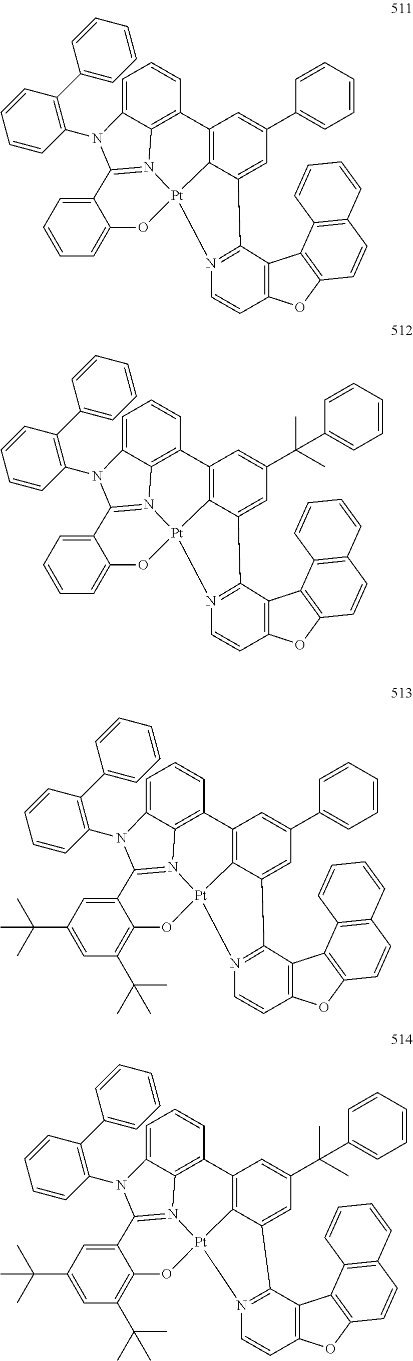

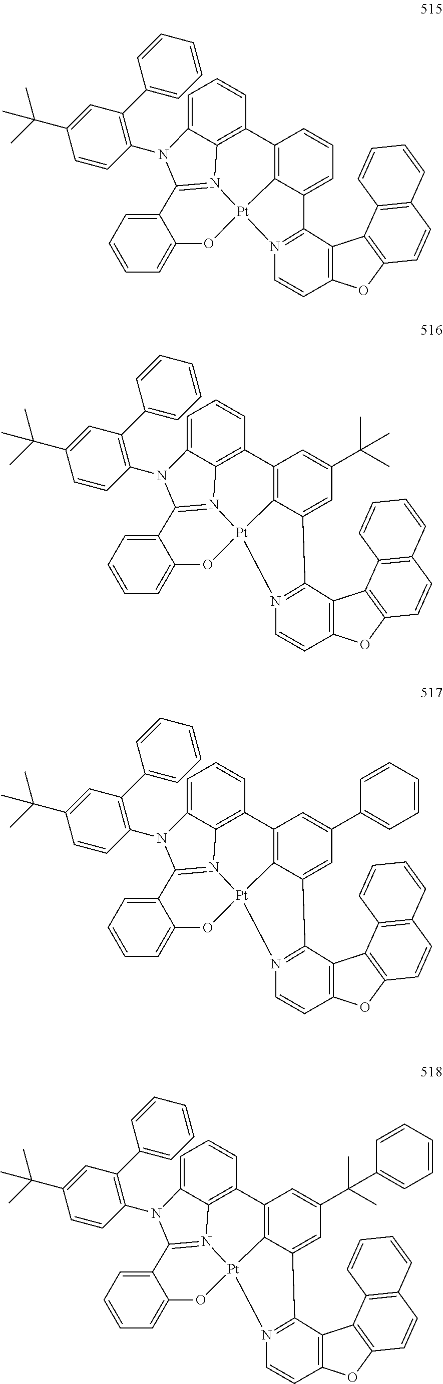

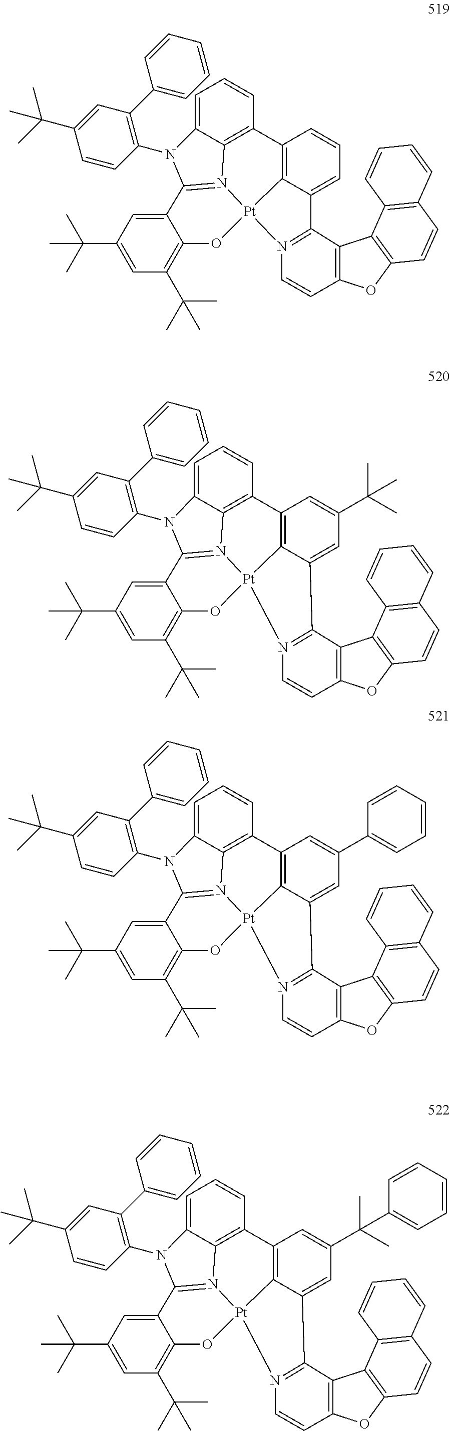

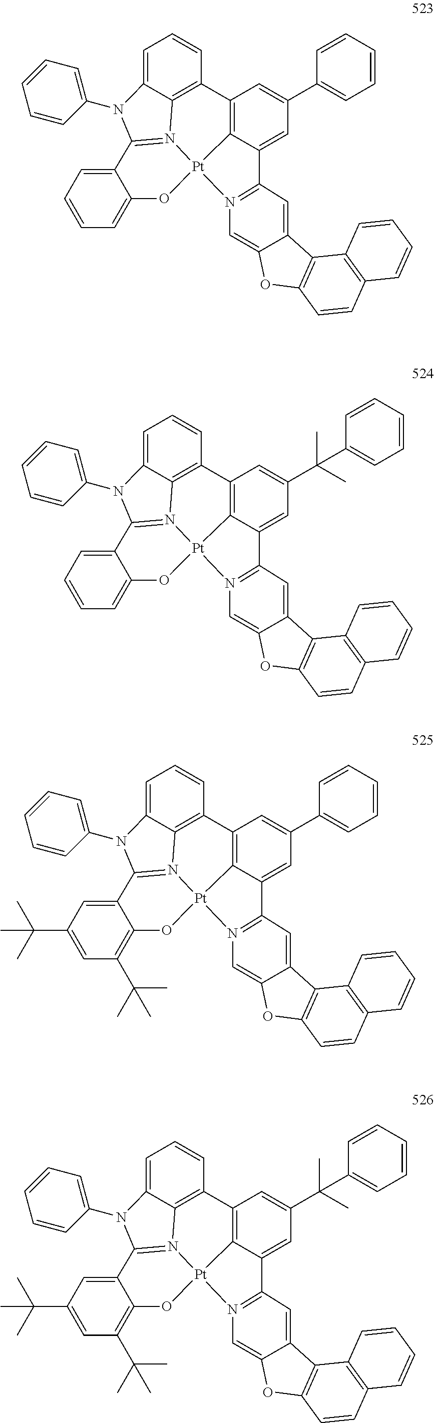

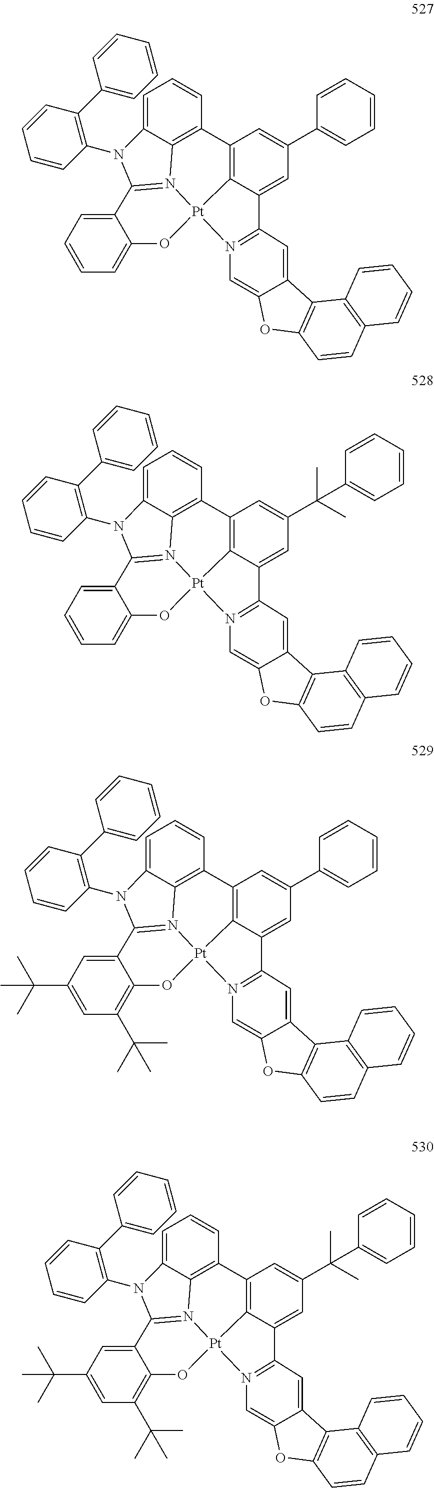

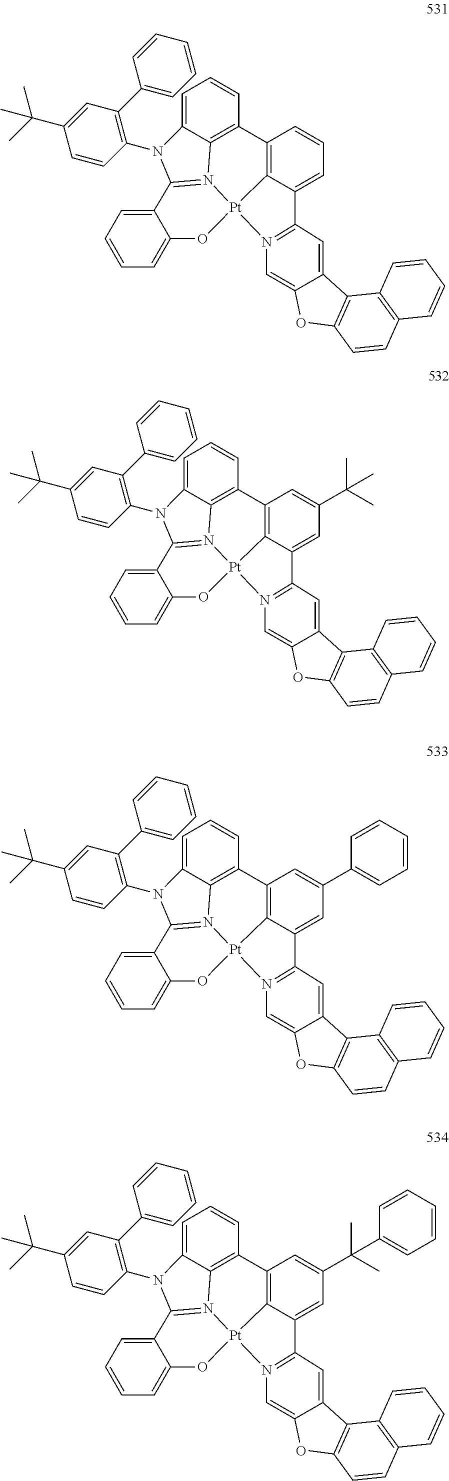

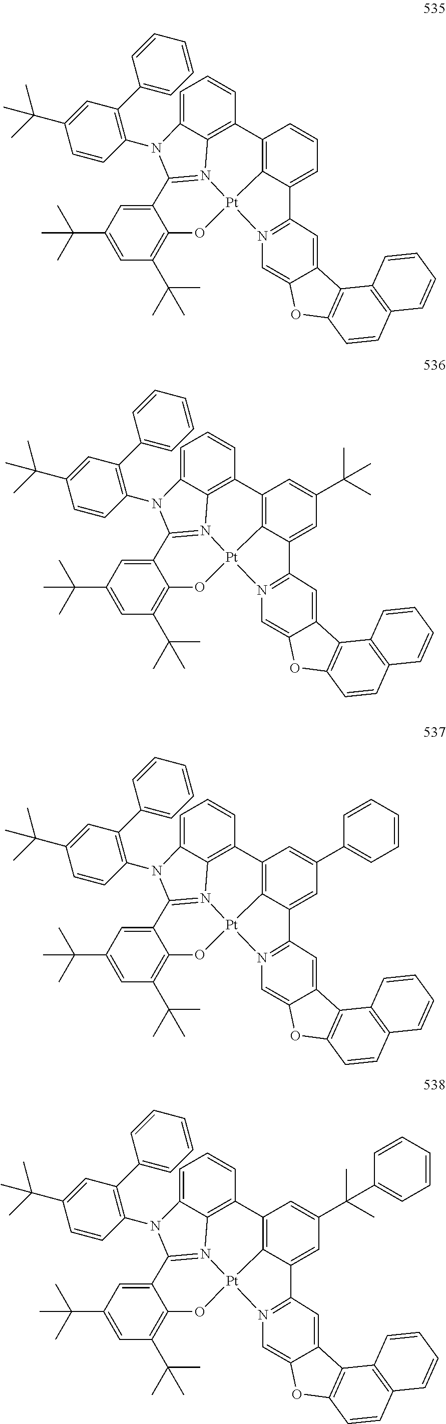

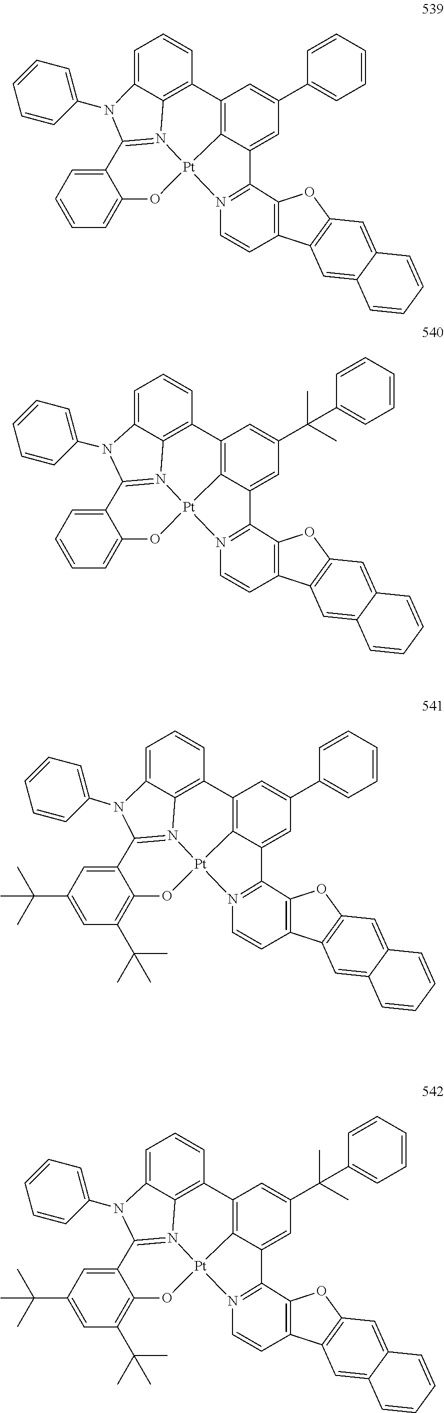

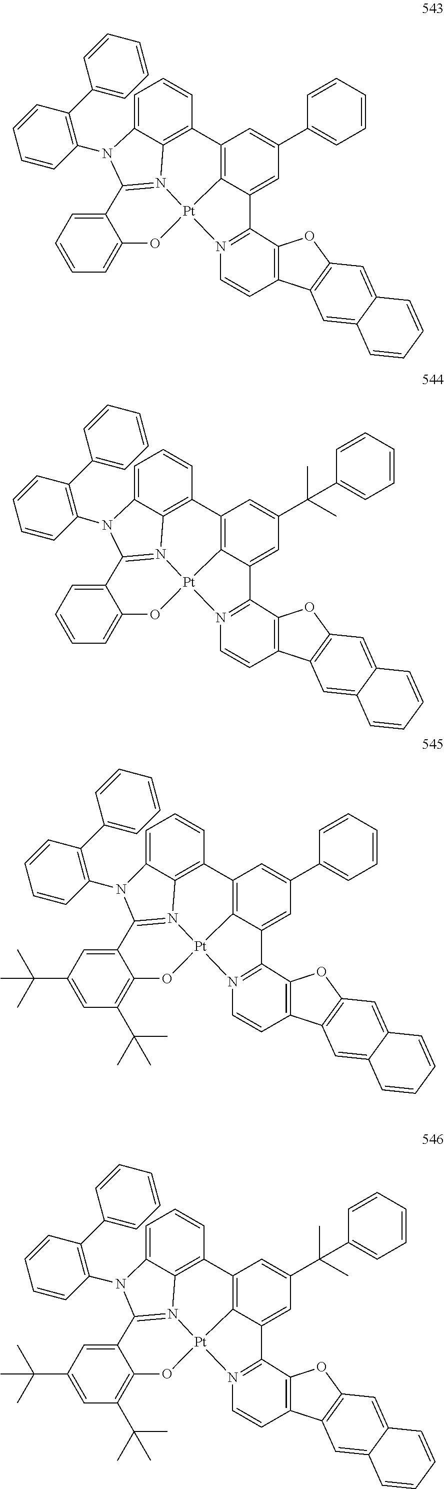

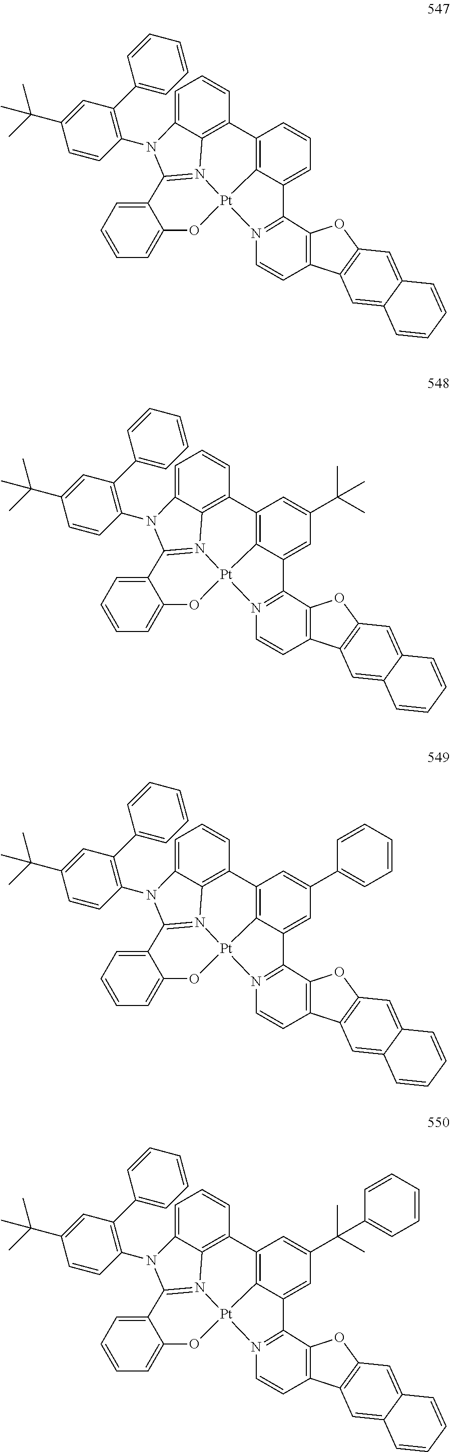

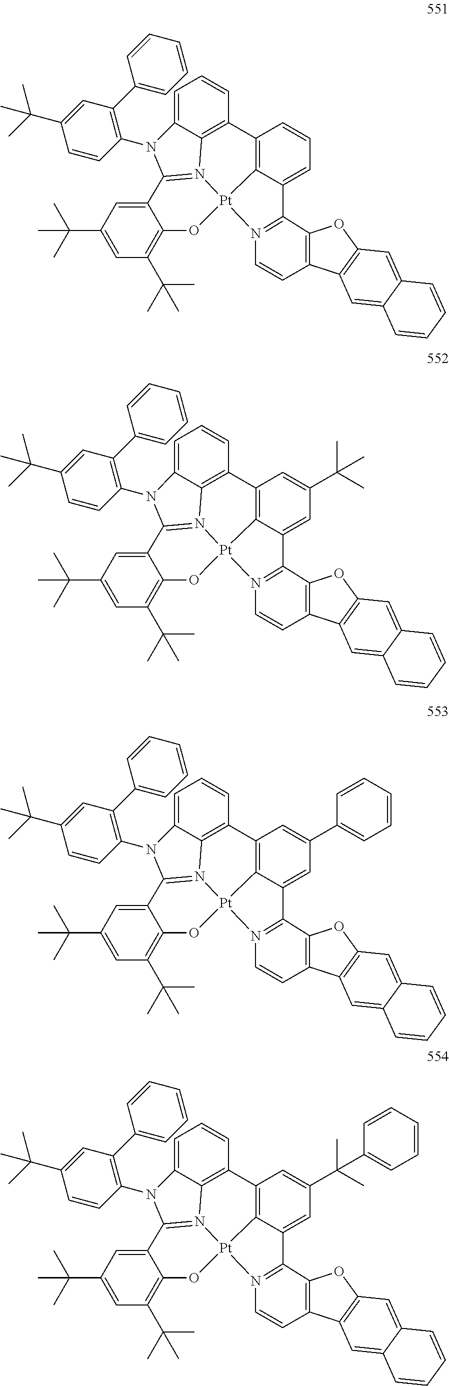

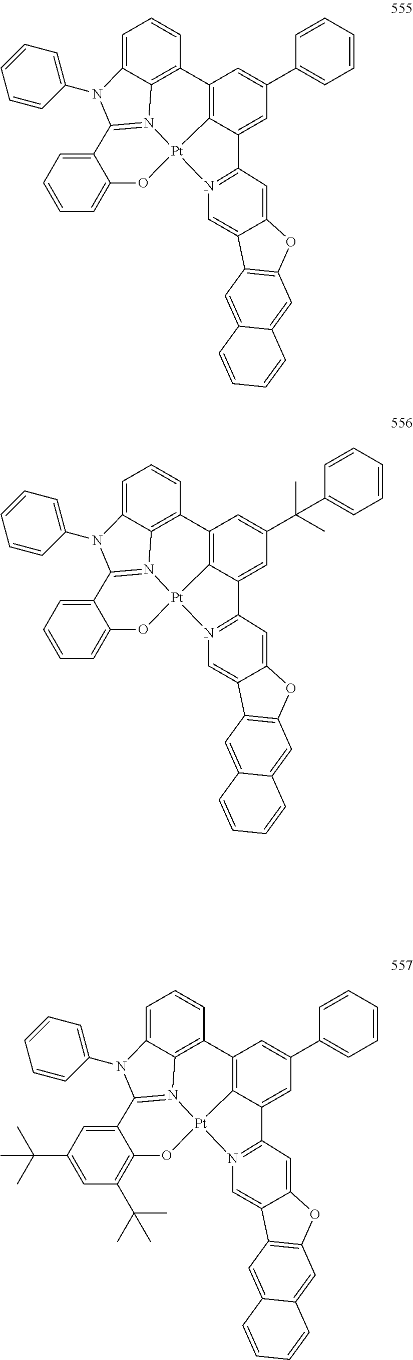

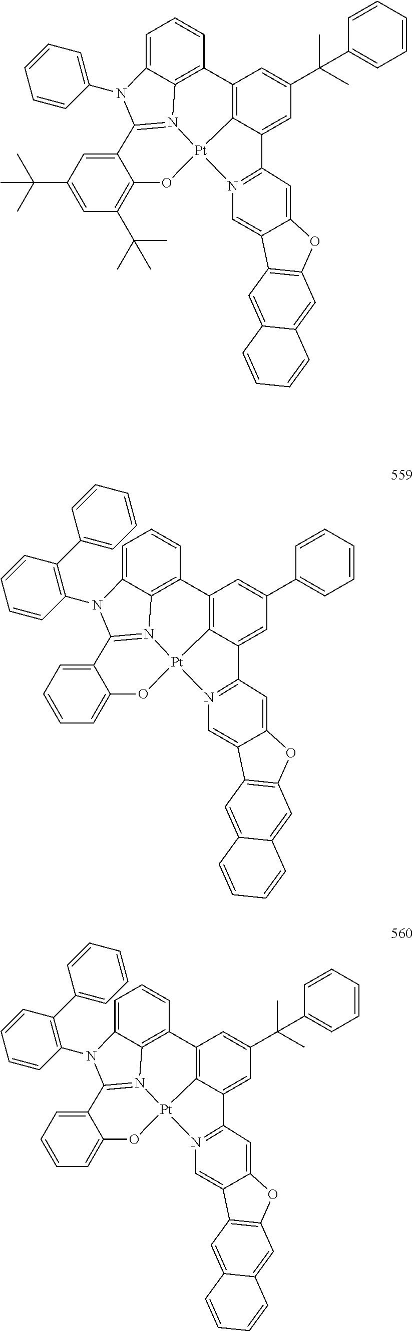

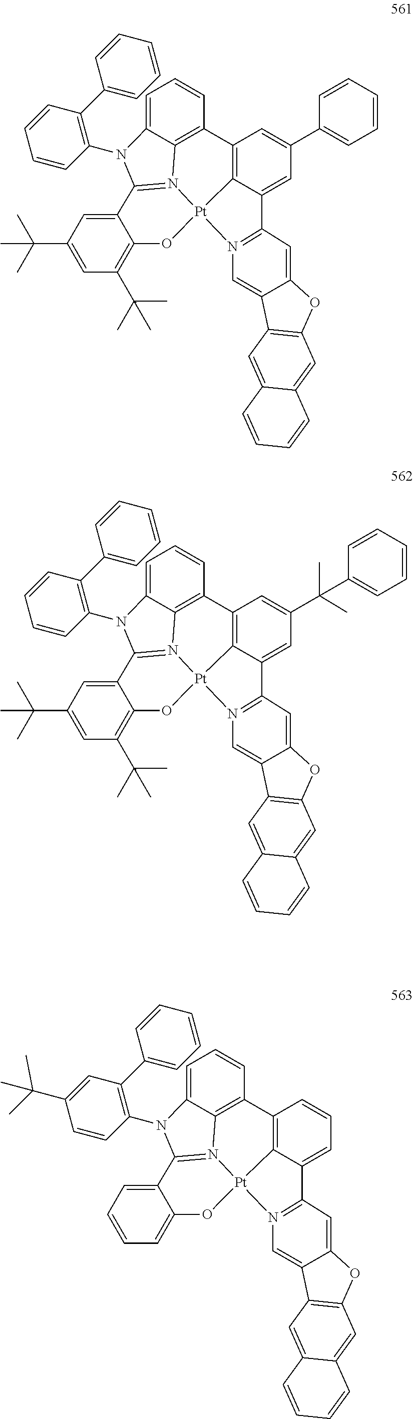

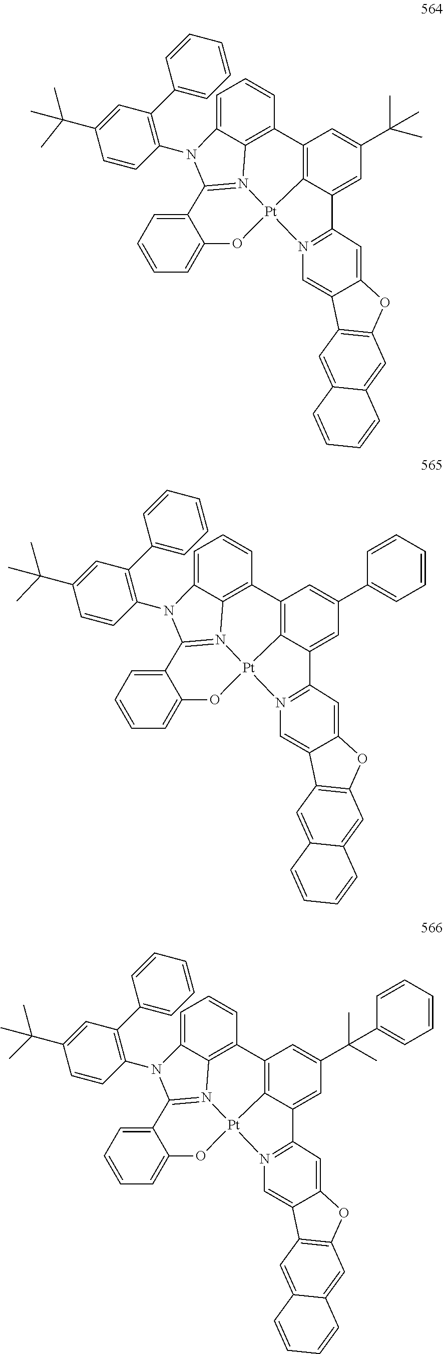

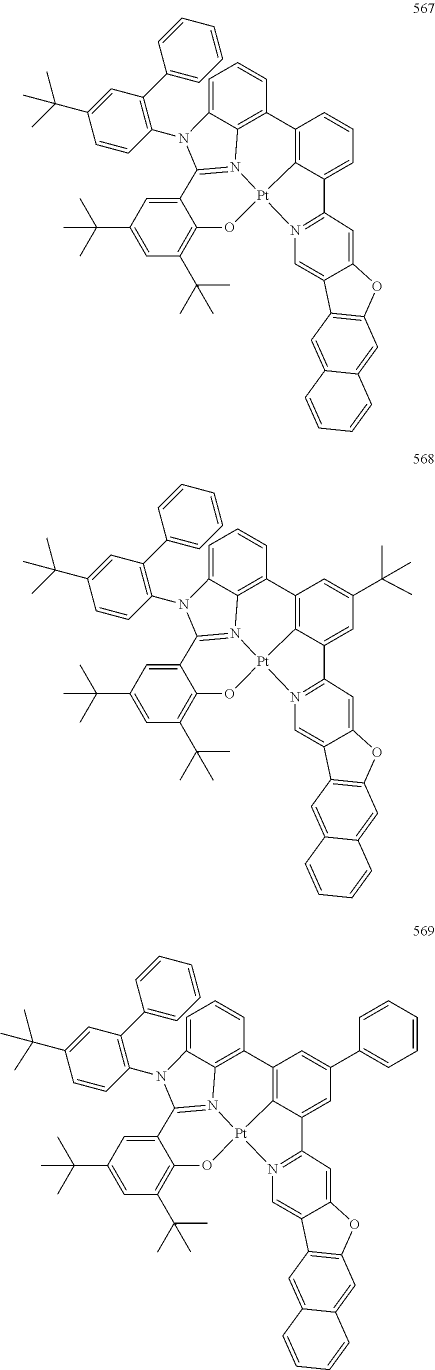

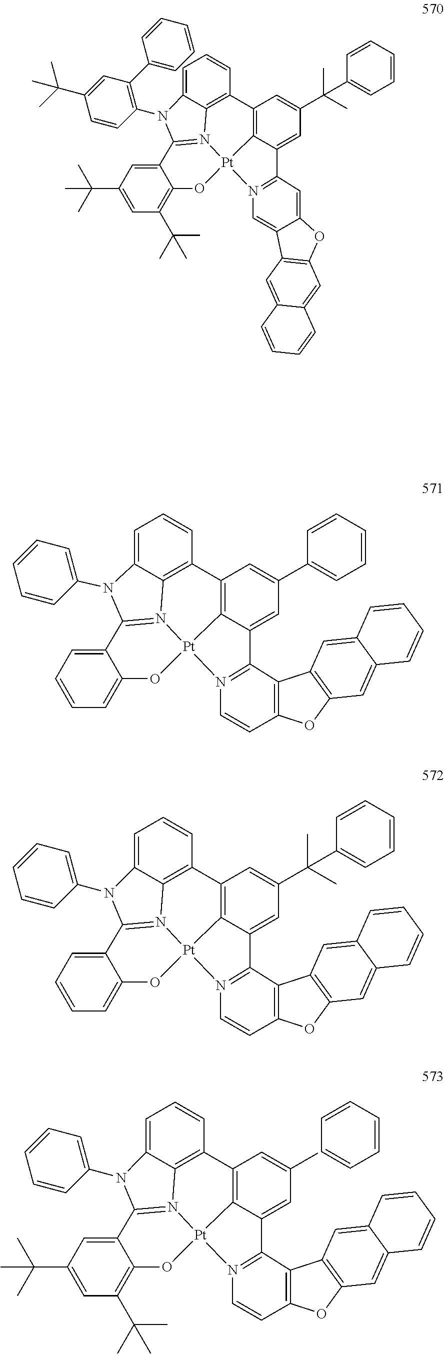

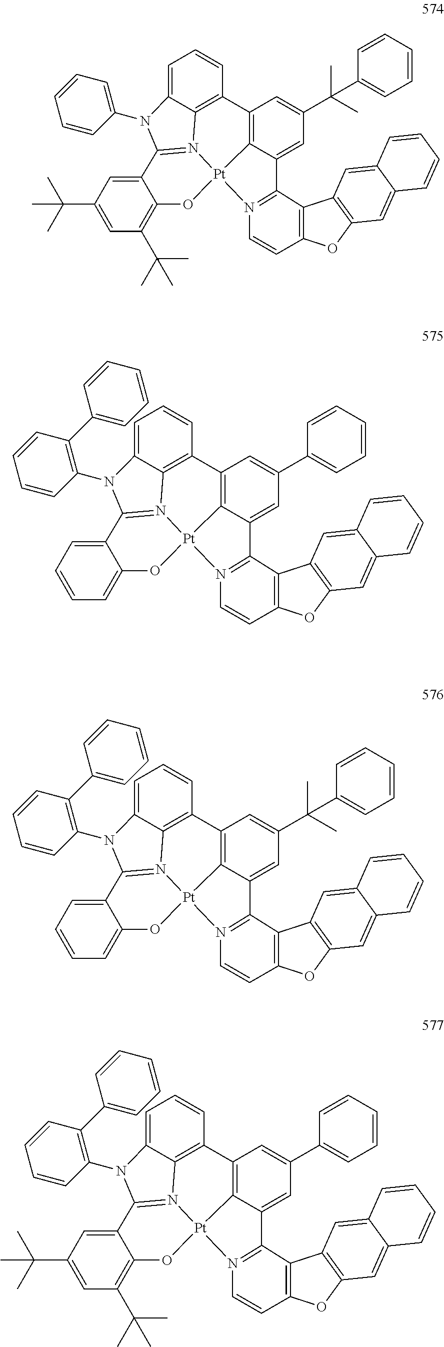

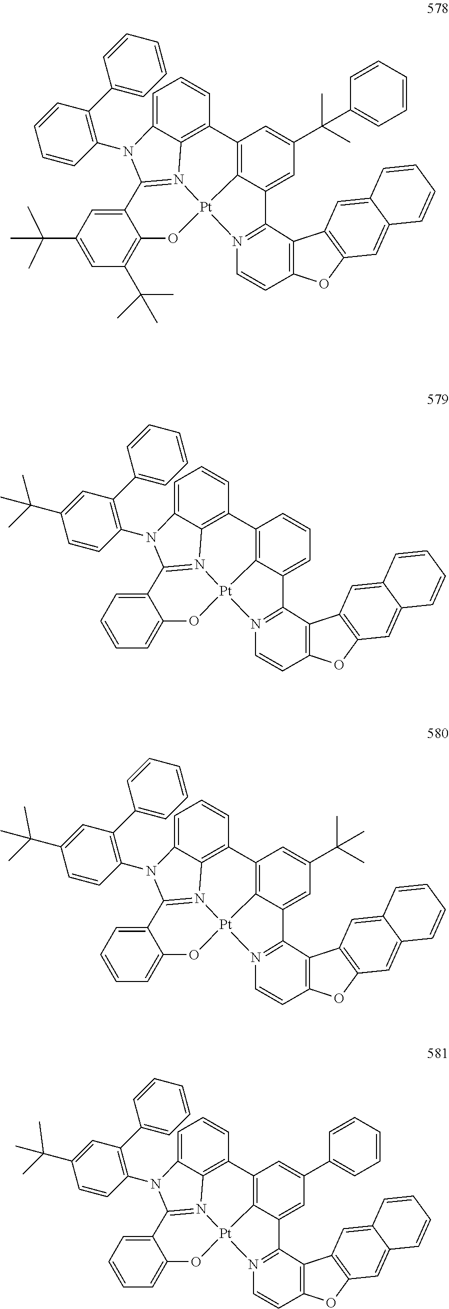

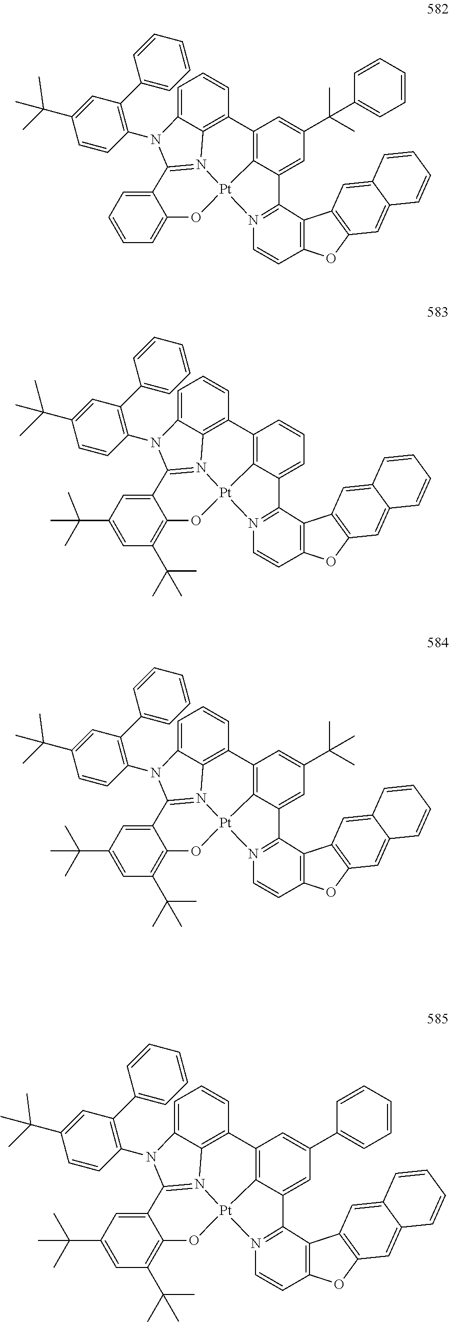

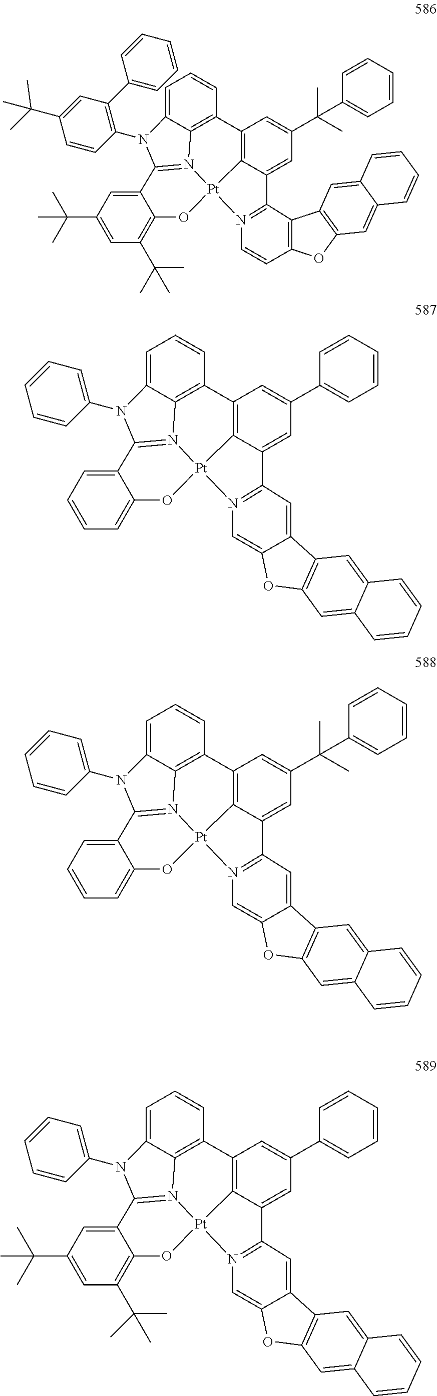

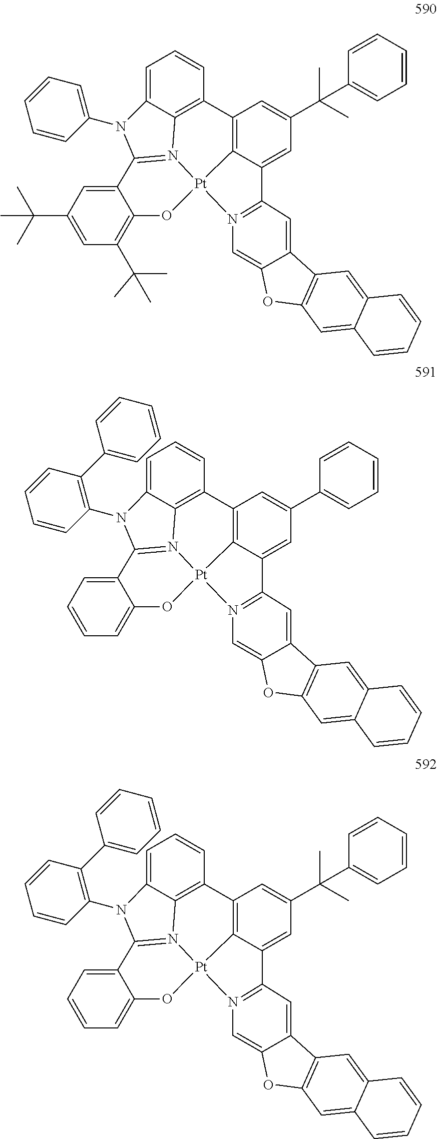

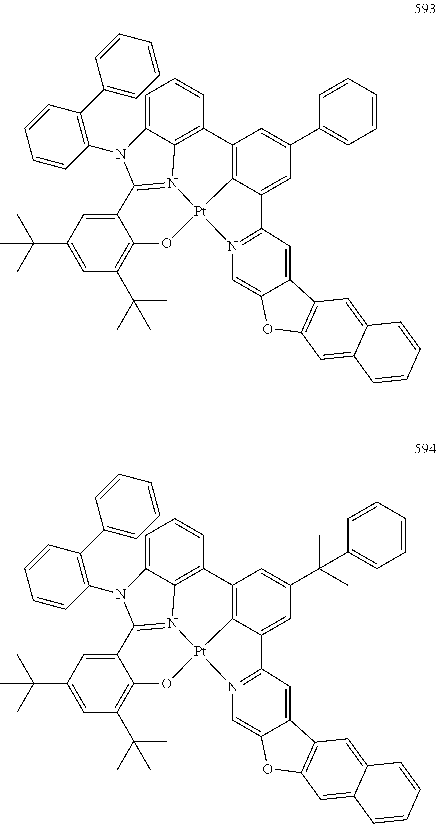

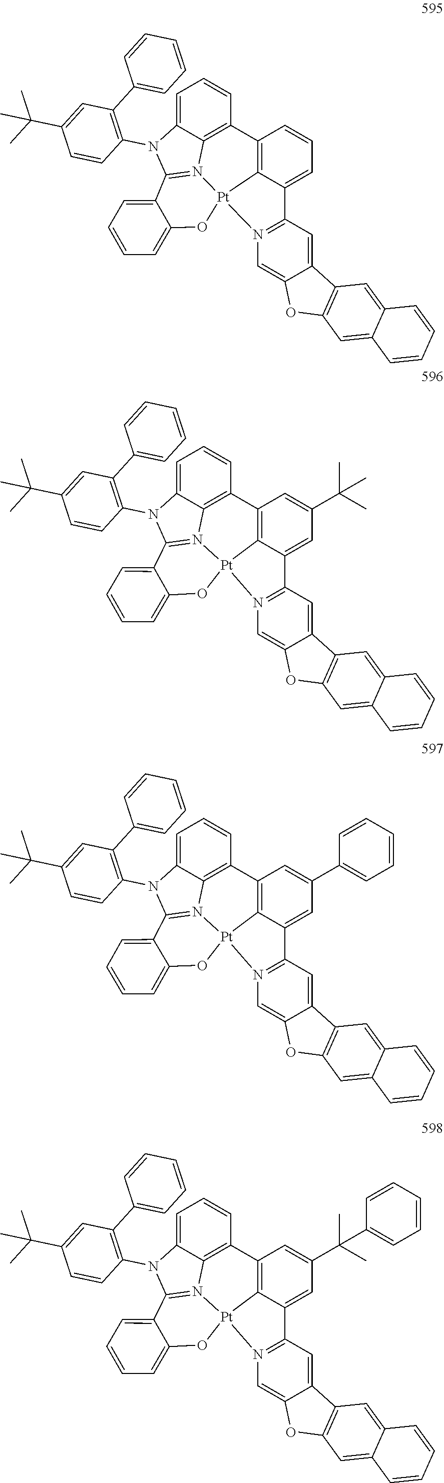

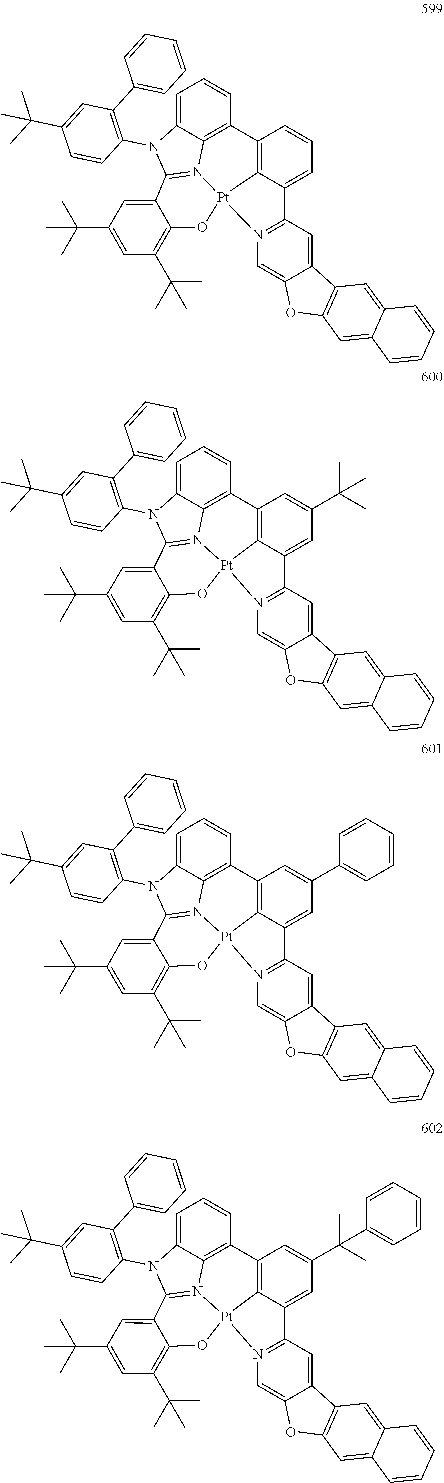

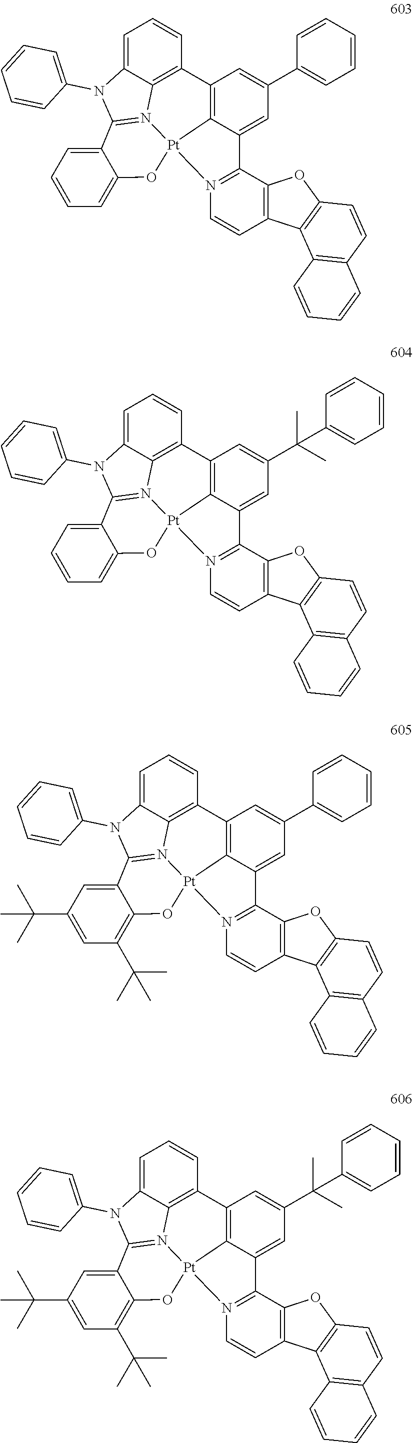

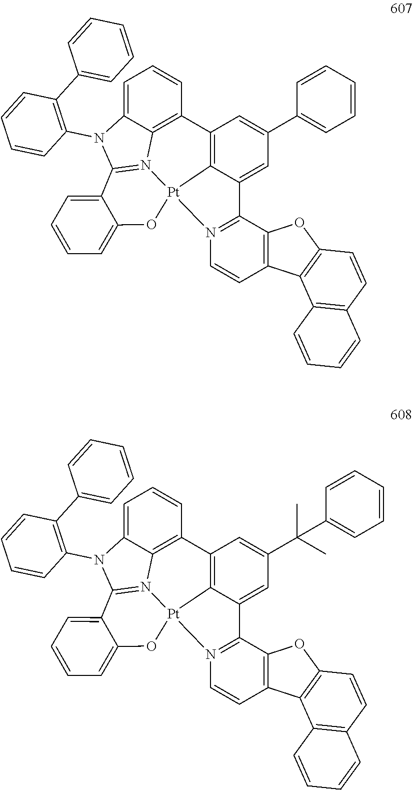

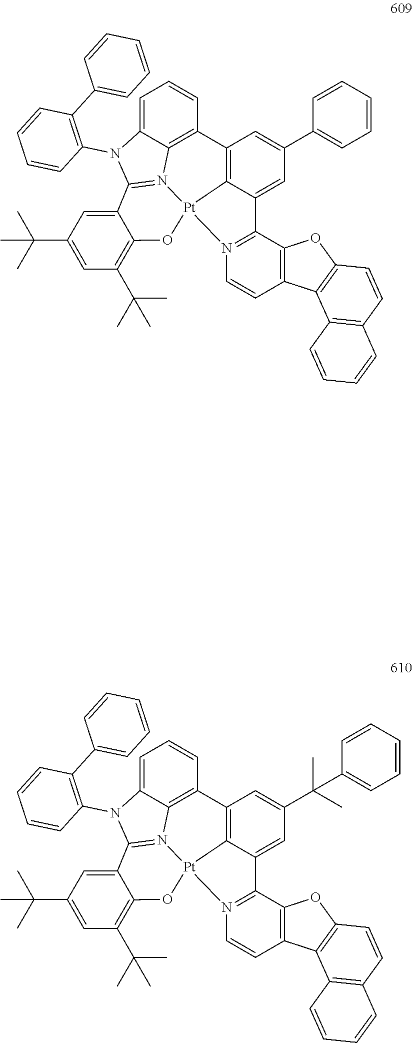

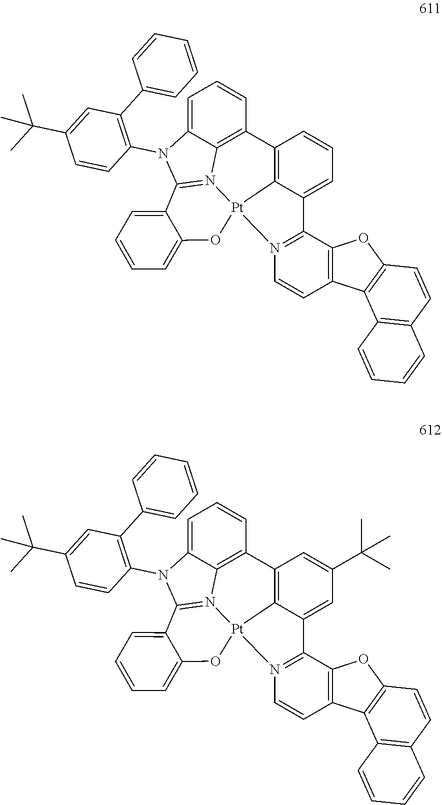

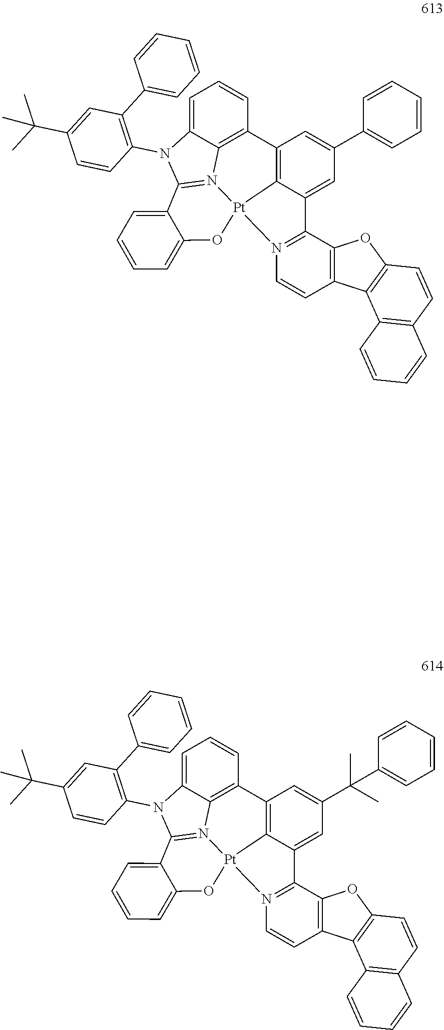

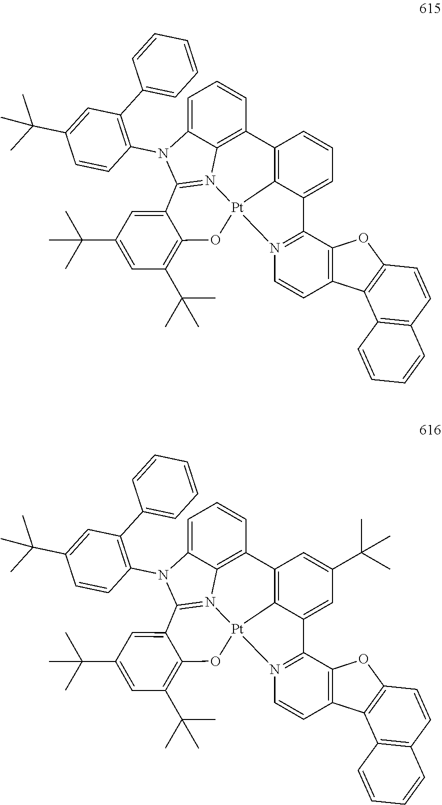

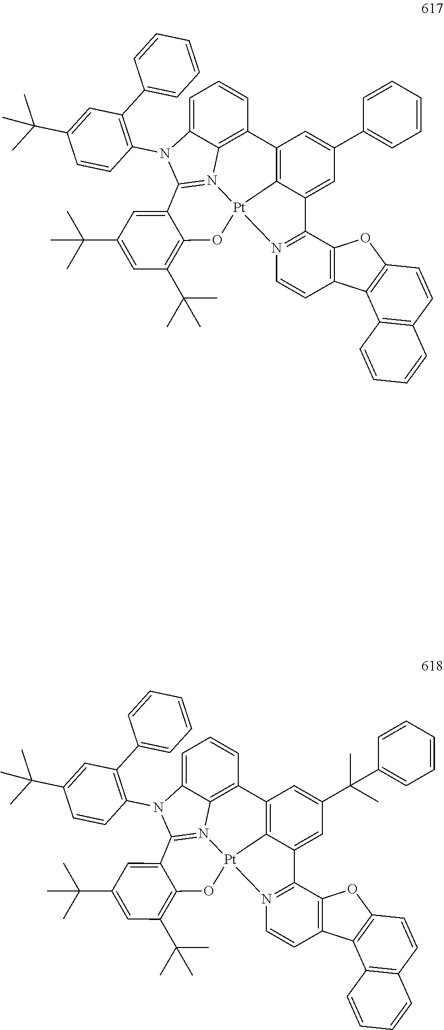

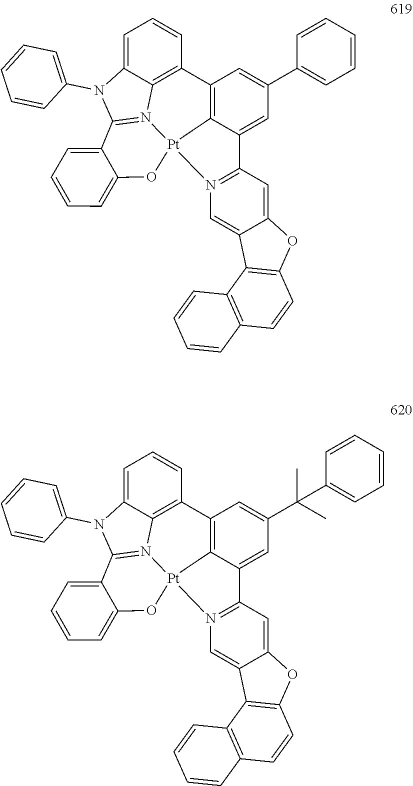

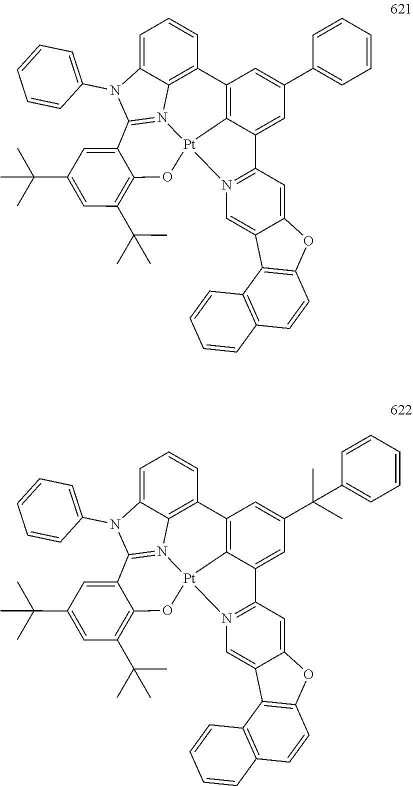

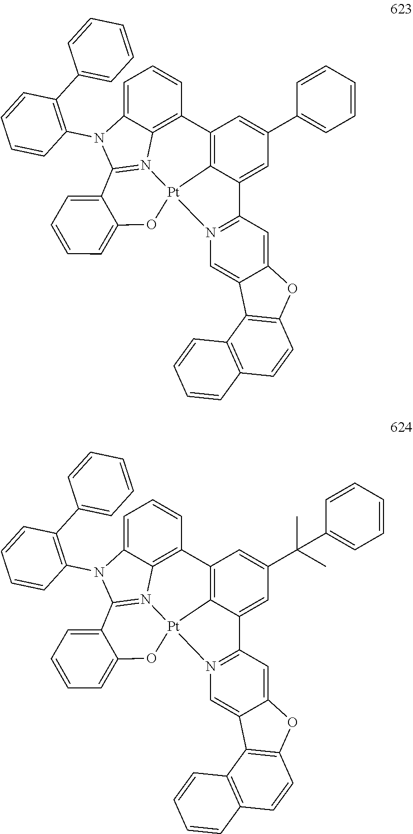

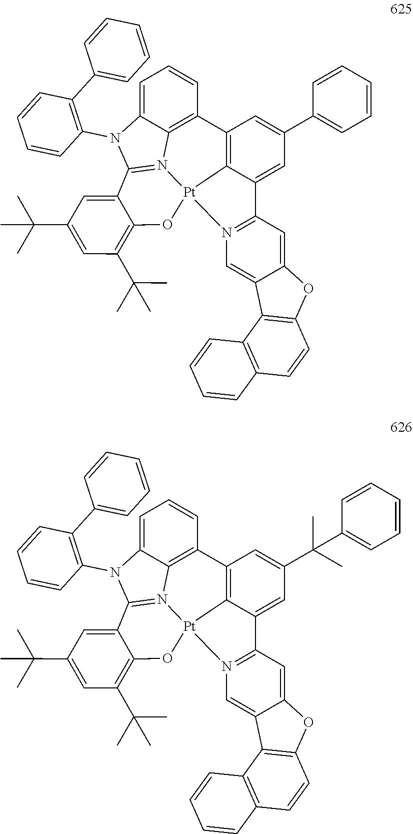

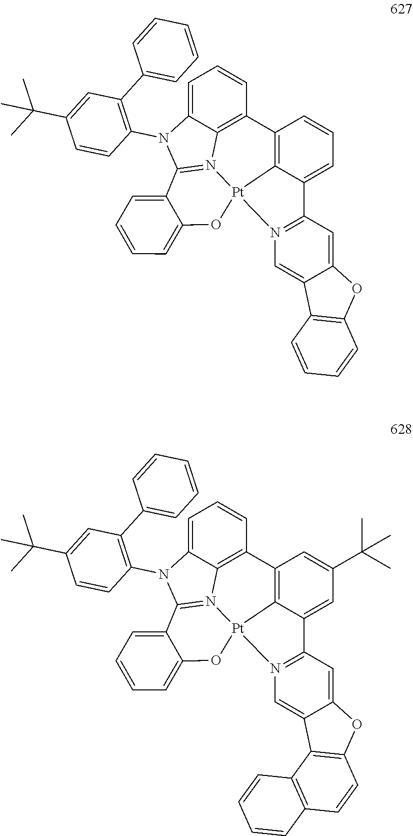

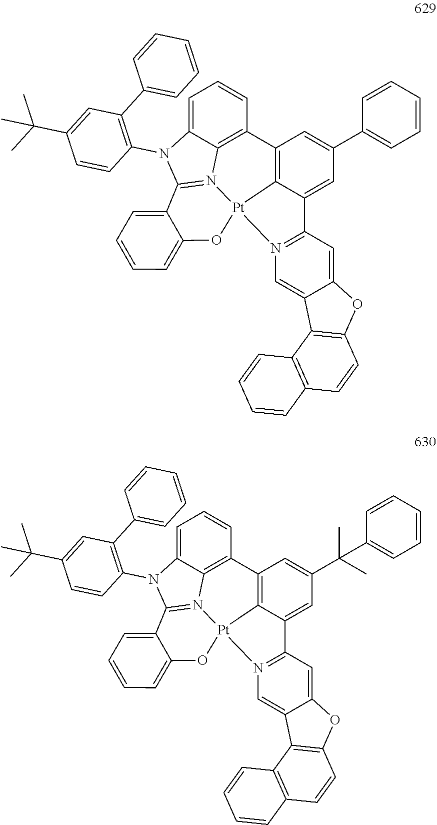

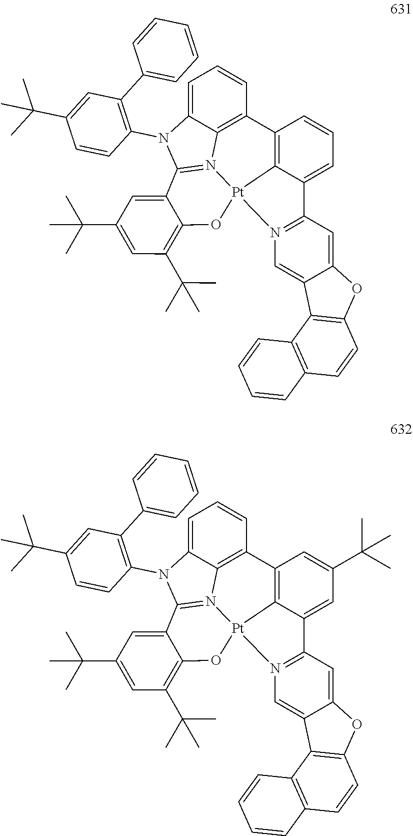

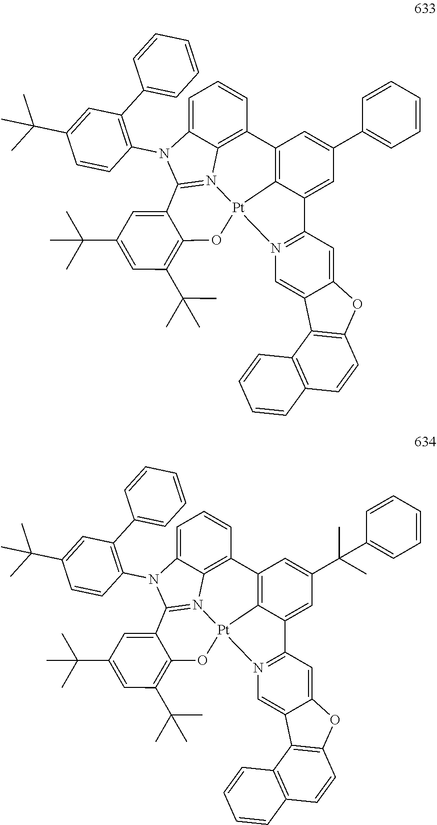

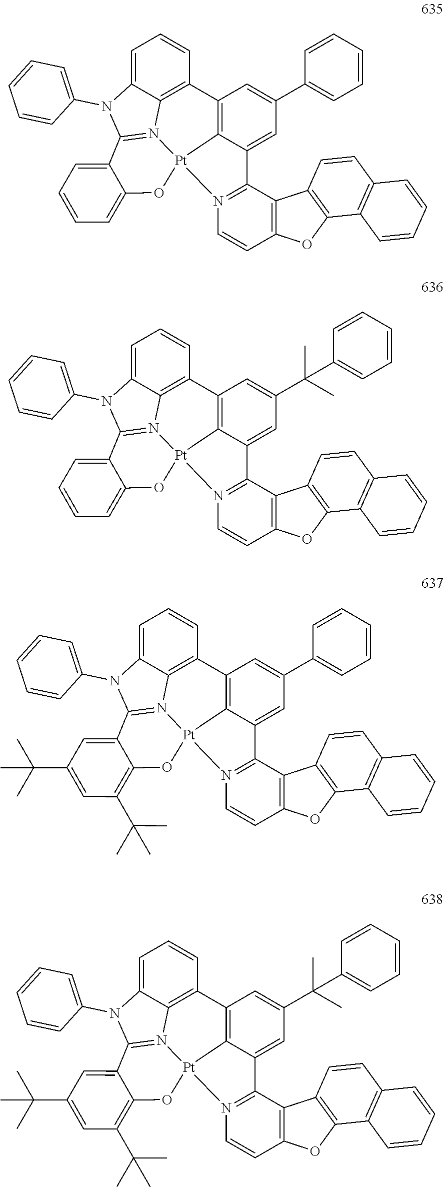

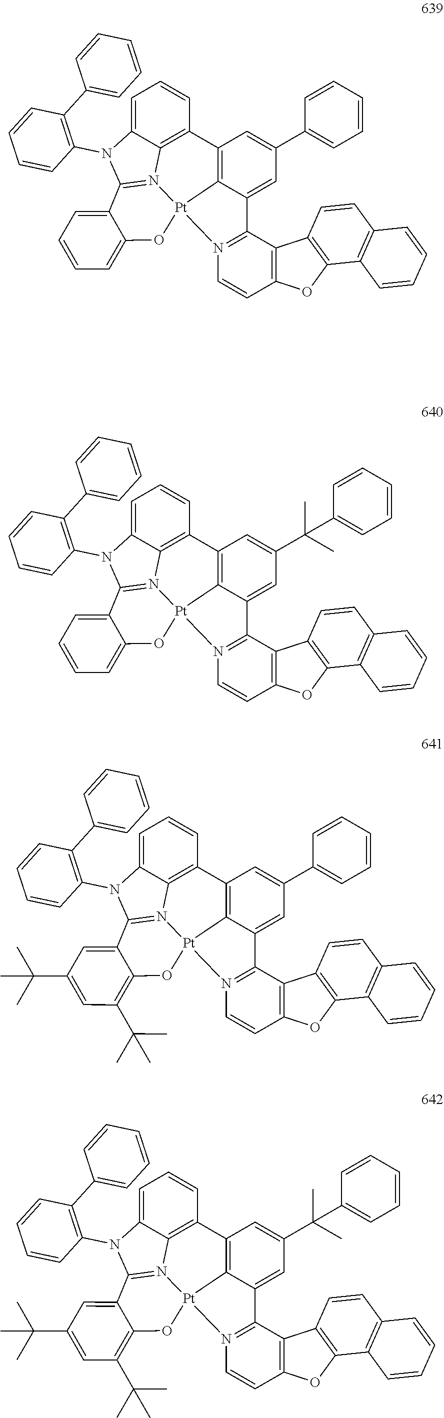

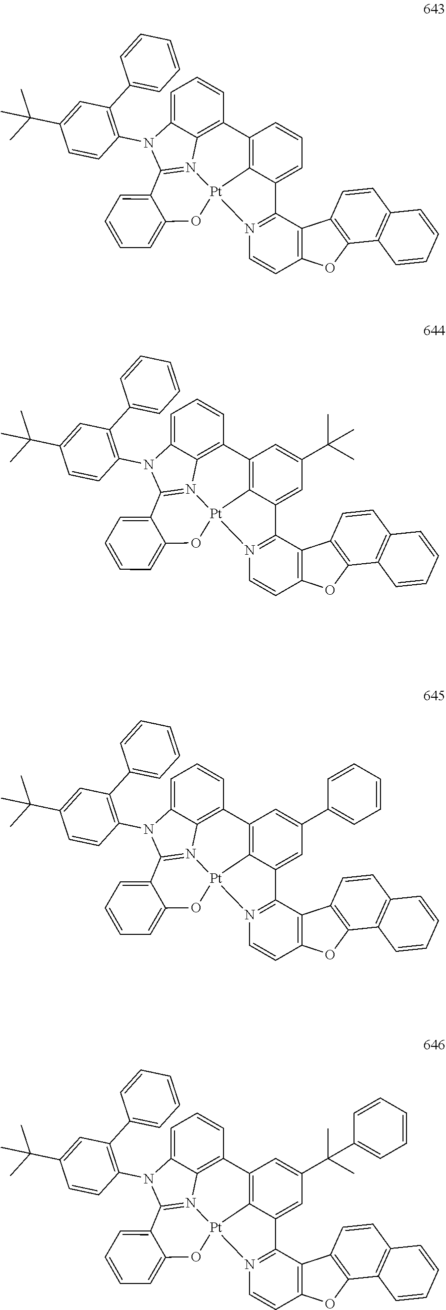

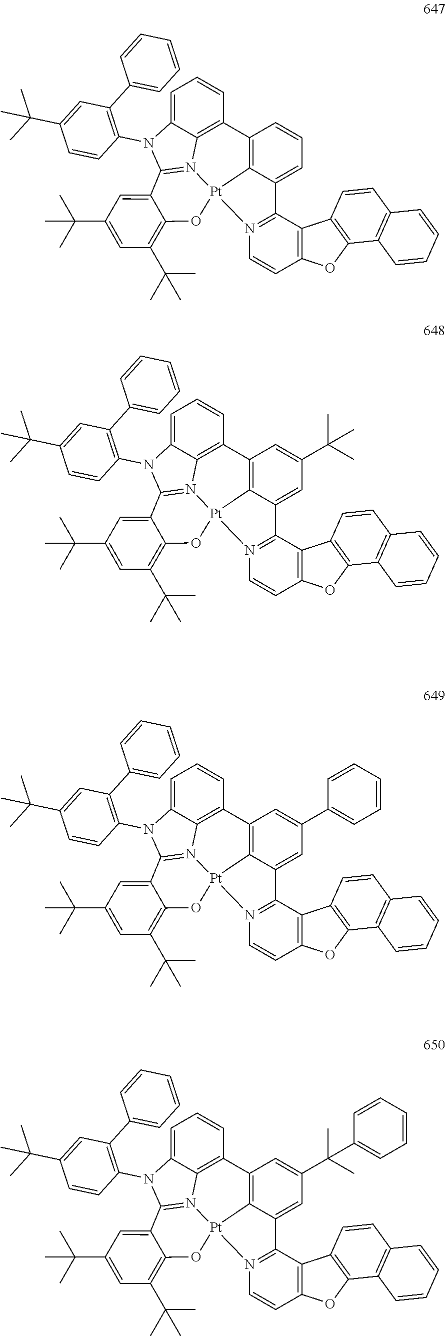

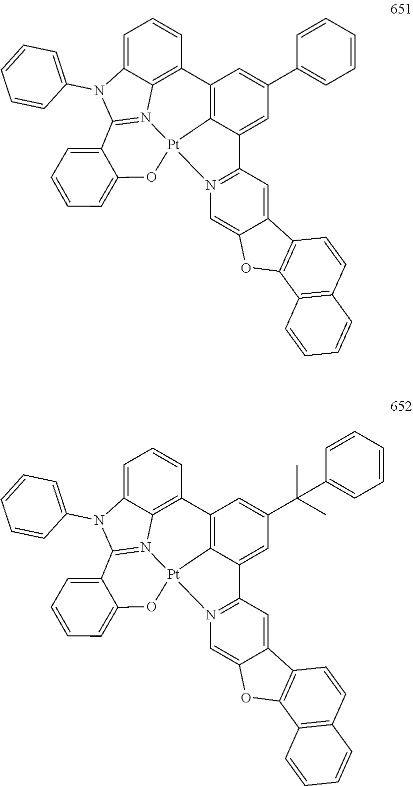

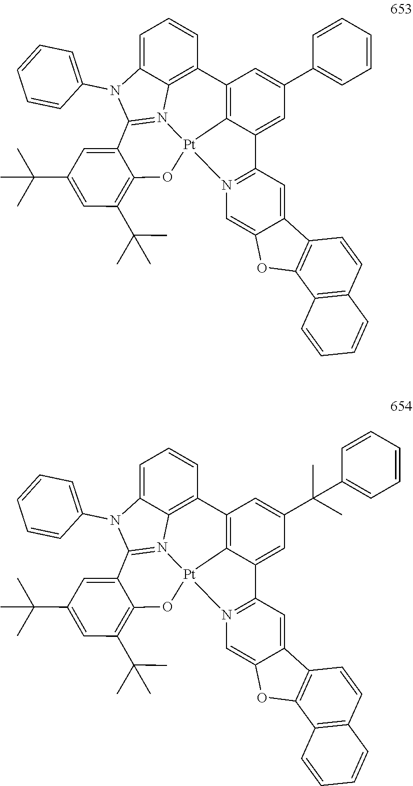

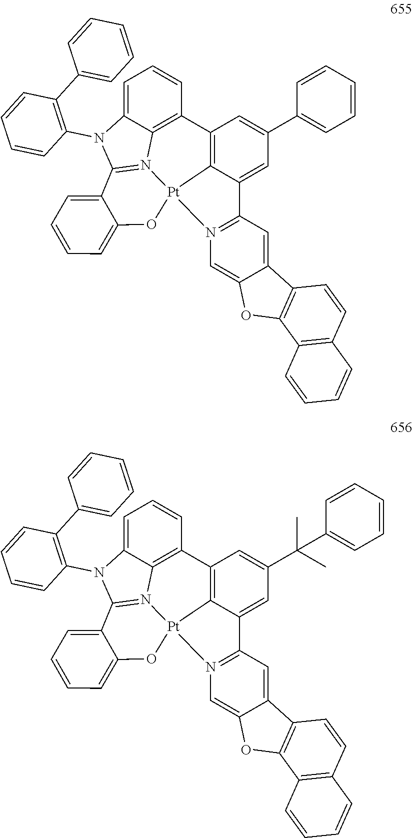

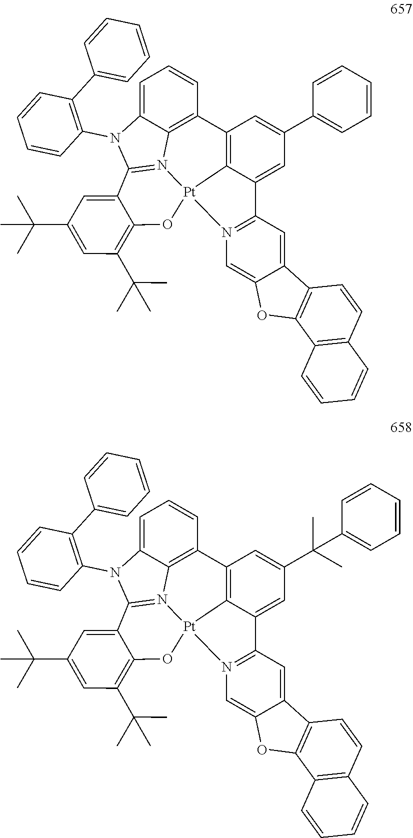

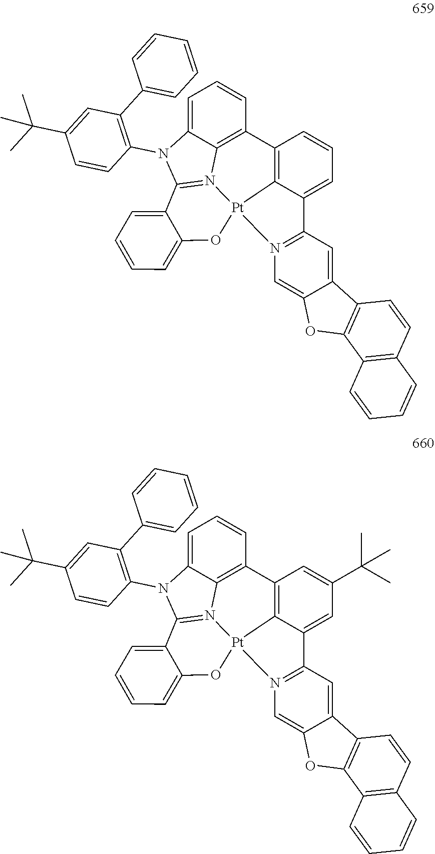

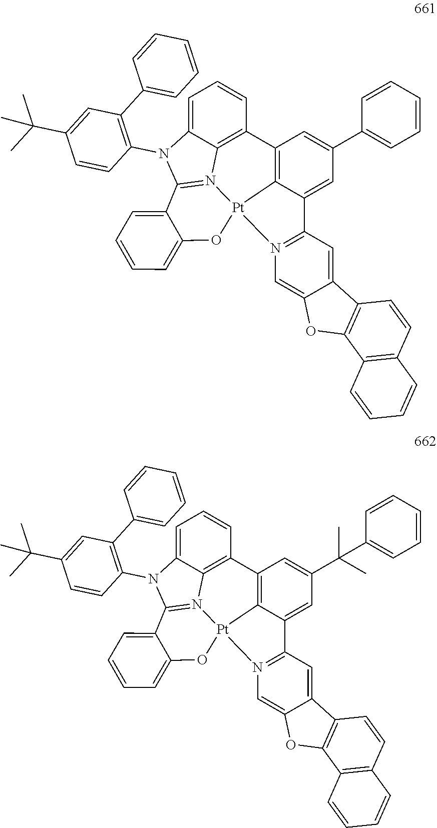

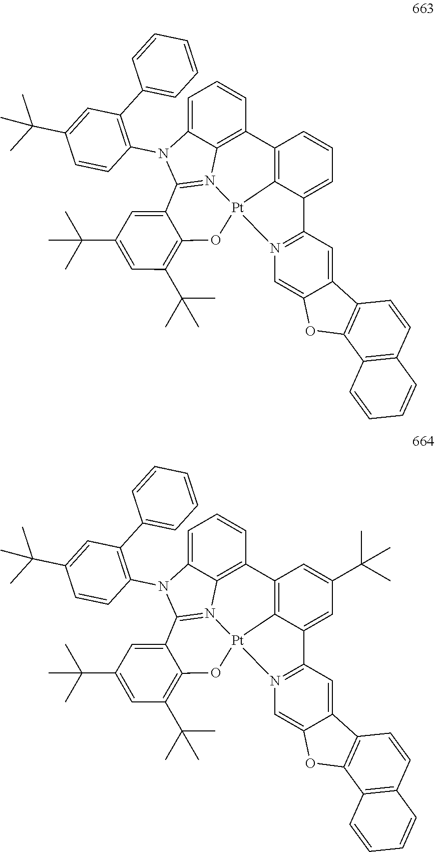

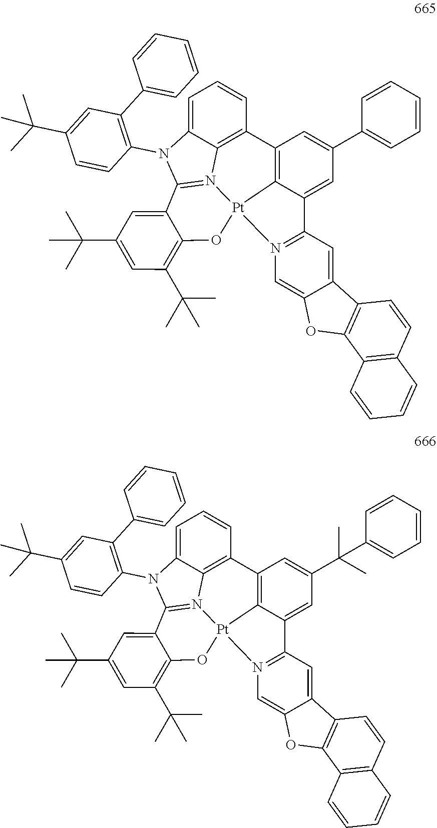

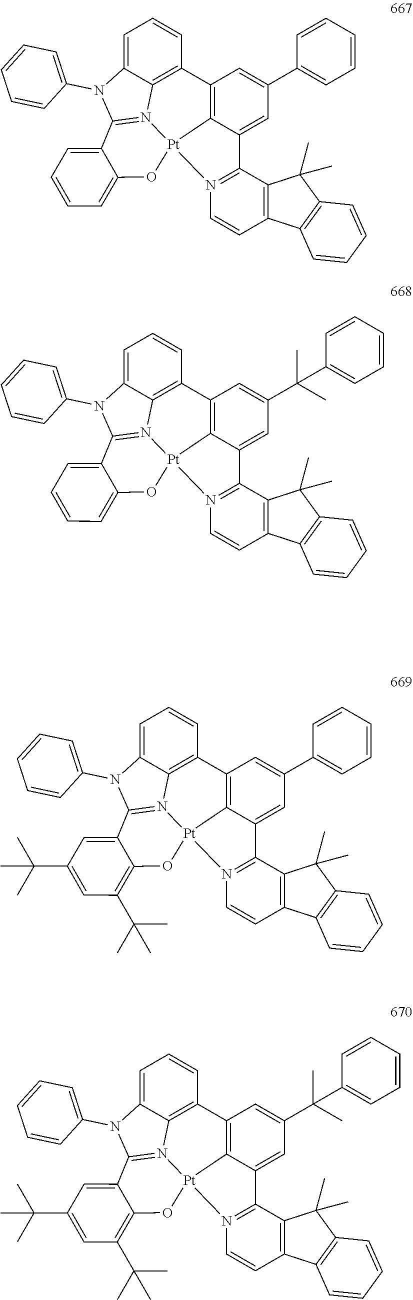

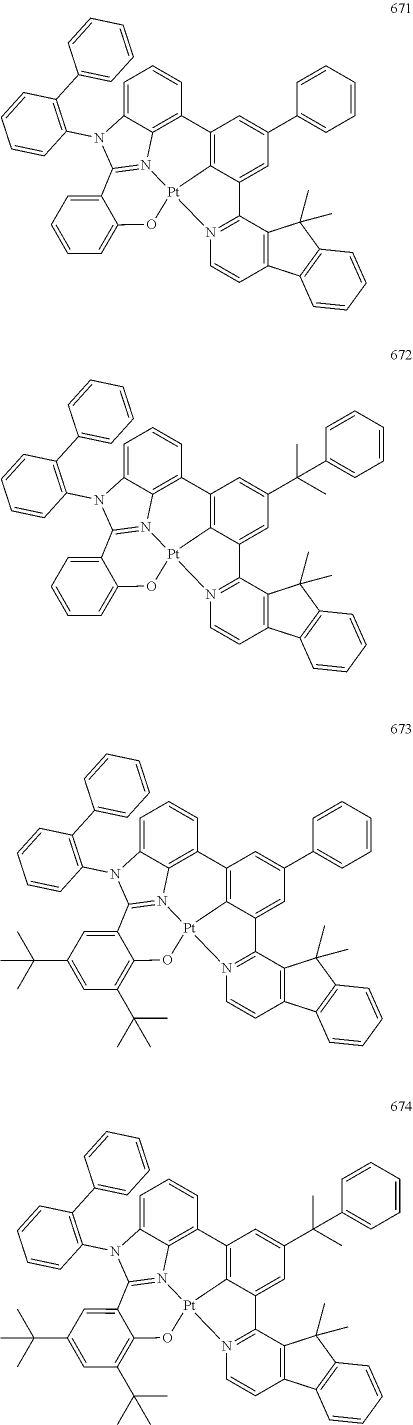

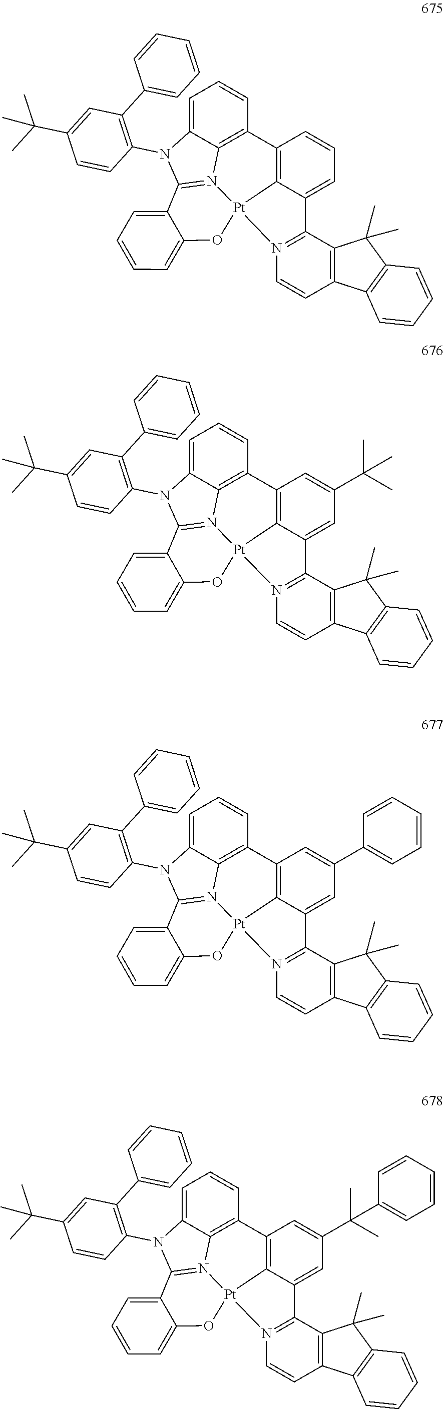

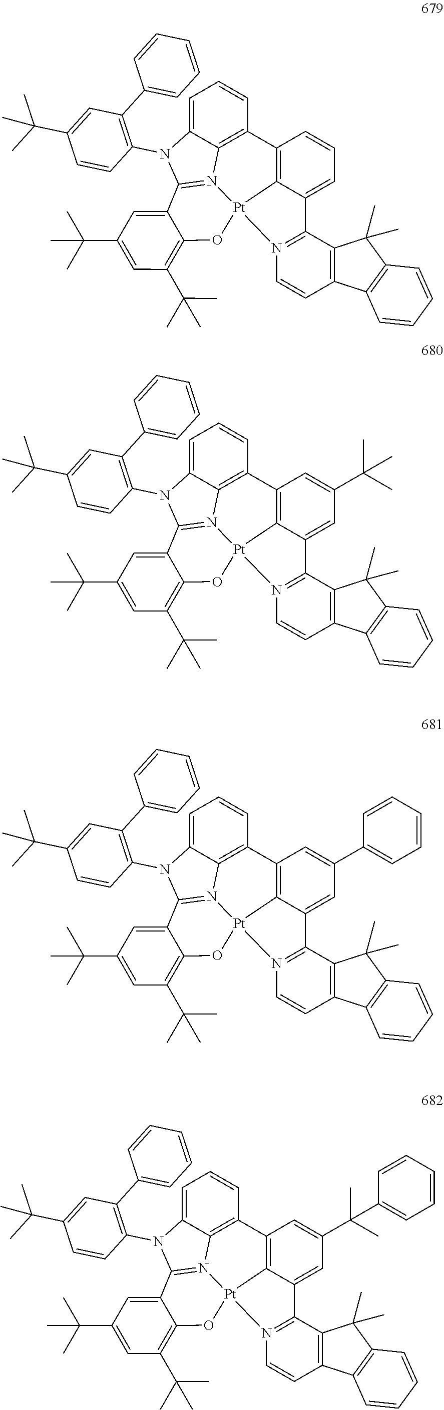

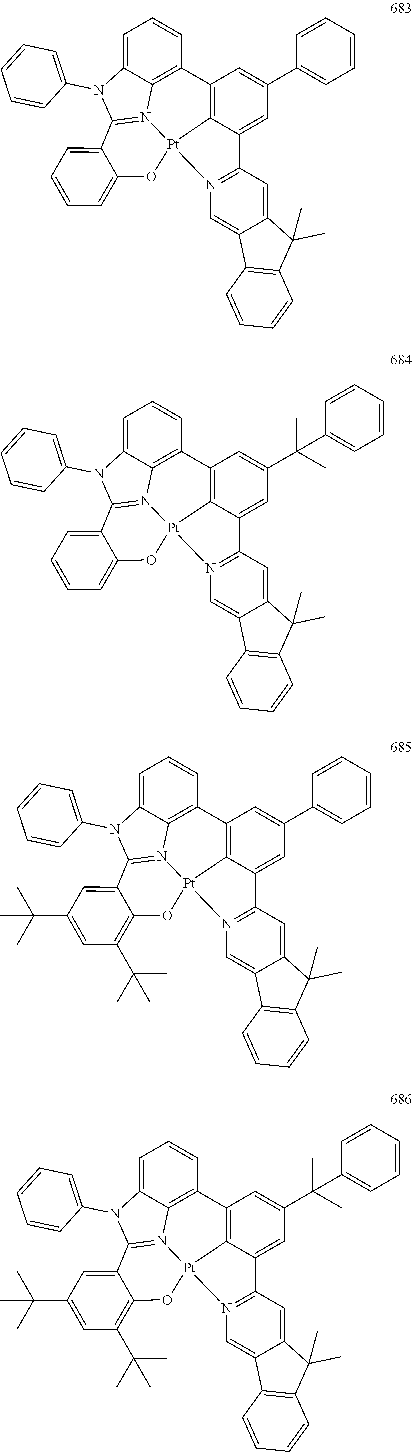

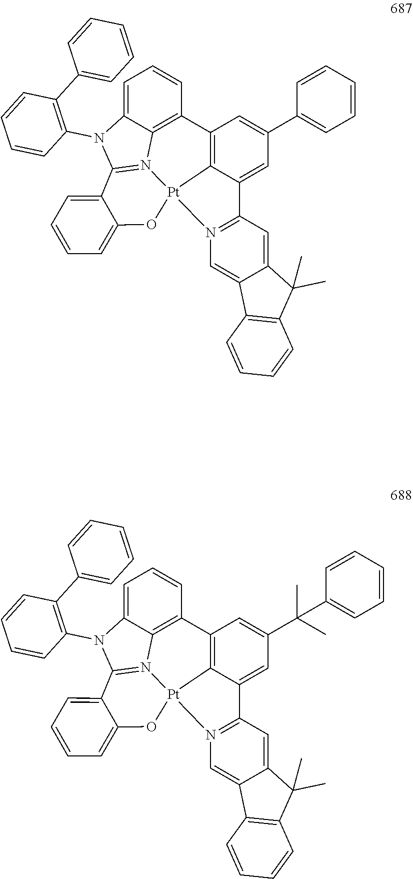

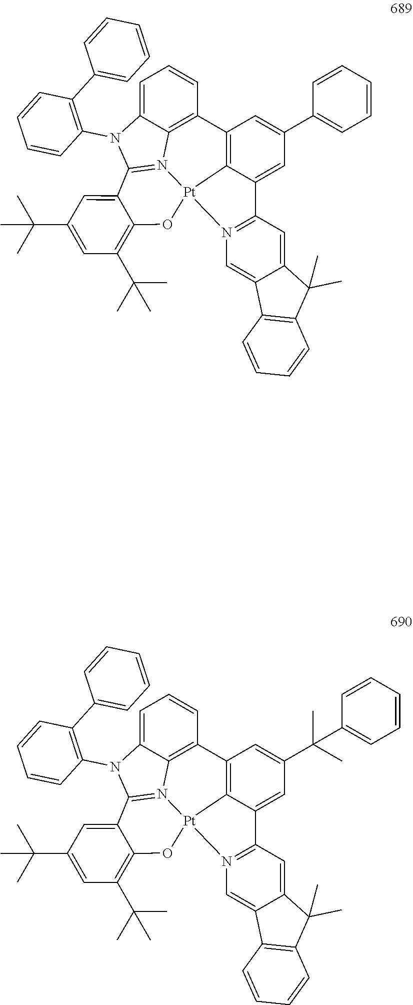

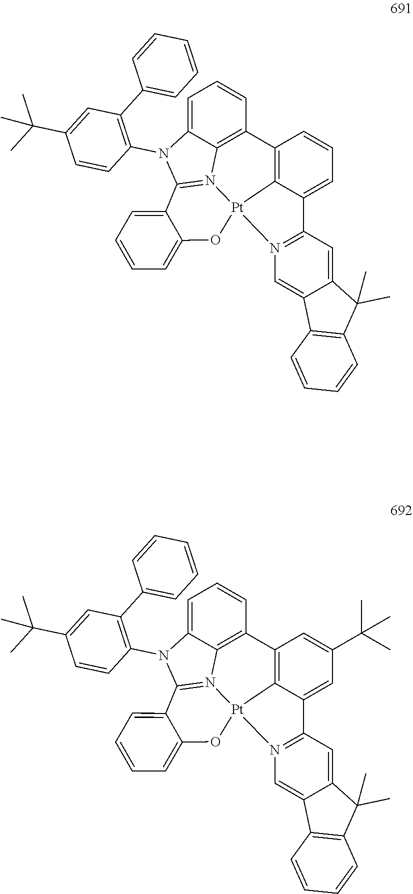

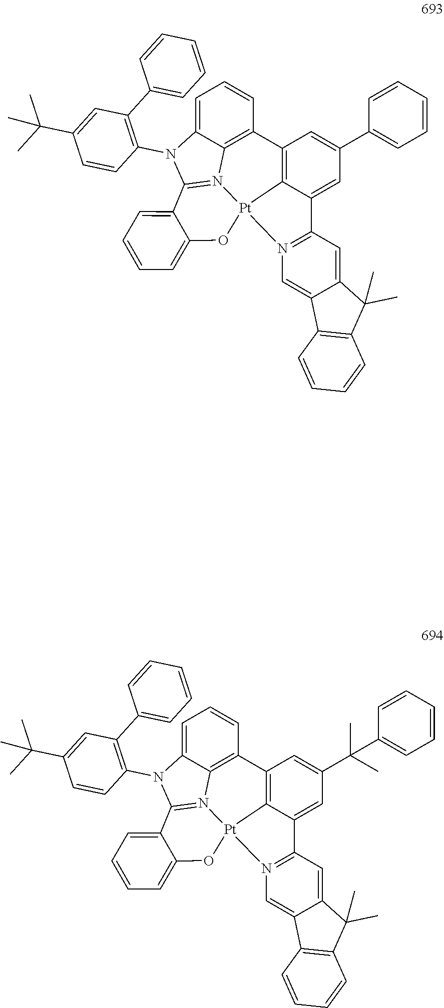

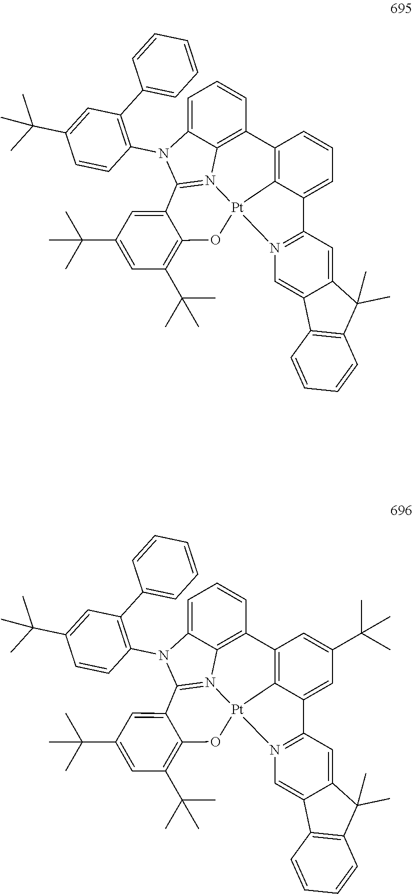

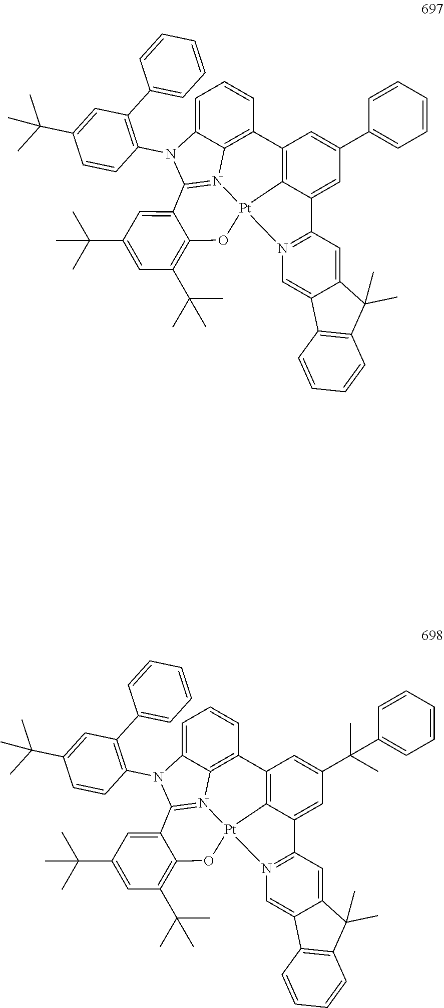

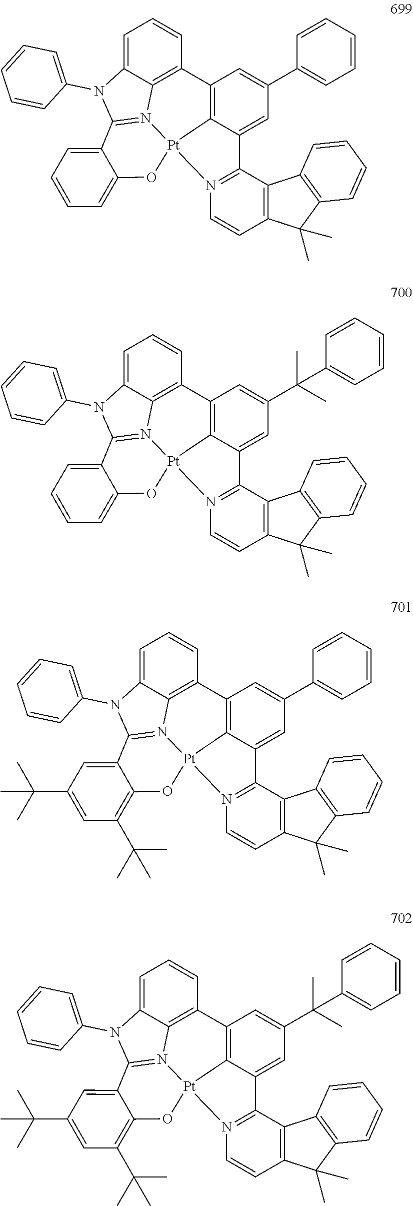

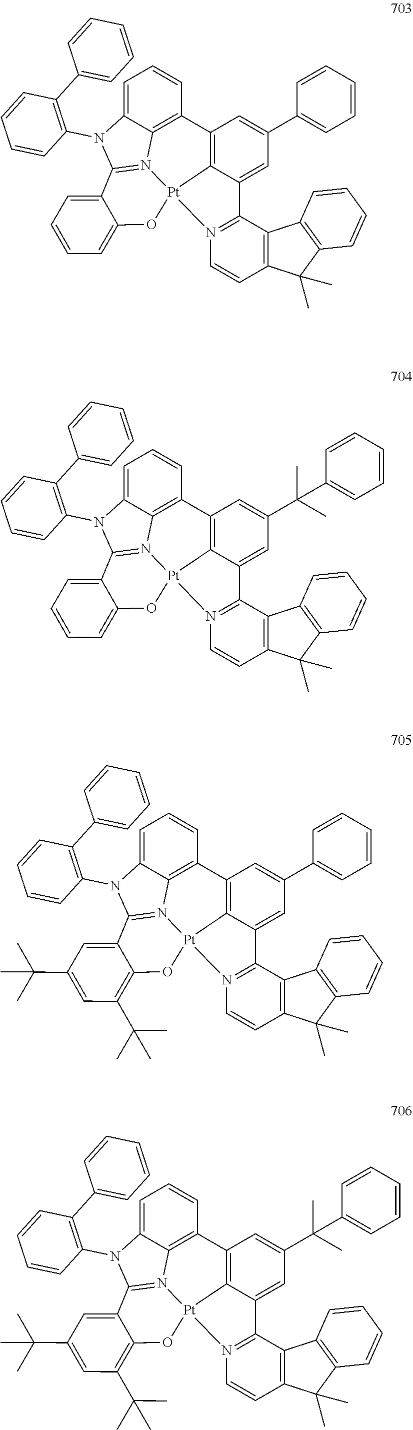

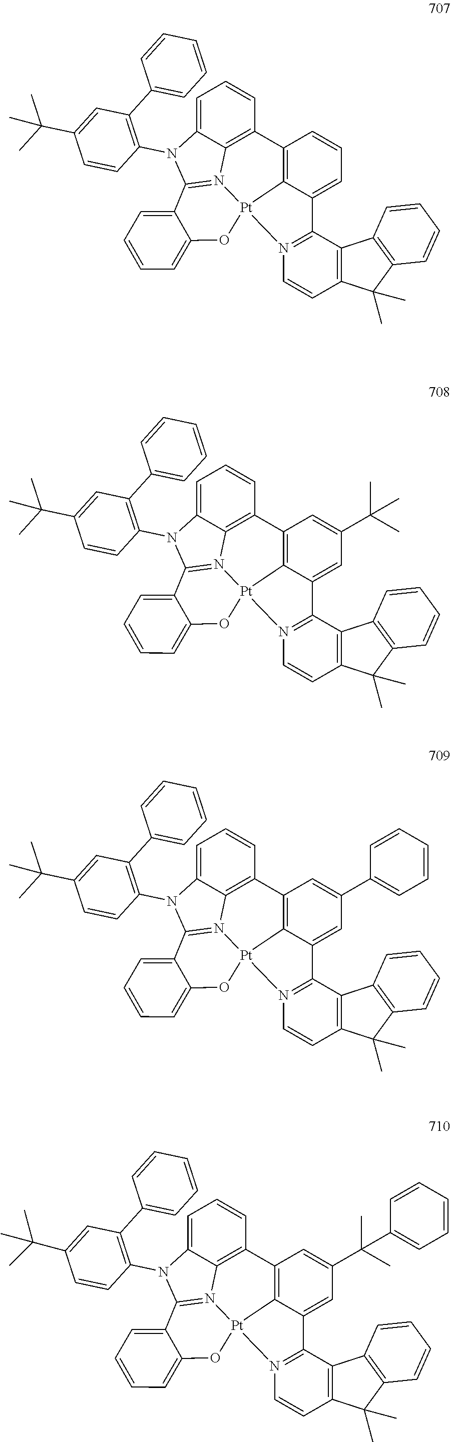

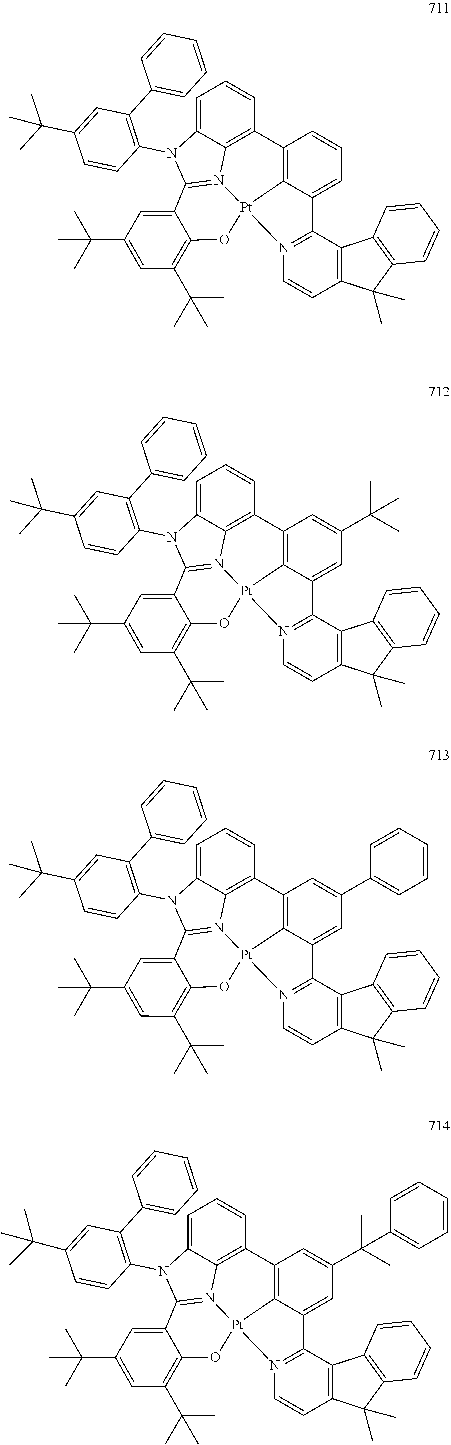

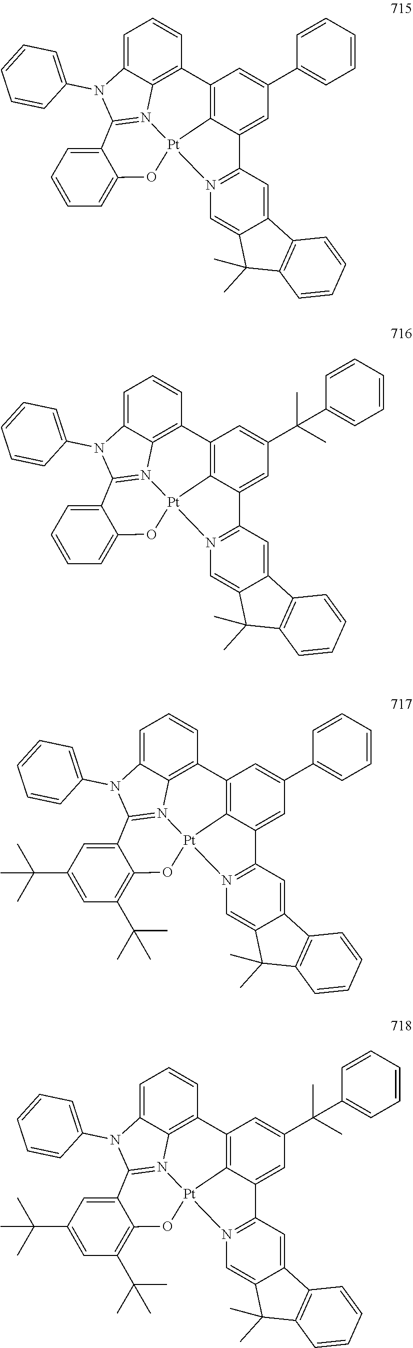

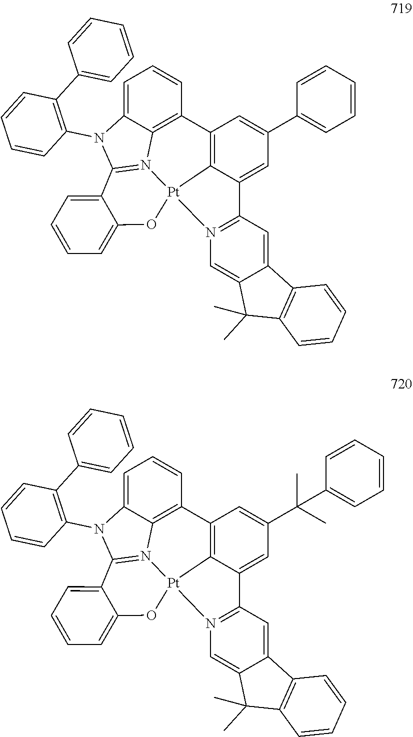

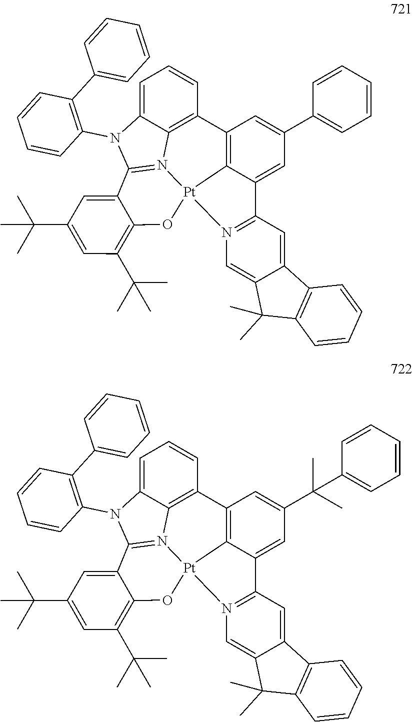

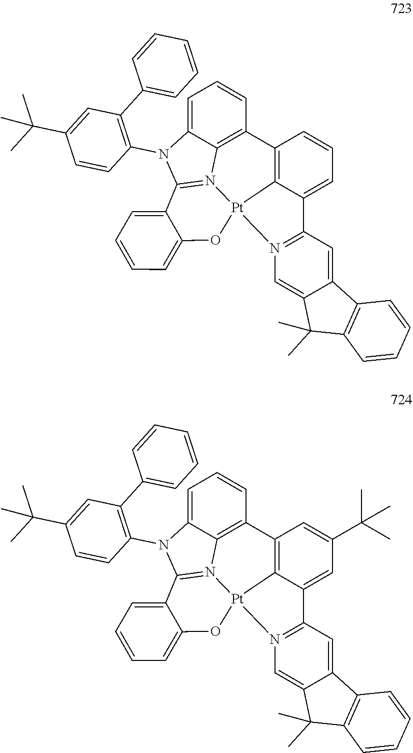

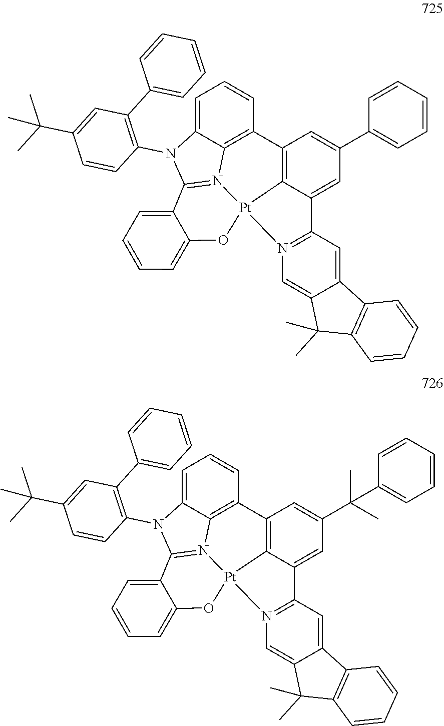

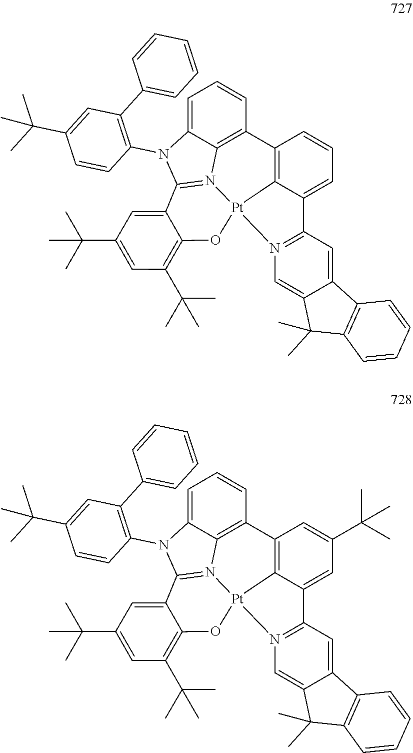

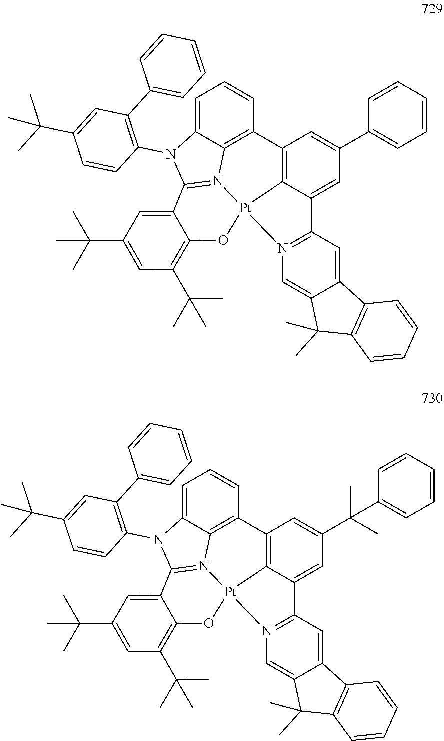

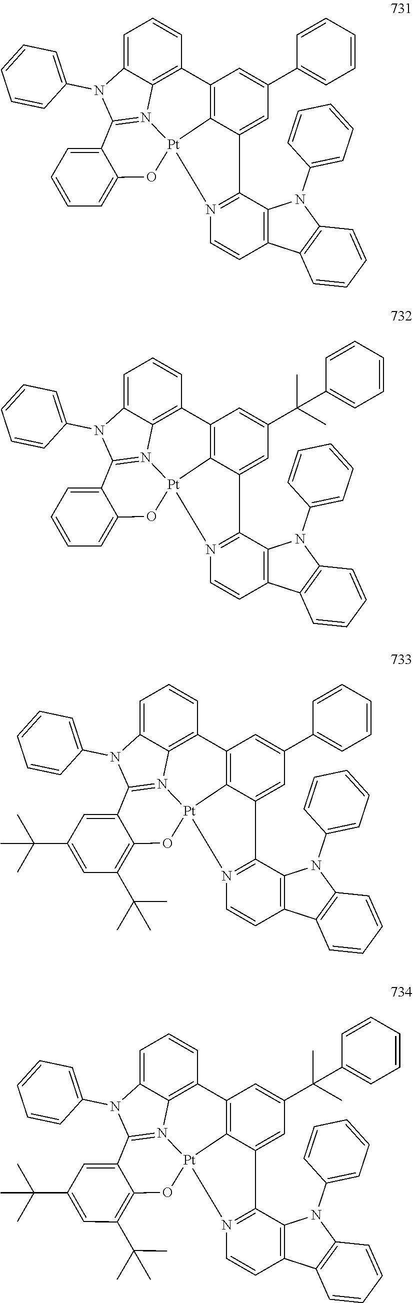

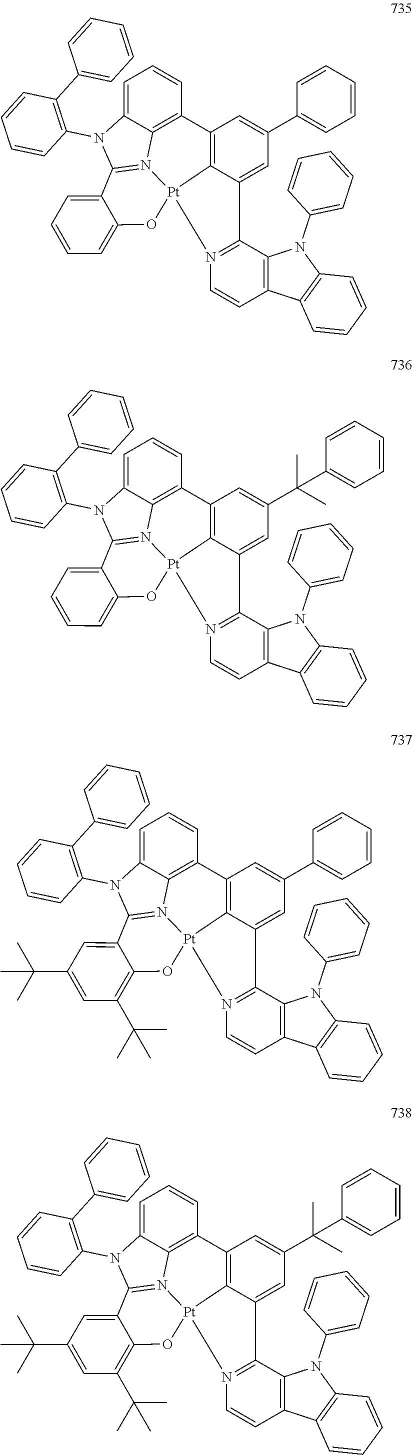

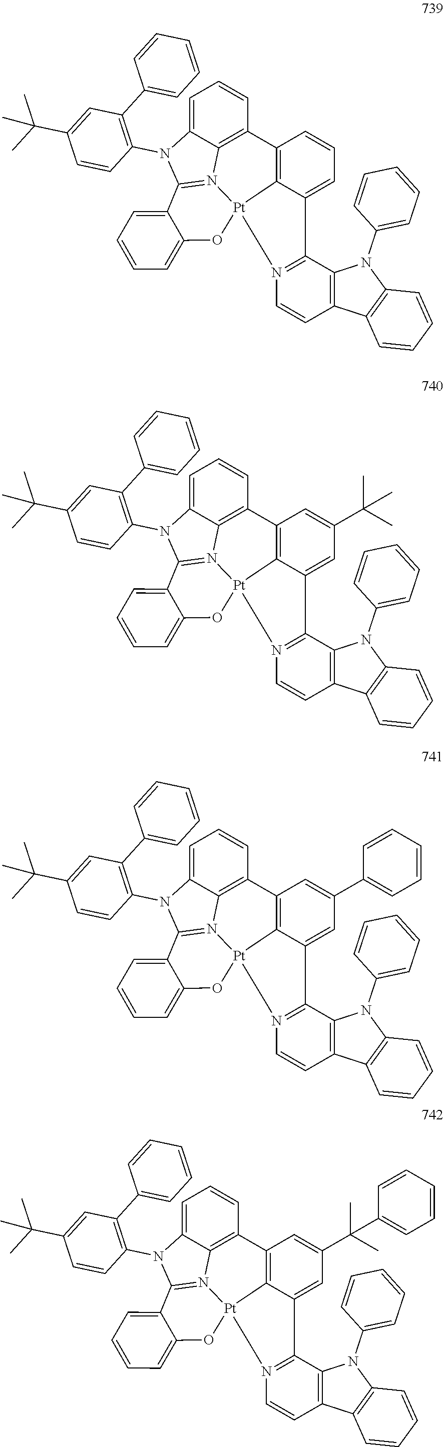

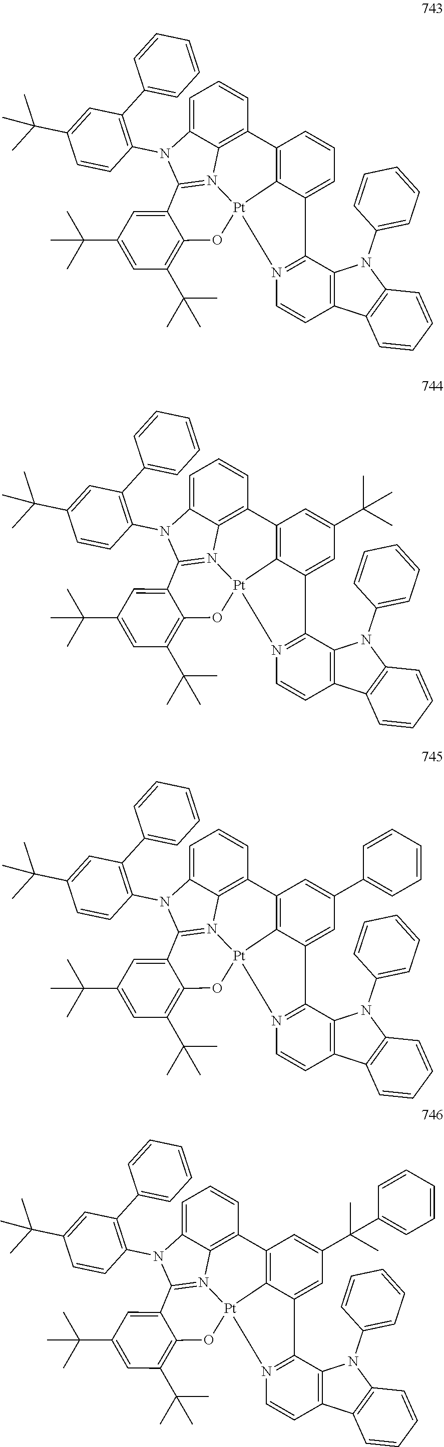

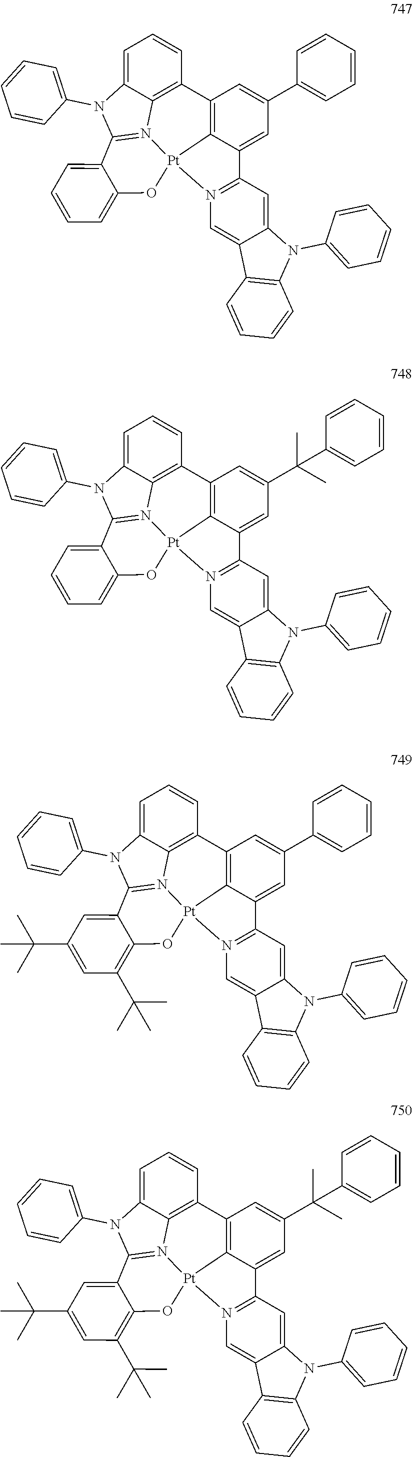

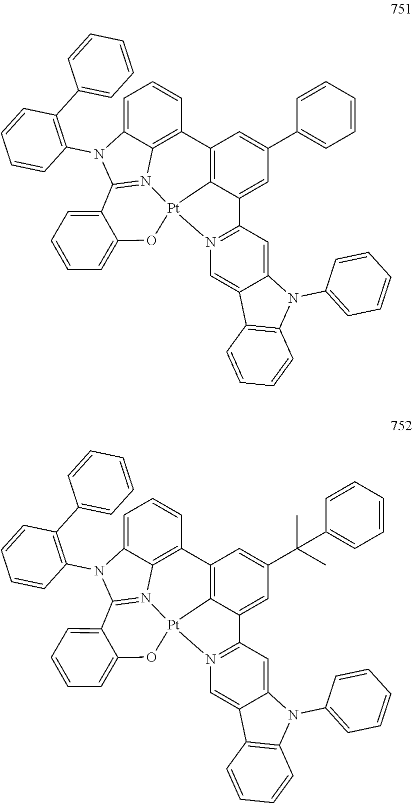

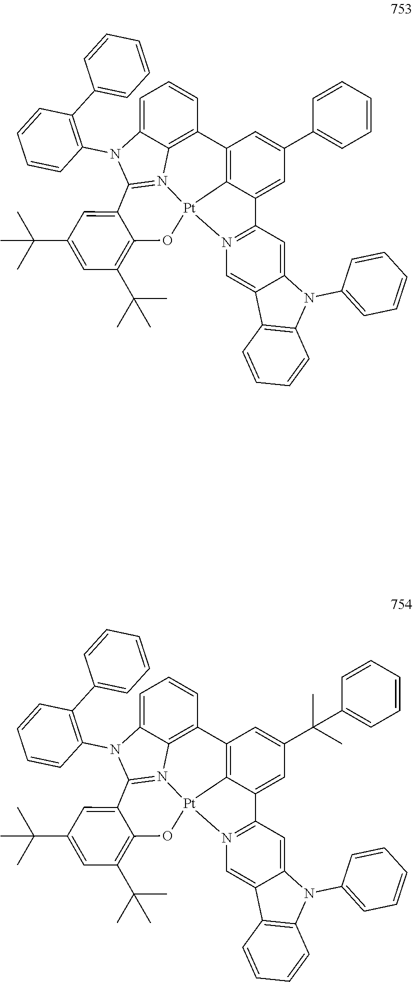

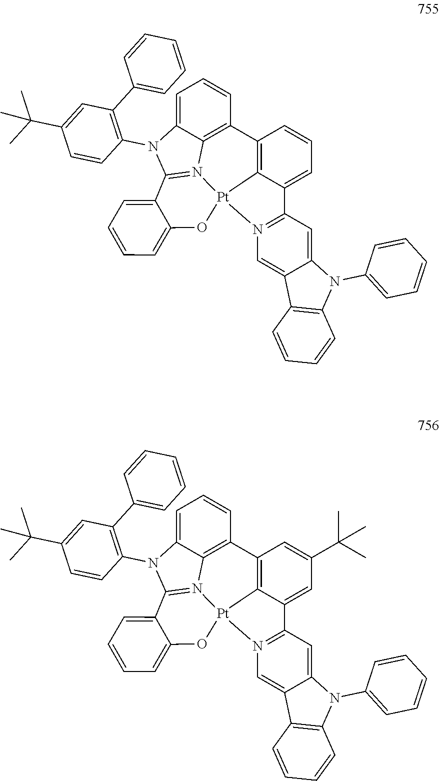

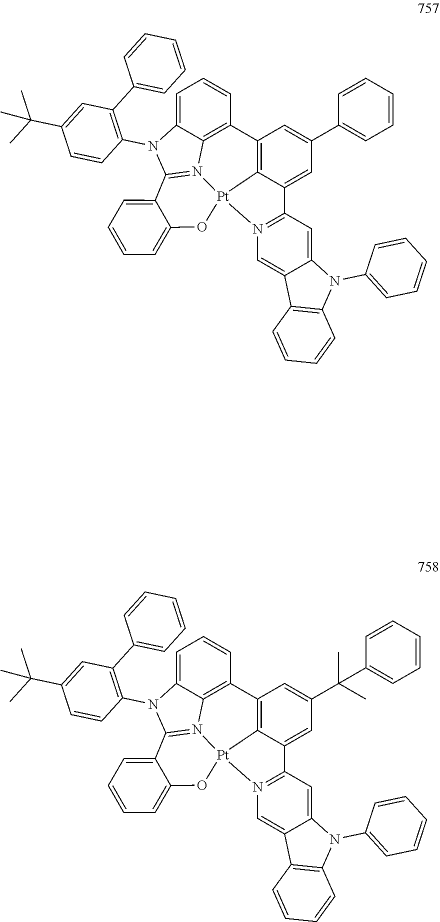

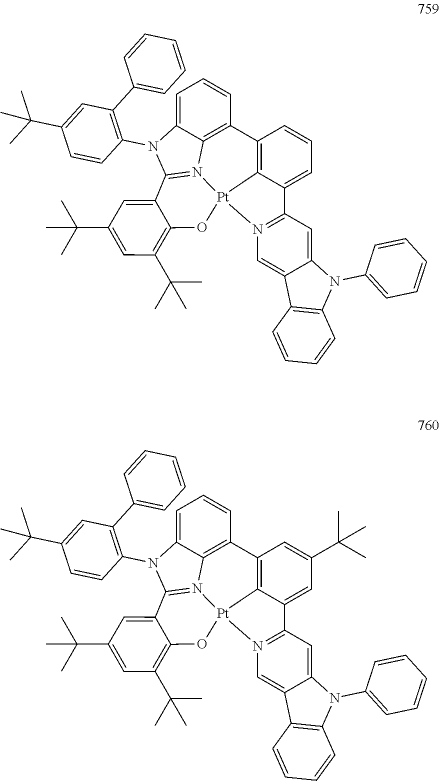

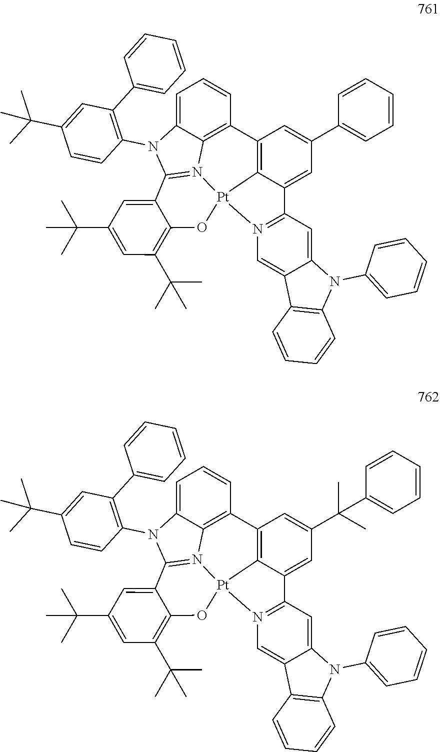

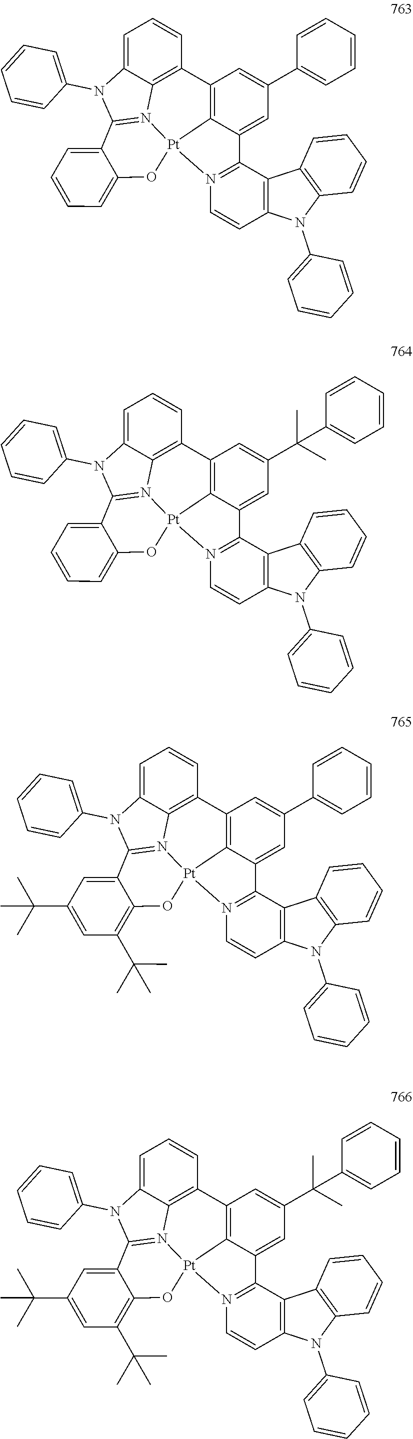

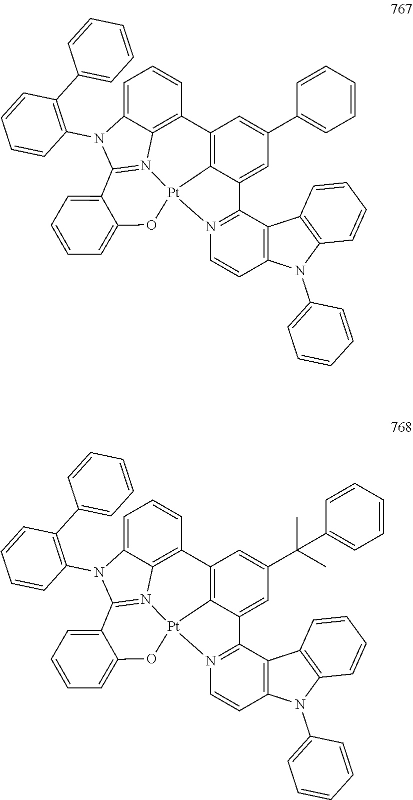

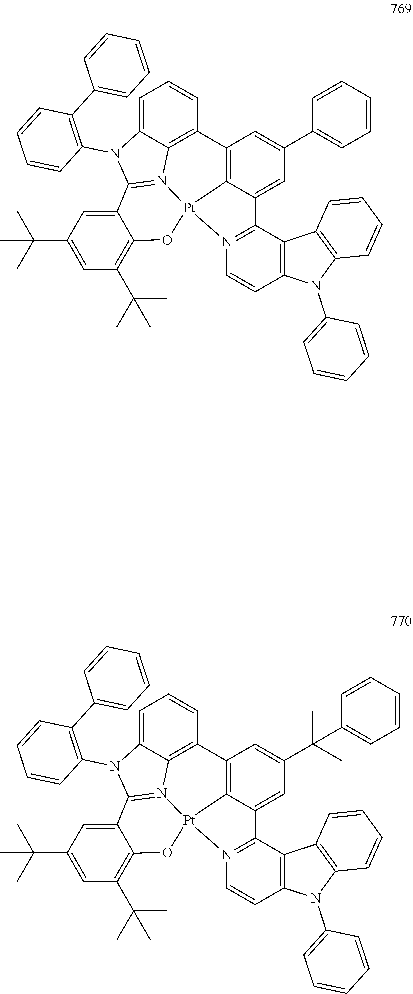

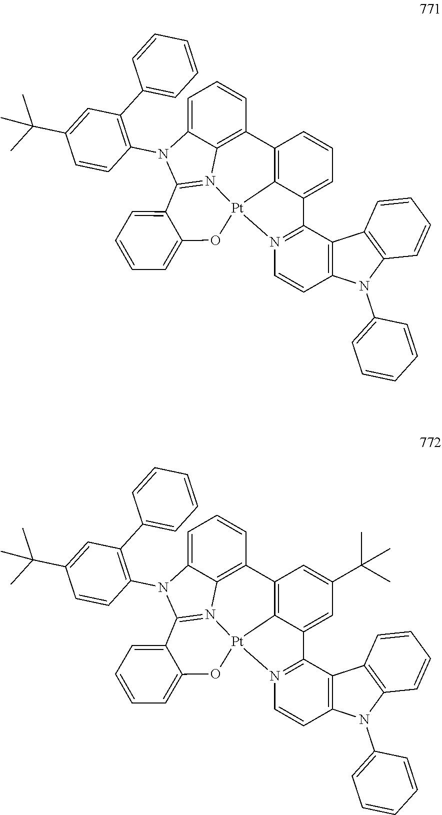

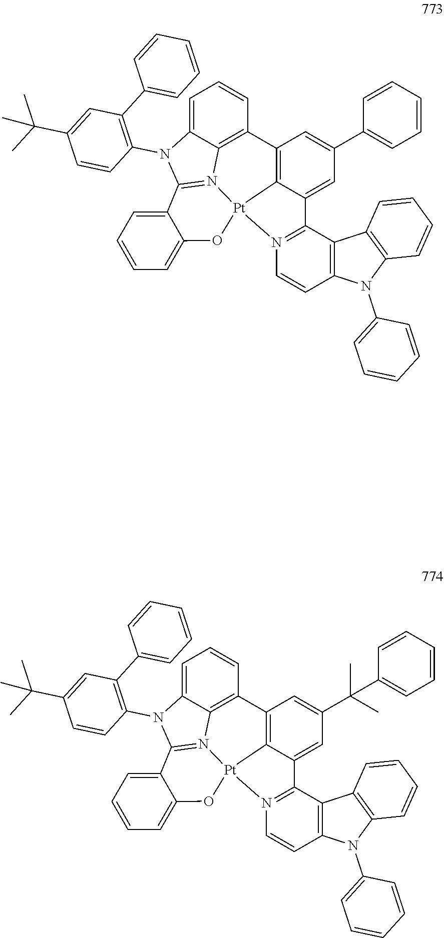

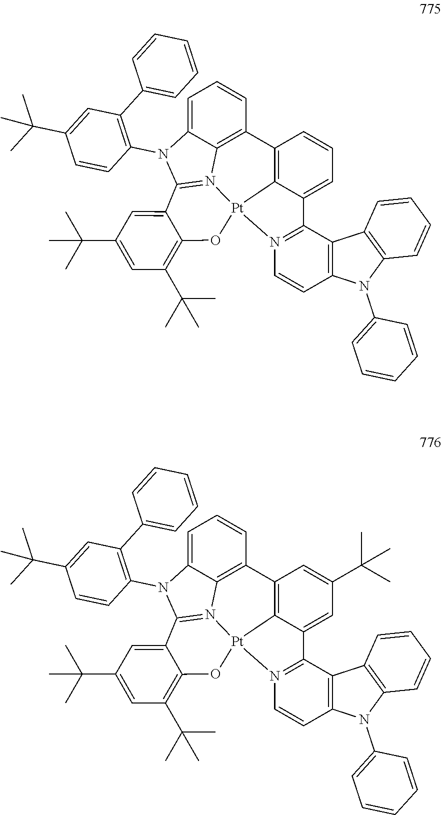

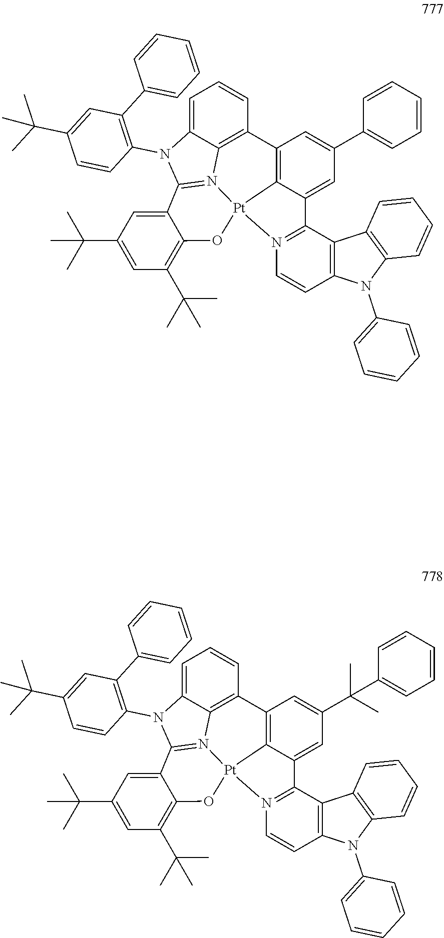

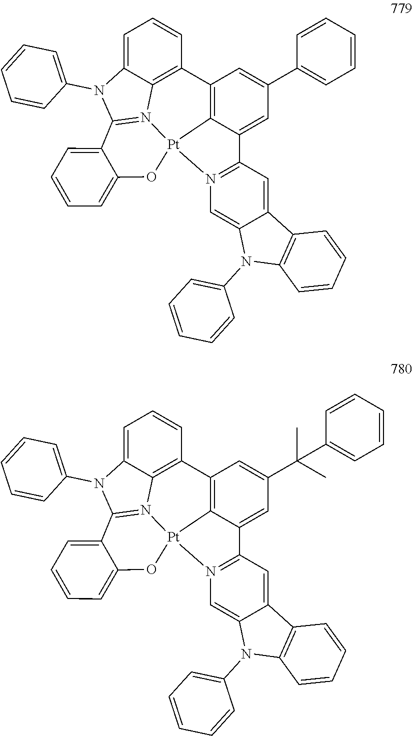

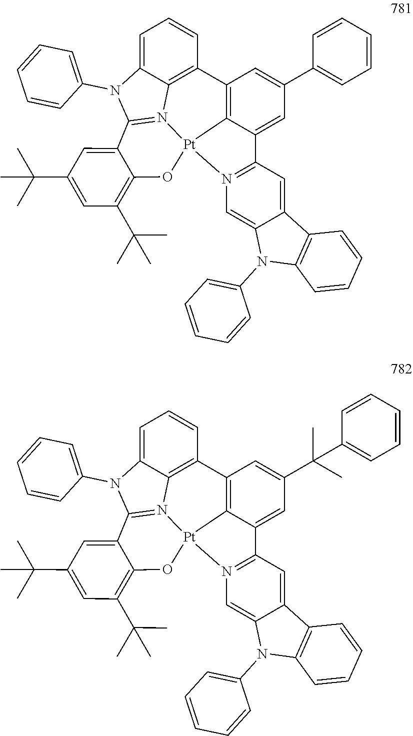

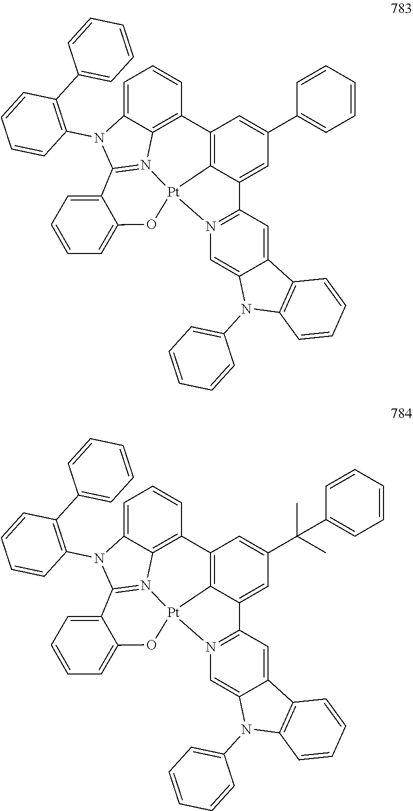

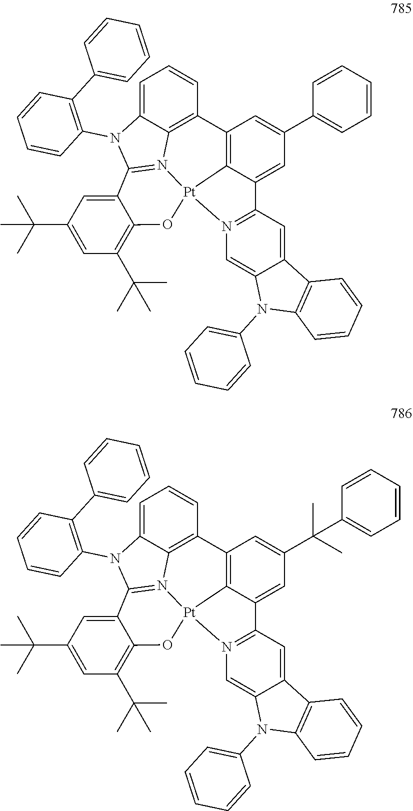

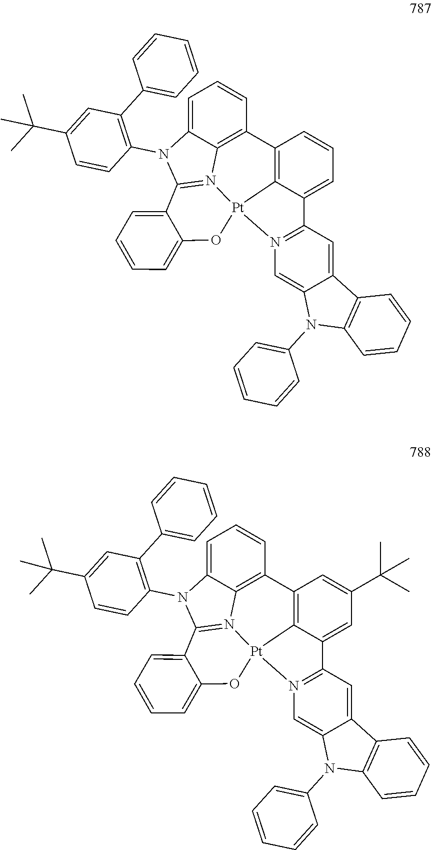

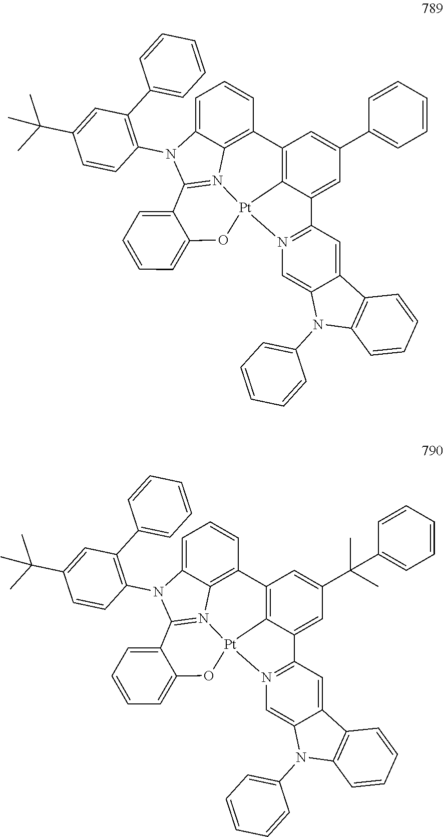

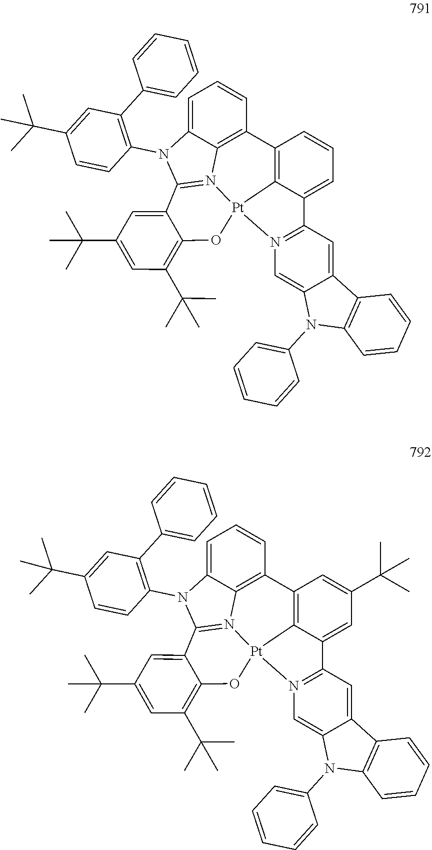

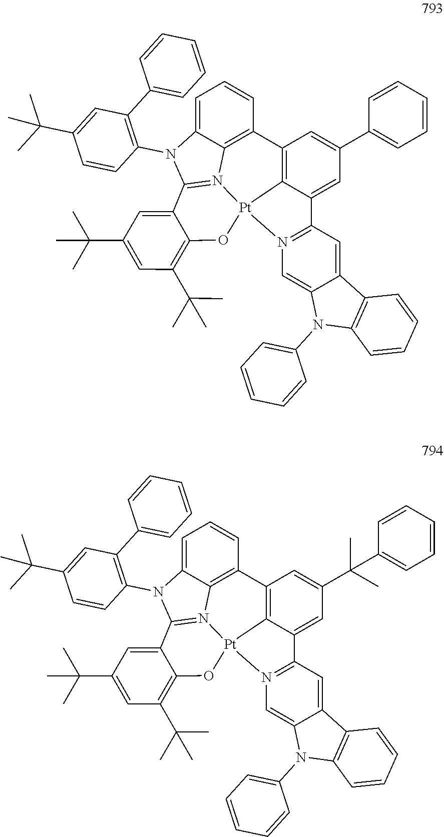

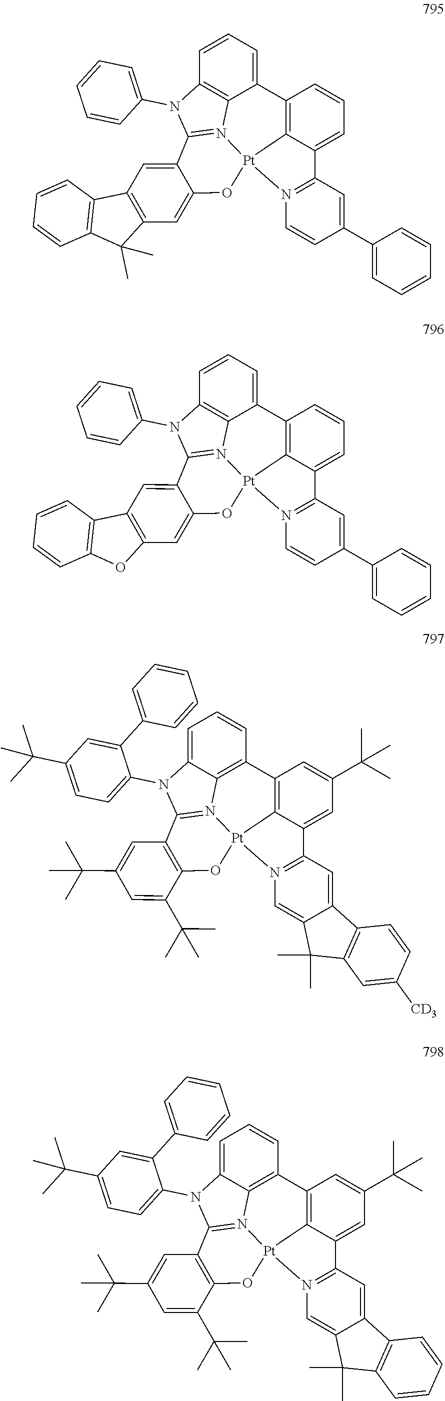

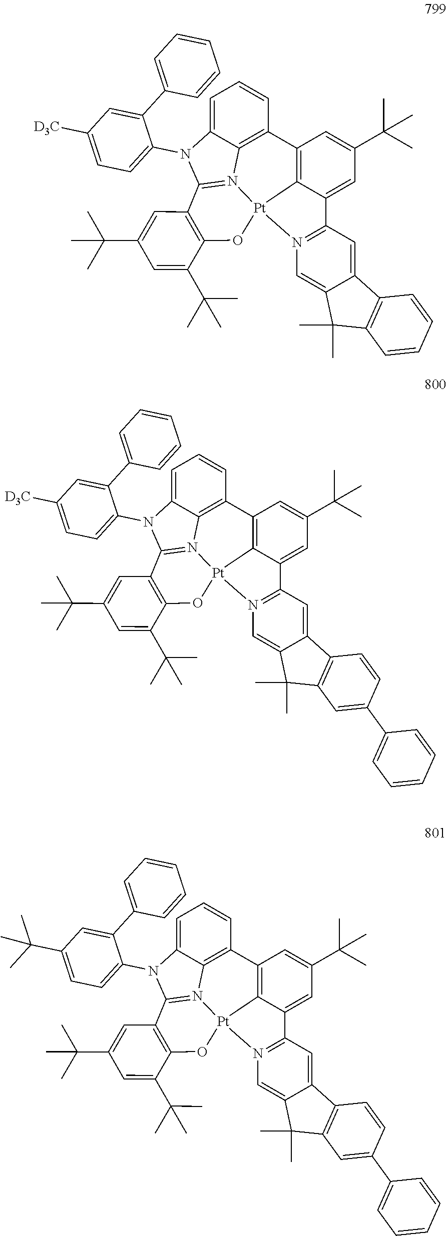

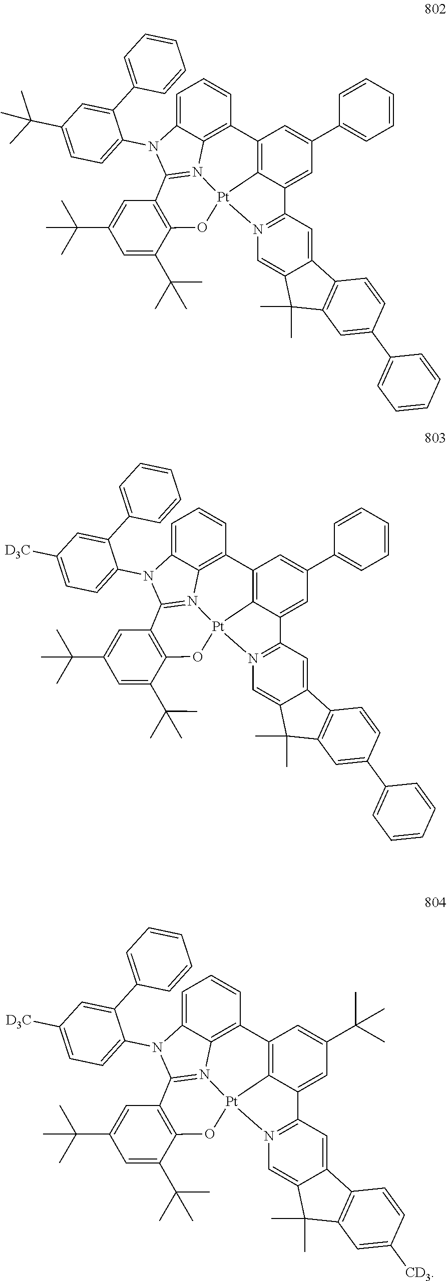

At least one of ring CY₁ to ring CY₄ of the organometallic compound represented by Formula 1 may each independently be a condensed cyclic group wherein two or more rings are condensed with each other and Formula 1 may satisfy at least one of Condition A to Condition D. As a result, the rigidity of the organometallic compound is increased so that deformation of the molecular structure of the organometallic compound may be reduced. Accordingly, the full width at half maximum (FWHM) in the luminescence spectrum of the organometallic compound is improved, and tau (decay time) may be reduced due to the increase in the CT (charge transfer) characteristics of the organometallic compound.

For example, the highest occupied molecular orbital (HOMO) energy level, lowest unoccupied molecular orbital (LUMO) energy level, energy band gap, lowest excitation singlet (S₁) energy level, and the lowest excitation triplet (T₁) energy levels of Compounds 1 to 6 were calculated using a density functional theory (DFT) method of the Gaussian 09 program with the molecular structure optimized at the B3LYP, 6-31G(d,p) levels, and evaluated. Results thereof are shown in Table 1 below and are reported in electron volts (eV).

TABLE 1

| | HOMO | LUMO | Energy band gap | S₁ | T₁ |
|---|---|---|---|---|---|
| Compound No. | (eV) | (eV) | (eV) | (eV) | (eV) |
| 1 | −4.547 | −1.638 | 2.909 | 2.465 | 2.299 |
| 2 | −4.664 | −1.653 | 3.011 | 2.541 | 2.359 |
| 3 | −4.503 | −1.604 | 2.899 | 2.438 | 2.287 |
| 4 | −4.589 | −1.621 | 2.968 | 2.481 | 2.313 |
| 5 | −4.649 | −1.651 | 2.998 | 2.507 | 2.344 |
| 6 | −4.638 | −1.687 | 2.951 | 2.499 | 2.368 |

From Table 1, it was confirmed that the organometallic compound represented by Formula 1 have such electric characteristics that are suitable for use as a dopant for an electronic device, for example, an organic light-emitting device.

Synthesis methods of the organometallic compound represented by Formula 1 may be recognizable by one of ordinary skill in the art by referring to Synthesis Examples provided below.

Accordingly, the organometallic compound represented by Formula 1 is suitable for use as a material for an organic layer of organic light-emitting device, for example, a dopant in an emission layer of the organic layer. Thus, another aspect provides an organic light-emitting device including: a first electrode; a second electrode; and an organic layer located between the first electrode and the second electrode and including an emission layer, and the organic layer includes at least one organometallic compound represented by Formula 1.

The organic light-emitting device may have low driving voltage, high external quantum efficiency, a low roll-off ratio, and high lifespan characteristics by having the organic layer including the organometallic compound represented by Formula 1 as described above.

The organometallic compound of Formula 1 may be used between a pair of electrodes of an organic light-emitting device. For example, the organometallic compound represented by Formula 1 may be included in the emission layer. In this regard, the organometallic compound may act as a dopant, and the emission layer may further include a host (that is, an amount of the organometallic compound represented by Formula 1 is smaller than an amount of the host). In one or more embodiments, the emission layer may emit green light to blue light.

The expression “(an organic layer) includes at least one of organometallic compounds” used herein may include a case wherein “(an organic layer) includes identical organometallic compounds represented by Formula 1” and a case wherein “(an organic layer) includes two or more different organometallic compounds represented by Formula 1”.

For example, the organic layer may include, as the organometallic compound, only Compound 1. In this embodiment, Compound 1 may be included in the emission layer of the organic light-emitting device. In one or more embodiments, the organic layer may include, as the organometallic compound, Compound 1 and Compound 2. In this regard, Compound 1 and Compound 2 may exist in an identical layer (for example, Compound 1 and Compound 2 all may exist in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In one or more embodiments, in the organic light-emitting device, the first electrode is an anode, and the second electrode is a cathode, and the organic layer may further include a hole transport region located between the first electrode and the emission layer and an electron transport region located between the emission layer and the second electrode, and the hole transport region may include a hole injection layer, a hole transport layer, an electron-blocking layer, a buffer layer, or a combination thereof, and the electron transport region may include a hole-blocking layer, an electron transport layer, an electron injection layer, or a combination thereof.

The term “organic layer” used herein refers to a single layer and/or a plurality of layers between the first electrode and the second electrode of the organic light-emitting device. The “organic layer” may include, in addition to an organic compound, an organometallic complex including metal.

FIGURE is a schematic cross-sectional view of an organic light-emitting device 10 according to one or more embodiments. Hereinafter, the structure and manufacturing method of the organic light-emitting device 10 according to one or more embodiments of the present disclosure will be described in connection with FIGURE. The organic light-emitting device 10 includes a first electrode 11, an organic layer 15, and a second electrode 19, which are sequentially stacked.

A substrate may be additionally located under the first electrode 11 or above the second electrode 19. For use as the substrate, any substrate that is used in organic light-emitting devices available in the art may be used, and the substrate may be a glass substrate or a transparent plastic substrate, each having excellent mechanical strength, thermal stability, transparency, surface smoothness, ease of handling, and water resistance.

In one or more embodiments, the first electrode 11 may be formed by depositing or sputtering a material for forming the first electrode 11 on the substrate. The first electrode 11 may be an anode. The material for forming the first electrode 11 may include materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), silver (Ag), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO.

The organic layer 15 may be located on the first electrode 11.

The organic layer 15 may include a hole transport region, an emission layer, and an electron transport region.

The hole transport region may be located between the first electrode 11 and the emission layer.

The hole transport region may include a hole injection layer, a hole transport layer, an electron-blocking layer, a buffer layer, or a combination thereof.

The hole transport region may include only either a hole injection layer or a hole transport layer. In one or more embodiments, the hole transport region may have a hole injection layer/hole transport layer structure or a hole injection layer/hole transport layer/electron-blocking layer structure, wherein, for each structure, each layer is sequentially stacked in this stated order from the first electrode 11.

When the hole transport region includes a hole injection layer, the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary depending on a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec.

When the hole injection layer is formed using spin coating, coating conditions may vary according to the material used to form the hole injection layer, and the structure and thermal properties of the hole injection layer. For example, a coating speed may be from about 2,000 rpm to about 5,000 rpm, and a temperature at which a heat treatment is performed to remove a solvent after coating may be from about 80° C. to about 200° C.

The conditions for forming the hole transport layer and the electron-blocking layer may be as the conditions for forming the hole injection layer.

The hole transport region may include m-MTDATA, TDATA, 2-TNATA, NPB, 3-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201 below, a compound represented by Formula 202 below, or a combination thereof:

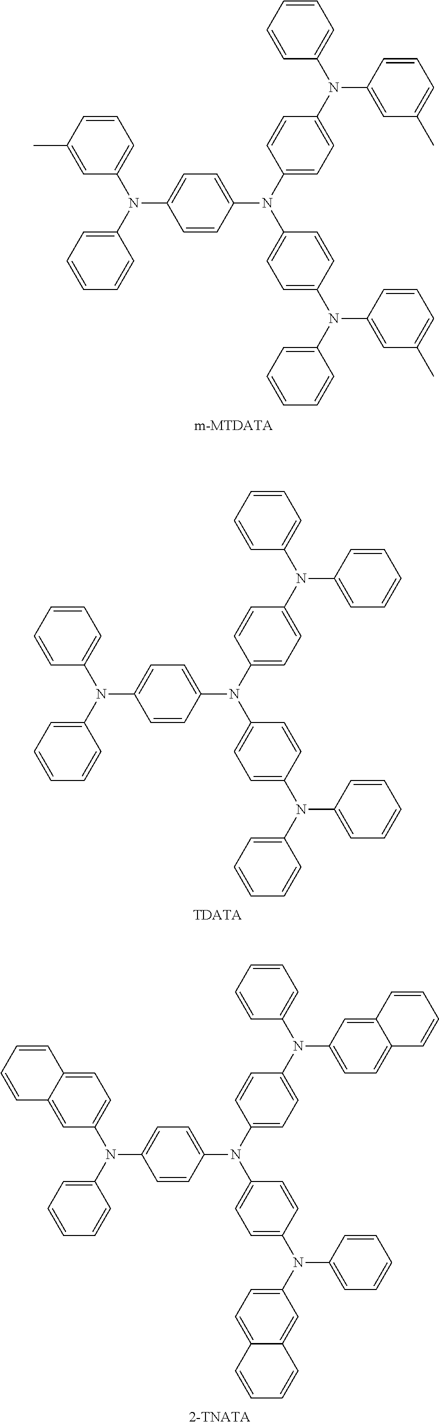

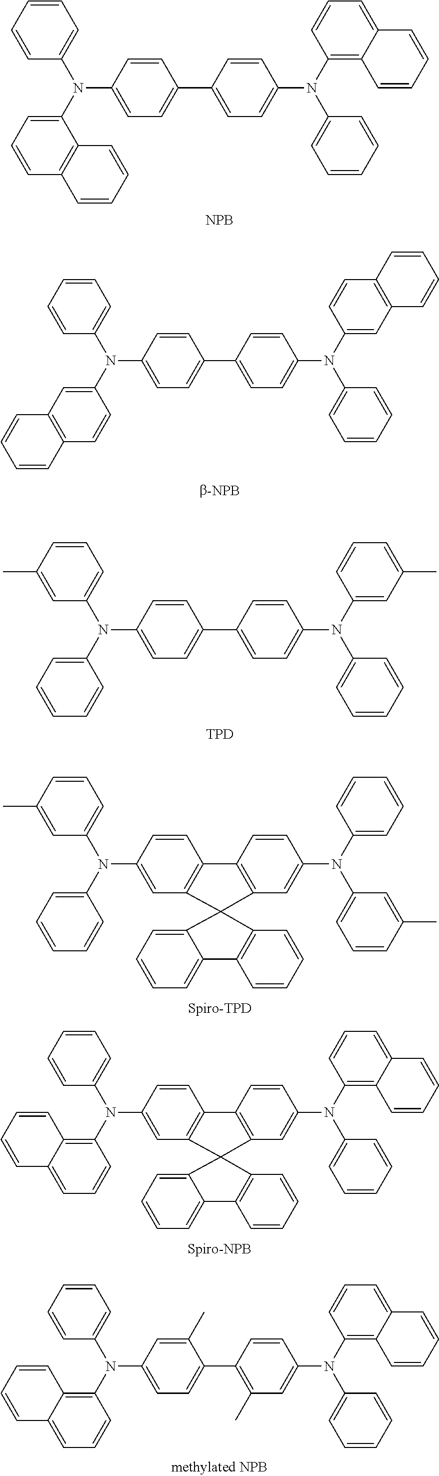

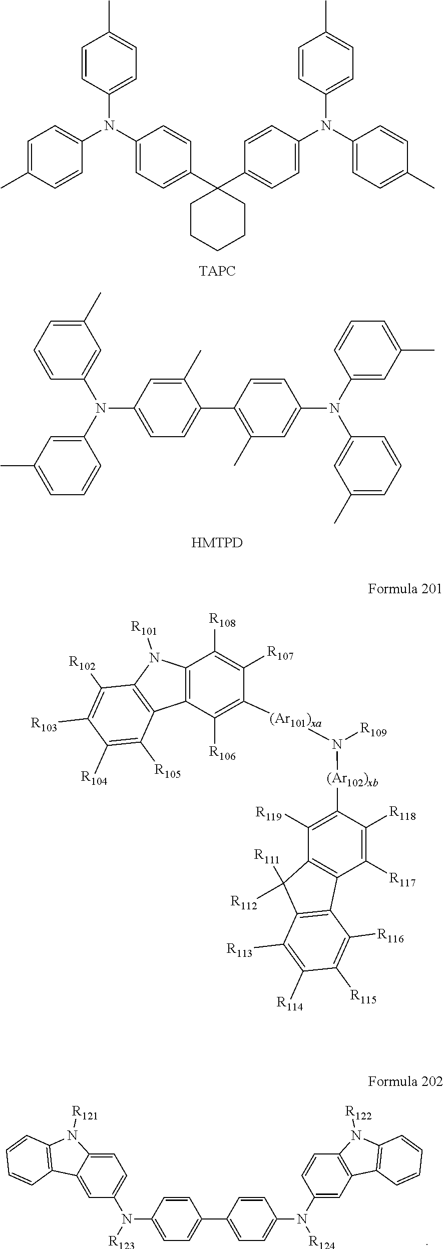

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₁₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

xa and xb in Formula 201 may each independently be an integer of 0 to 5, or 0, 1, or 2. For example, xa may be 1 and xb may be 0.

R₁₀₁ to R₁₀₈, R₁₁₁ to R₁₁₉ and R₁₂₁ to R₁₂₄ in Formulae 201 and 202 may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, pentyl group, a hexyl group, etc.), or a C₁-C₁₀ alkoxy group (for example, a methoxy group, an ethoxy group, a propoxy group, a butoxy group, a pentoxy group, etc.);

a C₁-C₁₀ alkyl group or a C₁-C₁₀ alkoxy group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof; or

a phenyl group, a naphthyl group, an anthracenyl group, a fluorenyl group or a pyrenyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or a combination thereof.

R₁₀₉ in Formula 201 may be a phenyl group, a naphthyl group, an anthracenyl group, or a pyridinyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or a combination thereof.

In one or more embodiments, the compound represented by Formula 201 may be represented by Formula 201A:

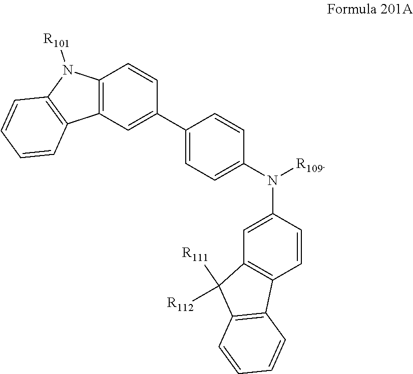

R₁₀₁, R₁₁₁, R₁₁₂, and R₁₀₉ in Formula 201A are each as described in the present specification.

For example, the hole transport region may include one of Compounds HT1 to HT20, or a combination thereof:

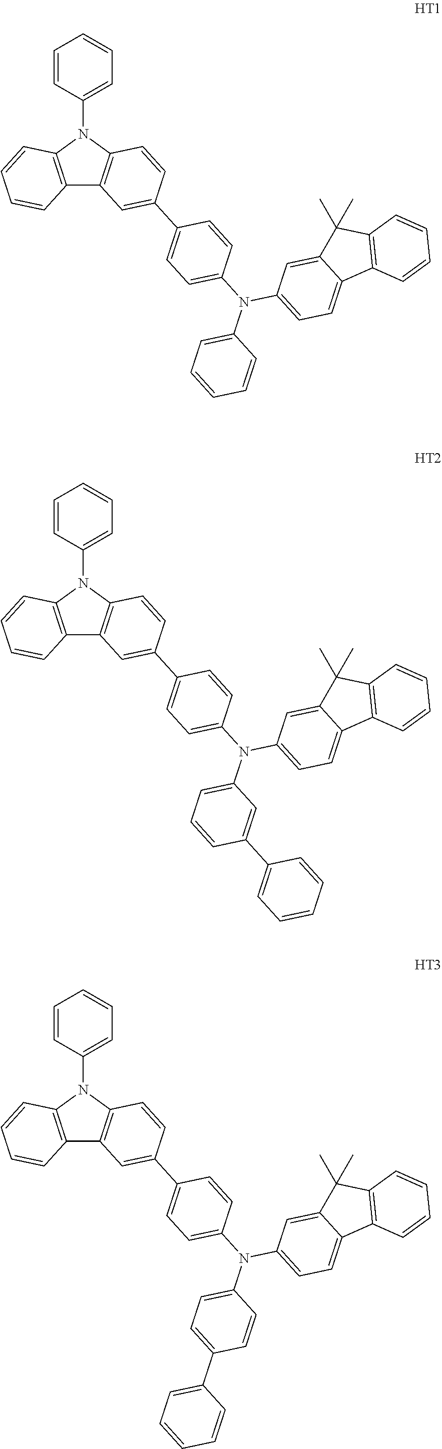 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

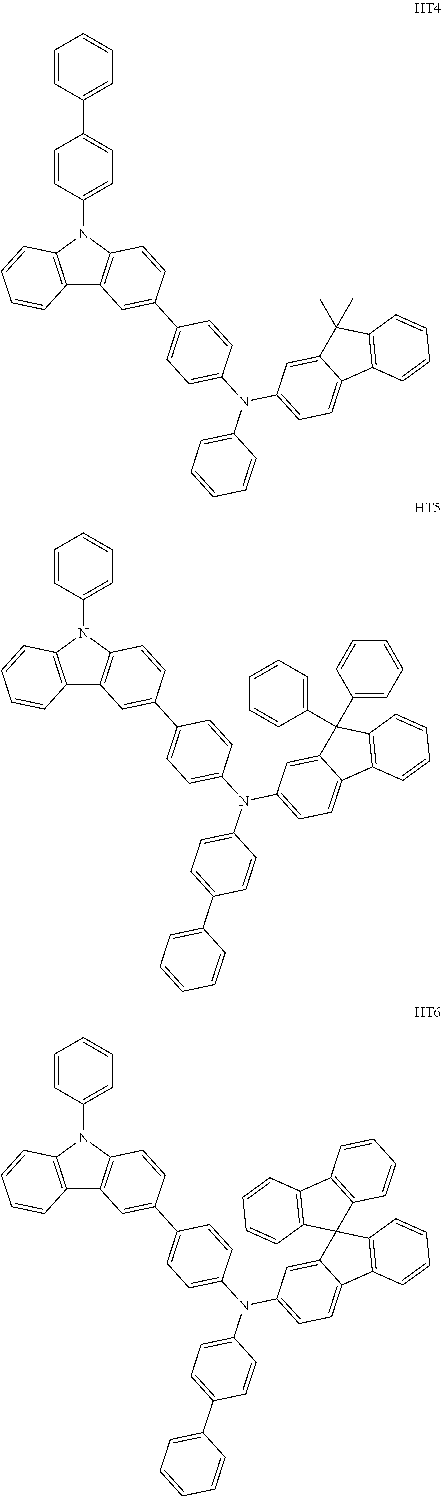 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

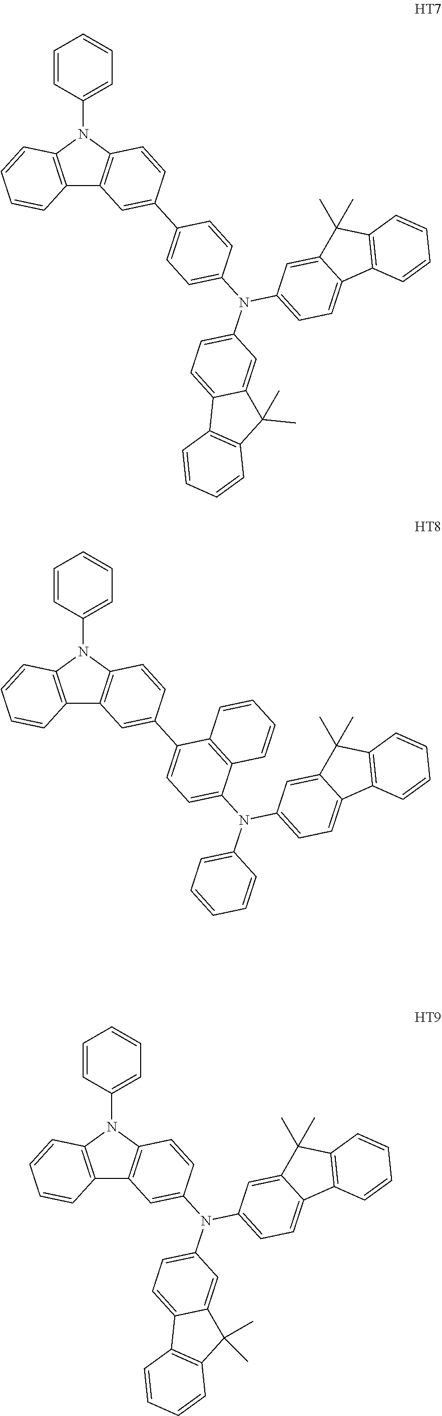 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

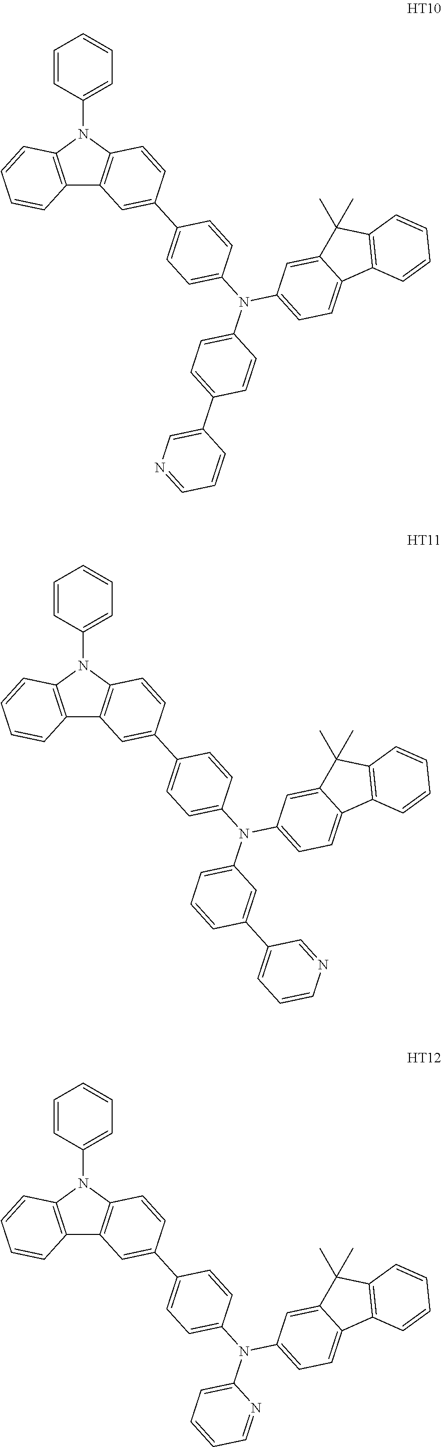 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

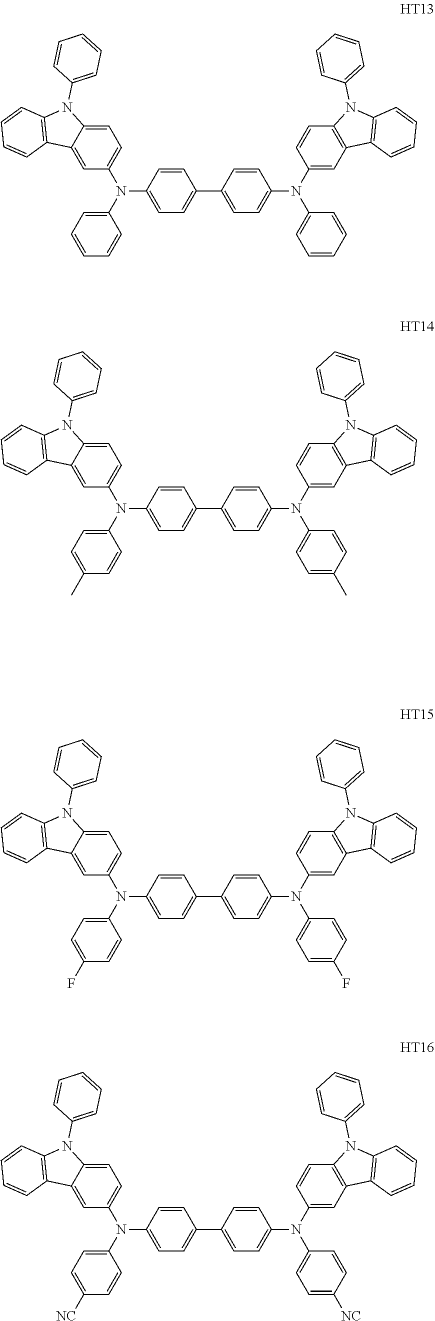

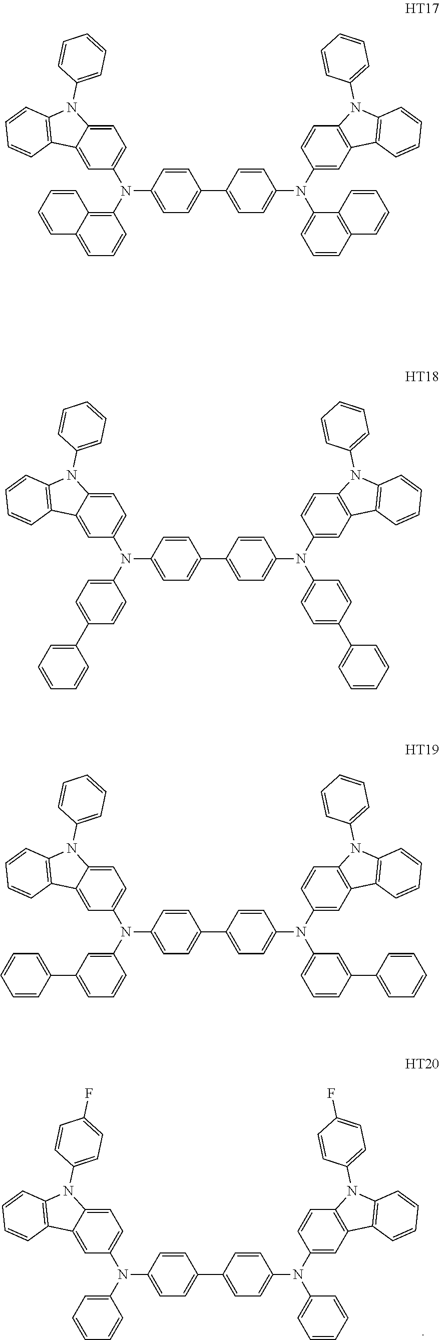 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in the range of about 100 Å to about 10,000 Å, for example, about 100 Å to about 1,000 Å. When the hole transport region includes at least one of a hole injection layer and a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may include a quinone derivative, a metal oxide, a cyano group-containing compound, or a combination thereof. For example, the p-dopant may be: a quinone derivative such as tetracyanoquinonedimethane (TCNQ), 2,3,5,6-tetrafluoro-tetracyano-1,4-benzoquinonedimethane (F4-TCNQ), or F6-TCNNQ; metal oxide, such as tungsten oxide and molybdenum oxide; a cyano group-containing compound, such as Compound HT-D1; or a combination thereof.

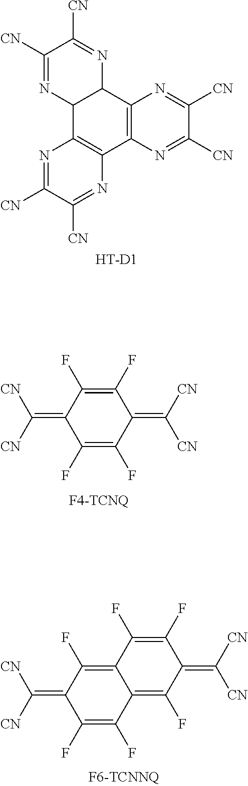

The hole transport region may include a buffer layer.

The buffer layer may compensate for an optical resonance distance according to a wavelength of light emitted from the emission layer, and thus, efficiency of a formed organic light-emitting device may be improved.

Meanwhile, when the hole transport region includes an electron-blocking layer, a material for forming the electron-blocking layer may include a material that is used in the hole transport region as described above, a host material described below, or a combination thereof. For example, when the hole transport region includes an electron-blocking layer, mCP, or a combination thereof may be used as the material for forming the electron-blocking layer.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a material that is used to form the emission layer.

The emission layer may include a host and a dopant, and the dopant may include the organometallic compound represented by Formula 1 as described herein.

The host may include TPBi, TBADN, ADN (also referred to as “DNA”), CBP, CDBP, TCP, mCP, Compound H50, Compound H51, Compound H52, or a combination thereof:

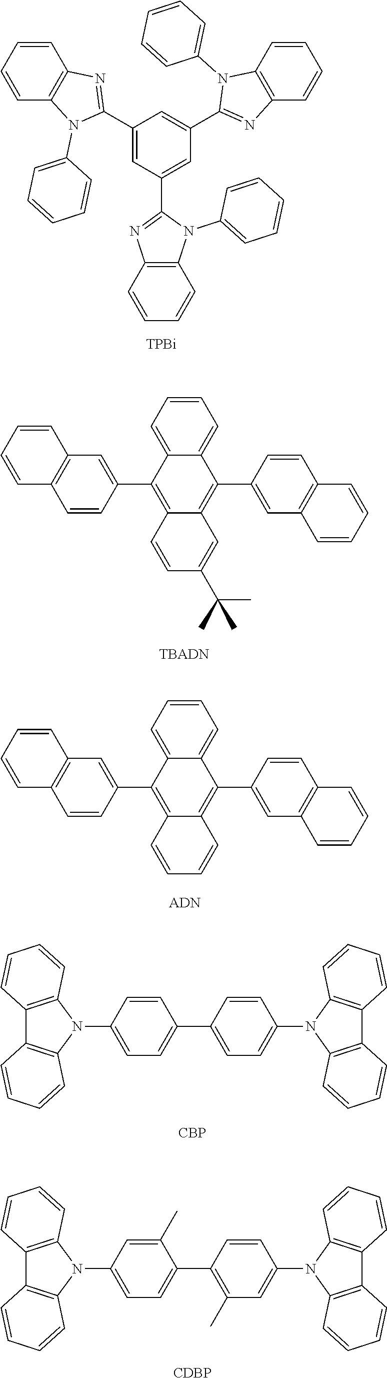

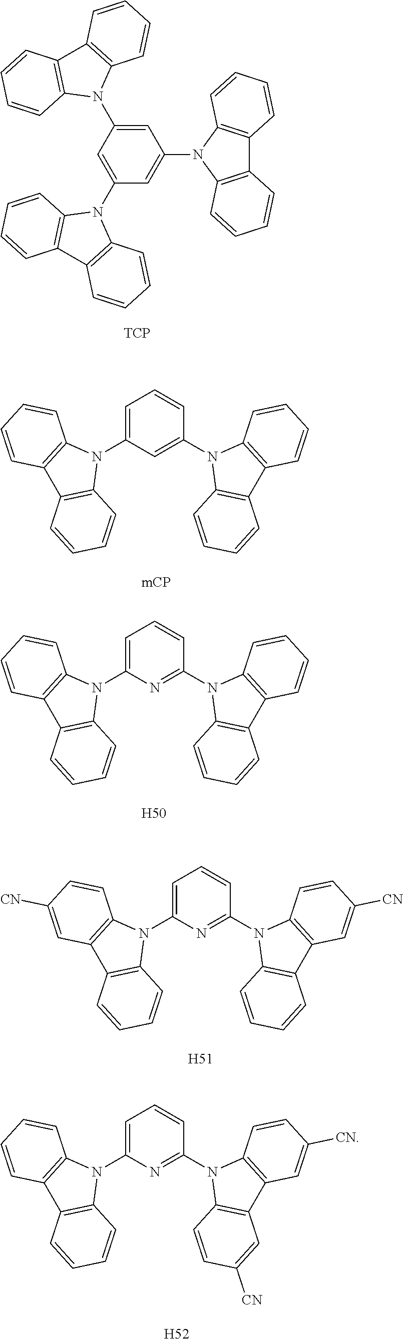

When the organic light-emitting device is a full-color organic light-emitting device, the emission layer may be patterned into a red emission layer, a green emission layer, and/or a blue emission layer. In one or more embodiments, due to a stacked structure including a red emission layer, a green emission layer, and/or a blue emission layer, the emission layer may emit white light.

When the emission layer includes a host and a dopant, an amount of the dopant may be in a range of about 0.01 parts by weight to about 15 parts by weight, based on 100 parts by weight of the host.

A thickness of the emission layer may be in a range of about 100 Å to about 1,000 Å, for example, about 200 Å to about 600 Å. When the thickness of the emission layer is within these ranges, excellent luminescence characteristics may be obtained without a substantial increase in driving voltage.

An electron transport region may be located on the emission layer.

The electron transport region may include a hole-blocking layer, an electron transport layer, an electron injection layer, or a combination thereof.

For example, the electron transport region may have a hole-blocking layer/electron transport layer/electron injection layer structure or an electron transport layer/electron injection layer structure. The electron transport layer may have a single-layered structure or a multi-layered structure including two or more different materials.

Conditions for forming the hole-blocking layer, the electron transport layer, and the electron injection layer which constitute the electron transport region may be understood by referring to the conditions for forming the hole injection layer.

When the electron transport region includes a hole-blocking layer, the hole-blocking layer may include, for example, BCP, Bphen, BAlq, or a combination thereof:

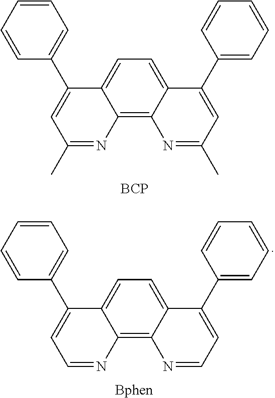

A thickness of the hole-blocking layer may be in a range of about 20 Å to about 1,000 Å, for example, about 30 Å to about 600 Å. When the thickness of the hole-blocking layer is within these ranges, excellent hole-blocking characteristics may be obtained without a substantial increase in driving voltage.

The electron transport layer may include BCP, Bphen, TPBi, Alq₃, Balq, TAZ, NTAZ, or a combination thereof:

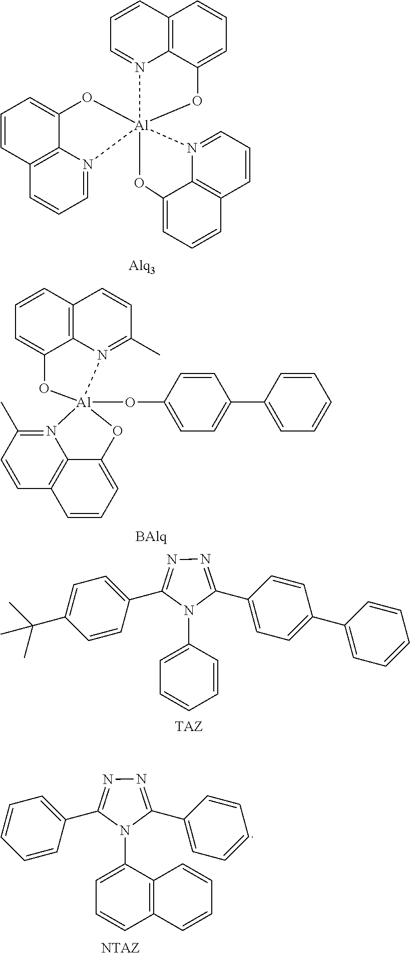

In one or more embodiments, the electron transport layer may include one of Compounds ET1 to ET25, or a combination thereof:

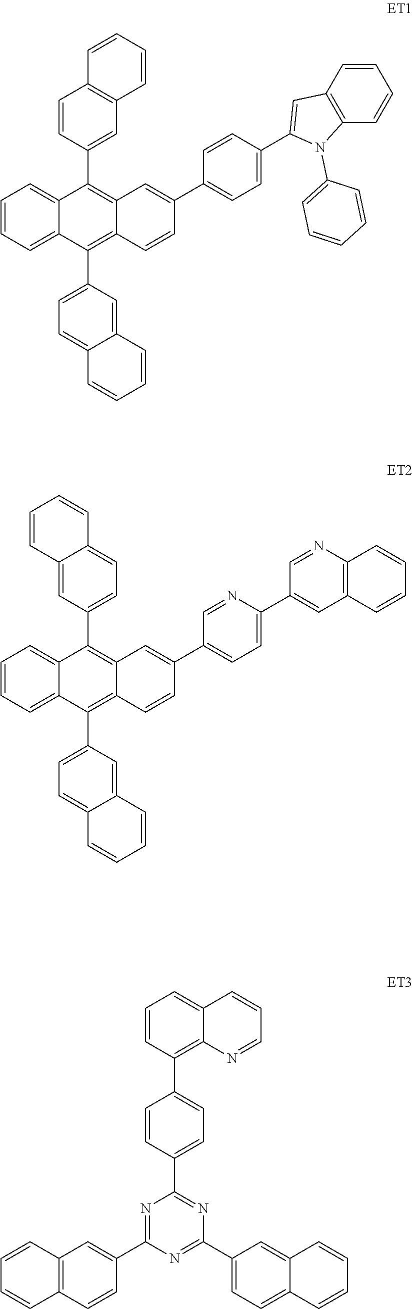 [SMILES: c1ccc(-n2c(-c3ccc(-c4ccc5c(-c6ccc7ccccc7c6)c6ccccc6c(-c6ccc7ccccc7c6)c5c4)cc3)cc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

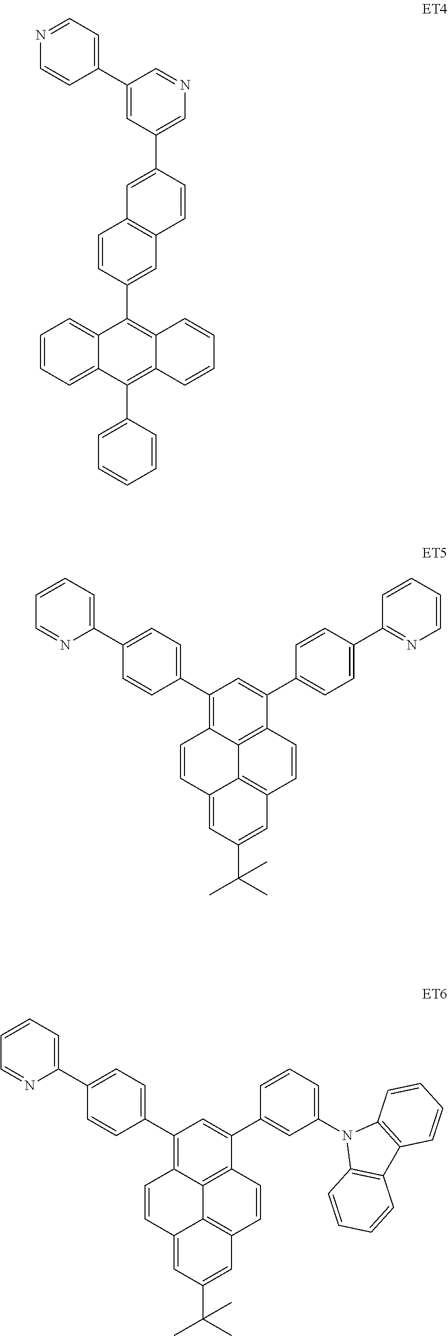 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

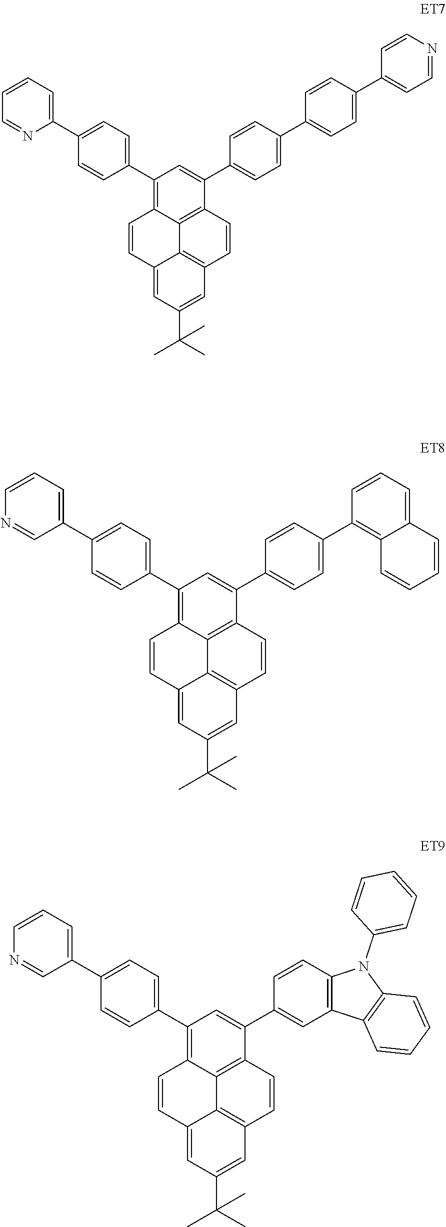 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

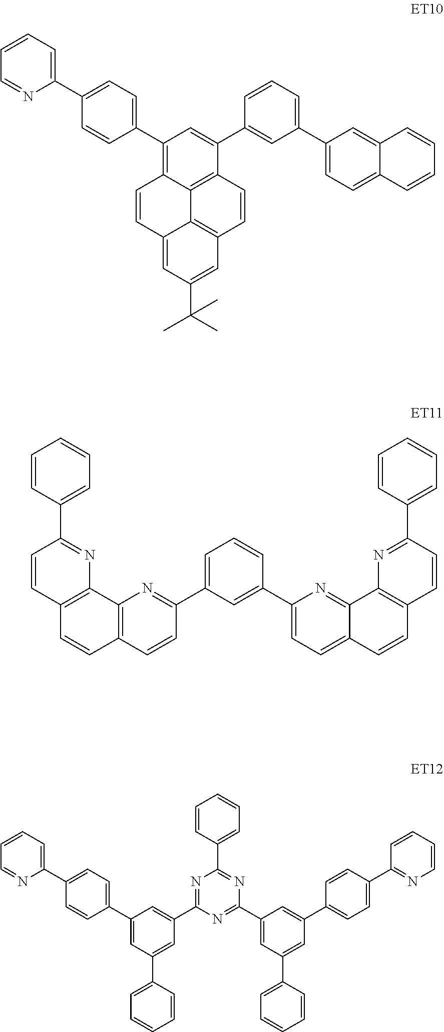 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1]

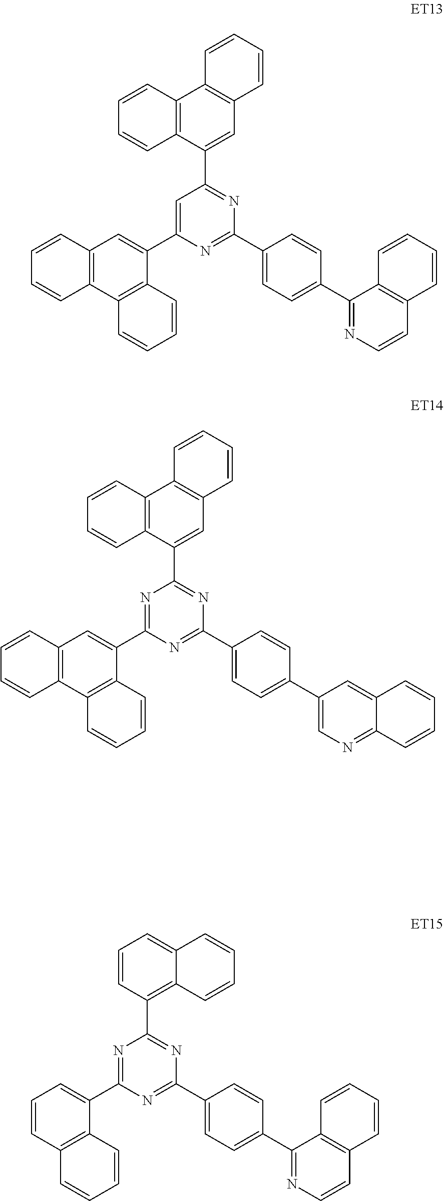 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3nc(-c4ccc(-c5nccc6ccccc56)cc4)nc(-c4cccc5ccccc45)n3)cccc2c1]

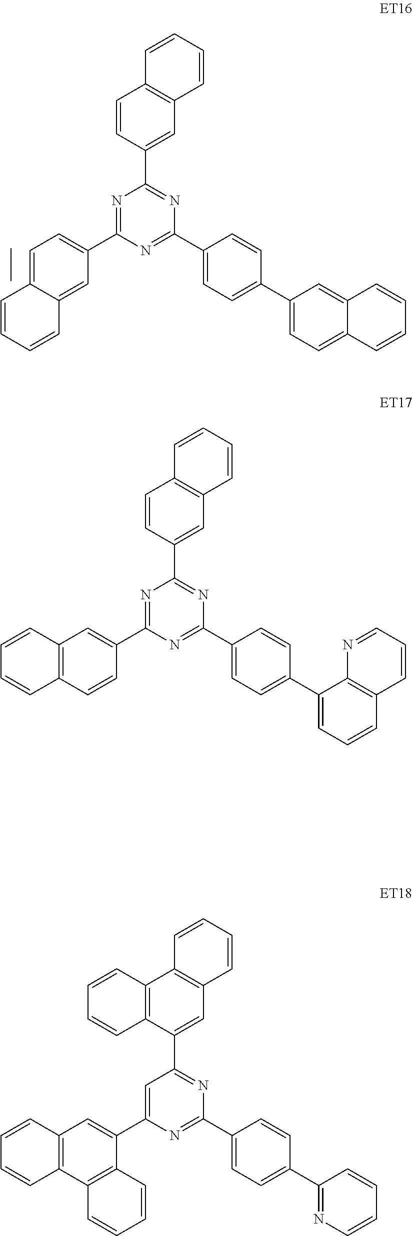

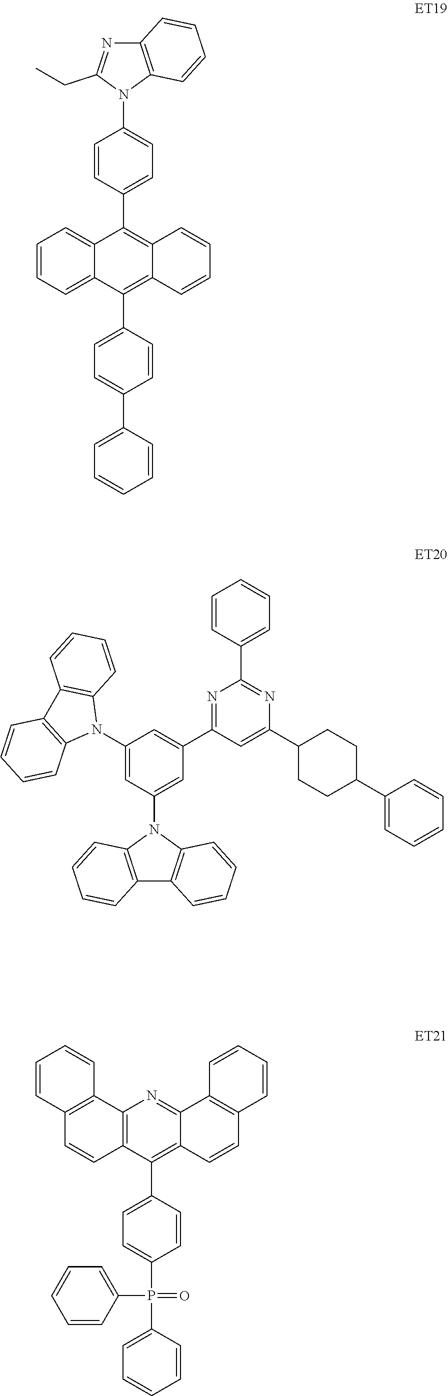 [SMILES: CCc1nc2ccccc2n1-c1ccc(-c2c3ccccc3c(-c3ccc(-c4ccccc4)cc3)c3ccccc23)cc1 ; c1ccc(-c2nc(-c3cc(-n4c5ccccc5c5ccccc54)cc(-n4c5ccccc5c5ccccc54)c3)cc(C3CCC(c4ccccc4)CC3)n2)cc1 ; O=P(c1ccccc1)(c1ccccc1)c1ccc(-c2c3ccc4ccccc4c3nc3c2ccc2ccccc23)cc1]

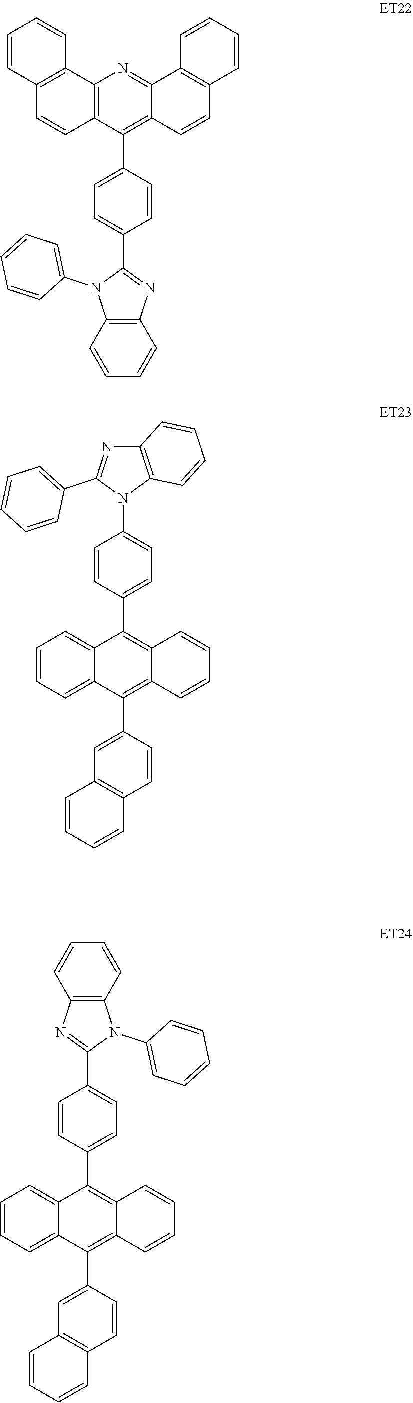 [SMILES: c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

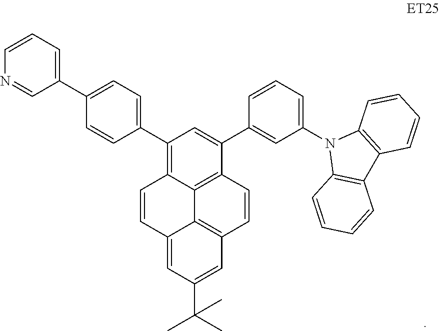 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in the range of about 100 Å to about 1,000 Å, for example, about 150 Å to about 500 Å. When the thickness of the electron transport layer is within the range described above, the electron transport layer may have satisfactory electron transporting characteristics without a substantial increase in driving voltage.

The electron transport layer may include a metal-containing material in addition to the material as described above.

The metal-containing material may include a Li complex. The Li complex may include, for example, Compound ET-D1 or ET-D2:

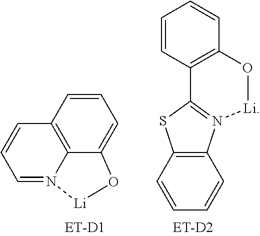

The electron transport region may include an electron injection layer that promotes the flow of electrons from the second electrode 19 thereinto.

The electron injection layer may include LiF, NaCl, CsF, Li₂O, BaO, or a combination thereof.

A thickness of the electron injection layer may be in a range of about 1 Å to about 100 Å, and, for example, about 3 Å to about 90 Å. When the thickness of the electron injection layer is within the range described above, the electron injection layer may have satisfactory electron injection characteristics without a substantial increase in driving voltage.

The second electrode 19 may be located on the organic layer 15. The second electrode 19 may be a cathode. A material for forming the second electrode 19 may be metal, an alloy, an electrically conductive compound, or a combination thereof, which have a relatively low workfunction. For example, lithium (Li), magnesium (Mg), silver (Ag), aluminum (Al), aluminum-lithium (Al—Li), calcium (Ca), magnesium-indium (Mg—In), or magnesium-silver (Mg—Ag) may be used as the material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIGURE, but embodiments of the present disclosure are not limited thereto.

According to another aspect, the organic light-emitting device may be included in an electronic apparatus. Thus, another aspect provides an electronic apparatus including the organic light-emitting device. The electronic apparatus may include, for example, a display, an illumination, a sensor, and the like.

Another aspect provides a diagnostic composition including at least one organometallic compound represented by Formula 1.

The organometallic compound represented by Formula 1 provides high luminescence efficiency. Accordingly, a diagnostic composition including the organometallic compound may have high diagnostic efficiency.

The diagnostic composition may be used in various applications including a diagnosis kit, a diagnosis reagent, a biosensor, and a biomarker.

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof.

For example, Formula 9-33 is a branched C₆ alkyl group, for example, a tert-butyl group that is substituted with two methyl groups.

The term “C₁-C₆₀ alkoxy group” used herein refers to a monovalent group represented by —OA₁₀₁ (wherein A₁₀₁ is the C₁-C₆₀ alkyl group), and examples thereof are a methoxy group, an ethoxy group, a propoxy group, a butoxy group, and a pentoxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the C₃-C₁₀ cycloalkylene group is a divalent group having the same structure as the C₃-C₁₀ cycloalkyl group.

Examples of the C₃-C₁₀ cycloalkyl group are a cyclopropyl group, a cyclobutyl group, a cyclopentyl, cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a saturated cyclic group that includes at least one heteroatom selected from N, O, P, Si, S, Se, Ge, and B as a ring-forming atom and 1 to 10 carbon atoms, and the C₁-C₁₀ heterocycloalkylene group refers to a divalent group having the same structure as the C₁-C₁₀ heterocycloalkyl group.

Examples of the C₁-C₁₀ heterocycloalkyl group are a silolanyl group, a silinanyl group, tetrahydrofuranyl group, a tetrahydro-2H-pyranyl group, and a tetrahydrothiophenyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group that has at least one heteroatom selected from N, O, P, Si, S, Se, Ge, and B as a ring-forming atom, 1 to 10 carbon atoms, and at least one carbon-carbon double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic ring system having 6 to 60 carbon atoms, and the term “C₆-C₆₀ arylene group” as used herein refers to a divalent group having a carbocyclic aromatic ring system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₇-C₆₀ alkyl aryl group” as used herein refers to a C₆-C₆₀ aryl group substituted with at least one C₁-C₆₀ alkyl group. The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group having at least one heteroatom selected from N, O, P, Si, S, Se, Ge, and B as a ring-forming atom of a cyclic aromatic ring system having 1 to 60 carbon atoms, and the term “C₁-C₆₀ heteroarylene group” as used herein refers to a divalent group having at least one heteroatom selected from N, O, P, Si, S, Se, Ge, and B as a ring-forming atom of a carbocyclic aromatic ring system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The term “C₂-C₆₀ alkylheteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein indicates —OA₁₀₂ (wherein A₁₀₂ indicates the C₆-C₆₀ aryl group). The term “C₆-C₆₀ arylthio group” as used herein indicates —SA₁₀₃ (wherein A₁₀₃ indicates the C₆-C₁₀ aryl group). The term “C₁-C₆₀ alkylthio group” as used herein indicates —SA₁₀₄ (wherein A₁₀₄ indicates the C₁-C₆₀ alkyl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as a monovalent non-aromatic condensed polycyclic group.

The term “monovalent non-aromatic condensed heteropolycyclic group” as used herein refers to a monovalent group (for example, having 1 to 60 carbon atoms) having two or more rings condensed to each other, a heteroatom selected from N, O, P, Si, S, Se, Ge, and B, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as a monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group. Examples of the “C₅-C₃₀ carbocyclic group (unsubstituted or substituted with at least one R₁₀ₐ)” are an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a fluorene group, each of which is unsubstituted or substituted with at least one R₁₀ₐ.

The term “C₁-C₃₀ heterocyclic group” as used herein refers to a saturated or unsaturated cyclic group having, as a ring-forming atom, at least one heteroatom selected from N, O, P, Si, Se, Ge, B, and S instead of carbon, and 1 to 30 carbon atoms. The C₁-C₃₀ heterocyclic group may be a monocyclic group or a polycyclic group. The “C₁-C₃₀ heterocyclic group (unsubstituted or substituted with at least one R₁₀ₐ)” may be, for example, a thiophene group, a furan group, a pyrrole group, a silole group, borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each of which is unsubstituted or substituted with at least one R₁₀ₐ.

The terms “fluorinated C₁-C₆₀ alkyl group (or a fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one fluoro group (—F). For example, the term “fluorinated C₁ alkyl group” (i.e., a fluorinated methyl group) includes —CF₃, —CF₂H, and —CFH₂. The terms “fluorinated C₁-C₆₀ alkyl group” or “a fluorinated C₁-C₂₀ alkyl group” or the like, “fluorinated C₃-C₁₀ cycloalkyl group”, “the fluorinated C₁-C₁₀ heterocycloalkyl group”, and “the fluorinated a phenyl group” may be i) a fully fluorinated C₁-C₆₀ alkyl group (or, a fully fluorinated C₁-C₂₀ alkyl group, or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or partially fluorinated phenyl group, wherein, in each group, all hydrogen included therein is not substituted with a fluoro group.

The terms “deuterated C₁-C₆₀ alkyl group (or a deuterated C₁-C₂₀ alkyl group or the like)”, “deuterated C₃-C₁₀ cycloalkyl group”, “deuterated C₁-C₁₀ heterocycloalkyl group,” and “deuterated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one deuterium. For example, the “deuterated C₁ alkyl group (that is, the deuterated methyl group)” may include —CD₃, —CD₂H, and —CDH₂, and examples of the “deuterated C₃-C₁₀ cycloalkyl group” are, for example, Formula 10-501 and the like. The “deuterated C₁-C₆₀ alkyl group (or, the deuterated C₁-C₂₀ alkyl group or the like)”, “the deuterated C₃-C₁₀ cycloalkyl group”, “the deuterated C₁-C₁₀ heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated C₁-C₁₀ heterocycloalkyl group, or a fully deuterated phenyl group, wherein, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated C₁-C₁₀ heterocycloalkyl group, or a partially deuterated phenyl group, wherein, in each group, all hydrogen included therein are not substituted with deuterium.

The term “(C₁-C₂₀ alkyl) ‘X’ group” as used herein refers to a ‘X’ group that is substituted with at least one C₁-C₂₀ alkyl group. For example, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of a (C₁ alkyl) phenyl group is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” as used herein respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” wherein, in each group, at least one carbon of ring-forming carbons is substituted with nitrogen.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may each independently be:

deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₁₀ alkylthio group, C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —B(Q₃₆)(Q₃₇), —P(═O)(Q₃₈)(Q₃₉), or —P(Q₃₈)(Q₃₉); or

a combination thereof.

Q₁ to Q₉, Q₁₁ to Q₁₉, Q₂₁ to Q₂₉, and Q₃₁ to Q₃₉ described herein may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group that is unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group that is unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉ and Q₃₁ to Q₃₉ described herein may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

Hereinafter, exemplary compounds and organic light-emitting devices according to one or more embodiments are described in further detail with reference to Synthesis Example and Examples. However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1 (Compound 202)

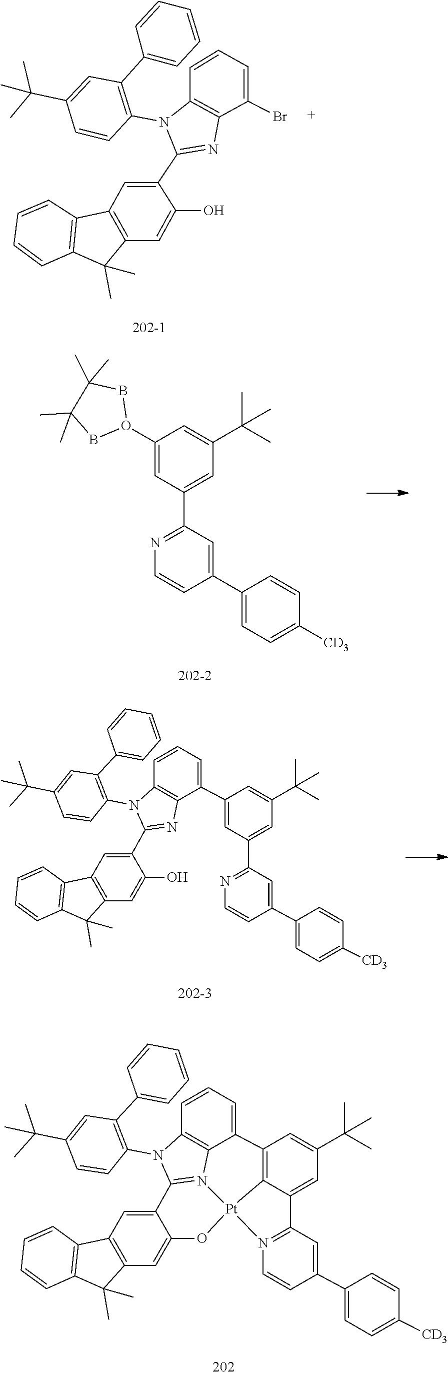

### Synthesis of Intermediate 202-3 (3-(4-(3-(tert-butyl)-5-(4-(4-(methyl-d3)phenyl)pyridin-2-yl)phenyl)-1-(5-(tert-butyl)-[1,1′-biphenyl]-2-yl)-1H-benzo[d]imidazol-2-yl)-9,9-dimethyl-9H-fluoren-2-ol)

2.0 grams (g) (0.003 moles (mol), 1.0 equivalents (equiv.)) of Intermediate 202-1 (3-(4-bromo-1-(5-(tert-butyl)-[1,1′-biphenyl]-2-yl)-1H-benzo[d]imidazol-2-yl)-9,9-dimethyl-9H-fluoren-2-ol), 1.5 g (0.004 mol, 1.1 equiv.) of Intermediate 202-2 (2-(3-(tert-butyl)-5-(4,4,5,5-tetramethyl-1,3,2-dioxaborolan-2-yl)phenyl)-4-(4-(methyl-d3)phenyl)pyridine), 0.26 g (0.00021 mol, 0.07 equiv.) of tetrakis(triphenylphosphine)palladium (0), and 1.4 g (0.010 mol, 3 equiv.) of potassium carbonate were mixed with 40 milliliters (mL) of a mixture wherein tetrahydrofuran (THF) and deionized water (DI water) were mixed at a volumetric ratio of 3:1, and then, heated at reflux for 12 hours. The obtained result was allowed to cool to room temperature, and then, the precipitate was removed therefrom to obtain a filtrate. The filtrate was washed with ethyl acetate (EA)/DI water, and column chromatography (EA and hexane (Hex) were used as eluents) was performed thereon to complete the purification of 2.3 g (yield of 84%) of Intermediate 202-3. The obtained material was identified through high resolution mass spectrometry (HRMS) using matrix assisted laser desorption ionization (MALDI) and HPLC analysis.

HRMS (MALDI) calcd for C₆₀H₅₂D₃N₃O: m/z 836.4533, Found: 836.4535.

### Synthesis of Compound 202

2.3 g (2.75 mmol) of Intermediate 202-3 and 1.37 g (3.30 mmol, 1.2 equiv.) of K₂PtCl₄ were mixed with 40 mL of a mixture in which 30 mL of AcOH (acetic acid) was mixed with 10 mL of DI water, and then, the resultant mixture was heated at reflux for 16 hours. The temperature of the resulting product was allowed to cool to room temperature, and then, the precipitate was filtered and then the obtained precipitate was dissolved in methylene chloride (MC) and washed with DI water, and then, column chromatography (10% to 35% MC, 65% to 90% Hex) was performed thereon to obtain 1.7 g (yield of 60%) of Compound 202. The obtained material was identified through HRMS and HPLC analysis.

HRMS (MALDI) calcd for C₆₀H₅₀D₃N₃OPt: m/z 1029.4025, Found: 1029.4028.

### Synthesis Example 2 (Compound 177)

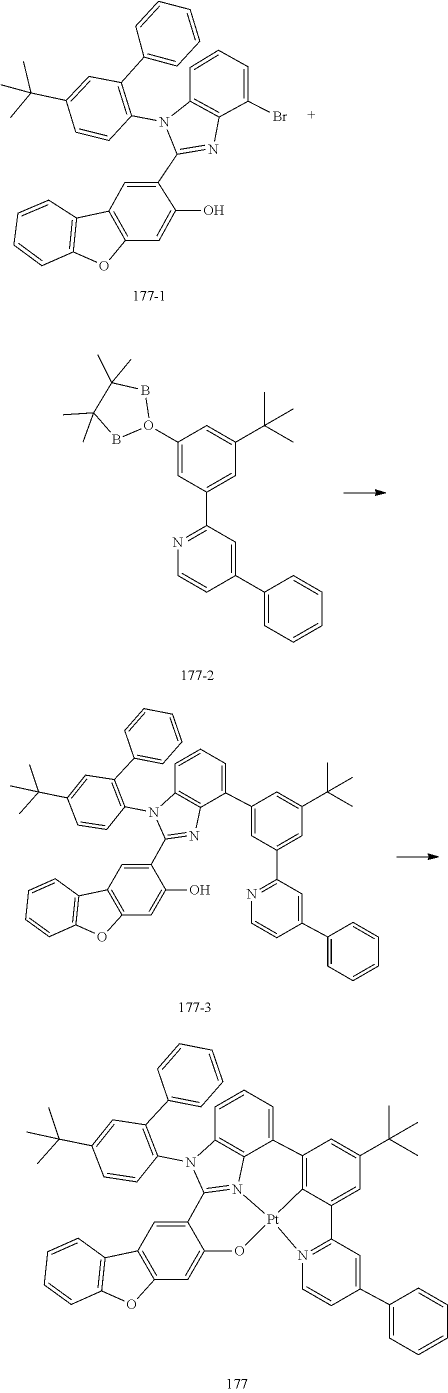

### Synthesis of Intermediate 177-3 (2-(4-(3-(tert-butyl)-5-(4-phenylpyridin-2-yl)phenyl)-1-(5-(tert-butyl)-[1,1′-biphenyl]-2-yl)-1H-benzo[d]imidazol-2-yl)dibenzo[b,d]furan-3-ol)

2.0 g (0.003 mol, 1.0 equiv.) of Intermediate 177-1 (2-(4-bromo-1-(5-(tert-butyl)-[1,1′-biphenyl]-2-yl)-1H-benzo[d]imidazol-2-yl)dibenzo[b,d]furan-3-ol), 1.55 g (0.004 mol, 1.1 equiv.) of Intermediate 177-2 (2-(3-(tert-butyl)-5-(4,4,5,5-tetramethyl-1,3,2-dioxaborolan-2-yl)phenyl)-4-phenylpyridine), 0.28 g (0.00021 mol, 0.07 equiv.) of tetrakis(triphenylphosphine)palladium (0), and 1.4 g (0.010 mol, 3 equiv.) of potassium carbonate were mixed with 40 mL of a mixture in which THF and DI water were mixed at a volumetric ratio of 3:1, and then, heated at reflux for 12 hours. The obtained result was allowed to cool to room temperature, and then, the precipitate was removed under vacuum therefrom to obtain a filtrate. The filtrate was washed with EA/DI water, and column chromatography (EA and Hex were used as eluents) was performed thereon to complete the purification of 2.1 g (yield of 78%) of Intermediate 177-3. The obtained material was identified through HRMS and HPLC analysis.

HRMS (MALDI) calcd for C₅₆H₄₇N₃O₂: m/z 793.3668, Found: 793.3664.

### Synthesis of Compound 177

1.32 g (3.18 mmol, 1.2 equiv.) of Intermediate 177-3 and 2.1 g (2.65 mmol) of K₂PtCl₄ was mixed with 40 mL of a mixture in which 30 mL of AcOH was mixed with 10 mL of DI water, and then, the resultant mixture was heated at reflux for 16 hours. The temperature of the resulting product was allowed to cool to room temperature, and then, the resulting precipitate was filtered and then the obtained precipitate was dissolved in MC and washed with H₂O, and then, column chromatography (10% to 35% MC, 65% to 90% Hex) was performed thereon to obtain 1.5 g (yield of 57%) of Compound 177. The obtained material was identified through HRMS and HPLC analysis.

HRMS (MALDI) calcd for C₅₆H₄₅N₃O₂Pt: m/z 986.3160, Found: 986.3162.

### Synthesis Example 3 (Compound 225)

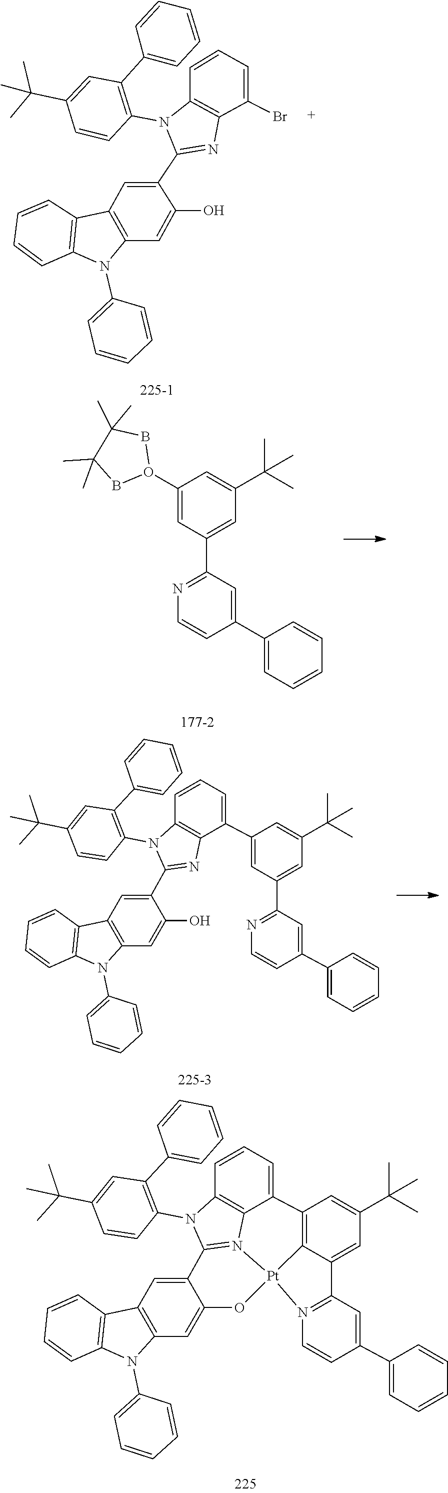

### Synthesis of Intermediate 225-3 (3-(4-(3-(tert-butyl)-5-(4-phenylpyridin-2-yl)phenyl)-1-(5-(tert-butyl)-[1,1′-biphenyl]-2-yl)-1H-benzo[d]imidazol-2-yl)-9-phenyl-9H-carbazol-2-ol)

2.0 g (0.003 mol, 1.0 equiv.) of Intermediate 225-1 (3-(4-bromo-1-(5-(tert-butyl)-[1,1′-biphenyl]-2-yl)-1H-benzo[d]imidazol-2-yl)-9-phenyl-9H-carbazol-2-ol), 1.37 g (0.003 mol, 1.0 equiv.) of Intermediate 177-2, 0.24 g (0.00021 mol, 0.07 equiv.) of tetrakis(triphenylphosphine)palladium (0), and 1.3 g (0.010 mol, 3 equiv.) of potassium carbonate were mixed with 40 mL of a mixture in which THF and DI water were mixed at a volumetric ratio of 3:1, and then, heated at reflux for 12 hours. The obtained result was allowed to cool to room temperature, and then, the resulting precipitate was removed therefrom to obtain a filtrate. The filtrate was washed with EA/DI water, and column chromatography (EA and Hex were used as eluents) was performed thereon to complete the purification of 2.1 g (yield of 80%) of Intermediate 225-3. The obtained material was identified through HRMS and HPLC analysis.

HRMS (MALDI) calcd for C₆₂H₅₂N₄O: m/z 868.4141, Found: 868.4143 Synthesis of Compound 225

2.1 g (2.42 mmol) of Intermediate 225-3 and 1.2 g (2.90 mmol, 1.2 equiv.) of K₂PtCl₄ was mixed with 40 mL of a mixture in which 30 mL of AcOH was mixed with 10 mL of DI water, and then, the resultant mixture was heated at reflux for 16 hours. The temperature of the resulting product was allowed to cool to room temperature, and then, the resulting precipitate was filtered and then the obtained precipitate was dissolved in MC and washed with DI water, and then, column chromatography (10% to 35% MC, 65% to 90% Hex) was performed thereon to obtain 1.3 g (yield of 51%) of Compound 225. The obtained material was identified through HRMS and HPLC analysis.

HRMS (MALDI) calcd for C₆₂H₅₀N₄OPt: m/z 1061.3632, Found: 1061.3635.

### Synthesis Example 4 (Compound 17)

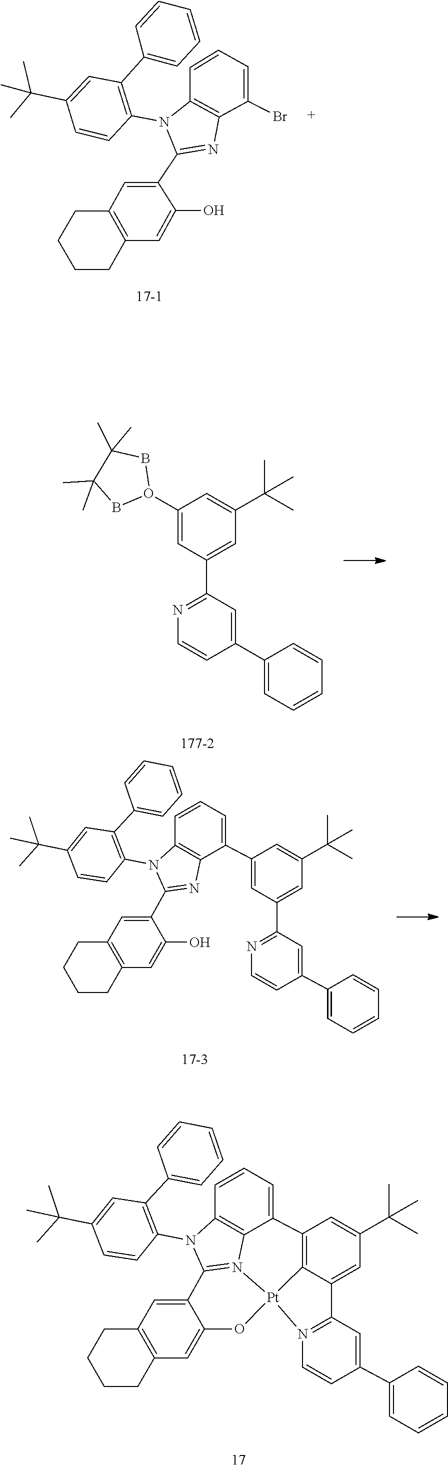

### Synthesis of Intermediate 17-3 (3-(4-(3-(tert-butyl)-5-(4-phenylpyridin-2-yl)phenyl)-1-(5-(tert-butyl)-[1,1′-biphenyl]-2-yl)-1H-benzo[d]imidazol-2-yl)-5,6,7,8-tetrahydronaphthalen-2-ol)

Intermediate 17-3 (1.8 g, yield of 78%) was synthesized in a similar manner as used to obtain Intermediate 177-3 of the Synthesis Example 2, except that Intermediate 17-1 ((3-(4-bromo-1-(5-(tert-butyl)-[1,1′-biphenyl]-2-yl)-1H-benzo[d]imidazol-2-yl)-5,6,7,8-tetrahydronaphthalen-2-ol) was used instead of Intermediate 177-1. The obtained material was identified through HRMS and HPLC analysis.

HRMS (MALDI) calcd for C₅₄H₅₁N₃O: m/z 757.4032, Found: 757.4033.

### Synthesis of Compound 17

Compound 17 (1.4 g, yield of 56%) was synthesized in a similar manner as used to obtain Compound 177 of Synthesis Example 2, except that Intermediate 17-3 was used instead of Intermediate 177-3. The obtained material was identified through HRMS and HPLC analysis.

HRMS (MALDI) calcd for C₅₄H₄₉N₃OPt: m/z 950.3523, Found: 950.3521.

### Synthesis Example 5 (Compound 69)

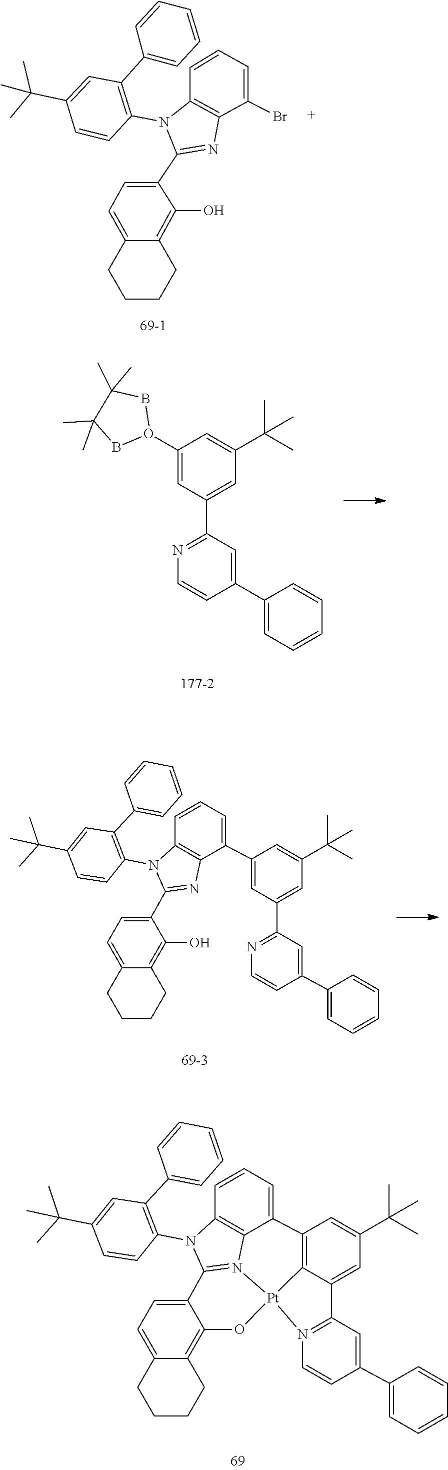

### Synthesis of Intermediate 69-3 (2-(4-(3-(tert-butyl)-5-(4-phenylpyridin-2-yl)phenyl)-1-(5-(tert-butyl)-[1,1′-biphenyl]-2-yl)-1H-benzo[d]imidazol-2-yl)-5,6,7,8-tetrahydronaphthalen-1-ol)

Intermediate 69-3 (1.6 g, yield of 81%) was synthesized in a similar manner as used to obtain Intermediate 177-3 of Synthesis Example 2, except that Intermediate 69-1 (2-(4-bromo-1-(5-(tert-butyl)-[1,1′-biphenyl]-2-yl)-1H-benzo[d]imidazol-2-yl)-5,6,7,8-tetrahydronaphthalen-1-ol) was used instead of Intermediate 177-1. The obtained material was identified through HRMS and HPLC analysis.

HRMS (MALDI) calcd for C₅₄H₅₁N₃O: m/z 757.4032, Found: 757.4031.

### Synthesis of Compound 69

Compound 69 (1.2 g, yield of 54%) was synthesized in a similar manner as used to obtain Compound 177 of Synthesis Example 2, except that Intermediate 69-3 was used instead of Intermediate 177-3. The obtained material was identified through HRMS and HPLC analysis.

HRMS (MALDI) calcd for C₅₄H₄₉N₃OPt: m/z 950.3523, Found: 950.3525.

### Synthesis Example 6 (Compound 154)

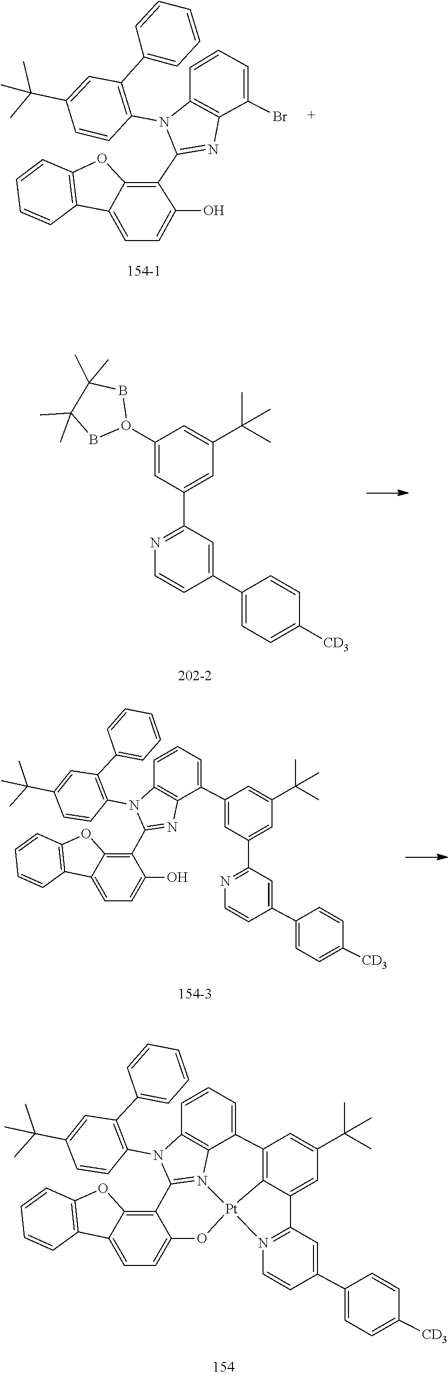

### Synthesis of Intermediate 154-3 (4-(4-(3-(tert-butyl)-5-(4-phenylpyridin-2-yl)phenyl)-1-(5-(tert-butyl)-[1,1′-biphenyl]-2-yl)-1H-benzo[d]imidazol-2-yl)dibenzo[b,d]furan-3-ol)

Intermediate 154-3 (2.1 g, yield of 83%) was synthesized in a similar manner as used to obtain Intermediate 202-3 of Synthesis Example 1, except that Intermediate 154-1 (4-(4-bromo-1-(5-(tert-butyl)-[1,1′-biphenyl]-2-yl)-1H-benzo[d]imidazol-2-yl)dibenzo[b,d]furan-3-ol) was used instead of Intermediate 202-1. The obtained material was identified through HRMS and HPLC analysis.

HRMS (MALDI) calcd for C₅₆H₄₇N₃O₂: m/z 793.3668, Found: 793.3669.

### Synthesis of Compound 154

Compound 154 (1.5 g, yield of 53%) was synthesized in a similar manner as used to obtain Compound 202 of Synthesis Example 1, except that Intermediate 154-3 (2.11 mmol) was used instead of Intermediate 202-3. The obtained material was identified through HRMS and HPLC analysis.

HRMS (MALDI) calcd for C₅₇H₄₄D3N₃₀₂Pt: m/z 1003.3504, Found: 1003.3507.

### Synthesis Example 7 (Compound 796)

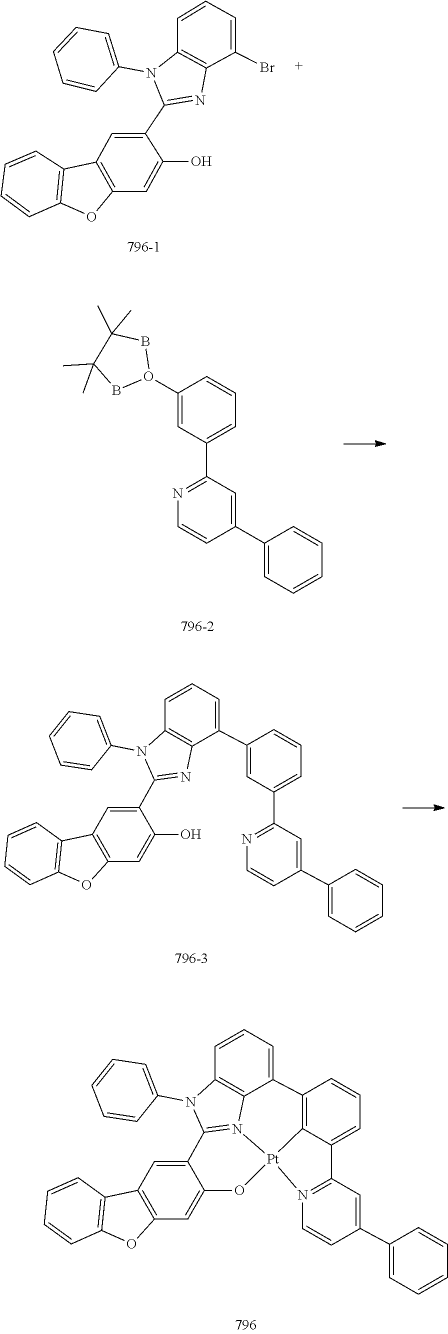

### Synthesis of Intermediate 796-3

Intermediate 796-3 (2.34 g, yield of 88%) was synthesized in a similar manner as used to obtain Intermediate 202-3 of Synthesis Example 1, except that Intermediate 796-1 and Intermediate 796-2 were used instead of Intermediate 202-1 and Intermediate 202-2, respectively. The obtained material was identified through HRMS and HPLC analysis.

HRMS (MALDI) calcd for C₄₂H₂₇N₃O₂: m/z 605.2103, Found: 605.2105.

### Synthesis of Compound 796

Compound 796 (1.20 g, yield of 39%) was synthesized in a similar manner as used to obtain Compound 202 of Synthesis Example 1, except that Intermediate 796-3 was used instead of Intermediate 202-3. The obtained material was identified through HRMS and HPLC analysis.

HRMS (MALDI) calcd for C₄₂H₂₅N₃O₂Pt: m/z 798.1595, Found: 798.1596.

### Synthesis Example 8 (Compound 3)

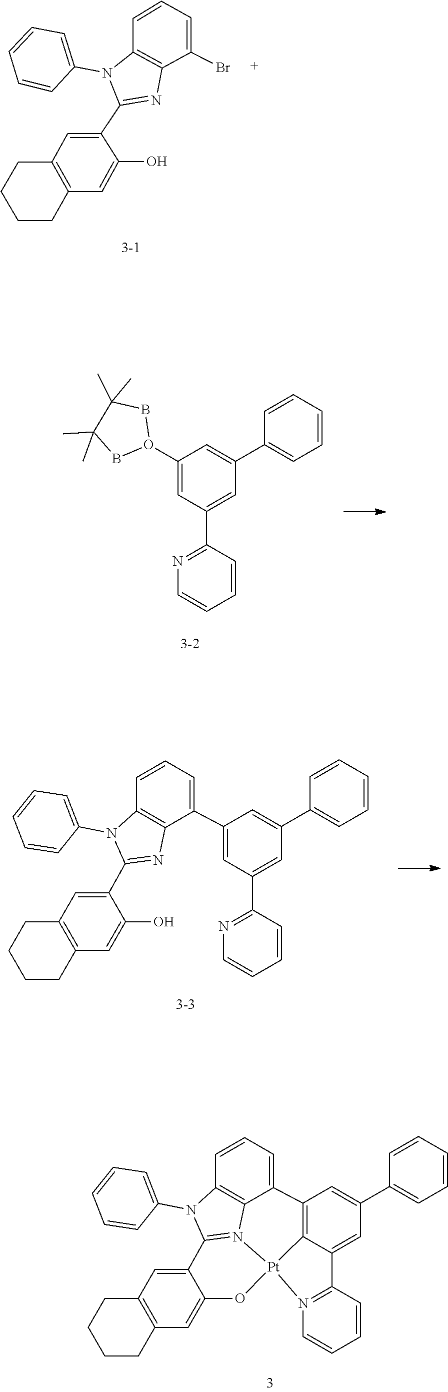

### Synthesis of Intermediate 3-3

Intermediate 3-3 (2.42 g, yield of 89%) was synthesized in a similar manner as used to obtain Intermediate 202-3 of Synthesis Example 1, except that Intermediate 3-1 and Intermediate 3-2 were used instead of Intermediate 202-1 and Intermediate 202-2, respectively. The obtained material was identified through HRMS and HPLC analysis.

HRMS (MALDI) calcd for C₄₀H₃₁N₃O: m/z 569.2467, Found: 569.2465.

### Synthesis of Compound 3

Compound 3 (1.36 g, yield of 42%) was synthesized in a similar manner as used to obtain Compound 202 of Synthesis Example 1, except that Intermediate 3-3 was used instead of Intermediate 202-3. The obtained material was identified through HRMS and HPLC analysis.

HRMS (MALDI) calcd for C₄₀H₂₉N₃OPt: m/z 762.1958, Found: 762.1955.

### Synthesis Example 9 (Compound 797)

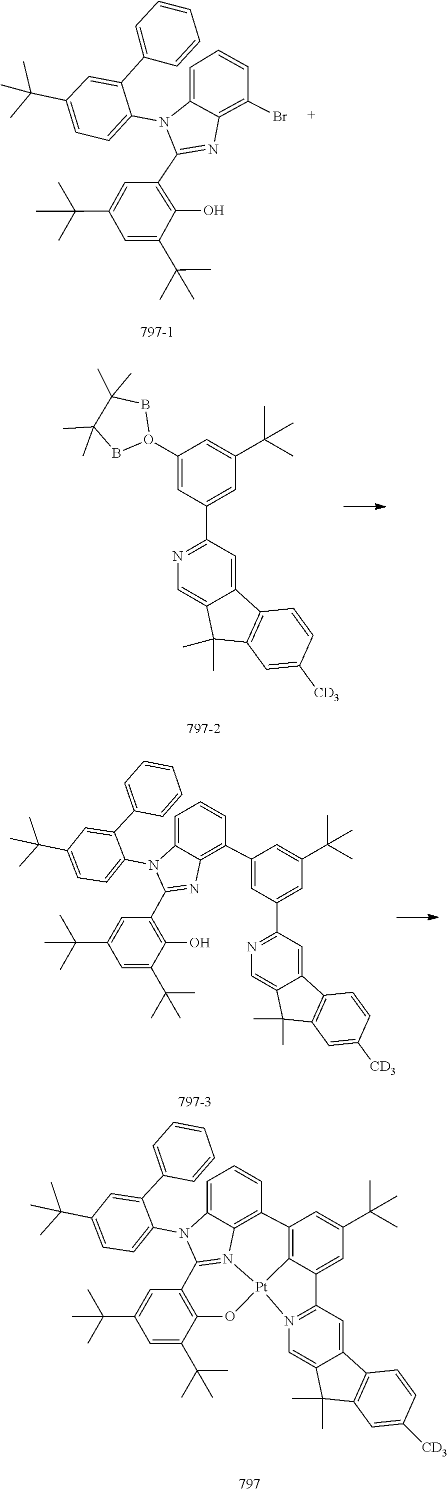

### Synthesis of Intermediate 797-3

Intermediate 797-3 was synthesized in a similar manner as used to obtain Intermediate 202-3 of Synthesis Example 1, except that Intermediate 797-1 and Intermediate 797-2 were used instead of Intermediate 202-1 and Intermediate 202-2, respectively. The obtained material was identified through HRMS and HPLC analysis.

### Synthesis of Compound 797

Compound 797 (1.0 g, yield of 48%) was synthesized in a similar manner as used to obtain Compound 202 of Synthesis Example 1, except that Intermediate 797-3 was used instead of Intermediate 202-3. The obtained material was identified through HRMS and HPLC analysis.

HRMS (MALDI) calcd for C₆₂H₆₂D₃N₃OPt: m/z 1065.4964, Found: 1065.4967.

### Evaluation Example 1: Evaluation of Luminescence Quantum Efficiency (PLQY) and Radiative Decay Rate

CBP and Compound 202 were co-deposited at a vacuum of 10⁻⁷ torr at a weight ratio of 9:1 to produce a film with a thickness of 40 nanometers (nm).

The PLQY of the film was evaluated by using a Hamamatsu Photonics absolute PL quantum yield measurement system equipped with a xenon light source, a monochromator, a photonic multichannel analyzer, and an integrating sphere, and using PLQY measurement software (Hamamatsu Photonics, Ltd., Shizuoka, Japan) to identify the PLQY in film of Compound 202. Results thereof are shown in Table 2.

Next, the PL spectrum of the film was evaluated at room temperature using FluoTime 300, a TRPL measurement system of PicoQuant, and PLS340, a pumping source of PicoQuant (excitation wavelength=340 nanometers, spectral width=20 nanometers), and then, the wavelength of the main peak of the spectrum was determined.

Then, the number of photons emitted from the film at the wavelength of the main peak by the photon pulse (pulse width=500 picosecond) which was applied to the film by the PLS340, was repeatedly measured over time based on time-correlated single photon counting (TCSPC), so as to obtain a TRPL curve that was sufficiently suitable for fitting.

The obtained result was fitted with one or more exponential decay functions to obtain T_{decay} (Ex), that is, the decay time of the film, and then the radiative decay rate thereof, which is the inverse value thereof, was calculated. Results obtained therefrom were shown in Table 2. A function for fitting is as shown in Equation 20, and from among T_{decay} values obtained from each exponential decay function used for fitting, the largest T_{decay} was obtained as T_{decay} (Ex). In this regard, the same measurement was performed during the same measurement time as that for obtaining TRPL curve in the dark state (in which pumping signals entering a film are blocked) to obtain a baseline or a background signal curve for use as a baseline for fitting.

$$f ( t ) = {\sum }_{i = 1}^{n} {A}_{i} exp ( - t \text{/} {T}_{decay , i} ) \qquad Equation 20$$

The PLQY and radiative decay rate measurements were performed for Compounds 177, 225, 17, 69, 154, 796, 3, and 797 and results thereof are shown in Table 2.

TABLE 2

| Compound No. | PLQY | Radiative decay rate (s⁻¹) |
|---|---|---|
| 202 | 0.999 | 2.87 ± 10⁵ |
| 177 | 0.999 | 3.11 ± 10⁵ |
| 225 | 0.943 | 2.95 ± 10⁵ |
| 17 | 0.999 | 3.92 ± 10⁵ |
| 69 | 0.997 | 3.81 ± 10⁵ |
| 154 | 0.999 | 8.16 ± 10⁴ |
| 796 | 0.997 | 3.30 ± 10⁵ |
| 3 | 0.999 | 3.83 ± 10⁵ |
| 797 | 0.951 | 2.97 ± 10⁵ |

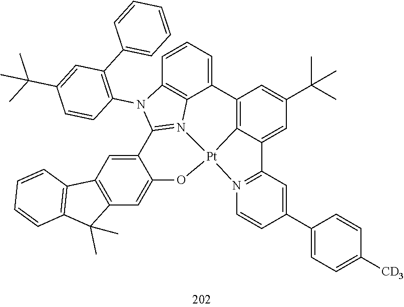

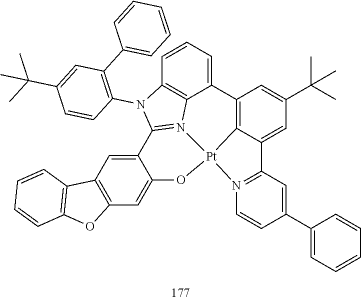

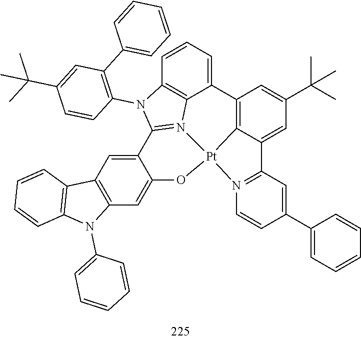

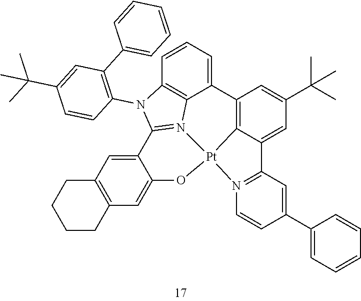

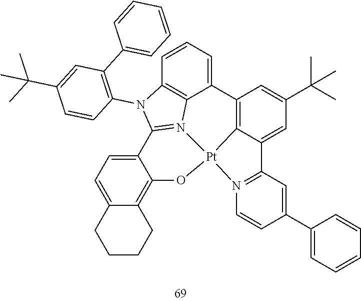

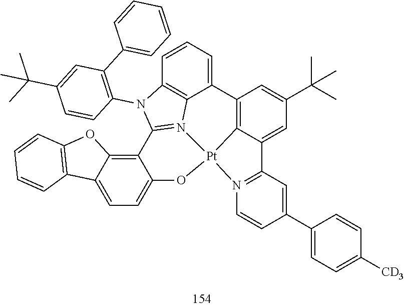

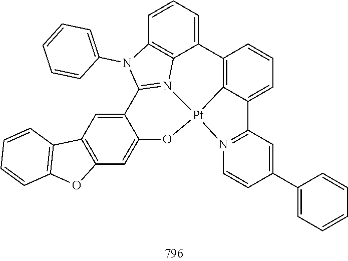

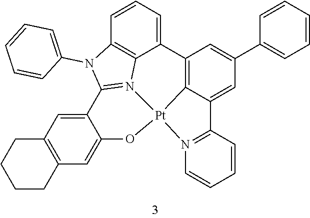

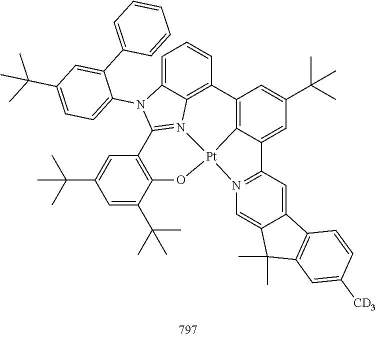

From Table 2, it can be seen that Compounds 202, 177, 225, 17, 69, 154, 796, 3, and 797 have high PLQY and high radiative decay rates.

### Evaluation Example 2: Evaluation of Horizontal Orientation Ratio

In a vacuum deposition apparatus having a vacuum degree of 1×10⁻⁷ torr, mCP and Compound 202 were co-deposited on a fused silica base layer (thickness of 1 mm) at a weight ratio of 92:8 to form Sample 1 having a thickness of 30 nm, followed by sealing using glass and glue under a nitrogen atmosphere. This experiment was repeated for each of the compounds shown in Table 3 below to prepare Samples 2 to 7.

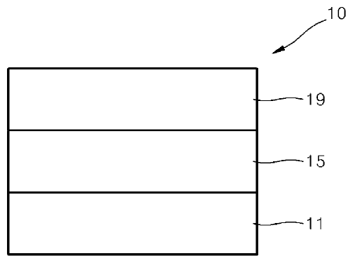

Meanwhile, an angle-dependent PL measurement apparatus having the same structure as that shown in FIG. 3 of Korean Patent Application Publication No. 2013-0150834 was prepared. Detailed specifications are as follows:
Excitation-light wavelength: 325 nm
Source of excitation-light: He—Cd laser of Melles Griot Inc.
Excitation-light irradiation member: optical fiber having a diameter of 1 mm of Thorlabs Inc.
Semi-cylindrical prism: a fused silica having a diameter of 100 mm and a length of 30 mm
Emitted-light detection member: photomultiplier tube of Acton Inc.
Polarizer mounted on emitted-light detection member: linear polarizer of Thorlabs Inc.
Recorder: SpectraSense of Acton Inc.
Incidence angle of excitation light: θP=45°, θH=0°
Distance from a sample to the emitted-light detection member (or a radius of a movement path of the emitted-light detection member): 900 mm

Subsequently, Samples 1 to 7 were fixed on a semi-cylindrical lens and irradiated with 325 nm laser excitation to emit light. The emitted light was allowed to pass through a polarization film, and then, in order to measure a p-polarized photoluminescence intensity with respect to light having the wavelength of 530 nm in a range of 90 degree to 0 degree, the semi-cylindrical lens, on which the sample was fixed, was rotated by 1 degree with respect to an axis of the semi-cylindrical lens by using a charge-coupled device (CCD).

The p-polarized photoluminescence intensity (a first p-polarized photoluminescence intensity) in a case where each compound is vertically aligned and the p-polarized photoluminescence intensity (a second p-polarized photoluminescence intensity) in a case where each compound is horizontally aligned were each calculated within a range of 0 degree to 90 degrees. A weight value at which the p-polarized photoluminescence intensity obtained by multiplying the first p-polarized photoluminescence intensity and the second p-polarized photoluminescence intensity by a weight value matches with found p-polarization photoluminescence intensity, was obtained. Then, the horizontal orientation ratio of each compound shown in Table 3 was measured and results thereof are shown in Table 3. Here, the angle-dependent photoluminescence spectrum was analyzed using a classical dipole model which regards light emitted from excitons as dissipated power consumed by an oscillating dipole.

TABLE 3

| | | Horizontal orientation |
|---|---|---|
| Sample No. | Co-deposition material | ratio (%) |
| 1 | mCP:Compound 202 (8 wt %) | 86 |
| 2 | mCP:Compound 177 (8 wt %) | 86 |
| 3 | mCP:Compound 225 (8 wt %) | 86 |
| 4 | mCP:Compound 17 (8 wt %) | 87 |
| 5 | mCP:Compound 69 (8 wt %) | 86 |
| 6 | mCP:Compound 154 (8 wt %) | 89 |
| 7 | mCP:Compound 797 (8 wt %) | 90 |

From Table 3, it can be seen that Compounds 202, 177, 225, 17, 69, 154, and 797 have an excellent horizontal orientation ratio, that is, optical orientation in the horizontal direction.

### Example 1

As an anode, a glass substrate with ITO/Ag/ITO (70 Å/1000 Å/70 Å) deposited thereon was cut to a size of 50 mm×50 mm×0.7 mm, sonicated with isopropyl alcohol and pure water each for 5 minutes, and then cleaned by exposure to ultraviolet rays and ozone for 30 minutes. The ITO glass substrate was provided to a vacuum deposition apparatus.

2-TNATA was vacuum-deposited on the anode on the substrate to form a hole injection layer having a thickness of 600 Å, and 4,4′-bis[N-(1-naphthyl)-N-phenylamino]biphenyl (NPB) was vacuum-deposited on the hole injection layer to form a hole transport layer having a thickness of 1350 Å.

Subsequentially, CBP (host) and Compound 202 (dopant) were co-deposited at a weight ratio of 94:6 on the hole transport layer to form an emission layer having a thickness of 400 Å.

Subsequently, BCP was deposited on the emission layer to form a hole-blocking layer having a thickness of 50 Å, Alq₃ was vacuum-deposited on the hole-blocking layer to form an electron transport layer having a thickness of 350 Å, LiF was deposited on the electron transport layer to form an electron injection layer having a thickness of 10 Å, and Mg and Ag were vacuum deposited at the weight ratio of 90:10 on the electron injection layer to form a cathode having a thickness of 120 Å, thereby completing manufacturing of an organic light-emitting device having a structure of anode/2-TNATA (600 Å)/NPB (1350 Å)/CBP+Compound 202 (6 wt %) (400 Å)/BCP(50 Å)/Alq₃(350 Å)/LiF(10 Å)/MgAg(120 Å).

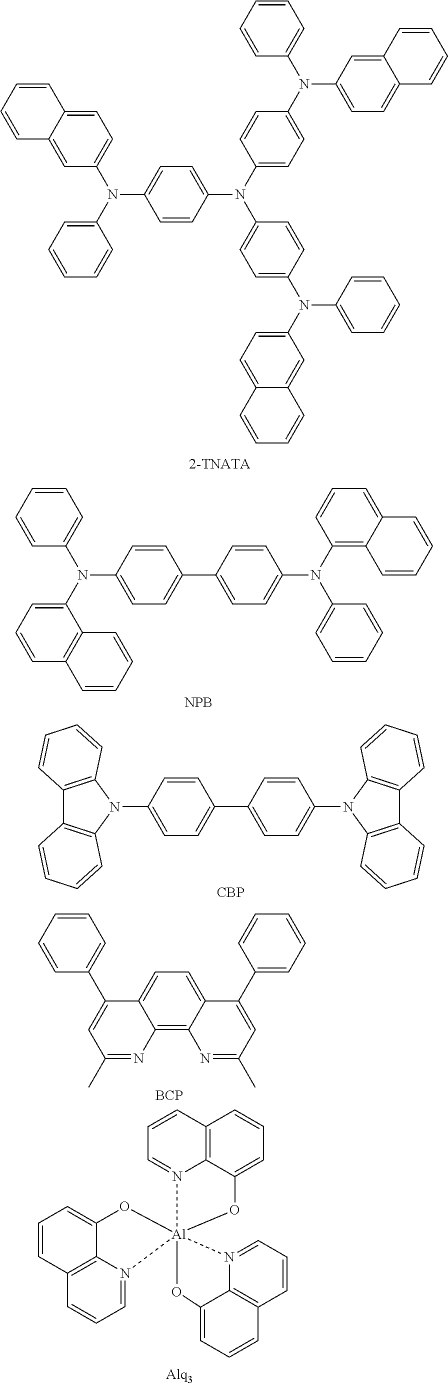

### Examples 2 to 7

Organic light-emitting devices were manufactured in a similar manner as in Example 1, except that the compounds shown in Table 4 were each used instead of Compound 202 as a dopant in forming an emission layer.

### Evaluation Example 3: Evaluation on Characteristics of Organic Light-Emitting Devices

The driving voltage (volts, V), current density (milliamperes per square centimeter, mA/cm²), maximum external quantum efficiency (EQE, %), roll-off ratio (%), FWHM (nm), the peak emission wavelength (λₘₐₓ, nm), and lifespan (LT₉₉, %) of the organic light-emitting devices manufactured in Examples 1 to 7 were evaluated, and results thereof are shown in Tables 4 and 5. The roll-off ratio was calculated by Equation 30. Lifespan (LT₉₉, at 6000 candela per square meter (cd/m², or nits)) is a measure of the hour at which luminance becomes 99% of the initial luminance, which is 100%. The maximum EQE and the lifespan were described as a relative value (%).

Roll off ratio={1−(luminescence efficiency (at 6000 cd/m²)/maximum luminescence efficiency)}×100% Equation 30

TABLE 4

| | | | | Maximum | | |
|---|---|---|---|---|---|---|
| | Dopant | Driving | Current | EQE | Roll-off | |
| | Compound | Voltage | Density | (Relative | ratio | FWHM |
| | No. | (V) | (mA/cm²) | value, %) | (%) | (nm) |
| Example 1 | 202 | 4.18 | 10 | 113 | 10 | 67 |
| Example 2 | 177 | 3.70 | 10 | 107 | 8 | 64 |
| Example 3 | 225 | 4.36 | 10 | 109 | 10 | 67 |
| Example 4 | 17 | 3.87 | 10 | 118 | 8 | 68 |
| Example 5 | 69 | 3.81 | 10 | 114 | 10 | 69 |
| Example 6 | 154 | 4.11 | 10 | 119 | 30 | 56 |
| Example 7 | 797 | 3.96 | 10 | 110 | 7 | 56 |

TABLE 5

| | Dopant | Peak emission | Lifespan (LT₉₉) |
|---|---|---|---|
| | Compound | wavelength | (at 6000 cd/m²) |
| | No. | (nm) | (Relative value, %) |
| Example 1 | 202 | 524 | 105 |
| Example 2 | 177 | 522 | 103 |
| Example 3 | 225 | 531 | 63 |
| Example 4 | 17 | 525 | 97 |
| Example 5 | 69 | 524 | 95 |
| Example 6 | 154 | 569 | 113 |
| Example 7 | 797 | 516 | 87 |

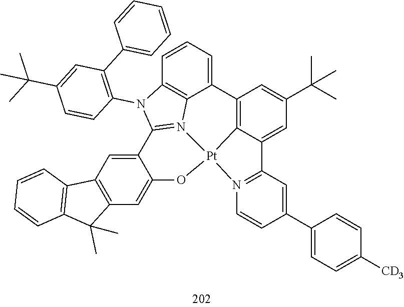

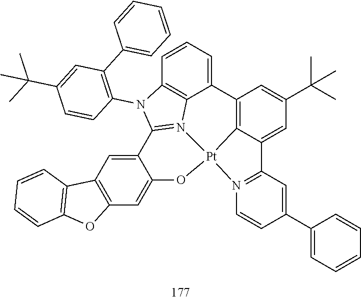

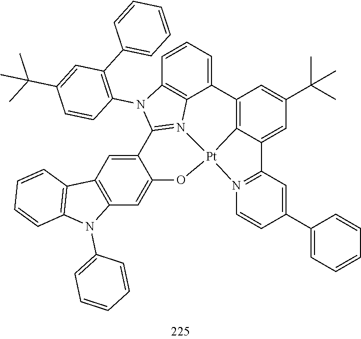

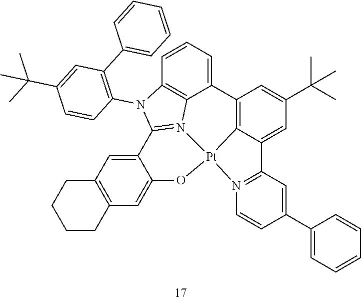

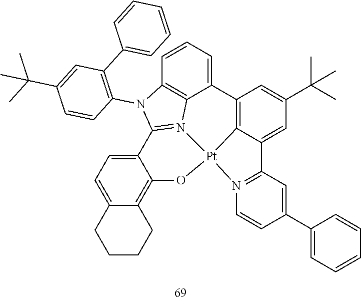

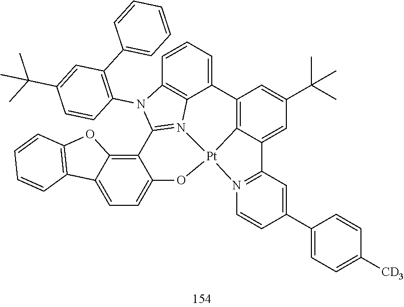

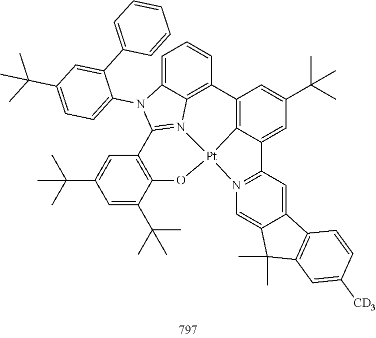

From Tables 4 and 5, it can be seen that the organic light-emitting devices of Examples 1 to 7 have excellent driving voltage, excellent EQE, excellent roll-off ratio, excellent lifespan characteristics, and relatively small FWHM.

### Example 8, Comparative Example A1 and Comparative Example A3

Organic light-emitting devices were manufactured in a similar manner as in Example 1, except that the compounds shown in Tables 6 and 7 were each used instead of Compound 202 as a dopant in forming an emission layer.

### Evaluation Example 4: Evaluation on Characteristics of Organic Light-Emitting Devices

The driving voltage (V), current density (mA/cm²), maximum EQE (%), roll-off ratio (%), FWHM (nm), the peak emission wavelength (nm), and lifespan (%) of the organic light-emitting devices manufactured in Example 8, Comparative Example A1 and Comparative Example A3 were evaluated in a similar manner described in Evaluation Example 3, and results thereof are shown in Tables 6 and 7.

TABLE 6

| | | | Current | Maximum | | |
|---|---|---|---|---|---|---|
| | Dopant | Driving | Density | EQE | roll-off | |
| | Compound | Voltage | (mA/ | (Relative | ratio | FWHM |
| | No. | (V) | cm²) | value, %) | (%) | (nm) |
| Example 8 | 796 | 3.50 | 10 | 100 | 8 | 59.2 |
| Comparative | A1 | 4.10 | 10 | 102 | 8 | 68 |
| Example A1 | | | | | | |
| Comparative | A3 | 4.57 | 10 | 88 | 16 | 63 |
| Example A3 | | | | | | |

TABLE 7

| | Dopant | Peak emission | Lifespan (LT₉₉) |
|---|---|---|---|
| | Compound | wavelength | (at 6000 cd/m²) |
| | No. | (nm) | (Relative value, %) |
| Example 8 | 796 | 519 | 75 |
| Comparative | A1 | 516 | 27 |
| Example A1 | | | |
| Comparative | A3 | 520 | 17 |
| Example A3 | | | |

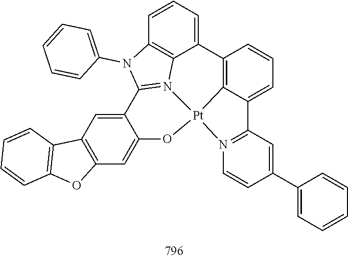

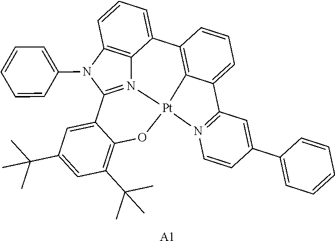

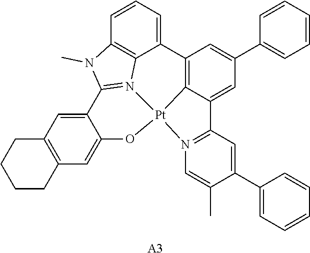

From Tables 6 and 7, it can be seen that the organic light-emitting device of Example 8 has excellent driving voltage, excellent or similar EQE, excellent roll-off ratio, and excellent lifespan characteristics, compared with the organic light-emitting devices of Comparative Examples A1 and A3.

### Example 9 and Comparative Example A2

Organic light-emitting devices were manufactured in a similar manner as in Example 1, except that the compounds shown in Tables 8 and 9 were each used instead of Compound 202 as a dopant in forming an emission layer.

### Evaluation Example 5: Evaluation on Characteristics of Organic Light-Emitting Devices

The driving voltage (V), current density (mA/cm²), maximum EQE (%), roll-off ratio (%), FWHM (nm), the peak emission wavelength (nm), and lifespan (%) of the organic light-emitting devices manufactured in Example 9 and Comparative Example A2 were evaluated in a similar manner described in Evaluation Example 3, and results thereof are shown in Tables 8 and 9, with results of Comparative Example A3.

TABLE 8

| | | | Current | Maximum | | |
|---|---|---|---|---|---|---|
| | Dopant | Driving | Density | EQE | roll-off | |
| | Compound | Voltage | (mA/ | (Relative | ratio | FWHM |
| | No. | (V) | cm²) | value, %) | (%) | (nm) |
| Example 9 | 3 | 4.35 | 10 | 89 | 16 | 62.6 |
| Comparative | A2 | 3.87 | 10 | 85 | 26 | 66 |
| Example A2 | | | | | | |
| Comparative | A3 | 4.57 | 10 | 88 | 16 | 63 |
| Example A3 | | | | | | |

TABLE 9

| | Dopant | Peak emission | Lifespan (LT₉₉) |
|---|---|---|---|
| | Compound | wavelength | (at 6000 nit) |
| | No. | (nm) | (Relative value, %) |
| Example 9 | 3 | 517 | 65 |
| Comparative | A2 | 519 | 39 |
| Example A2 | | | |
| Comparative | A3 | 520 | 17 |
| Example A3 | | | |

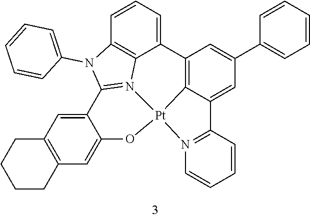

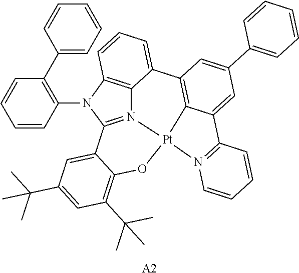

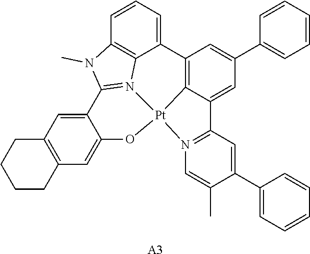

From Tables 8 and 9, it can be seen that the organic light-emitting device of Example 9 has excellent EQE, excellent roll-off ratio, and excellent lifespan characteristics, and relatively small FWHM, compared with the organic light-emitting devices of Comparative Examples A2 and A3.

The organometallic compound emits light with a relatively narrow FWHM, and has excellent EQE, excellent radiative decay rate, and excellent horizontal orientation ratio. Accordingly, since an organic light-emitting device using the organometallic compound may have improved characteristics in terms of driving voltage, external quantum efficiency, roll-off ratio and/or lifespan, and thus, a high-quality electronic apparatus can be manufactured by using the organometallic compound.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organometallic compound represented by Formula 1: 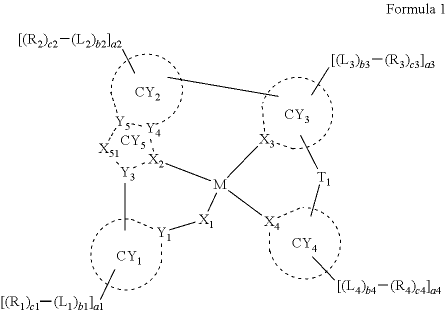
wherein, in Formula 1,
M is a transition metal,
X₁ is a chemical bond, O, S, N(R′), P(R′), B(R′), C(R′)(R″), or Si(R′)(R″), and when X₁ is a chemical bond, Y₁ is directly bonded to M,
X₂ to X₄ are each independently C or N,
a bond between X₁ or Y₁ and M is a covalent bond,
one of a bond between X₂ and M, a bond between X₃ and M, and a bond between X₄ and M is a covalent bond, and the other two bonds are coordinate bonds,
Y₁ and Y₃ to Y₅ are each independently C or N,
X₂ and Y₃ are connected to each other via a chemical bond, X₂ and Y₄ are connected to each other via a chemical bond, Y₄ and Y₅ are connected to each other via a chemical bond, X₅₁ and Y₃ are connected to each other via a chemical bond, and X₅₁ and Y₅ are connected to each other via a chemical bond,
ring CY₁ to ring CY₄ are each independently a C₅-C₃₀ carbocyclic group or a C₁-C₃₀ heterocyclic group, and at least one of ring CY₁ to ring CY₄ are each independently a condensed cyclic group wherein two or more rings are condensed with each other,
a cyclometallated ring formed between ring CY₅, ring CY₂, ring CY₃, and M is a 6-membered ring,
T₁ is a single bond, a double bond, *—N(R₅)—*′, *—B(R₅)—*′, *—P(R₅)—*′, *—C(R₅)(R₆)—*, *—Si(R₅)(R₆)—*′, *—Ge(R₅)(R₆)—*′, *—S—*′, *—Se—*′, *—O—*′, *—C(═O)—*′, *—S(═O)—*′, *—S(═O)₂—*, *—C(R₅)=*′, *═C(R₅)—*′, *—C(R₅)═C(R₆)—*′, *—C(═S)—*′, or *—C≡C—*′, and each of * and *′ is a binding site to a neighboring atom,
X₅₁ is N-[(L₇)_{b7}-(R₇)_{c7}], L₁ to L₄ and L₇ are each independently a single bond, a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
b1 to b4 and b7 are each independently 1, 2, 3, 4, or 5,
R₁ to R₇, R′, and R″ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
c1 to c4 and c7 are each independently 1, 2, 3, 4, or 5,
at least one of R₇ in number of c7 is a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,
a1 to a4 are each independently 0, 1, 2, 3, 4, or 5,
two or more of a plurality of R₁ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₂ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₃ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₄ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of R₁ to R₄ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
R₁₀ₐ is as described in connection with R₁, and
the substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₁₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof,
wherein Q₁ to Q₉, Q₁₁ to Q₁₉, Q₂₁ to Q₂₉, and Q₃₁ to Q₃₉ are each independently hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group that is unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group that is unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a C₂-C₆₀ alkyl heteroaryl group; a C₂-C₆₀ heteroaryl alkyl group; a C₁-C₆₀ heteroaryloxy group; a C₁-C₆₀ heteroarylthio group; a monovalent non-aromatic condensed polycyclic group; or a monovalent non-aromatic condensed heteropolycyclic group, and
wherein Formula 1 satisfies at least one of Condition A, Condition B, Condition C and Condition D:
Condition A
a group represented by *-[(L₇)_{b7}-(R₇)_{c7}] in N-[(L₇)_{b7}-(R₇)_{c7}] is a group represented by Formula N51: 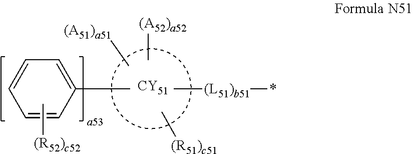
wherein, in Formula N51,
ring CY₅₁ is a C₅-C₃₀ carbocyclic group or a C₁-C₃₀ heterocyclic group,
L₅₁, b51, R₅₁, and c51 are each as described in connection with L₇, b₇, R₇, and c7,
R₅₂ and c52 are each as described in connection with R₇ and c7,
A₅₁ is a C₁-C₆₀ alkyl group,
A₅₂ is a deuterated C₁-C₆₀ alkyl group,
a51 and a52 are each independently an integer from 0 to 10, and the sum of a51 and a52 is an integer of 1 or more,
a53 is an integer from 1 to 10, and
* indicates a binding site to a neighboring nitrogen atom,
Condition B
the ring CY₁ is a condensed cyclic group wherein two or more rings are condensed with each other,
Condition C
the ring CY₃ is a condensed cyclic group wherein two or more rings are condensed with each other,
a4 is 1, 2, 3, 4, or 5, and
at least one of R₄ in number of c4 is a C₁-C₆₀ alkyl group substituted with at least one C₆-C₆₀ aryl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,
Condition D
the ring CY₄ is a condensed cyclic group wherein two or more rings are condensed with each other,
a3 is 1, 2, 3, 4, or 5, and
at least one of R₃ in number of c3 is a C₁-C₆₀ alkyl group substituted with at least one C₆-C₆₀ aryl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

2. The organometallic compound of claim 1, wherein ring CY₁ to ring CY₄ are each independently i) a first ring, ii) a second ring, iii) a condensed ring wherein two or more first rings are condensed with each other, iv) a condensed ring wherein two or more second rings are condensed with each other, or v) a condensed ring wherein one or more first rings and one or more second rings are condensed with each other,
at least one of ring CY₁ to ring CY₄ are each independently iii) a condensed cyclic group wherein two or more first rings are condensed with each other, iv) a condensed cyclic group wherein two or more second rings are condensed with each other, or v) a condensed cyclic group wherein at least one first ring is condensed with at least one second ring,
the first ring is a cyclopentane group, a cyclopentadiene group, a furan group, a thiophene group, a pyrrole group, a silole group, a germole group, a borole group, a phosphole group, a selenophene group, an oxazole group, an oxadiazole group, an oxatriazole group, a thiazole group, a thiadiazole group, a thiatriazole group, a pyrazole group, an imidazole group, a triazole group, a tetrazole group, an azasilole group, an azagermole group, an azaborole group, an azaphosphole group, or an azaselenophene group, and
the second ring is an adamantane group, a norbornane group, a norbornene group, a bicyclo[1.1.1]pentane group, a bicyclo[2.1.1]hexane group, a bicyclo[2.2.2]octane group, a cyclohexane group, a cyclohexene group, a benzene group, a pyridine group, a pyrimidine group, a pyrazine group, a pyridazine group, or a triazine group.

3. The organometallic compound of claim 1, wherein,
ring CY₁ is a naphthalene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group,
ring CY₃ is a benzene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group, and
ring CY₄ is a pyridine group, an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group.

4. The organometallic compound of claim 1, wherein,
ring CY₁ is a benzene group, a naphthalene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group,
ring CY₃ is a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group, and
ring CY₄ is a pyridine group, an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group.

5. The organometallic compound of claim 1, wherein,
ring CY₁ is a benzene group, a naphthalene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, a dinaphthosilole group, a benzene group condensed with a cyclohexane group, a benzene group condensed with an adamantane group, or a benzene group condensed with a norbornane group,
ring CY₃ is a benzene group, a fluorene group, a carbazole group, a dibenzofuran group, a dibenzothiophene group, a dibenzosilole group, a benzofluorene group, a benzocarbazole group, a naphthobenzofuran group, a naphthobenzothiophene group, a naphthobenzosilole group, a dibenzofluorene group, a dibenzocarbazole group, a dinaphthofuran group, a dinaphthothiophene group, or a dinaphthosilole group, and
ring CY₄ is an azafluorene group, an azacarbazole group, an azadibenzofuran group, an azadibenzothiophene group, an azadibenzosilole group, an azabenzofluorene group, an azabenzocarbazole group, an azanaphthobenzofuran group, an azanaphthobenzothiophene group, an azanaphthobenbenzosilole group, an azadibenzofluorene group, an azadibenzocarbazole group, an azadinaphthofuran group, an azadinaphthothiophene group, or an azadinaphthosilole group.

6. The organometallic compound of claim 1, wherein Formula 1 satisfies Condition A.

7. The organometallic compound of claim 1, wherein A₅₁ in Formula N51 is a C₄-C₂₀ alkyl group.

8. The organometallic compound of claim 1, wherein a group represented by 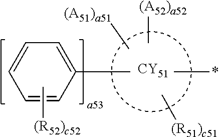
in Formula N51 is a group represented by one of Formulae 51-1 to 51-20: 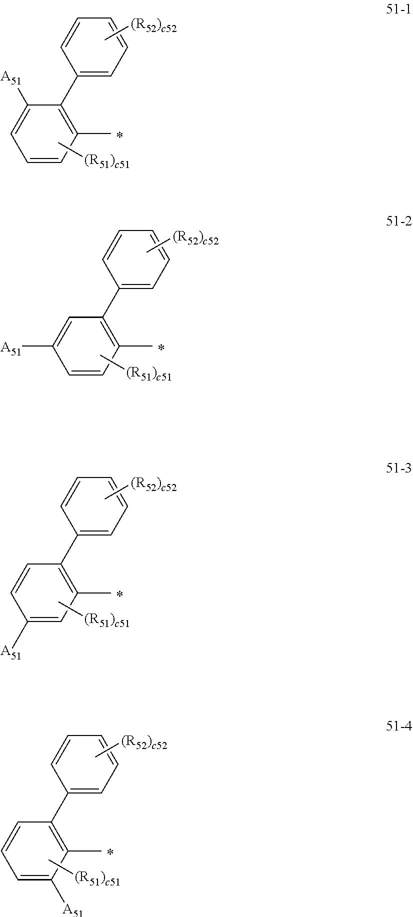 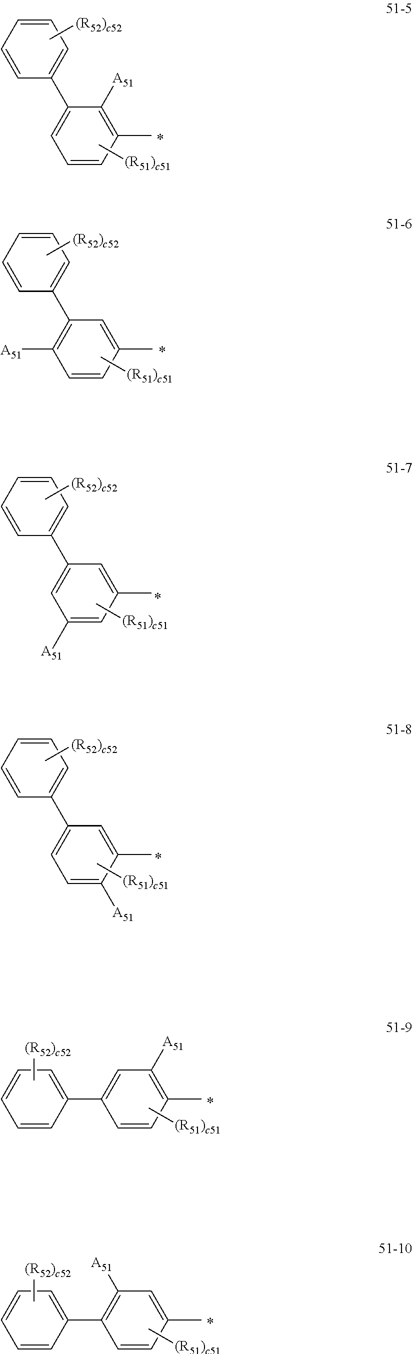 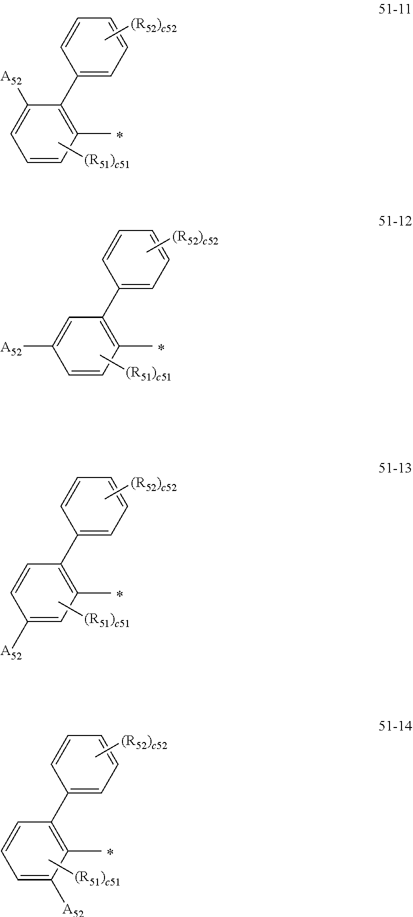 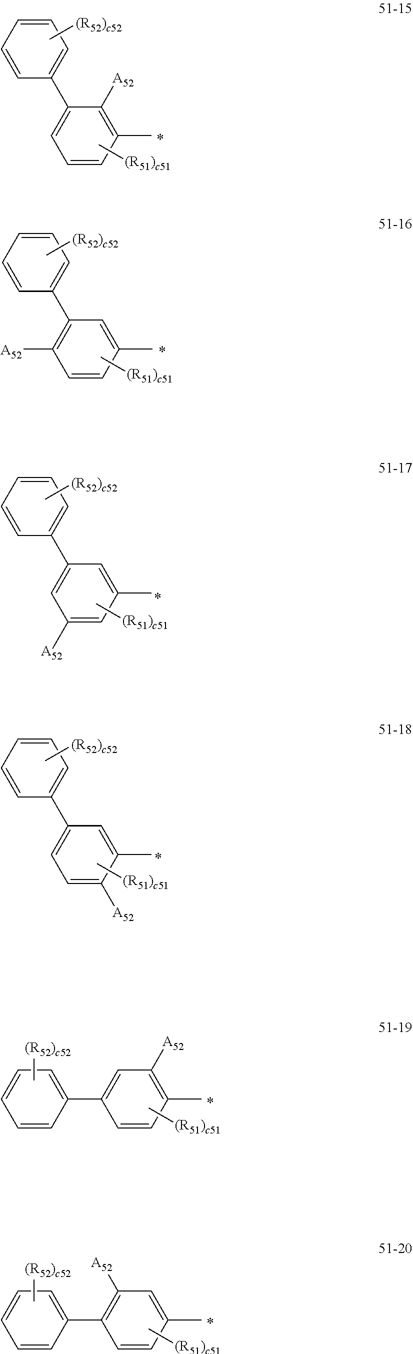
wherein, in Formulae 51-1 to 51-20, R₅₁, R₅₂, c51, c52, A₅₁ and A₅₂ are as described in claim 1, and * indicates a binding site to L₅₁.

9. The organometallic compound of claim 1, wherein Formula 1 satisfies Condition B.

10. The organometallic compound of claim 1, wherein Formula 1 satisfies Condition C.

11. The organometallic compound of claim 1, wherein Formula 1 satisfies Condition D.

12. The organometallic compound of claim 1, wherein a group represented by 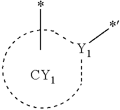
in Formula 1 is a group represented by one of Formulae CY1-1 to CY1-48: 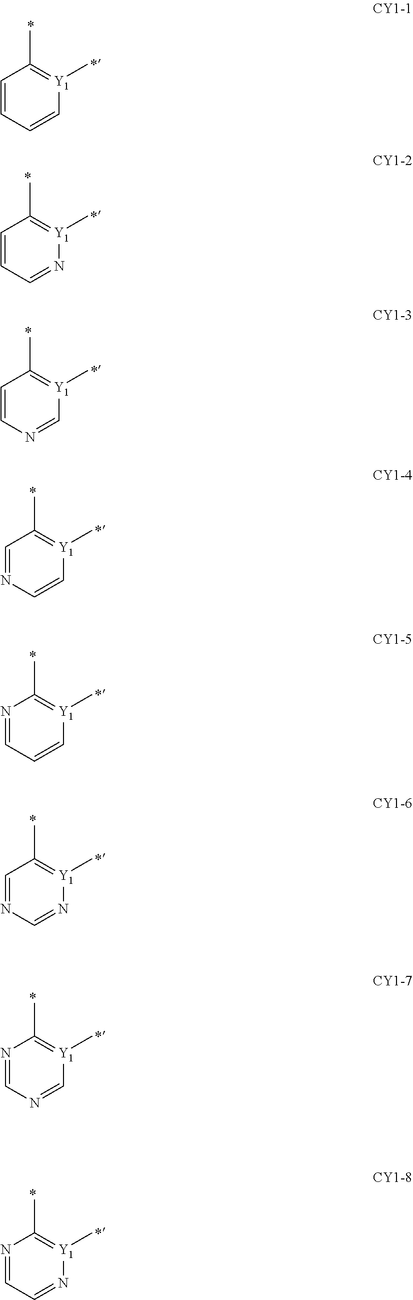 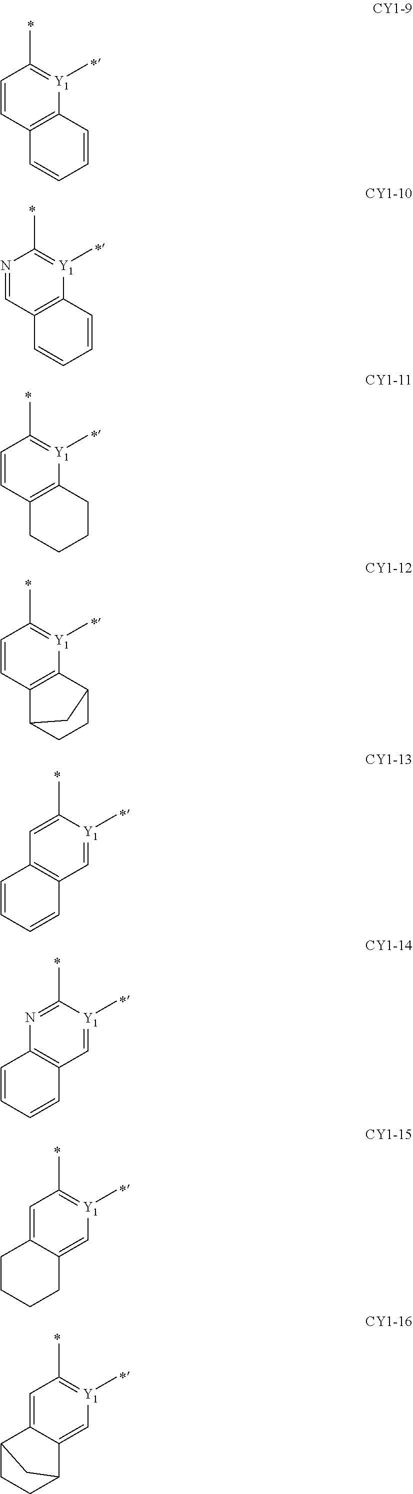 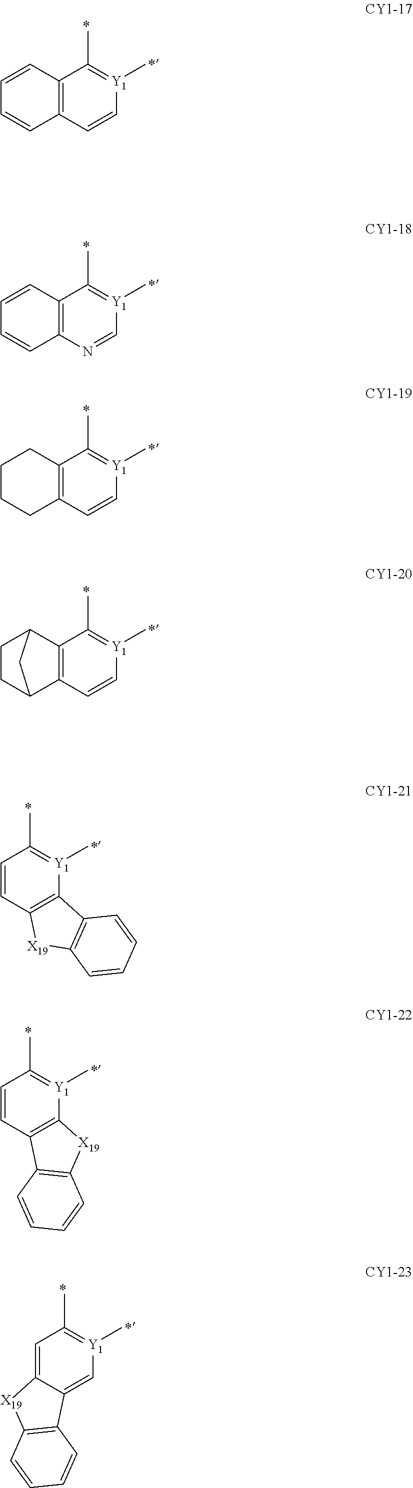 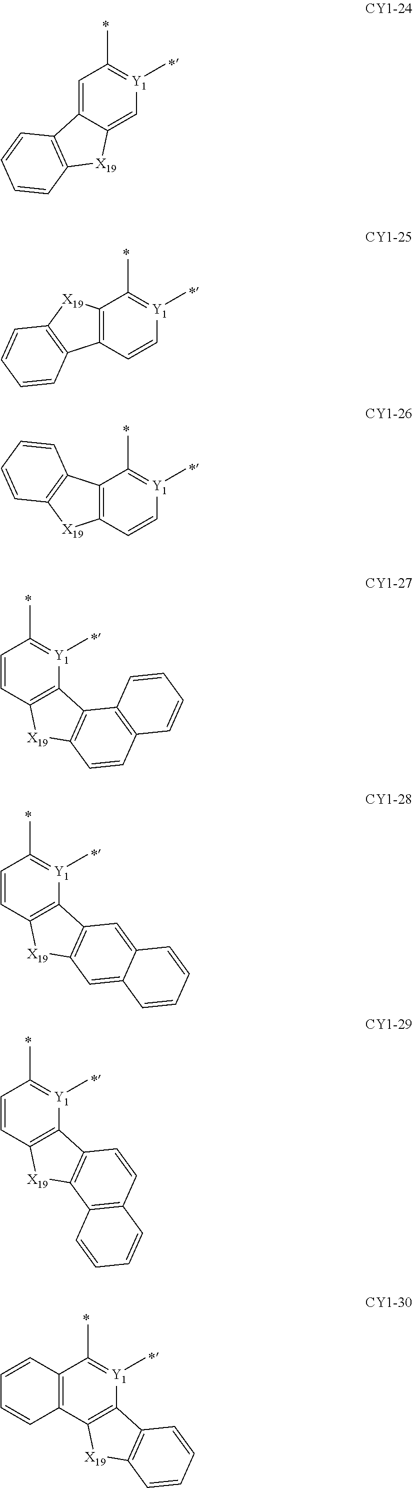 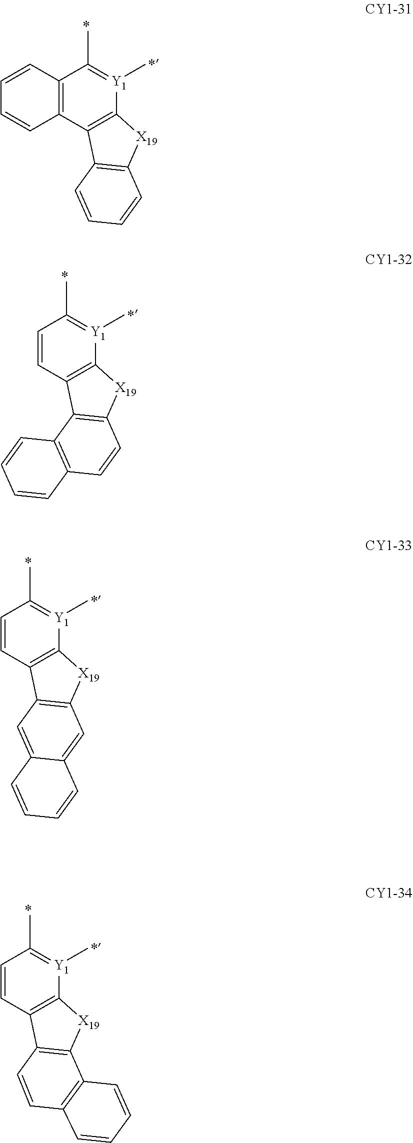 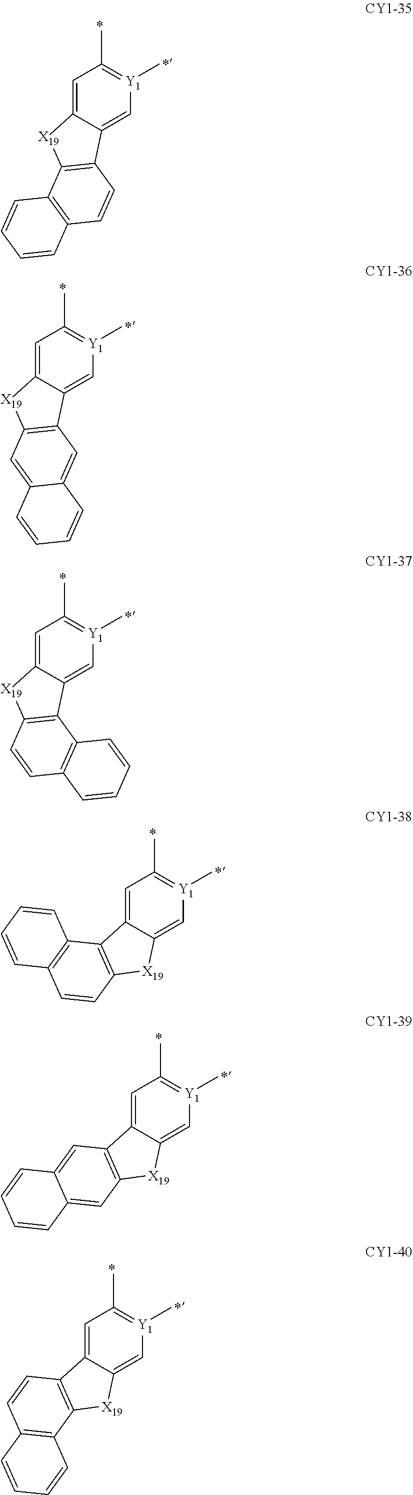 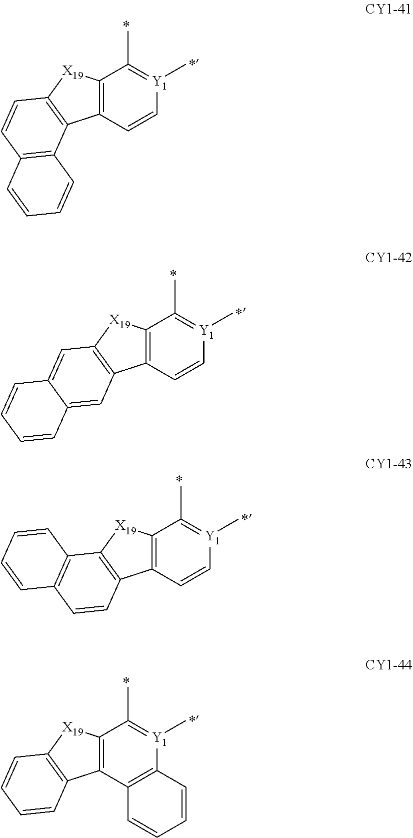 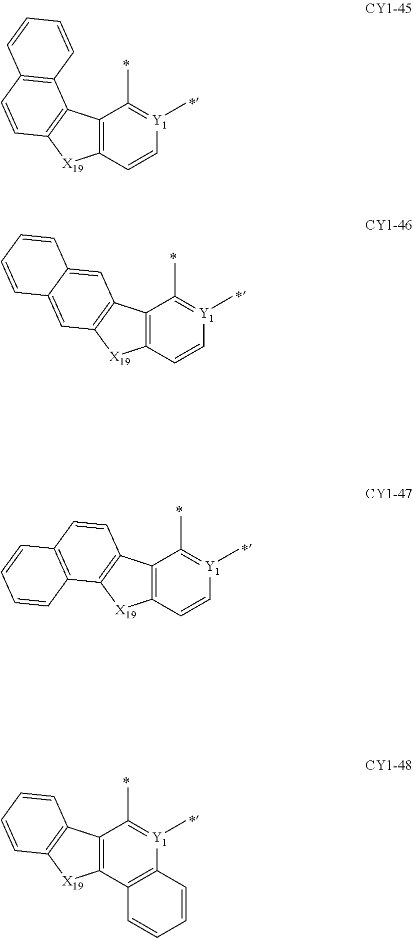
wherein, in Formulae CY1-1 to CY1-48,
Y₁ is as described in connection with claim 1,
X₁₉ is G(R₁₉ₐ)(R_{19b}), N[(L₁₉)_{b19}-(R₁₉)_{c19], 0, 8}, or Si(R₁₉ₐ)(R_{19b}),
L₁₉ is as described in connection with Li in claim 1,
b19 and c19 are as described in connection with b1 and c1 in claim 1, respectively,
R₁₉, R₁₉ₐ, and R_{19b} are as described in connection with R₁ in claim 1,
*′ indicates a binding site to X₁ or M in Formula 1, and
* indicates a binding site to ring CY₅ in Formula 1.

13. The organometallic compound of claim 1, wherein a group represented by 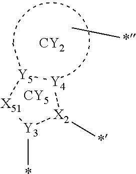
in Formula 1 is a group represented by one of Formulae CY2-1 to CY2-20: 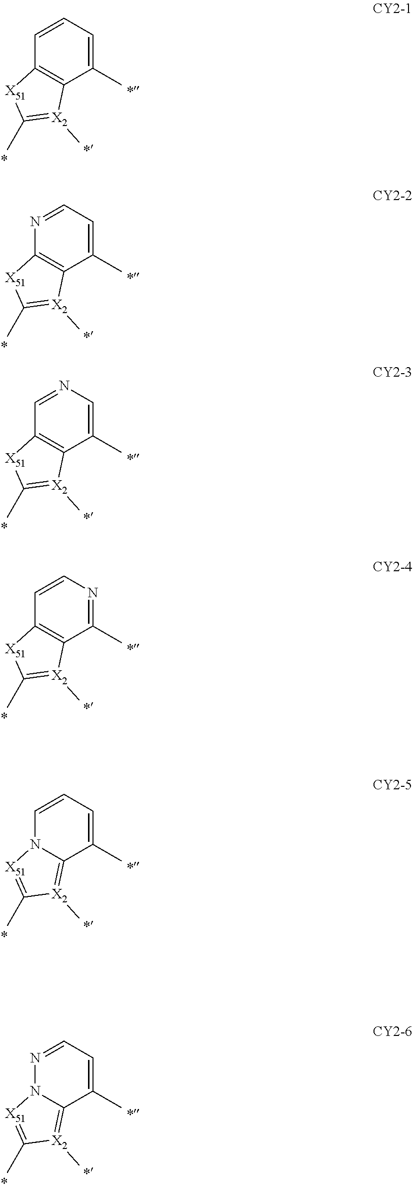 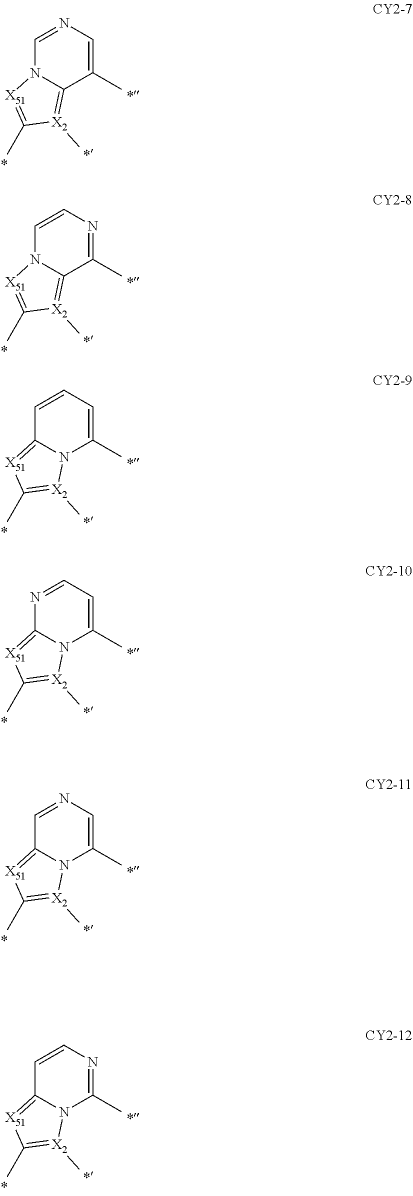 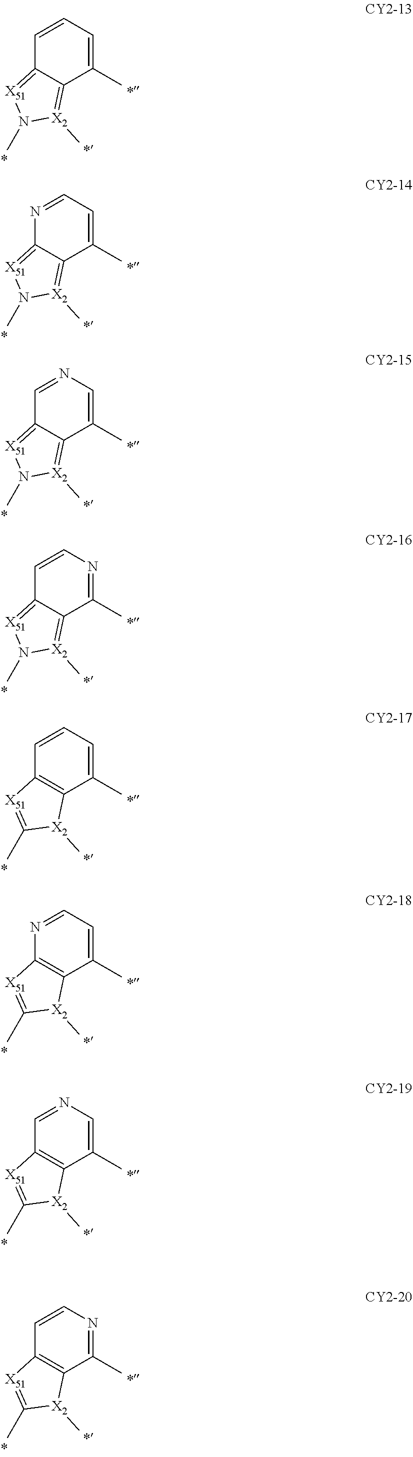
wherein, in Formulae CY2-1 to CY2-20,
X₂ and X₅₁ are each as described in connection with claim 1,
* indicates a binding site to ring CY₁ in Formula 1,
*′ indicates a binding site to M in Formula 1, and
*″ indicates a binding site to ring CY₃ in Formula 1.

14. The organometallic compound of claim 1, wherein a group represented by 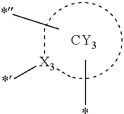
in Formula 1 is a group represented by one of Formulae CY3-1 to CY3-26: 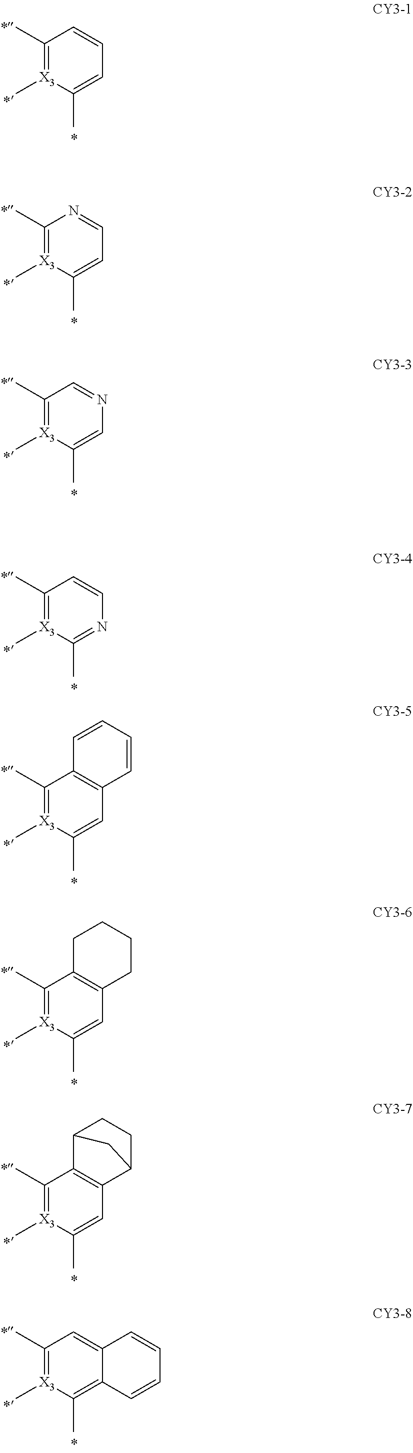 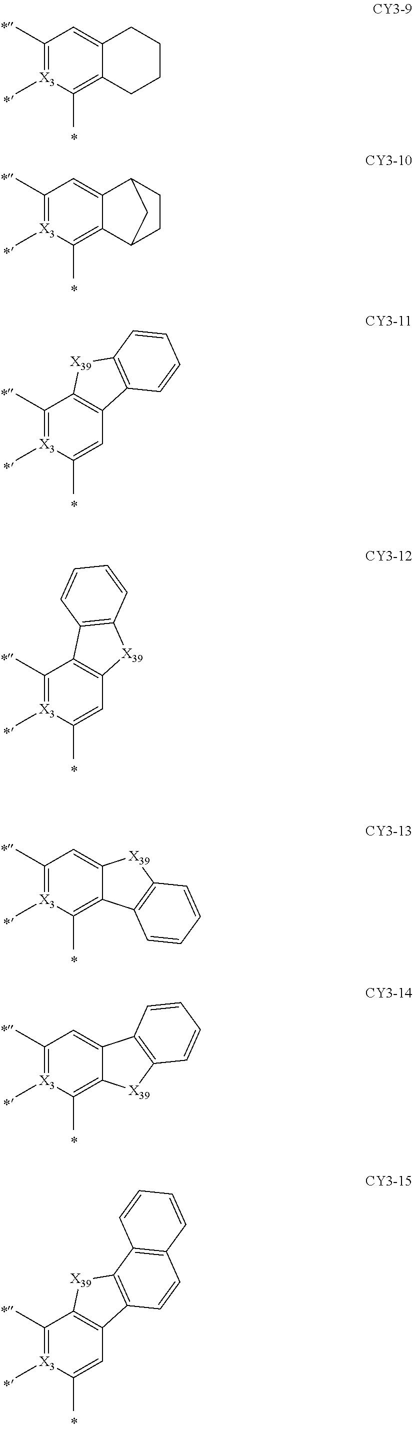 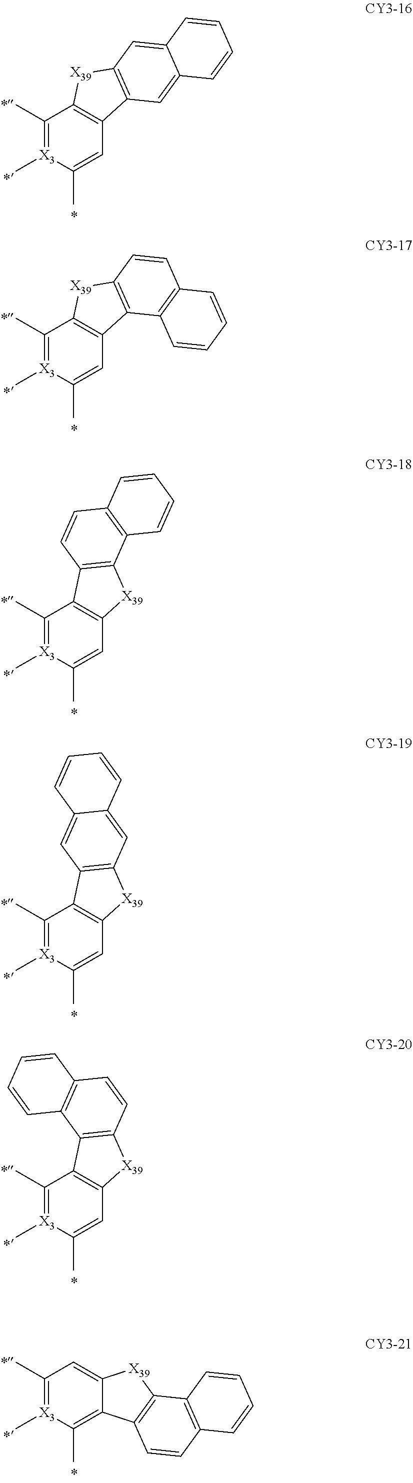 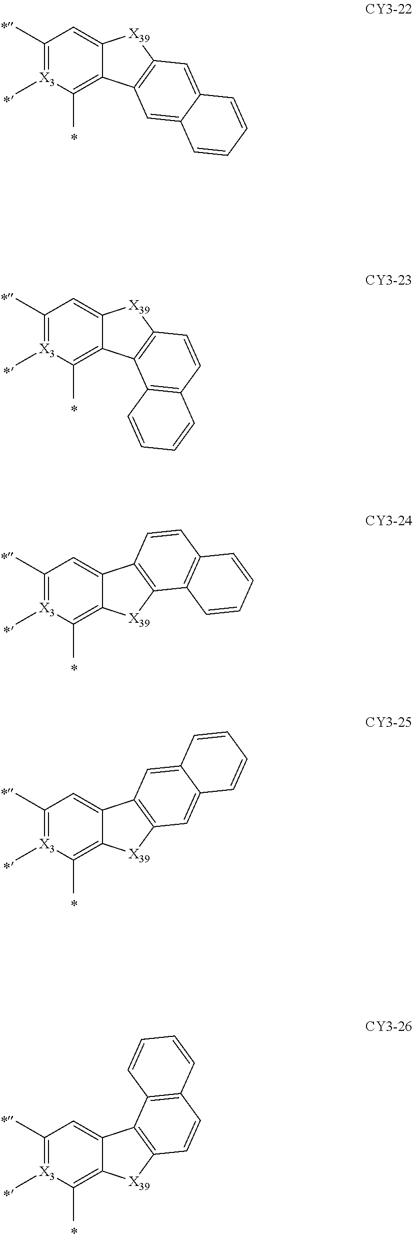
wherein, in Formulae CY3-1 to 3-26,
X₃ is as described in claim 1,
X₃₉ is C(R₃₉ₐ)(R_{39b}), N[(L₃₉)_{b39}-(R₃₉)_{c39}], O, S, or Si(R₃₉ₐ)(R_{39b}),
L₃₉ is as described in connection with L₃ in claim 1,
b39 and c39 are as described in connection with b3 and c3 in claim 1, respectively, and
R₃₉, R₃₉ₐ, and R_{39b} are each as described in connection with R₃ in claim 1,
* indicates a binding site to T₁ in Formula 1,
*′ indicates a binding site to M in Formula 1, and
*″ indicates a binding site to ring CY₂ in Formula 1.

15. The organometallic compound of claim 1, wherein a group represented by 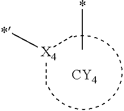
in Formula 1 is a group represented by one of Formulae CY4-1 to CY4-48: 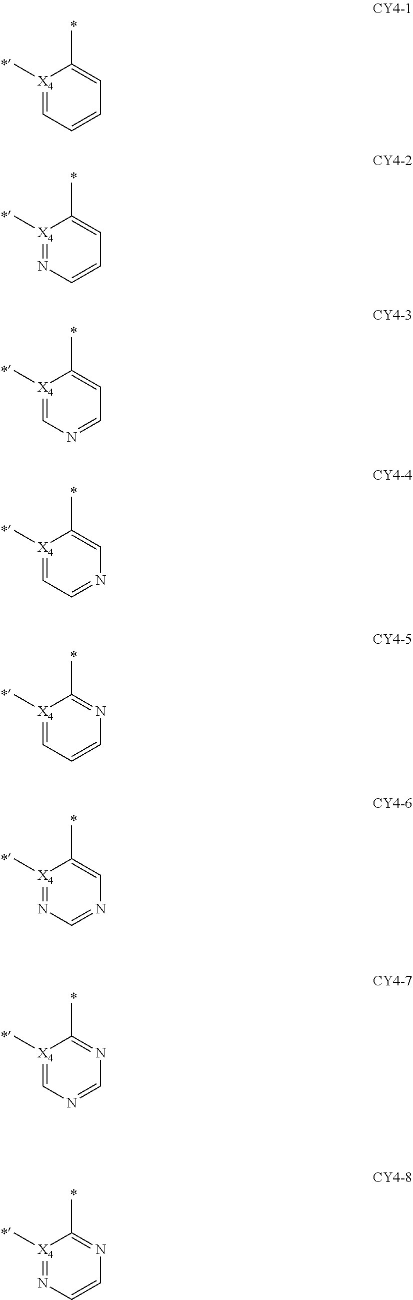 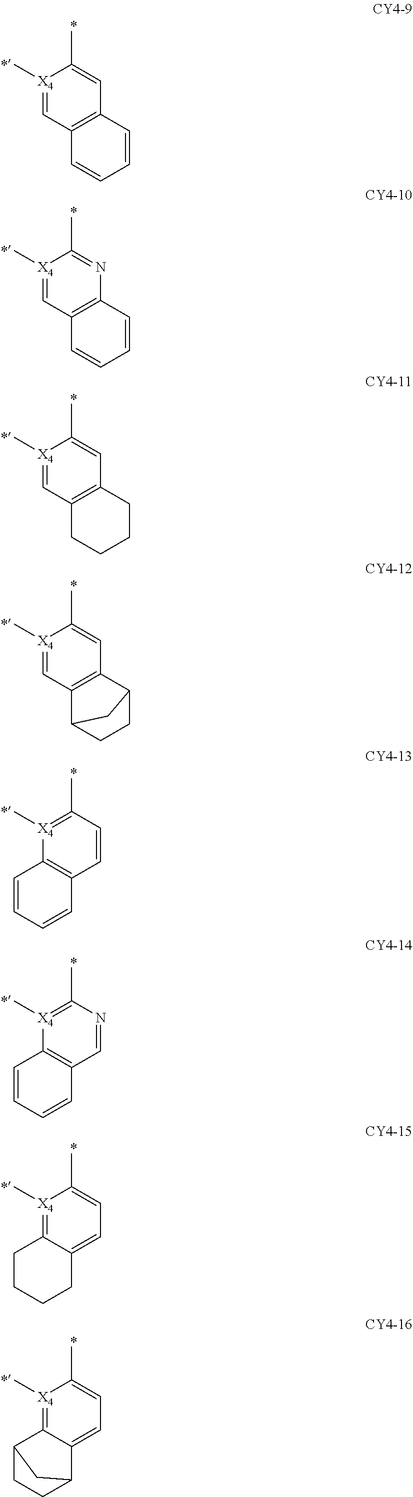 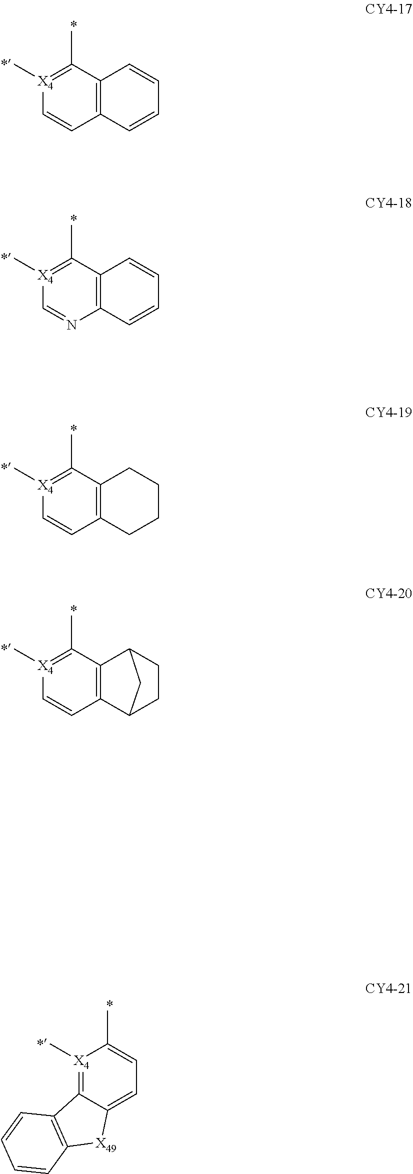 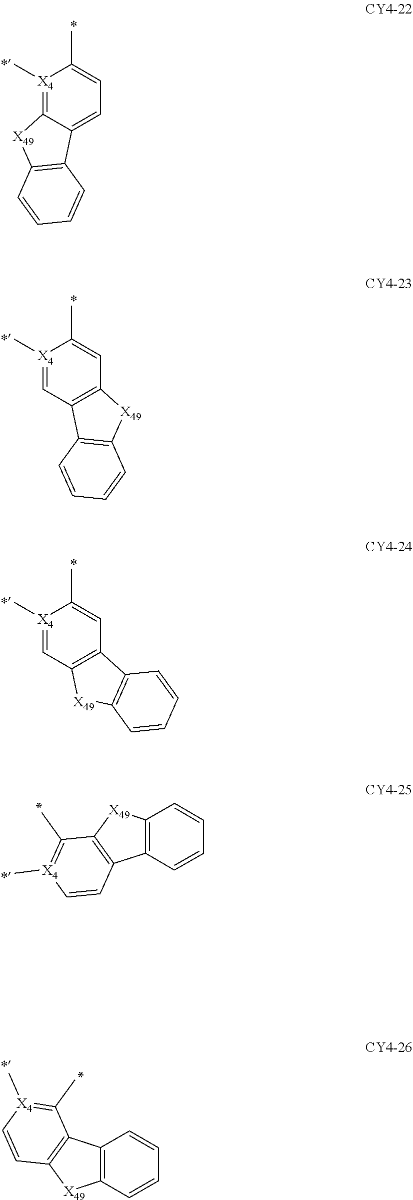 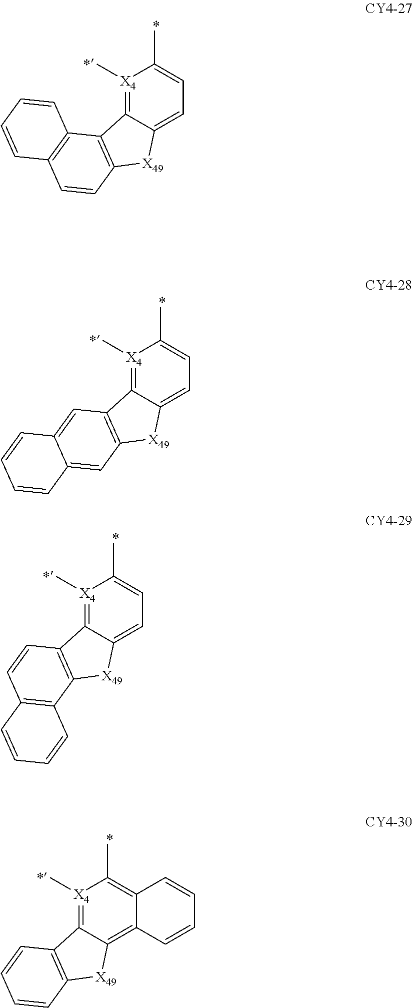 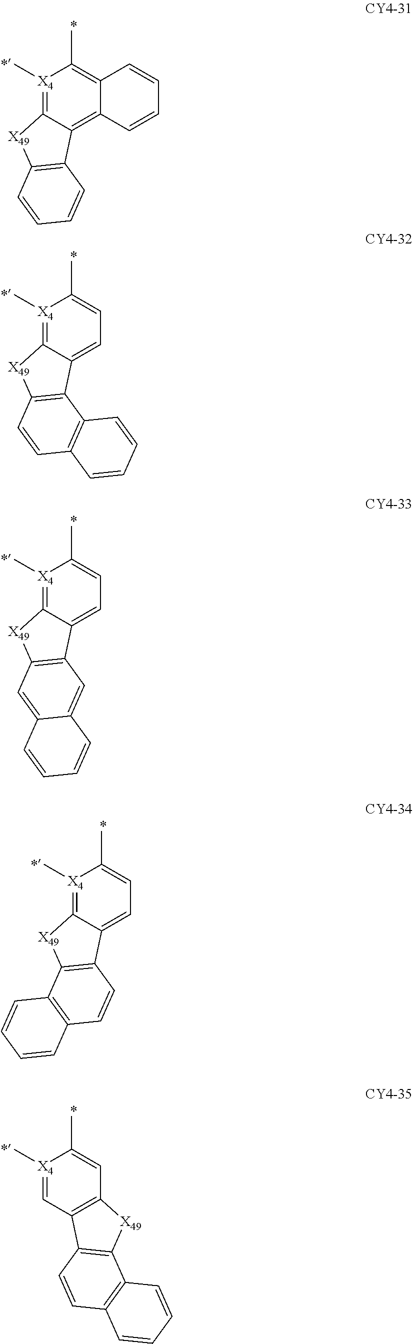 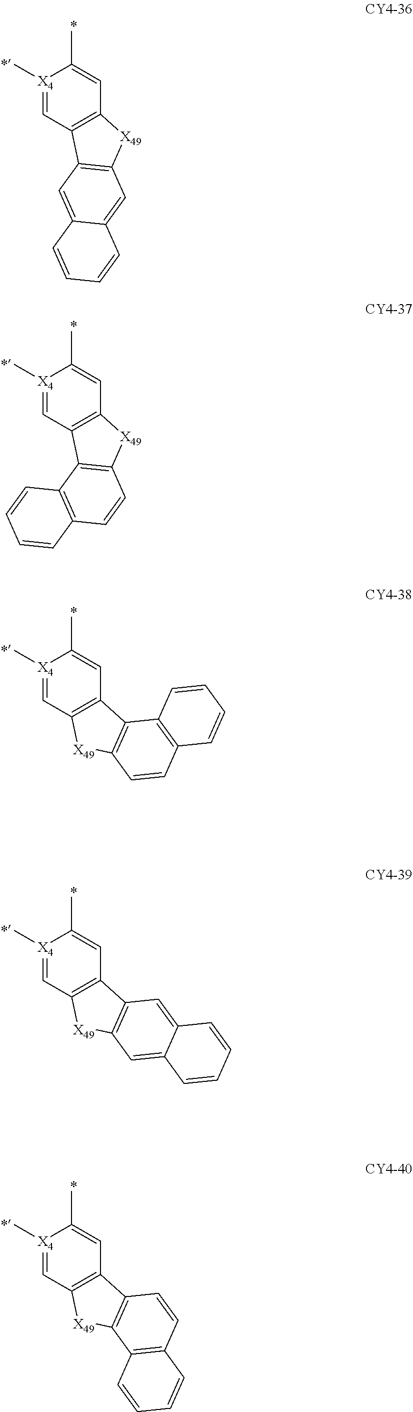 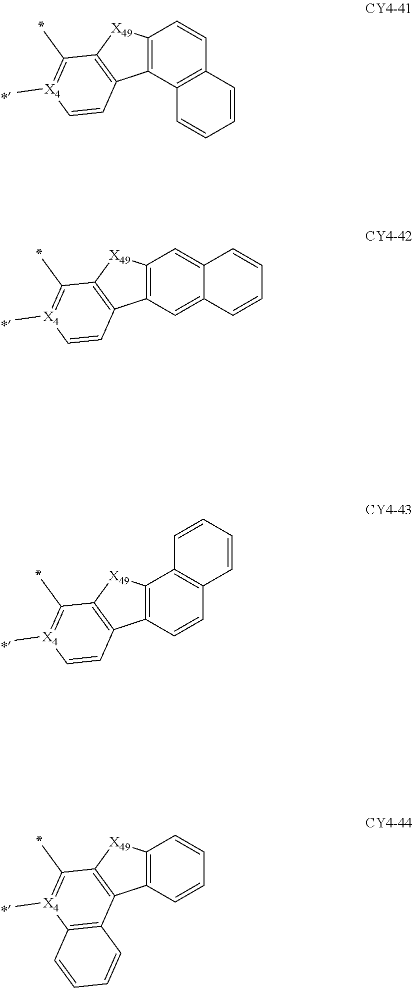 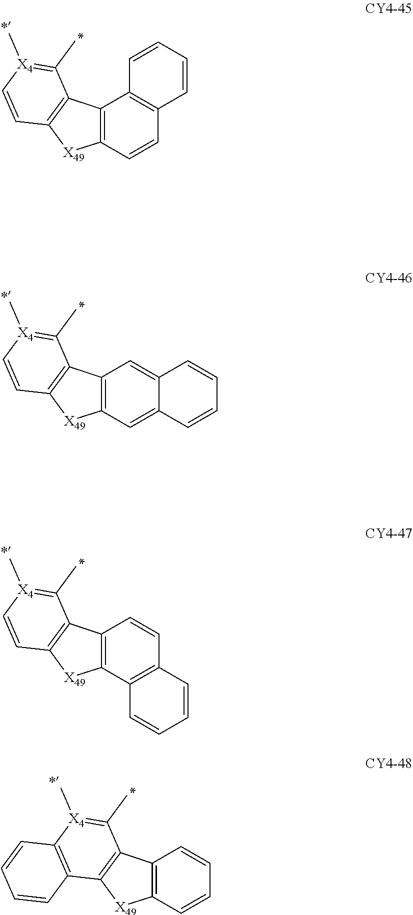
wherein, in Formulae CY4-1 to 4-48,
X₄ is as described in claim 1,
X₄₉ is C(R₄₉ₐ)(R_{49b}), N[(L₄₉)_{b49}-(R₄₉)_{c49}], O, S, or Si(R₄₉ₐ)(R_{49b}),
L₄₉ is as described in connection with L₄ in claim 1,
b49 and c49 are as described in connection with b4 and c4 in claim 1, respectively,
R₄₉, R₄₉ₐ, and R_{49b} are each as described in connection with R₄ in claim 1,
* indicates a binding site to T₁ in Formula 1, and
*′ indicates a binding site to M in Formula 1.

16. An organic light-emitting device, comprising:
a first electrode,
a second electrode, and
an organic layer located between the first electrode and the second electrode,
wherein the organic layer comprises an emission layer, and
wherein the organic layer further comprises at least one of the organometallic compound of claim 1.

17. The organic light-emitting device of claim 16, wherein
the first electrode is an anode,
the second electrode is a cathode,
the organic layer further comprises a hole transport region located between the first electrode and the emission layer and an electron transport region located between the emission layer and the second electrode,
the hole transport region comprises a hole injection layer, a hole transport layer, an electron-blocking layer, a buffer layer, or a combination thereof, and
the electron transport region comprises a hole-blocking layer, an electron transport layer, an electron injection layer, or a combination thereof.

18. The organic light-emitting device of claim 16, wherein the emission layer comprises the at least one organometallic compound.

19. The organic light-emitting device of claim 18, wherein the emission layer further comprises a host, and an amount of the host in the emission layer is greater than an amount of the organometallic compound in the emission layer.

20. An electronic apparatus, comprising the organic light-emitting device of claim 16.
